(19) United States
(12) Patent Application Publication
(10) Pub. No.: US 2011/0198730 A1
(43) Pub. Date: Aug. 18, 2011

(54) HYPERBRANCHED POLYMER SYNTHESIZING METHOD, HYPERBRANCHED POLYMER, RESIST COMPOSITION, SEMICONDUCTOR INTEGRATED CIRCUIT, AND SEMICONDUCTOR INTEGRATED CIRCUIT FABRICATION METHOD

(75) Inventors: Yuko Tanaka, Tokyo (JP); Akinori Uno, Tokyo (JP); Shinichiro Kabashima, Tokyo (JP); Minoru Tamura, Tokyo (JP); Yoshiyasu Kubo, Tokyo (JP); Yusuke Sasaki, Tokyo (JP); Mineko Horibe, Tokyo (JP); Yukihiro Kaneko, Tokyo (JP); Kaoru Suzuki, Tokyo (JP)

(73) Assignee: Lion Corporation

(21) Appl. No.: 12/521,384

(22) PCT Filed: Dec. 20, 2007
(86) PCT No.: PCT/JP2007/074579

§ 371 Date: Jun. 26, 2009

(30) Foreign Application Priority Data
Dec. 27, 2006 (JP) 2006-352037

(51) Int. Cl. H01L 29/02; C08F 12/18; C08F 257/02; H01L 21/302

(52) U.S. Cl. 257/618; 526/293; 525/292; 438/758; 257/E29.001; 257/E21.214

(57) ABSTRACT

A method of synthesizing a hyperbranched polymer by living radical polymerization of a monomer in the presence of a metal catalyst includes at least adding a compound or setting the amount of the monomer in the living radical polymerization. The compound added is at least a compound represented by R₁-A or a compound represented by R₂—B—R₃, where R₁ denotes hydrogen, an alkyl group (1-10 carbons), aryl group (1-10 carbons), or aralkyl group (7-10 carbons), A denotes a cyano group, hydroxyl group, or nitro group, R₂ and R₃ denote hydrogen, alkyl groups (1-10 carbons), aryl groups (6-10 carbons), aralkyl groups (7-10 carbons), or dialkylamino groups (2-10 carbons), and B denotes a carbonyl group or sulfonyl group. Setting of the monomer amount includes setting the amount of monomer to be mixed into a reaction system at one mixing to be less than the total monomer to be mixed with the reaction system.

### TECHNICAL FIELD

The present invention relates to a hyperbranched polymer synthesizing method, a hyperbranched polymer, a resist composition, a semiconductor integrated circuit, and a semiconductor integrated circuit fabrication method.

### BACKGROUND ART

### First Background Art

A hyperbranched polymer is a collective term for multibranched polymers having a branching structure in a repeating unit. The hyperbranched polymer is expected to be applied in various ways since the hyperbranched polymer has a unique structure actively incorporating branching instead of a string-like shape of conventional general polymers, has a nanometer-order size, and is capable of retaining a lot of functional groups on the surface.

The hyperbranched polymer is generally synthesized by first stage polymerization of ABx monomers and recently also synthesized by polymerization of monomers containing both a polymerization initiating group and a vinyl group. Such polymerization is referred to as Self-Condensing Vinyl Polymerization (SCVP).

It is proposed for the hyperbranched polymer synthesis through SCVP to use living systems such as living cationic polymerization and living radical polymerization such as an atom transfer radical polymerization method (ATRP) and NMP so as to prevent gelation due to side reactions and the spreading of molecular weight distribution exceeding a desired range. The atom transfer radical polymerization method is a living radical polymerization method causing polymerization using organic halide as an initiating agent and transition metal complex as a catalyst.

Conventionally, for example, it is reported that hyperbranched polystyrene may be acquired by polymerization in benzene or chlorobenzene or solventless system in the presence of copper(I) chloride of 4-chloromethyl styrene and 2,2′-bipyridine (see, e.g., Nonpatent Literature 1). This reaction system generates primary and secondary benzene radical species during the polymerization, affects branching structures with a difference in reactivity between the generated primary and secondary benzene radical species, generates a polymer with a lower branching degree in the case of lower concentration of copper chloride acting as a catalyst, and enables acquisition of the hyperbranched polymer with a higher branching degree as the catalyst concentration increases.

### Description of the Second Background Art

In recent years, in photo lithography expected as a promising future microfabrication technology, design rules with an emphasis on miniaturization have been progressing by a shift to a shorter wavelength in a light source, thereby realizing a high integration of a semi-conductor integrated circuit such as a very-large-scale integrated circuit. For design rules of 32 nanometers or less, EUV lithography draws a high degree of expectation.

In a resist composition, a base polymer having a chemical structure transparent to light sources has been developed. Resist compositions containing the following polymers have been proposed, for example, a polymer having a base skeleton of a novolak type polyphenol in a KrF excimer laser beam (248 nanometers wavelength) (see, for example, Patent Document 1), a poly(meth)acrylate ester in an ArF excimer laser beam (193 nanometers wavelength) (see, for example, Patent Document 2), and a polymer containing fluorine atoms (perfluoro structure) in an F2 excimer laser beam (157 nanometers wavelength) (see, for example, Patent Document 3). These polymers are based on a linear structure.

However, when these linear polymers are applied to form an ultrafine miniaturized pattern of 32 nanometers or less, the concavity and convexity of the pattern wall, which is a barometer of a line edge roughness, became a problem. It is pointed out that, to form an ultrafine pattern by irradiating an electronic beam or an extreme ultraviolet beam (EUV: 13.5 nanometers) to conventional resists composed of mainly, for example, PMMA (poly(methyl methacrylate)) and PHS (poly-hydroxystyrene), control of surface smoothness at a nanometer level will become a problem (see, for example, Nonpatent Literature 2).

It is assumed that the concavity and convexity of the pattern wall is caused by a cluster formation of polymers composing the resist (see, for example, Nonpatent Literature 3). Although it is said that a decrease of the line edge roughness due to clustering may be reduced by using a low molecular weight mono-dispersion polymer (see, for example, Patent Document 4), it lacks practicability because, when a low molecular weight polymer is used, the glass transition temperature (Tg) of the polymer is lowered, making thermal baking difficult.

On the other hand, a branched polymer is known as an example to improve the line edge roughness as compared to a linear polymer (see, for example, Nonpatent Literature 4). However, requirements in substrate adhesiveness and sensitivity accompanying the progress of design rules in terms of miniaturization have yet to be satisfied.

In view of the above, attempts to use a hyperbranched polymer as a resist material has been made in recent years. A hyperbranched polymer having a highly branching structure in a core part, and an acid group (for example, a carboxylic acid) and an acid-degradable group (for example, a carboxylate ester) in a molecular terminal has less intermolecular entanglement, which is seen in a linear polymer, and swells less by an organic solvent as compared with a molecular structure of a crosslinked main chain. It is reported that, when a resist material containing a hyperbranched polymer such as this is used, formation of a large molecular aggregate body causing surface roughness on a pattern wall is suppressed (see, for example, Patent Document 5).

A hyperbranched polymer usually takes a spherical morphology. In photo lithography, when an acid-degradable group is present on a surface of a spherical hyperbranched polymer, a degradation reaction takes place in a light-exposed part by the action of acid generated from a photo-inductive acid-generating material, thereby forming a hydrophilic group. It is reported that it became clear that this enabled a spherical micellar structure having a large number of hydrophilic groups at the periphery of the hyperbranched polymer.

A hyperbranched polymer with a spherical micellar structure having a large number of hydrophilic groups at its periphery is dissolved efficiently in an aqueous basic solution, and thus is removed along with the basic solution. It is reported that it became clear that a resist material containing a hyperbranched polymer like this enabled the formation of a fine pattern, thereby allowing it to be used suitably as a base resin in a resist material. In addition, it became clear that solubility in a basic solution after optical exposure, namely sensitivity, can be improved when the core part and the shell part exist at a specific value, and also the acid-degradable carboxylate ester group and the carboxylic acid group coexist at a specific ratio in the shell part.

Generally, when a hyperbranched polymer having a core part with a highly branched structure and containing in its molecular terminal an acid-degradable group and an acid group, for example, a carboxylic acid group and a carboxylate ester group, at a specific ratio is synthesized by the ATRP method (atom transfer radical polymerization), the synthesis can be performed via the following steps (a) and (b).

(a) A step of synthesizing a core part in the presence of a metal catalyst, thereby introducing an acid-degradable group (a carboxylate ester group) (hereinafter, “shell part”) to the core part.

(b) A step of obtaining a carboxylic acid group (hereinafter, “acid group”) by partially degrading the carboxylate ester group (hereinafter, “de-esterification” or “deprotection”) in such a manner as to obtain an optimum base-solubility when exposed to light.

When a hyperbranched polymer is synthesized by the ATRP method, which enables the step (a) and the step (b) and has a high practicality because of the availability of raw materials and an ease of up-scaling, a metal catalyst such as a copper is used in the synthesis. Because of this, when a hyperbranched polymer is synthesized by the ATRP method, the removal of metal is indispensable to prevent adverse effects on subsequent processes. A metal catalyst is also used in the step of introducing the acid-degradable group into the core part. If a large amount of metals derived from the metal catalyst remain in the core part after the core part synthesis, there is a risk of causing adverse effects such as particularly large change in the reactivity and insolubilization of a resist composition containing the hyperbranched polymer after exposure to light. Accordingly, it is necessary to remove the metal to a level not causing significant effects.

In the past, a method such as a column fractionation (see, for example, Patent Document 6), an alumina adsorption (see, for example, Patent Document 5), has been known for removal of the metal catalyst.

When the hyperbranched polymer is contaminated by monomer and by-product oligomer, there is also a risk of adverse effects such as insolubilization of a resist composition containing the hyperbranched polymer after exposure to light. Accordingly, it is desirable that impurities such as monomer used for polymerization to the hyperbranched polymer and by-product oligomer be removed appropriately. In the past, as a method of removing monomer and oligomer, a method of washing by a solvent mixture of a good solvent and a poor solvent has been known; however, a conventional method like this has problems in that the number of the washing operations needs to be increased and a large amount of solvent is used to achieve high removal efficiency.

### Description of the Third Background Art

In recent years, in photo lithography expected as a promising future microfabrication technology, design rules with an emphasis on miniaturization have been progressing by a shift to a shorter wavelength in a light source, thereby realizing a high integration of a very-large-scale integrated circuit. For design rules of 32 nanometers or less, UV lithography draws a high degree of expectation.

In a resist composition, a base polymer having a chemical structure transparent to light sources has been developed. Resist compositions containing the following polymers have been proposed, for example, a polymer having a base skeleton of a novolak type polyphenol in a KrF excimer laser beam (248 nanometers wavelength) (Patent Document 1), a poly(meth)acrylate ester in an ArF excimer laser beam (193 nanometers wavelength) (Patent Document 2), and a polymer containing fluorine atoms (perfluoro structure) in an F2 excimer laser beam (157 nanometers wavelength) (Patent Document 3). These polymers are based on a linear structure.

However, when these linear polymers are applied to form an ultrafine miniaturized pattern of 32 nanometers or less, the concavity and convexity of the pattern wall, which is a barometer of a line edge roughness, became a problem. In Nonpatent Literature 2, it is pointed out that, to form an ultrafine pattern by irradiating an electronic beam or an extreme ultraviolet beam (EUV: 13.5 nanometers) to conventional resists composed of mainly PMMA (poly(methyl methacrylate)) and PHS (poly-hydroxystyrene), control of surface smoothness at a nanometer level will become a problem.

According to Nonpatent Literature 3, it is assumed that the concavity and convexity of the pattern wall is caused by a cluster formation of polymers composing the resist. Although it is said that a decrease of the line edge roughness due to clustering may be reduced by using a low molecular weight mono-dispersion polymer (Patent Document 4), it lacks practicability because, when a low molecular weight polymer is used, the glass transition temperature (Tg) of the polymer is lowered, making thermal baking difficult.

On the other hand, a branched polymer is known as an example to improve the line edge roughness as compared to a linear polymer (Nonpatent Literature 4). However, requirements in substrate adhesiveness and sensitivity accompanying the progress of the design rules in terms of miniaturization have yet to be satisfied.

In view of the above, in recent years attempts have been made to use a hyperbranched polymer as a resist material. According to Patent Document 5, it is reported that a hyperbranched polymer having a highly branching structure in a core part, and an acid group (for example, a carboxylic acid) and an acid-degradable group (for example, a carboxylate ester) in a molecular terminal has less intermolecular entanglement, which is seen in a linear polymer, and swells less by an organic solvent as compared with a molecular structure of a crosslinked main chain, thereby suppressing formation of a large molecular aggregate body which causes surface roughness on a pattern wall.

Further, it is reported that it became clear that, although a hyperbranched polymer usually takes a spherical morphology, in photo lithography, when an acid-degradable group is present on a surface of a spherical hyperbranched polymer, a degradation reaction takes place in the exposed part by the action of acid generated from a photo-inductive acid-generating material, thereby forming a hydrophilic group and thus enabling a spherical micellar structure having a large number of hydrophilic groups at the periphery of the hyperbranched polymer.

It is reported that it became clear that, because of this, the polymer can be dissolved efficiently in an aqueous basic solution and removed along with the basic solution, thereby enabling formation of a fine pattern and thus, is advantageously usable as a base resin in a resist material. In addition, it has become clear that an improvement of solubility in a basic solution after optical exposure, namely an improvement of the sensitivity, can be achieved when the acid-degradable carboxylate ester group and the carboxylic acid group coexist at a specific ratio.

Generally, a hyperbranched polymer having a core part with a highly branched structure and containing an acid-degradable group and an acid group, for example, a carboxylic acid group and a carboxylate ester group, at a specific ratio in its molecular terminal may be synthesized by the ATRP method (atom transfer radical polymerization) via the following steps.

(a) A step of synthesizing a core part in the presence of a metal catalyst, thereby introducing an acid-degradable group (a carboxylate ester group) to the core part; and

(b) A step of obtaining a carboxylic acid group (acid group) by partially degrading the carboxylate ester group (de-esterification or deprotection) in such a manner as to obtain an optimum base-solubility when exposed to light.

The ATRP method, which enables the above steps, has a high practicality because of the availability of raw materials and ease of up-scaling. However, because a metal catalyst such as copper is used, metal removal is indispensable. In a high performance photo resist polymer, the amount of metal impurities needs to be reduced markedly to avoid pollution in plasma treatment and prevent any adverse effects on electrical properties of a semi-conductor due to metal impurities remaining in a pattern.

The methods for removing metals after a photo resist polymer is synthesized by the ATRP method, namely, for example, the column fractionation after step (b) (Patent Document 6) and the alumina adsorption after step (a) (Patent Document 5), are known; however, both are costly and thus, not suitable for industrialization.

On the other hand, as a method to remove a small amount of metals, methods using an ion-exchange resin and an acidic water wash are known (Patent Documents 7 and 8). However, these methods have problems in that removal of the large amount of metals used in such a method as the ATRP method is difficult, and in addition, particularly in the polymer of the present invention containing a carboxylic acid group and an acid-degradable group in its terminal, the carboxylic acid group forms a chelate with metal, and further the acid-degradable group is degraded by protons generated from the ion-exchange resin, thereby causing a change in the ratio of the carboxylate ester group to the carboxylic acid group.

### Description of the Fourth Background Art

“Hyperbranched polymer” is a general term for a multi-branched polymer having a branching structure in its repeating units. The hyperbranched polymer has a specific structure having intentionally introduced branches, while a conventional linear polymer is generally in the form of a string. The polymer is in the size of nanometers and can have many functional groups on its surface. Because of these characteristics, the polymer is expected to have various applications.

In the past, there is a technology in which, for example, the core part is firstly formed by polymerizing monomers by a living radical polymerization in the presence of a metal catalyst, then the acid-degradable group is introduced to the core part formed therein to form the shell part, and subsequently the acid group is formed by partially degrading the acid-degradable group in the shell part by using an acid catalyst to synthesize the core-shell type hyperbranched polymer.

A hyperbranched polymer like this is applied, for example, to a resist composition in a photo-resist. It is known that in a resist composition, when impurities such as unreacted monomers and the hyperbranched polymer are concomitantly present, polymerization of the hyperbranched polymer progresses with time, resulting in an increase in molecular weight and thereby, leading to a decrease in the degree of resolution in the photo resist process.

Accordingly, to obtain a high degree of resolution in the photo resist process regardless of the elapse of time, resist compositions, using the core-shell type hyperbranched polymer with a suppressed formation of the photopolymer assembly and an excellent dissolving contrast (see, for example, Patent Document 5) and the hyperbranched polymer from which surface-active sub-micron particles that accelerate polymerization are removed by filtration (see, for example, Nonpatent Literature 5), or the like, are known.

### Description of the Fifth Background Art

“Hyperbranched polymer” is a general term for a multi-branched polymer having a branching structure in its repeating units. The hyperbranched polymer has a specific structure having intentionally introduced branches, while a conventional linear polymer is generally in the form of a string. The polymer is in the size of nanometers and can have many functional groups on its surface. Because of these characteristics, the polymer is expected to have various applications. The hyperbranched polymer may be synthesized by polymerizing monomers by a living radical polymerization in the presence of a metal catalyst.

In the past, it was reported that a hyperbranched polystyrene could be obtained as a hyperbranched polymer, for example, by polymerizing 4-chlorostyrene in the presence of copper (I) chloride and 2,2′-bipyridine in benzene, chlorobenzene, or without a solvent (see, for example, Nonpatent Literature 1). In addition, there is a technology designing the core-shell type hyperbranched polymer having the hyperbranched polymer as the core part by a graft polymerization of the hyperbranched polymer chain at its terminal with a monomer (see, for example, Patent Document 9).
Patent Document 1: Japanese Patent Application Laid-Open Publication No. 2004-231858
Patent Document 2: Japanese Patent Application Laid-Open Publication No. 2004-359929
Patent Document 3: Japanese Patent Application Laid-Open Publication No. 2005-91428
Patent Document 4: Japanese Patent Application Laid-Open Publication No. H6-266099
Patent Document 5: International Publication Pamphlet No. WO 2005/061566
Patent Document 6: Japanese Patent Application Laid-Open Publication No. 2003-268057
Patent Document 7: Japanese Patent Application Publication No. H7-504762
Patent Document 8: Japanese Patent Application Laid-Open Publication No. H5-019463
Patent Document 9: Japanese Patent Application Publication No. 2000-514479
Nonpatent Literature 1: JEAN M. J. Frechet, J. Poly. Sci., 36, 955 (1998)
Nonpatent Literature 2: Franco Cerrina, Vac. Sci. Tech. B, 19, 2890 (2001)
Nonpatent Literature 3: Toru Yamaguti, Jpn. J. Appl. Phys., 38, 7114 (1999)
Nonpatent Literature 4: Alexander R. Trimble, Proceedings of SPIE, 3999, 1198 (2000)
Nonpatent Literature 5: Realize Science & Engineering Center Co., “Semiconductor/Liquid Crystal Display Photolithography Technology Handbook”, 75, 2006

### DISCLOSURE OF INVENTION

### Problem to be Solved by the Invention

### (Problem to Be Solved by First Aspect of the Present Invention)

In the conventional technology above, if the catalyst concentration is increased to acquire a hyperbranched polymer with a higher branching degree, the polymerization rate is accelerated, resulting in a rapid increase in the molecular weight of the polymer, and therefore, it is problematically difficult to accurately acquire a hyperbranched polymer having a molecular weight at a desired range. The above conventional technology also has a problem in that molecules cause a coupling reaction and form a gel with each other if the catalyst concentration is too high.

To solve the above problem of the conventional technology, an object of the present invention is to provide a hyperbranched polymer synthesizing method capable of stable acquisition of a hyperbranched polymer having a desired molecular weight while maintaining a higher branching degree.

### (Problem to Be Solved by Second Aspect of the Present Invention)

Further, the conventional technology above has a problem in that the each method is costly and inappropriate for industrialization. If an absorbent such as alumina is used, the conventional technology of removing metal catalyst has a problem in that metal is inevitably mixed in the hyperbranched polymer due to elution of metal, for example, aluminum derived from absorbent.

To solve the above problem of the conventional technology, an object of the present invention is to provide a hyperbranched polymer synthesizing method capable of simple and stable mass synthesis of a hyperbranched polymer, a hyperbranched polymer, a resist composition, a semiconductor integrated circuit, and a semiconductor integrated circuit producing method.

### (Problem to Be Solved by Third Aspect of the Present Invention)

Therefore, an object of the present invention is to provide a simple method of synthesizing a core-shell hyperbranched polymer containing an acid-degradable group and an acid group in a shell portion and having a reduced metal content.

### (Problem to Be Solved by Fourth Aspect of the Present Invention)

The above conventional technology further has a problem that increase in molecular weight due to progress over time in polymerization of the hyper branch polymer cannot be prevented sufficiently.

To solve the above problem of the conventional technology, an object of the present invention is to provide a hyperbranched polymer synthesizing method capable of improving the long-term stability of the resolution performance of a hyperbranched polymer utilizable in a resist composition.

### (Problem to Be Solved by Fifth Aspect of the Present Invention)

Further, the hyperbranched polymer easily forms gel depending on temperature at the time of distilling off solvent or drying after the distilling-off of solvent even in the absence of solvent due to a complicated branching structure unlike linear polymers, the conventional technology problematically requires cumbersome temperature control and is troublesome.

To solve the above problem of the conventional technology, an object of the present invention is to provide a hyperbranched polymer synthesizing method capable of stably acquiring the hyperbranched polymer having a desired molecular weight without considerably increasing a molecular weight due to progression of the cross-linking reaction between hyperbranched polymer molecules, a hyperbranched polymer, a resist composition, a semiconductor integrated circuit, and a semiconductor integrated circuit producing method.

### Means for Solving Problem

### (Means for Solving the First Problem)

To solve the above problem and achieve an object, a hyperbranched polymer synthesizing method according to the present invention is a hyperbranched polymer synthesizing method of synthesizing a hyperbranched polymer by causing living radical polymerization of a monomer in the presence of a metal catalyst, wherein among (1) and (2) below, at least one is performed in the living radical polymerization.

(1) At least a compound represented by R₁-A or a compound represented by R₂—B—R₃ is added. R₁ of the compound denotes a hydrogen atom, an alkyl group having 1 to 10 carbon atoms, an aryl group having 1 to 10 carbon atoms, or an aralkyl group having 7 to 10 carbon atoms. A of the compound denotes a cyano group, a hydroxyl group, or a nitro group. R₂ and R₃ of the compound denote hydrogen, alkyl groups having 1 to 10 carbon atoms, aryl groups having 6 to 10 carbon atoms, aralkyl groups having 7 to 10 carbon atoms, or dialkylamino groups having 2 to 10 carbon atoms. B of the compound denotes a carbonyl group or a sulfonyl group.

(2) Each mixing amount of the monomer into a reaction system is made less than a total amount of the monomer to be mixed with the reaction system.

According to the present invention, the rapid increase in the molecular weight can be prevented to stably synthesize the hyperbranched polymer having the desired molecular weight and branching degree.

At (2) above, in the hyperbranched polymer synthesizing method according to the present invention, the monomer is mixed multiple times.

According to the present invention, by a simple method, the rapid increase in the molecular weight can be prevented to stably synthesize the hyperbranched polymer having a desired molecular weight and branching degree.

At (2) above in the hyperbranched polymer synthesizing method according to the present invention, the monomer is mixed by dropping for a predetermined time period.

According to the present invention, the rapid increase in the molecular weight can be prevented to stably synthesize the hyperbranched polymer having a desired molecular weight and branching degree with a simple method.

A hyperbranched polymer according to the present invention is manufactured according to the hyperbranched polymer synthesizing method.

According to the present invention, the hyperbranched polymer having a desired molecular weight and branching degree can stably be acquired.

A resist composition according to the present invention contains the hyperbranched polymer.

According to the present invention, the resist composition containing the hyperbranched polymer having a desired molecular weight and branching degree can be acquired stably.

A semiconductor integrated circuit according to the present invention has a pattern formed with the resist composition through the electron-beam, deep-ultraviolet (DUV), or extreme-ultraviolet (EUV) lithography.

According to the present invention, a highly-integrated, high-capacity semiconductor integrated circuit having stable performance can be acquired.

A semiconductor integrated circuit manufacturing method according to the present invention includes a step of forming a pattern with the use of the resist composition through the electron-beam, deep-ultraviolet (DUV), or extreme-ultraviolet (EUV) lithography.

According to the present invention, a highly-integrated, high-capacity semiconductor integrated circuit having stable performance can be manufactured.

### (Means for Solving the Second Problem)

To solve the above problem and achieve an object, a hyperbranched polymer synthesizing method according to the present invention is a hyperbranched polymer synthesizing method of synthesizing a hyperbranched polymer by polymerizing a monomer capable of living radical polymerization in the presence of a metal catalyst, including a precipitation generating step of generating a precipitate by mixing two or more mixed solvents each having a solubility parameter of 10.5 or more in a reaction solution containing a hyperbranched polymer synthesized by the living radical polymerization.

According to the present invention, since impurities such as metal catalyst, monomer, and by-product oligomer can be removed easily without using absorbent, the hyperbranched polymer can be synthesized easily and stably in large amounts.

At the precipitation generating step of the hyperbranched polymer synthesizing method according to the present invention, the precipitate is generated by mixing 0.2 to 10 parts by volume of a mixed solvent consisting of two or more solvents and having a solubility parameter of 10.5 or more (hereinafter, a solvent A in some cases) based on the reaction solution.

According to the present invention, since impurities such as metal catalyst, monomer, and by-product oligomes can be removed easily without using absorbent, the hyperbranched polymer may be further easily and stably synthesized in large amounts.

In the present invention, the precipitate generated by mixing the solvent A into the reaction solvent containing the hyperbranched polymer synthesized by the living radical polymerization is dissolved by adding a solvent having a solubility parameter of 7 to 10.5 (hereinafter, a solvent B in some cases), and a precipitate is generated again by further adding a solvent having a solubility parameter of 10.5 or more (hereinafter, a solvent C in some cases). The step of dissolving the precipitate with the solvent B and causing the reprecipitation with the solvent C may be repeated multiple times.

In the hyperbranched polymer synthesizing method according to the present invention, the hyperbranched polymer synthesizing method includes a step of using the precipitate generated at the precipitation generating step as a core portion to generate a core-shell hyperbranched polymer including a shell portion formed by introducing an acid-degradable group into the core portion, and a step of forming an acid group by using an acid catalyst to degrade a portion of the acid-degradable group constituting the shell portion of the core-shell hyperbranched polymer generated at the above step.

A hyperbranched polymer according to the present invention is synthesized according to the hyperbranched polymer synthesizing method.

According to the present invention, since impurities such as metal catalyst, monomer, and by-product oligomer can be removed easily without using absorbent, a hyperbranched polymer having stable quality can be acquired in large amounts with impurities such as metal catalyst, monomer, and by-product oligomer removed.

A resist composition according to the present invention includes the hyperbranched polymer.

According to the present invention, occurrence of adverse effects such as considerable changes in reactivity and insolubilization after exposure can be reduced.

A semiconductor integrated circuit according to the present invention has a pattern formed with the resist composition.

According to the present invention, a semiconductor integrated circuit having an ultrafine circuit pattern formed can be acquired.

A semiconductor integrated circuit manufacturing method according to the present invention includes a step of forming an ultrafine circuit pattern with the use of the resist composition.

According to the present invention, a semiconductor integrated circuit having an ultrafine circuit pattern formed can be produced.

### (Means for Solving the Third Problem)

To solve the above problem, as a result of keen examinations, the present inventors have found that removing metals in the middle of a synthesizing step can considerably reduce the metals and keep variations in the rate of the acid group and the acid-degradable group in the shell portion at a lower level in the synthesis of the hyperbranched polymer containing a carboxylic acid and a carboxylic acid ester at terminals.

The present invention provides a hyperbranched polymer synthesizing method of a core-shell hyperbranched polymer having an acid group and an acid-degradable group in a shell portion, including:

(A) a step of synthesizing a core portion by polymerizing a monomer capable of living radical polymerization in the presence of a metal catalyst to form the shell portion by introducing an acid-degradable group into the acquired core portion;

(B) a step of washing a hyperbranched polymer having the acid-degradable group in the shell portion with the use of pure water to acquire the hyperbranched polymer having a metal content not greater than 100 ppb; and

(C) a step of subsequently degrading a portion of the acid-degradable group constituting the shell portion with an acid catalyst to form the acid group.

The present invention provides a hyperbranched polymer synthesizing method for a core-shell hyperbranched polymer having an acid group and an acid-degradable group in a shell portion, the method including:

(A) a step of synthesizing a core portion by polymerizing a monomer capable of living radical polymerization in the presence of a metal catalyst to form the shell portion by introducing an acid-degradable group into the acquired core portion;

(B) a step of washing a hyperbranched polymer having the acid-degradable group in the shell portion with the use of pure water and an aqueous solution of an organic compound having chelating ability and/or an aqueous solution of an inorganic solution to acquire the hyperbranched polymer having a metal content not greater than 100 ppb; and

(C) a step of subsequently degrading a portion of the acid-degradable group constituting the shell portion with an acid catalyst to form the acid group.

### (Means for Solving the Fourth Problem)

To solve the above problem and achieve an object, a hyperbranched polymer synthesizing method according to the present invention is a hyperbranched polymer synthesizing method including a polymerizing method of causing living radical polymerization of a monomer in the presence of a metal catalyst to polymerize a polymer; a refining step of using a reprecipitating method for a reaction solution containing the polymer polymerized at the polymerizing step to collect the polymer; and a filtrating step of filtrating the refined polymer with the use of a filter having a pore diameter of 0.1 μm or less.

The present invention provides a hyperbranched polymer synthesizing method capable of improving the temporal stability of the resolving performance of the hyperbranched polymer available for the resist composition by using a polar solvent to prevent the rapid increase in the molecular weight and acquire a hyperbranched polymer having a desired molecular weight and branching degree and to prevent the increase in the molecular weight due to temporal progress in the polymerization of the hyper branch polymer.

The hyperbranched polymer synthesizing method according to the present invention can include a shell portion generating step of using the polymer polymerized at the polymerizing step as a core portion to generate a shell portion by introducing an acid-degradable group into the core portion and the polymer may be collected by a refining step using the reprecipitating method.

The present invention can provide the hyperbranched polymer synthesizing method capable of improving the temporal stability of the resolving performance of the hyperbranched polymer available for the resist composition by preventing the increase in the molecular weight due to temporal progress in the polymerization of the hyper branch polymer including the shell portion with the acid-degradable group introduced.

A hyperbranched polymer according to the present invention is produced according to the hyperbranched polymer synthesizing method.

According to the present invention, the hyperbranched polymer having a desired molecular weight and branching degree can be acquired with the increase in the molecular weight due to temporal progress in the polymerization being prevented.

A resist composition according to the present invention contains the hyperbranched polymer.

According to the present invention, a resist composition containing the hyperbranched polymer having a desired molecular weight and branching degree can be acquired with the increase in the molecular weight due to temporal progress of the polymerization being prevented.

A semiconductor integrated circuit according to the present invention has a pattern formed with the resist composition.

According to the present invention, a fine semiconductor integrated circuit having stable performance and supporting electron beams, deep ultraviolet (DUV), and extreme ultraviolet (EUV) can be manufactured.

A semiconductor integrated circuit manufacturing method according to the present invention includes a step of forming a pattern with the use of the resist composition.

According to the present invention, a fine semiconductor integrated circuit having stable performance and supporting electron beams, deep ultraviolet (DUV), and extreme ultraviolet (EUV) can be manufactured.

### (Means for Solving the Fifth Problem)

To solve the above problem and achieve an object, a hyperbranched polymer synthesizing method according to the present invention is a hyperbranched polymer synthesizing method of synthesizing a hyperbranched polymer through living radical polymerization of a monomer in the presence of a metal catalyst, including a removing step of removing a metal catalyst in a reaction system where the hyperbranched polymer synthesized by the living radical polymerization exists after the living radical polymerization; and a drying step of drying a solvent existing in the reaction system after the removing step at 10 to 70 degrees C. to remove the solvent.

According to the present invention, since the considerable increase in the molecular weight due to progress in a bridging reaction between hyperbranched polymer molecules can be prevented by drying the solvent in the reaction system to prevent the adhesion and entwining of the hyperbranched polymer molecules, a hyperbranched polymer having a desired molecular weight can be acquired stably.

The hyperbranched polymer synthesizing method according to the present invention includes a catalyst removing step of removing the metal catalyst in the reaction system after the living radical polymerization and, at the drying step, the solvent is removed by drying the solvent existing in the reaction system after the metal catalyst is removed at the catalyst removing step.

According to the present invention, since the progress in the bridging reaction between hyperbranched polymer molecules can be prevented more effectively by drying the solvent in the reaction system after removing the metal catalyst activating the progress in the bridging reaction between hyperbranched polymer molecules, a hyperbranched polymer having a desired molecular weight can be acquired stably.

According to the present invention, since the progress in the bridging reaction between hyperbranched polymer molecules can be prevented in the middle of the drying by managing a temperature of the reaction system during the drying, the hyperbranched polymer having the desired molecular weight can be acquired stably.

At the drying step of the hyperbranched polymer synthesizing method according to the present invention, a pressure of the reaction system is reduced to a pressure lower than the atmosphere pressure to achieve a vacuum state.

According to the present invention, since the solvent in the reaction system can be dried easily, a hyperbranched polymer having a desired molecular weight can be acquired stably and easily.

At the drying step of the hyperbranched polymer synthesizing method according to the present invention, the solvent in the reaction system is dried for 1 to 20 hours.

According to the present invention, since the solvent in the reaction system can be dried with certainty, a hyperbranched polymer having a desired molecular weight can be acquired stably and with certainty.

A hyperbranched polymer according to the present invention is produced according to the hyperbranched polymer synthesizing method.

According to the present invention, the hyperbranched polymer can be acquired stably in large amounts without considerably increasing the amount of waste liquid associated with the up scaling of the synthesis.

A resist composition according to the present invention contains the hyperbranched polymer.

According to the present invention, the resist composition containing the hyperbranched polymer having a desired molecular weight and branching degree can be acquired stably.

A semiconductor integrated circuit according to the present invention has a pattern formed with the resist composition through the electron-beam, deep-ultraviolet (DUV), or extreme-ultraviolet (EUV) lithography.

According to the present invention, a highly-integrated, high-capacity semiconductor integrated circuit having stable performance can be acquired.

A semiconductor integrated circuit manufacturing method according to the present invention includes a step of forming a pattern with the use of the resist composition through the electron-beam, deep-ultraviolet (DUV), or extreme-ultraviolet (EUV) lithography.

According to the present invention, a highly-integrated, high-capacity semiconductor integrated circuit having stable performance can be manufactured.

### BRIEF DESCRIPTION OF DRAWINGS

FIG. 1 is a graph indicating, with respect to the reaction time (min), the weight-average molecular weight (Mw) obtained from the reaction according to a method described in a first example;

FIG. 2 is a graph indicating, with respect to the reaction time (min), the weight-average molecular weight (Mw) obtained from the reaction according to a method described in a first comparative example;

FIG. 3 is a flowchart of hyperbranched polymer synthesis.

### BEST MODE(S) FOR CARRYING OUT THE INVENTION

The best modes for carrying out the invention will now be described in the first to fifth chapters.

### <First Chapter>

A hyperbranched polymer of an embodiment according to the present invention has a structure with a core portion that is a hyperbranched core polymer acting as a macroinitiator and a shell portion covering the core portion. When synthesizing the hyperbranched polymer, the hyperbranched core polymer is used as a macroinitiator. The hyperbranched core polymer is a collective term for multibranched polymers (hyperbranched polymers) acting as the core portions of hyperbranched polymers in multibranched polymers (hyperbranched polymers) having a branching structure in a repeating unit.

The hyperbranched core polymer is synthesized by an atom transfer radical polymerization method (ATRP), which is a kind of the living radical polymerization. Monomers used in the synthesis of the hyperbranched core polymer include at least monomers represented by the following structural formula (I).

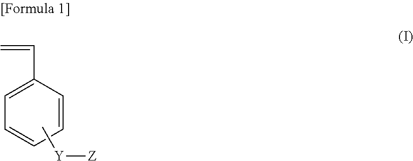

Y of the formula (I) denotes a straight-chain, branched, or cyclic alkylene group having 1 to 10 carbon atoms. The preferred number of carbon atoms of Y is one to six. Y of the formula (I) may contain a hydroxyl group or a carboxyl group.

Specifically, Y of the formula (I) may denote, for example, a methylene group, an ethylene group, a propylene group, an isopropylene group, a butylene group, an isobutylene group, an amylene group, a hexylene group, and a cyclohexylene group. Y of the formula (I) may denote groups formed by combining the above groups or groups formed by containing “—O—”, “—CO—”, or “—COO—” between the above groups.

Among the above groups, Y of the formula (I) preferably denotes an alkylene group having one to eight carbon atoms. Among the alkylene groups having one to eight carbon atoms, Y of the formula (I) is preferably a straight-chain alkylene group having one to eight carbon atoms. A more preferred alkylene group includes, for example, a methylene group, an ethylene group, a —OCH₂— group, and a —OCH₂CH₂— group. Z of the formula (I) denotes a halogen atom (halogen group) such as a fluorine atom, a chlorine atom, a bromine atom, and an iodine atom. Specifically, Z of the formula (I) is preferably a chlorine atom or a bromine atom among the above halogen atoms.

Specifically, monomers represented by the formula (I) include, for example, chloromethyl styrene, bromomethyl styrene, p-(1-chloroethyl)styrene, bromo(4-vinylphenyl)phenylmethane, 1-bromo-1-(4-vinylphenyl)propane-2-one, and 3-bromo-3-(4-vinylphenyl)propanol. More specifically, among the monomers used in the synthesis of the hyperbranched polymer, the monomers represented by the formula (I) preferably are chloromethyl styrene, bromomethyl styrene, p-(1-chloroethyl)styrene, etc.

Monomers constituting the core portion of the hyperbranched polymer of the present invention may include other monomers in addition to monomers represented by the formula (I). Other monomers are not particularly limited provided the monomer is radically polymerizable, and may be selected according to purpose. Other radically polymerizable monomers include, for example, compounds having a radically polymerizable unsaturated bond and may be selected from among (meth)acrylic acid and (meth)acrylic esters, vinylbenzoic acid, vinylbenzoic esters, styrenes, allyl compounds, vinyl ethers, and vinyl esters.

Specifically, (meth)acrylic esters cited as other radically polymerizable monomers include, for example, tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1 ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1 ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl) oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate.

Specifically, vinylbenzoic esters cited as other radically polymerizable monomers include, for example, tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1 n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinylbenzoate, adamantyl vinylbenzoate, 2-(2-methyl)adamantyl vinylbenzoate, chloroethyl vinylbenzoate, 2-hydroxyethyl vinylbenzoate, 2,2-dimethylhydroxypropyl vinylbenzoate, 5-hydroxybenzyl vinylbenzoate, trimethylolpropane vinylbenzoate, glycidyl vinylbenzoate, benzyl vinylbenzoate, phenyl vinylbenzoate, and naphthyl vinylbenzoate.

Specifically, styrenes cited as other radically polymerizable monomers include, for example, styrene, benzylstyrene, trifluoromethylstyrene, acetoxystyrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, 4-fluoro-3-trifluoromethylstyrene, and vinylnaphthalene.

Specifically, allyl compounds cited as other radically polymerizable monomers include, for example, allyl acetate, allyl caproate, allyl caprylate, allyl laurate, allyl palmitate, allyl stearate, allyl benzoate, allyl acetoacetate, allyl lactate, and allyloxyethanol.

Specifically, vinyl ethers cited as other radically polymerizable monomers include, for example, hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether, tetrahydrofurfuryl vinyl ether, vinylphenyl vinyl ether, vinyl tolyl ether, vinyl chlorophenyl ether, vinyl-2,4-dichlorophenyl ether, vinyl naphthyl ether, and vinyl anthranyl ether.

Specifically, vinylesters cited as other radically polymerizable monomers include, for example, vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl-β-phenylbutyrate, and vinyl cyclohexylcarboxylate.

Specifically, other radically polymerizable monomers constituting the hyperbranched core polymer preferably include, for example, (meth)acrylic acid, tert-butyl (meth)acrylate, 4-vinylbenzoic acid, tert-butyl 4-vinylbenzoate, styrene, benzylstyrene, chlorostyrene, and vinylnaphthalene.

The amount of monomer constituting the hyperbranched core polymer is preferably 10 to 90 mol %, more preferably 10 to 80 mol %, and yet more preferably 10 to 60 mol % relative to the total amount of monomers used for the synthesis of the hyperbranched polymer.

For example, if the core-shell hyperbranched polymer having the hyperbranched core polymer as the core portion is utilized for a resist composition, appropriate hydrophobicity may be induced to the developing fluid of the hyperbranched polymer by adjusting the amount of monomer constituting the hyperbranched core polymer to be at the above ranges. This is preferable since the resist composition containing the hyperbranched polymer may be used to prevent the dissolution of the unexposed portion at the time of the microfabrication when manufacturing semiconductor integrated circuits, flat panel displays, and printed-wiring boards, for example.

The amount of monomer represented by the formula (I) is preferably 5 to 100 mol %, more preferably 20 to 100 mol %, and yet more preferably 50 to 100 mol % relative to the total amount of monomer used for the synthesis of the hyperbranched core polymer. When the amount of monomer represented by the formula (I) is at the above ranges in the hyperbranched core polymer, this is preferable since the entwining of molecules is advantageously prevented because the hyperbranched core polymer takes a spherical form.

If the hyperbranched core polymer is a polymerization product of a monomer represented by formula (I) and another monomer, the amount of monomer represented by formula (I) is preferably 10 to 99 mol %, more preferably 20 to 99 mol %, and yet more preferably 30 to 99 mol % relative to the total amount of monomer constituting the hyperbranched core polymer. If the amount of monomer represented by formula (I) is at the above ranges in the hyperbranched core polymer, since the hyperbranched core polymer takes a spherical form, this advantageously constrains entwining of molecules and induces functions such as adhesiveness to substrates and an increase in the glass-transition temperature, which is preferable. According to purpose, the amount of the monomer represented by the formula (I) and the amount of other monomers in the core portion may be adjusted by the ratio of the charging amount at the time of polymerization.

A metal catalyst is used when synthesizing the hyperbranched polymer. The metal catalyst includes a metal catalyst consisting of a combination of a transition metal compound such as copper, iron, ruthenium, and chromium, and a ligand, for example. The transition metal compound includes, for example, cuprous chloride, cuprous bromide, cuprous iodide, cuprous cyanide, cuprous oxide, cuprous perchlorate, ferrous chloride, ferrous bromide, and ferrous iodide.

The ligand includes pyridines, bipyridines, polyamines, phosphines, etc., not substituted or substituted by an alkyl group, an aryl group, an amino group, a halogen group, an ester group, etc. A preferred metal catalyst may be, for example, a copper(I) bipyridyl complex and a copper(I) pentamethyldiethylenetriamine complex constituted by copper chloride and a ligand, an iron(II) triphenylphosphine complex and an iron(II) tributylamine complex constituted by iron chloride and a ligand, etc. Ligands described in Chem. rev. 2001, 101, 3689—may also be used for the ligand.

The amount of metal catalyst used is preferably 0.01 to 70 mol %, more preferably 0.1 to 60 mol % relative to the total amount of monomer used for the synthesis of the hyperbranched polymer. If the catalyst is used at such ranges, the reactivity may be improved to synthesize a hyperbranched polymer having a preferred branching degree.

If the amount of metal catalyst used is less than the above ranges, the reactivity is considerably reduced and the polymerization may not progress. On the other hand, if the amount of metal catalyst exceeds the above ranges, since the polymerization reaction becomes excessively active, a coupling reaction tends to occur between radicals at the growth ends and the polymerization tends to become difficult to control. If the amount of metal catalyst exceeds the above ranges, the coupling reaction between radicals triggers gelation of the reaction system.

The metal catalyst may be made into a complex compound by mixing the above transition metal compound and the ligand in an apparatus. The metal catalyst consisting of the transition metal compound and the ligand may be added in a state of an active complex to the apparatus. It is more preferable to mix the transition metal compound and the ligand in the apparatus to form a complex since the synthesis operation of the hyperbranched polymer may be simplified.

The method of adding the metal catalyst is not particularly limited and, for example, the metal catalyst may be added at one time before the polymerization of the hyperbranched polymer. Alternatively, after the polymerization starts, additional metal catalyst may be added depending on the level of deactivation of the catalyst. For example, if the distribution of the complex acting as the metal catalyst is not uniform in the reaction system, the transition metal compound may preliminarily be added into the apparatus and only the ligand may be added afterward.

In the presence of the above metal catalyst, the polymerization reaction for synthesizing the hyperbranched polymer is preferably performed in a solvent although the reaction can occur in the absence of solvent. The solvent used for the polymerization reaction of the hyperbranched polymer in the presence of the metal catalyst is not particularly limited and includes, for example, a hydrocarbon solvent such as benzene and toluene, an ether solvent such as diethyl ether, tetrahydrofuran, diphenyl ether, anisole, and dimethoxybenzene, a halogenated hydrocarbon solvent such as methylene chloride, chloroform, and chlorobenzene, a ketone solvent such as acetone, methyl ethyl ketone, and methyl isobutyl ketone, an alcohol solvent such as methanol, ethanol, propanol, and isopropanol, a nitrile solvent such as acetonitrile, propionitrile, and benzonitrile, an ester solvent such as ethyl acetate and butyl acetate, a carbonate solvent such as ethylene carbonate and propylene carbonate, and an amide solvent such as N,N-dimethylformamide and N,N-dimethylacetamide. These solvents may independently be used or two or more of the solvents may concurrently be used.

In the synthesis (core polymerization) of the hyperbranched polymer, the core polymerization is preferably performed in the presence of or in the flow of nitrogen or inert gas or in the absence of oxygen to prevent oxygen from affecting radicals. The core polymerization may be applied to both a batch method and a continuous method. In the core polymerization, all substances used for the core polymerization, i.e., the metal catalyst, the solvent, the monomer, etc., are preferably deoxygenated (degassed) sufficiently by evacuation or blowing-in of an inert gas such as nitrogen or argon to prevent the metal catalyst from being oxidized and deactivated.

The core polymerization may be performed while dropping monomer into a reactor, for example. By controlling the dropping rate of the monomer, a higher branching degree may be maintained and the rapid increase in the molecular weight may be prevented in the hyperbranched core polymer to be synthesized (macroinitiator). By controlling the dropping rate of the monomer, the polymer molecular weight may accurately be controlled while maintaining a higher branching degree in the hyperbranched core polymer to be synthesized. To prevent the rapid increase in the molecular weight of the hyperbranched core polymer, the concentration of the monomer to be dropped is preferably 1 to 50 mass %, more preferably 2 to 20 mass % relative to the total reaction amount.

In the core polymerization, the reaction may be caused by adding the monomer (charged monomer) into the reactor for the polymerization reaction at a later time. Each mixing (addition) amount of the monomer into the reactor (reaction system) is less than the total amount of the monomer to be mixed into the reaction system. To maintain a higher branching degree and prevent the rapid increase in the molecular weight of the hyperbranched core polymer, each amount of the monomer to be mixed into the reaction system is preferably less than 50%, more preferably less than 30% of the total amount of the monomer.

For example, each mixing (addition) amount of the monomer into the reactor (reaction system) is less than the total amount of monomer to be mixed into the reaction system by mixing the monomer into the reaction system according to methods such as a continuous method for mixing the monomer into the reaction system by dropping the monomer for a predetermined time period and a dividing method for mixing the monomer into the reaction system by dividing the total amount of the monomer to be mixed with the reaction system and adding a certain amount of the monomer at certain intervals.

For example, the monomer may be mixed into the reaction system by continuously injecting the monomer for a predetermined time period. In this case, at each unit time, the mixing (addition) amount of the monomer mixed into the reaction system is less than the total amount of the monomer to be mixed into the reaction system.

If the continuous method is used to mix the monomer into the reaction system, the dropping time of the monomer is preferably 5 to 300 minutes. If the continuous method is used to mix the monomer into the reaction system, more preferably the dropping time of the monomer is 15 to 240 minutes. If the continuous method is used to mix the monomer into the reaction system, yet more preferably the dropping time of the monomer is 30 to 180 minutes.

If the dividing method is used to mix the monomer into the reaction system, a given amount of the monomer is mixed at predetermined intervals. The predetermined intervals may be, for example, the time required for the mixed monomer to perform one polymerization reaction, the time required for the mixed monomer to uniformly disperse into the entire reaction system, or the time required for the temperature of the reaction system varied due to the mixing of the monomer to be stabilized.

If the dropping time of the monomer into the reaction system is too short, the rapid increase in the molecular weight may not be prevented sufficiently. If the dropping time of the monomer to the reaction system is too long, this is not preferable since the total polymerization time from the start to the end of the synthesis of the hyperbranched polymer increases and the cost of the synthesis of the hyperbranched polymer accordingly increases.

An additive is used for the core polymerization. In the core polymerization, among compounds represented by formula (1-1) and compounds represented by (1-2), at least one type may be added.

R₁-A (1-1)

R₂—B—R₃ (1-2)

R₁ of formula (1-1) denotes an alkyl group having 1 to 10 carbon atoms, an aryl group having 1 to 10 carbon atoms, or an aralkyl group having 1 to 10 carbon atoms. More particularly, R₁ of formula (1-1) represents hydrogen, an alkyl group having 1 to 10 carbon atoms, an aryl group having 6 to 10 carbon atoms, or an aralkyl group having 7 to 10 carbon atoms. A of formula (1-1) denotes a cyano group, a hydroxyl group, or a nitro group. The compounds represented by formula (1-1) include nitriles, alcohols, and nitro compounds, for example.

Specifically, nitriles included in the compounds represented by formula (1-1) are, for example, acetonitrile, propionitrile, butyronitrile, and benzonitrile. Specifically, alcohols included in the compounds represented by formula (1-1) are, for example, methanol, ethanol, 1-propanol, 2-propanol, 1-butanol, cyclohexyl alcohol, and benzyl alcohol. Specifically, nitro compounds included in the compounds represented by formula (1-1) are, for example, nitromethane, nitroethane, nitropropane, and nitrobenzene. The compounds represented by formula (1-1) are not limited to the above compounds.

R₂ and R₃ of formula (1-2) denote alkyl groups having 1 to 10 carbon atoms, aryl groups having 1 to 10 carbon atoms, aralkyl groups having 1 to 10 carbon atoms, or dialkylamide groups having 1 to 10 carbon atoms and B denotes a carbonyl group or a sulfonyl group. More particularly, R₂ and R₃ of formula (1-2) represent hydrogen, alkyl groups having 1 to 10 carbon atoms, aryl groups having 6 to 10 carbon atoms, aralkyl groups having 7 to 10 carbon atoms, or dialkylamide groups having 1 to 10 carbon atoms. R₂ and R₃ of formula (1-2) may be the same or different.

The compounds represented by formula (1-2) include ketones, sulfoxides, and alkylformamide compounds, for example. Specifically, ketones include, for example, acetone, 2-butanone, 2-pentanone, 3-pentanone, 2-hexanone, cyclohexanone, 2-methylcyclohexanone, acetophenone, and 2-methylacetophenone.

Specifically, sulfoxides included in the compounds represented by formula (1-2) are, for example, dimethyl sulfoxide and diethyl sulfoxide. Specifically, alkylformamide compounds included in the compounds represented by formula (1-2) are, for example, N,N-dimethylformamide, N,N-diethylformamide, and N,N-dibutylformamide.

The compounds represented by formula (1-2) are not limited to the above compounds. The compounds represented by formula (1-1) or formula (1-2) are preferably nitriles, nitro compounds, sulfoxides, ketones, and alkylformamide compounds, and more preferably, acetonitrile, propionitrile, benzonitrile, nitroethane, nitropropane, dimethyl sulfoxide, acetone, and N,N-dimethylformamide.

In the synthesis of the hyperbranched polymer, the compounds represented by formula (1-1) or formula (1-2) may be used independently or two or more of the compounds may be used in combination.

In the synthesis of the hyperbranched polymer, the compounds represented by formula (1-1) or formula (1-2) may be used independently or two or more of the compounds may be used in combination as a solvent.

The amount of the compounds represented by formula (1-1) or formula (1-2) to be added in the synthesis of the hyperbranched polymer is preferably 2 times to 10000 times the amount of the transition metal in the above metal catalyst by molar ratio. The amount of the compounds represented by formula (1-1) or formula (1-2) to be added is more preferably 3 times to 7000 times and yet more preferably 4 times to 5000 times the amount of the transition metal in the above metal catalyst by molar ratio.

If the added amount of the compounds represented by formula (1-1) or formula (1-2) is too small, the rapid increase in the molecular weight may not be controlled sufficiently. On the other hand, if the added amount of the compounds represented by formula (1-1) or formula (1-2) is too large, the reaction rate is slowed and a large amount of oligomers is generated.

The polymerization time of the core polymerization is preferably 0.1 to 30 hours depending on the molecular weight of the polymerization product, more preferably 0.1 to 10 hours, and particularly preferably 1 to 10 hours. In the core polymerization, the reaction temperature is preferably a range of 0 to 200 degrees C., and more preferably a range of 50 to 150 degrees C. If the polymerization is performed at a temperature higher than the boiling point of the solvent to be used, the pressure may be increased within an autoclave, for example.

In the core polymerization, it is preferable for the reaction system to be uniformly distributed. For example, the reaction system is uniformly distributed by agitating the reaction system. A specific example of an agitation condition of the core polymerization is that preferably the power necessary for agitation per unit volume is set as 0.01 kW/m³ or more. In the core polymerization, additional catalyst or a reducing agent regenerating the catalyst may be added depending on the progress in the polymerization and the level of deactivation of the catalyst.

In the core polymerization, the polymerization reaction is terminated when the set molecular weight is attained. A method of terminating the core polymerization is not particularly limited and, for example, a method such as cooling or deactivating the catalyst with the addition of an oxidizing agent or a chelating agent may be used.

According to the hyperbranched polymer synthesizing method of the embodiment, the hyperbranched core polymer molecules can be prevented from forming gel, for example, when at least a compound represented by R₁-A or a compound represented by R₂—B—R₃ is added in the core polymerization as described above.

As described above, according to the hyperbranched polymer synthesizing method of the embodiment, the amount of the metal catalyst used can be reduced and the rapid increase in the molecular weight can be prevented, for example, by making each mixing amount of the monomer into the reaction system less than the total amount of the monomer to be mixed with the reaction system, as compared to the case of mixing the total amount of the monomer with the reaction system at one time in the core polymerization.

Therefore, according to the hyperbranched polymer synthesizing method of the embodiment, the amount of the metal catalyst can be reduced and the rapid increase in the molecular weight can be prevented to stably produce the hyperbranched polymer having the desired molecular weight and branching degree.

According to the synthesizing method of the embodiment, the hyperbranched polymer synthesized as described can be used for the core portion to synthesize the core-shell hyperbranched polymer provided with the shell portion constituting the molecular terminals. The shell portion of the hyperbranched polymer includes at least a repeating unit represented by the formula (II) or a repeating unit represented by formula (III).

The repeating unit represented by the following formulas (II), (III) includes an acid-degradable group degraded by an effect of an organic acid such as acetic acid, maleic acid, and benzoic acid or an inorganic acid such as hydrochloric acid, sulfuric acid, and nitric acid or by an effect of a photoacid generator that generates an acid using optical energy. Degradation of the acid-degradable group to form a hydrophilic group is preferable.

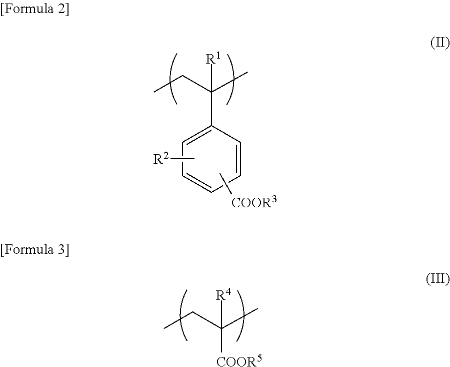

R¹ of formula (II) and R⁴ of formula (III) denote hydrogen atoms or alkyl groups having 1 to 3 carbon atoms. R¹ of formula (II) and R⁴ of formula (III) are preferably hydrogen atoms and methyl groups. R¹ of formula (II) and R⁴ of formula (III) are more preferably hydrogen atoms.

R² of formula (II) denotes a hydrogen atom, an alkyl group, or an aryl group. The alkyl group of R² of formula (II) preferably has 1 to 30 carbon atoms, more preferably has 1 to 20 carbon atoms, and yet more preferably has 1 to 10 carbon atoms, for example. The alkyl group has a straight-chain, branched, or cyclic structure. Specifically, the alkyl group of R² of formula (II) includes, for example, a methyl group, an ethyl group, a propyl group, an isopropyl group, a butyl group, an isobutyl group, a t-butyl group, a cyclohexyl group, etc.

The aryl group of R² of formula (II) preferably has 6 to 30 carbon atoms, for example. The aryl group of R² of formula (II) more preferably has 6 to 20 carbon atoms and yet more preferably has 6 to 10 carbon atoms. Specifically, the aryl group of R² of formula (II) includes, for example, a phenyl group, a 4-methylphenyl group, and a naphthyl group. A hydrogen atom, a methyl group, an ethyl group, and a phenyl group are particularly cited among the above groups. A hydrogen atom is cited as one of the most preferable groups for R² of formula (II).

R³ of formula (II) and R⁵ of formula (III) denote hydrogen atoms, alkyl groups, trialkylsilyl groups, oxoalkyl groups, or groups represented by the following formula (i). The alkyl groups of R³ of formula (II) and R⁵ of formula (III) preferably have 1 to 40 carbon atoms. The alkyl groups of R³ of formula (II) and R⁵ of formula (III) more preferably have 1 to 30 carbon atoms.

The alkyl groups of R³ of formula (II) and R⁵ of formula (III) yet more preferably have 1 to 20 carbon atoms. The alkyl groups of R³ of formula (II) and R⁵ of formula (III) have a straight-chain, branched, or cyclic structure. Branched alkyl groups having 1 to 20 carbon atoms are more preferable for R³ of formula (II) and R⁵ of formula (III).

Each of the alkyl groups of R³ of formula (II) and R⁵ of formula (III) preferably has 1 to 6 carbon atoms and more preferably has 1 to 4 carbon atoms. The alkyl group of the oxoalkyl groups of R³ of formula (II) and R⁵ of formula (III) preferably has 4 to 20 carbon atoms and more preferably has 4 to 10 carbon atoms.

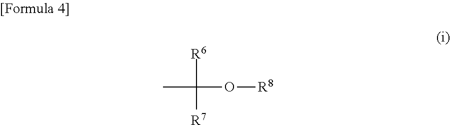

R⁶ of formula (i) denotes a hydrogen atom or an alkyl group. The alkyl group of R⁶ in the groups represented by formula (i) has a straight-chain, branched-chain, or cyclic structure. The alkyl group of R⁶ in the groups represented by formula (i) preferably has 1 to 10 carbon atoms. The alkyl group of R⁶ in the groups represented by formula (i) more preferably has 1 to 8 carbon atoms and yet more preferably has 1 to 6 carbon atoms.

R⁷ and R⁸ of formula (i) denote hydrogen atoms or alkyl groups. The hydrogen atoms or alkyl groups of R⁷ and R⁸ of formula (i) may be independent of each other or form a ring. The alkyl groups of R⁷ and R⁸ of formula (i) have a straight-chain, branched-chain, or cyclic structure. The alkyl groups of R⁷ and R⁸ of formula (i) preferably have 1 to 10 carbon atoms. The alkyl groups of R⁷ and R⁸ of formula (i) more preferably have 1 to 8 carbon atoms. The alkyl groups of R⁷ and R⁸ of formula (i) yet more preferably have 1 to 6 carbon atoms. Branched alkyl groups having 1 to 20 carbon atoms are preferable for R⁷ and R⁸ of formula (i).

The group represented by formula (i) includes a straight-chain or branched acetal group such as a 1-methoxyethyl group, a 1-ethoxyethyl group, a 1-n-propoxyethyl group, a 1-isopropoxyethyl group, a 1-n-butoxyethyl group, a 1-isobutoxyethyl group, a 1-sec-butoxyethyl group, a 1-tert-butoxyethyl group, a 1-tert-amyloxyethyl group, a 1-ethoxy-n-propyl group, a 1-cyclohexyloxyethyl group, a methoxypropyl group, an ethoxypropyl group, a 1-methoxy-1-methyl-ethyl group, and a 1-ethoxy-1-methyl-ethyl group; and a cyclic acetal group such as a tetrahydrofuranyl group and a tetrahydropyranyl group. The ethoxyethyl group, the butoxyethyl group, the ethoxypropyl group, and the tetrahydropyranyl group are particularly preferred among the above groups for the group represented by formula (i).

The straight-chain, branched, or cyclic alkyl groups of R³ of formula (II) and R⁵ of formula (III) include an ethyl group, a propyl group, an isopropyl group, a butyl group, an isobutyl group, a tert-butyl group, a cyclopentyl group, a cyclohexyl group, a cycloheptyl group, a triethylcarbyl group, a 1-ethylnorbornyl group, a 1-methylcyclohexyl group, an adamantyl group, a 2-(2-methyl)adamantyl group, a tert-amyl group, etc. Among above groups, the tert-butyl group is particularly preferable.

The trialkylsilyl group of R³ of formula (II) and R⁵ of formula (III) includes the alkyl groups having 1 to 6 carbon atoms such as a trimethylsilyl group, a triethylsilyl group, and a dimethyl-tert-butylsilyl group. The oxoalkyl group includes a 3-oxocyclohexyl group, etc.

Monomers giving repeating units represented by formula (II) include, for example, vinylbenzoic acid, tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1 n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinylbenzoate, adamantyl vinylbenzoate, 2-(2-methyl)adamantyl vinylbenzoate, chloroethyl vinylbenzoate, 2-hydroxyethyl vinylbenzoate, 2,2-dimethylhydroxypropyl vinylbenzoate, 5-hydroxybenzyl vinylbenzoate, trimethylolpropane vinylbenzoate, glycidyl vinylbenzoate, benzyl vinylbenzoate, phenyl vinylbenzoate, and naphthyl vinylbenzoate. Among these, a polymer of 4-vinylbenzoic acid and tert-butyl 4-vinylbenzoate is preferable.

Monomers giving repeating units represented by formula (III) include, for example, acrylate, tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1-ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1-ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, methacrylic acid, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl) oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate. Among these, polymers of acrylate and tert-butyl acrylate are preferable.

The monomer constituting the shell portion is also preferably a polymer of at least one among 4-vinylbenzoic acid and acrylic acid and at least one among tert-butyl 4-vinylbenzoate and tert-butyl acrylate. In addition to monomers giving repeating units represented by formula (II) and formula (III), a monomer constituting the shell portion may be any monomer having a structure with a radically polymerizable unsaturated bond.

In addition to the styrenes above, usable monomers include compounds having a radically polymerizable unsaturated bond and may be selected from among allyl compounds, vinyl ethers, vinyl esters, crotonates, etc.

Specifically, in addition to styrenes cited above as monomers usable as a monomer constituting the shell portion include, for example, styrene, tert-butoxystyrene, α-methyl-tert-butoxystyrene, 4-(1-methoxyethoxy)styrene, 4-(1-ethoxyethoxy)styrene, tetrahydropyranyloxystyrene, adamantyloxystyrene, 4-(2-methyl-2-adamantyloxy)styrene, 4-(1-methylcyclohexyloxy)styrene, trimethylsilyloxystyrene, dimethyl-tert-butylsilyloxystyrene, tetrahydropyranyloxystyrene, benzylstyrene, trifluoromethylstyrene, acetoxystyrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, 4-fluoro-3-trifluoromethylstyrene, and vinylnaphthalene.

Specifically, allyl esters cited above as monomers usable as a monomer constituting the shell portion include, for example, allyl acetate, allyl caproate, allyl caprylate, allyl laurate, allyl palmitate, allyl stearate, allyl benzoate, allyl acetoacetate, allyl lactate, and allyloxyethanol.

Specifically, vinyl ethers cited as monomers usable as a monomer constituting the shell portion include, for example, hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether, tetrahydrofurfuryl vinyl ether, vinylphenyl vinyl ether, vinyl tolyl ether, vinyl chlorophenyl ether, vinyl-2,4-dichlorophenyl ether, vinyl naphthyl ether, and vinyl anthranyl ether.

Specifically, vinylesters cited as monomers usable as a monomer constituting the shell portion include, for example, vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl-p-phenylbutyrate, and vinyl cyclohexylcarboxylate.

Specifically, crotonates cited as monomers usable as a monomer constituting the shell portion include, for example, butyl crotonate, hexyl crotonate, glycerin monocrotonate, dimethyl itaconate, diethyl itaconate, dibutyl itaconate, dimethyl maleate, dibutyl fumarate, maleic anhydride, maleimide, acrylonitrile, methacrylonitrile, and maleilonitrile.

Specifically, monomers usable as a monomer constituting the shell portion also include, for example, the following formulas (IV) to (XIII).

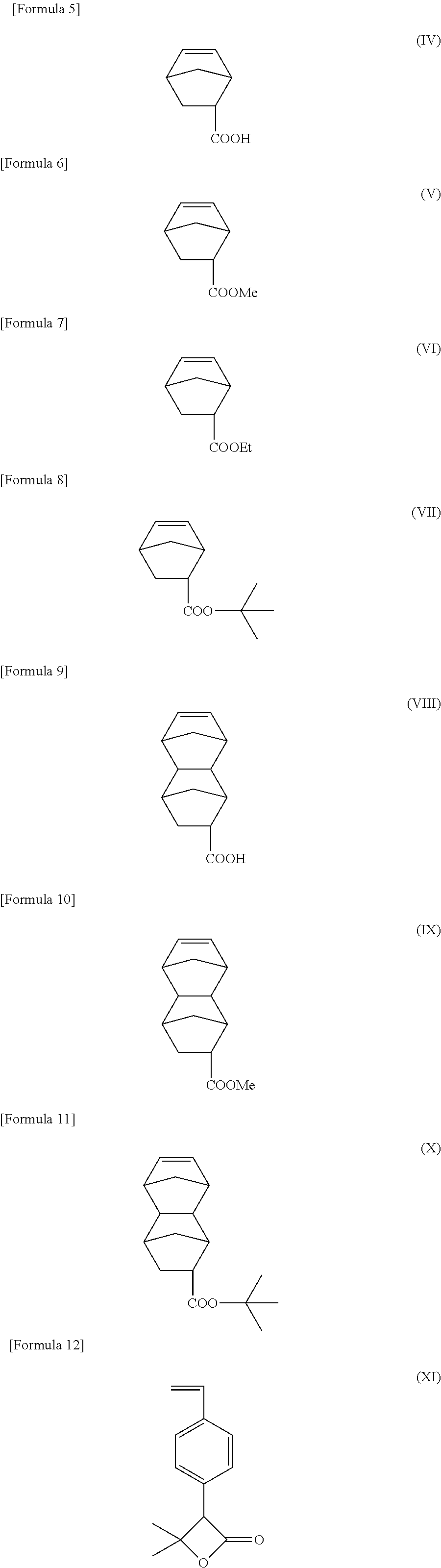

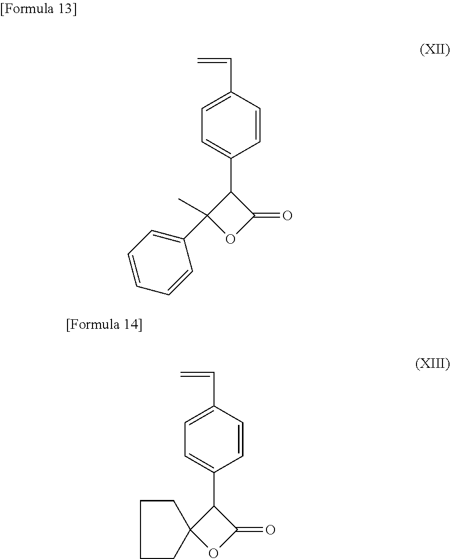

Among monomers usable as monomer constituting the shell portion, styrenes and crotonates are preferable. Among monomers usable as monomer constituting the shell portion, styrene, benzylstyrene, chlorostyrene, vinylnaphthalene, butyl crotonate, hexyl crotonate, and maleic anhydride are preferable.

The hyperbranched polymer contains at least monomer giving repeating units represented by formula (II) or monomer giving repeating units represented by formula (III). Monomer giving the above repeating units is preferably included at 10 to 90 mol % relative to the total charging amount of monomer used for the synthesis of the hyperbranched polymer at the time of charging and is more preferably at 20 to 90 mol % relative to the total charging amount of monomer used for the synthesis of the hyperbranched polymer at the time of charging.

Monomer giving the above repeating units is yet more preferably included at 30 to 90 mol % relative to the total charging amount of monomer used for the synthesis of the hyperbranched polymer at the time of charging. Particularly, it is preferred that the repeating unit represented by formula (II) or the repeating unit represented by formula (III) be included in the shell portion at 50 to 100 mol %, preferably at 80 to 100 mol % relative to the total charging amount of monomer used for the synthesis of the hyperbranched polymer at the time of charging. When monomer giving the above repeating units is at the above ranges relative to the total charging amount of monomer used for the synthesis of the hyperbranched polymer at the time of charging, this is preferable since an exposed portion is efficiently dissolved into alkaline solution and removed at a development step of lithography using a resist composition containing the hyperbranched polymer.

If the shell portion of the core-shell hyperbranched polymer is a polymerized product of monomer giving a repeating unit represented by formula (II) or monomer giving a repeating unit represented by formula (III) and other monomer, the amount of monomer giving a repeating unit represented by formula (II) and/or the amount of monomer giving a repeating unit represented by formula (III) preferably accounts for 30 to 90 mol %, more preferably 50 to 70 mol % relative to the total amount of monomer constituting the shell portion.

If monomer giving a repeating unit represented by formula (II) and/or monomer giving a repeating unit represented by formula (III) is at the above ranges relative to the total amount of monomer constituting the shell portion, functions such as increases in the etching resistance, wetting properties, and glass transition temperature are preferably induced without inhibiting efficient alkali solubility of the exposed portion. According to purpose, the ratio of the repeating units represented by formula (II) and/or the repeating units represented by formula (III) to other repeating units in the shell portion may be adjusted by the charging amount (molar ratio) at the time of introduction of the shell portion.

If the shell portion is polymerized with the hyperbranched core polymer (shell polymerization), the polymerization is preferably performed in the presence of or in the flow of nitrogen or inert gas or in the absence of oxygen to prevent oxygen from affecting radicals. The shell polymerization may be applied to both a batch method and a continuous method. The shell polymerization may continuously be performed after the above core polymerization or may be performed by removing the metal catalyst and monomers and adding a catalyst again after the above core polymerization. The shell polymerization may be performed after drying the hyperbranched core polymer synthesized by the core polymerization.

The shell polymerization is performed in the presence of a metal catalyst. The same metal catalyst as the metal catalyst used for the above core polymerization may be used for the shell polymerization. In the shell polymerization, for example, the metal catalyst is preliminarily provided in a reaction system for the shell polymerization before starting the shell polymerization, and the hyperbranched core polymer (macroinitiator, core macromer) synthesized by the core polymerization and the monomer constituting the shell portion are dropped into the reaction system.

Specifically, for example, the metal catalyst is preliminarily provided on the inner surface of a furnace for the reaction and the macroinitiator and the monomer are dropped into the furnace for the reaction. Specifically, for example, the above monomer constituting the shell portion may be dropped into the furnace for the reaction where the hyperbranched core polymer exists in advance. The monomer, the metal catalyst, and the solvent used in the shell polymerization are preferably deoxygenated (degassed) sufficiently as is the case with the core polymerization.

By performing the shell polymerization as described above, the gelation can be prevented efficiently regardless of the concentration of the hyperbranched core polymer. The concentration of the hyperbranched core polymer in the shell polymerization is preferably 0.1 to 30 mass %, more preferably 1 to 20 mass % based on a total reaction amount including the hyperbranched core polymer and the monomer at the time of charging.

The concentration of the monomer in the shell polymerization is preferably 0.5 to 20 mole equivalents based on the reaction active sites of the core macromer. The concentration of the monomer in the shell polymerization is more preferably 1 to 15 mole equivalents based on the reaction active sites of the core macromer. A core/shell ratio may be controlled by appropriately controlling the monomer amount relative to the reaction active sites of the core macromer.

In the shell polymerization, the reaction may be caused with the monomer preliminarily added into a reactor or by adding the monomer into the reactor later.

For example, the polymerization may be performed, for example, by a continuous dropping method for mixing the monomer into the reaction system by dropping the monomer for a predetermined time period and a divided dropping method for mixing the monomer into the reaction system by dividing the total amount of the monomer to be mixed with the reaction system and adding a given amount of the monomer at given time intervals.

The polymerization time for the shell polymerization is preferably 0.1 to 30 hours, more preferably 0.1 to 10 hours, particularly preferably 1 to 10 hours depending on the molecular weight of the polymerized product. The reaction temperature for the shell polymerization is preferably 0 to 200 degrees C. The reaction temperature for the shell polymerization is more preferably 50 to 150 degrees C. If the polymerization is caused at a temperature higher than the boiling point of the solvent to be used, the pressure may be increased within an autoclave, for example.

In the shell polymerization, the reaction system is uniformly distributed. For example, the reaction system is uniformly distributed by agitating the reaction system. A specific example of an agitation condition of the shell polymerization is that preferably the power necessary for agitation per unit volume is set as 0.01 kW/m³ or more, for example.

In the shell polymerization, a catalyst may be added or a reducing agent regenerating the catalyst may be added depending on the progress in the polymerization and the level of deactivation of the catalyst. The shell polymerization is terminated when the shell polymerization attains the set molecular weight. A method of terminating the shell polymerization is not particularly limited and, for example, a method such as cooling-down or deactivating the catalyst with the addition of an oxidizing agent or a chelating agent may be used.

The synthesis of the core-shell hyperbranched polymer includes removal of the metal catalyst, removal of the monomer, and removal of trace metal (derived from the metal catalyst) performed after the shell polymerization. The metal catalyst is removed after the shell polymerization is terminated. A method of removing the metal catalyst may be performed, for example, with one or a combination of the following methods (a) to (c):

(a) using various absorbents such as Kyoward manufactured by Kyowa Chemical Industry Co., Ltd;

(b) removing insoluble substances by filtration or centrifugation; and

(c) extraction with aqueous solution containing an acid and/or a substance having a chelating effect.

The acid used in the case of the method (c) includes, for example, p-toluenesulfonic acid, acetic acid, trifluoroacetic acid, trifluoromethanesulfonic acid, formic acid, hydrochloric acid, and sulfuric acid. The substances having a chelating effect include, for example, organic carboxylic acid such as oxalic acid, citric acid, gluconic acid, tartaric acid, and malonic acid; amino carbonate such as nitrilotriacetic acid, ethylenediaminetetraacetic acid, and diethylenetriaminopentaacetic acid, and hydroxyamino carbonate. The concentration of the acid in aqueous solution varies depending on the kind of acid and is preferably 0.03 mass % to 20 mass %. The concentration of the substance having chelating ability in aqueous solution varies depending on the chelating ability of the compound and is preferably 0.05 mass % to 10 mass %, for example. The acid and the substance having chelating ability may be used separately or in combination.

The removal of the monomer may be performed after the above removal of the metal catalyst or after metal cleaning following the removal of the metal catalyst is performed. In the removal of the monomer, among the monomer dropped at the time of the core polymerization and the shell polymerization described above, the unreacted monomer is removed. A method of removing the unreacted monomer may be performed, for example, with one or a combination of the following methods (d) to (e):

(d) adding a poor solvent to a reaction product dissolved in a good solvent to precipitate the polymer; and

(e) washing the polymer with a mixed solvent of a good solvent and a poor solvent.

In (d) to (e) above, the good solvent includes, for example, halogenated hydrocarbon, nitro compound, nitrile, ether, ketone, ester, carbonate, or a mixed solvent containing these solvents. Specifically, for example, tetrahydrofuran, chlorobenzene, and chloroform are included. The poor solvent includes, for example, methanol, ethanol, 1-propanol, 2-propanol, water, or a solvent obtained by combining these solvents.

In the synthesis of the core-shell hyperbranched polymer, trace amounts of residual metal in the polymer are reduced after the removal of the metal catalyst, the removal of the monomer, or the removal of trace metal described above. This may be performed, for example, with one or a combination of the following methods (f) to (g):

(f) performing the liquid-liquid extraction with aqueous solution of an organic compound having chelating ability, inorganic acid aqueous solution, and pure water; and

(g) using an absorbent and an ion-exchange resin.

The organic solvent used in the liquid-liquid extraction of (f) preferably includes, for example, halogenated hydrocarbon such as chlorobenzene and chloroform; acetic esters such as ethyl acetate, n-butyl acetate, and isoamyl acetate; ketones such as methyl ethyl ketone, methyl isobutyl ketone, cyclohexanone, 2-heptane, and 2-pentanone; glycol ether acetates such as ethylene glycol monoethyl ether acetate, ethylene glycol monobutyl ether acetate, and ethylene glycol monomethyl ether acetate; and aromatic hydrocarbons such as toluene and xylene.

More preferably, the organic solvent used in the liquid-liquid extraction of (f) includes, for example, chloroform, methyl isobutyl ketone, and ethyl acetate. These solvents may independently be used or two or more of the solvents may be mixed and used. In the liquid-liquid extraction in the case of (f) above, mass % of the core-shell hyperbranched polymer based on the organic solvent is preferably about 1 to 30 mass % and more preferably about 5 to 20 mass % after the monomer and the metal catalyst are removed.

The organic compound having chelating ability used in the liquid-liquid extraction in the case of (f) above preferably includes, for example, organic carboxylic acid such as formic acid, acetic acid, oxalic acid, citric acid, gluconic acid, tartaric acid, and malonic acid, amino carbonate such as nitrilotriacetic acid, ethylenediaminetetraacetic acid, and diethylenetriaminopentaacetic acid, and hydroxyamino carbonate. The inorganic acid used in the liquid-liquid extraction of (f) preferably includes, for example, hydrochloric acid and sulfuric acid.

In the liquid-liquid extraction in the case of (f) above, the concentrations of the organic compound having chelating ability and the inorganic acid in aqueous solution are preferably about 0.05 to 10 mass %. The concentrations of the organic compound having chelating ability and the inorganic acid in aqueous solution in the liquid-liquid extraction of (f) vary depending on the chelating ability of the compound.

In the removal of metal, if the aqueous solution of the organic compound having chelating ability and the inorganic acid aqueous solution are used, the aqueous solution of the organic compound having chelating ability and the inorganic acid aqueous solution may be mixed and used or the aqueous solution of the organic compound having chelating ability and the inorganic acid aqueous solution may be used separately. If the aqueous solution of the organic compound having chelating ability and the inorganic acid aqueous solution are used separately, either the aqueous solution of the organic compound having chelating ability or the inorganic acid aqueous solution may be used first.

In the removal of metal, if the aqueous solution of the organic compound having chelating ability and the inorganic acid aqueous solution are used separately, it is more preferable to use the inorganic acid aqueous solution in the latter half. This is because the aqueous solution of the organic compound having chelating ability is effective in the removal of a copper catalyst and polyvalent metal; and the inorganic acid aqueous solution is effective in removal of monovalent metal derived from experimental instruments, etc.

Even when the aqueous solution of the organic compound having chelating ability and the inorganic acid aqueous solution are mixed and used, it is desirable to solely use the inorganic acid aqueous to wash the shell portion in the latter half. Although the number of times of extraction is not particularly limited, it is desirable to perform the extraction two to five times, for example. In particular, the experimental instruments used with copper ion reduced are preferably used after preliminary washing to prevent metal derived from the experimental instruments, etc., from being mixed. A method of the preliminary washing is not particularly limited and includes, for example, washing with nitric acid aqueous solution.

The number of washings only with the inorganic acid aqueous solution is preferably one to five. By performing the washing with the inorganic acid aqueous solution one to five times, monovalent metal can be removed sufficiently. To remove residual acid components, it is preferable to perform the extraction process with pure water last to completely remove acid. The number of times of the washing with the pure water is preferably one to five. By performing the washing with the pure water one to five times, the residual acid can be removed sufficiently.

In the removal of metal, the ratio of a reaction solvent containing the refined hyperbranched polymer (hereinafter, simply “reaction solvent”) to the aqueous solution of the organic compound having chelating ability, the inorganic acid aqueous solution, and pure water is preferably 1:0.1 to 1:10 by volume. The ratio is more preferably 1:0.5 to 1:5 by volume. By using the solvent in such a ratio for the washing, the metal can be removed easily by an appropriate number of times. This enables the facilitation of the operation and the simplification of the operation and is preferred for the efficient synthesis of the hyperbranched polymer. It is preferable that the concentration by mass of a resist polymer intermediate dissolved in the reaction solvent by normally approximately 1 to 30 mass % relative to the solvent.

The liquid-liquid extraction process of (f) is performed, for example, by separating a mixed solvent of the aqueous solution of the organic compound having chelating ability, the inorganic acid aqueous solution, and the pure water (hereinafter, simply “mixed solvent”) into two layers and removing a water layer with migrated metal ions through decantation, etc.

A method of separating the mixed solvent into two layers is performed, for example, by adding the aqueous solution of the organic compound having chelating ability, the inorganic acid aqueous solution, and the pure water to the reaction solvent, sufficiently mixing the solvent with agitation, etc., and keeping still. For example, a centrifugal separation method may be used for the method of separating the mixed solvent into two layers. The liquid-liquid extraction process of (f) is performed, for example, preferably at 10 to 50 degrees C. and more preferably at 20 to 40 degrees C.

In the synthesis of the core-shell hyperbranched polymer, after the removal of metal, the acid-degradable group may be partially degraded as needed. In the partial degradation of the acid-degradable group, for example, a portion of the acid-degradable group is degraded into an acid group (acid-degradable group is induced) with the use of the acid catalyst described above.

In the degradation of the portion of the acid-degradable group into an acid group with the use of the acid catalyst described above (the partial degradation of the acid-degradable group), 0.001 to 100 equivalents of the acid catalyst are normally used for the acid-degradable group in the hyperbranched polymer after the removal of metal. The acid catalyst is not particularly limited and includes, for example, hydrochloric acid, sulfuric acid, phosphoric acid, hydrobromic acid, p-toluenesulfonic acid, acetic acid, trifluoroacetic acid, trifluoromethanesulfonic acid, and formic acid.

An organic solvent used for the reaction of partially degrading the acid-degradable group with the use of the acid catalyst described above is desirably a solvent capable of dissolving the hyperbranched polymer with the metal removed and having compatibility with water and, for example, the organic solvent used for the reaction of partially degrading the acid-degradable group with the use of the acid catalyst described above is preferably a solvent selected from a group including 1,4-dioxane, tetrahydrofuran, acetone, methyl ethyl ketone, diethyl ketone, and a mixture thereof because of availability and manageability.

The amount of the organic solvent used for the reaction of partially degrading the acid-degradable group with the use of the acid catalyst described above is not particularly limited if the core-shell hyperbranched polymer with the metal removed and the acid catalyst are dissolved as above and is preferably 5 to 500 times by mass based on the core-shell hyperbranched polymer with the metal removed. The amount of the organic solvent used for the reaction of partially degrading the acid-degradable group with the use of the acid catalyst described above is more preferably 8 to 200 times by mass. The reaction of partially degrading the acid-degradable group with the use of the acid catalyst described above can be caused by heating and agitation at 50 to 150 degrees C. for 10 minutes to 20 hours.

The ratio of the acid-degradable group to the acid group in the hyperbranched polymer after the partial degradation of the acid-degradable group is preferably defined such that 0.1 to 80 mol % of the monomer containing the introduced acid-degradable group is deprotected and converted into the acid group. For example, if the hyperbranched polymer after the partial degradation of the acid-degradable group is utilized for a resist composition such as photoresist, the optimum value for the ratio of the acid-degradable group to the acid group in the hyperbranched polymer is varied depending on the composition of the resist composition using the hyperbranched polymer.

If the ratio of the acid-degradable group to the acid group in the hyperbranched polymer after the partial degradation of the acid-degradable group is at such a range, this is preferable since the sensitivity to light is improved and efficient alkali solubility is achieved after exposure. The ratio of the acid-degradable group to the acid group in the hyperbranched polymer after the partial degradation of the acid-degradable group may be adjusted by appropriately determining the amount of acid catalyst, temperature, and reaction time.

After the reaction of partially degrading the acid-degradable group, the reaction liquid is mixed with ultrapure water to precipitate the hyperbranched polymer after the partial degradation of the acid-degradable group and is subjected to, for example, centrifugal separation, filtration, and decantation to separate the hyperbranched polymer after the partial degradation of the acid-degradable group. To remove the residual acid catalyst, the hyperbranched polymer after the partial degradation of the acid-degradable group is preferably brought into contact and washed with an organic solvent and water as needed.

### (Molecular Structure)

A molecular structure of the core-shell hyperbranched polymer will be described. A branching degree (Br) of the core portion in the core-shell hyperbranched polymer is preferably 0.3 to 0.7, more preferably 0.4 to 0.6, and the branching degree (Br) of the core portion in the core-shell hyperbranched polymer at the above ranges is preferable since the entwining of the polymer molecules is reduced and surface roughness is prevented on pattern side walls when the core-shell hyperbranched polymer synthesized with the use of the hyperbranched core polymer is used for the resist composition.

The branching degree (Br) of the hyperbranched core polymer in the core-shell hyperbranched polymer may be obtained by measuring ¹H-NMR of the product as follows. For example, if chloromethylstyrene is used as the monomer used for the synthesis of the hyperbranched core polymer, the branching degree (Br) may be calculated by carrying out an operation of the following equation (A) using an integration ratio H1° of proton of a —CH₂Cl site appearing at 4.6 ppm and an integration ratio H2° of proton of a —CHCl site appearing at 4.8 ppm. If the polymerization proceeds at both the —CH₂Cl site and the —CHCl site and the branching is enhanced, the value of the branching degree (Br) approaches 0.5.

$$\begin{matrix}[ Equation 1 ] & \\ Br = \frac{\frac{1}{2} H 1 °}{\frac{1}{2} H 1 ° + H 2 °} & ( A )\end{matrix}$$

A weight-average molecular weight (Mw) of the hyperbranched core polymer is preferably 300 to 8,000, also preferably 5000 to 6,000, and most preferably 1,000 to 4,000. The weight-average molecular weight (Mw) of the hyperbranched core polymer at such a range is preferable since solubility into the reaction solvent can be ensured in the acid-degradable group introducing reaction. This is also preferable since an excellent film forming property is achieved and the dissolution of unexposed portions is advantageously prevented in the hyperbranched polymer after the acid-degradable group is partially degraded (the acid-degradable group is induced) in the hyperbranched core polymer at the above molecular weight ranges.

A polydispersity (Mw/Mn) of the hyperbranched core polymer is preferably 1 to 3 and more preferably 1 to 2.5. The polydispersity (Mw/Mn) of the hyperbranched core polymer at such a range is desirable since adverse effects such as insolubilization of the hyperbranched polymer are not caused after exposure if the core-shell hyperbranched polymer synthesized with the use of the hyperbranched core polymer is used for the resist composition.

A weight-average molecular weight (M) of the core-shell hyperbranched polymer is preferably 500 to 21,000, more preferably 2,000 to 21,000, and most preferably 3,000 to 21,000. If the weight-average molecular weight (M) of the core-shell hyperbranched polymer is at the above ranges, a resist containing the hyperbranched polymer has a favorable film forming property and may keep a shape since a process pattern formed at a lithography step is strong. The resist composition containing the hyperbranched polymer has an excellent dry etching resistance and favorable surface roughness.

The weight-average molecular weight (Mw) of the core portion of the core-shell hyperbranched polymer may be obtained by preparing a 0.5-mass % tetrahydrofuran solution and performing the GPC measurement at a temperature of 40 degrees C. Tetrahydrofuran may be used as a mobile solvent and styrene may be used as a standard substance.

The weight-average molecular weight (M) of the core-shell hyperbranched polymer may be obtained by using ¹H-NMR to obtain introduction rates (component ratios) of the repeating units of the polymer with the acid-degradable group introduced and performing a calculation using the introduction rates of the constituent units and the molecular weights of the constituent units based on the weight-average molecular weight (Mw) of the core portion of the hyperbranched polymer.

### (Uses of Hyperbranched Polymer)

The uses of the hyperbranched polymer are not particularly limited and, for example, the hyperbranched polymer is used for a photoresist polymer, an ink-jet processing resin such as a color filter and a biochip, a cross-linking agent such as a powder coating, a base material for a solid electrolyte, and a pour-point depressant for BDF.

For example, if the hyperbranched polymer is used for a photoresist polymer, the excellent photoresist polymer with reduced unevenness of the pattern side walls and high alkali solubility after exposure, i.e., high sensitivity to light may be acquired by using the hyperbranched polymer as the core portion and introducing the acid-degradability as the shell portion at the terminal of the hyperbranched polymer. In such a use, for example, t-butyl acrylate may be polymerized as the shell portion with the above hyperbranched polymer through the atom transfer radical polymerization.

The core-shell hyperbranched polymer synthesized described above is used for a resist composition, for example. In the resist composition using the core-shell hyperbranched polymer (hereinafter, simply “resist composition”), a compounding amount of the hyperbranched polymer is preferably 4 to 40 mass %, more preferably 4 to 20 mass % relative to total amount of the resist composition.

The resist composition contains the above hyperbranched polymer and a photoacid generator. The resist composition may also contain an acid diffusion inhibitor (acid trapping agent), a surfactant, other components, a solvent, etc., as needed.

The photoacid generator included in the resist composition is not particularly limited as long as an acid is generated, for example, when ultraviolet light, X-ray, electron ray, etc., are applied, and may be appropriately selected from known various photoacid generators according to the purpose. Specifically, the photoacid generator includes, for example, onium salts, sulfonium salts, halogen-containing triazine compounds, sulfone compounds, sulfonate compounds, aromatic sulfonate compounds, and sulfonate compounds of N-hydroxyimide.

Onium salts included in the above photoacid generator include, for example, diaryliodonium salts, triarylselenonium salts, and triarylsulfonium salts. The diaryliodonium salts include, for example, diphenyliodonium trifluoromethanesulfonate, 4-methoxyphenylphenyiodonium hexafluoroantimonate, 4-methoxyphenylphenyliodonium trifluoromethanesulfonate, bis(4-tert-butylphenyl)iodonium tetrafluoroborate, bis(4-tert-butylphenyl)iodonium hexafluorophosphate, bis(4-tert-butylphenyl)iodonium hexafluoroantimonate, and bis(4-tert-butylphenyl)iodonium trifluoromethanesulfonate.

Specifically, triarylselenonium salts included in the above onium salts include, for example, a triphenylselenoniumhexafluorophosphonium salt, a triphenylselenoniumfluoroboric salt, and a triphenylselenoniumhexafluoroantimonate salt. Triarylsulfonium salts included in the above onium salts include, for example, a triphenylsulfonium hexafluorophosphonium salt, a triphenylsulfonium hexafluoroantimonate salt, a diphenyl-4-thiophenoxyphenylsulfonium hexafluoroantimonate salt, and a diphenyl-4-thiophenoxyphenylsulfonium pentafluoro hydroxyantimonate salt.

Sulfonium salts included in the above photoacid generator include, for example, triphenylsulfonium hexafluorophosphate, triphenylsulfonium hexafluoroantimonate, triphenylsulfonium trifluoromethanesulfonate, 4-methoxyphenyldiphenylsulfonium hexafluoroantimonate, 4-methoxyphenyldiphenylsulfonium trifluoromethanesulfonate, p-tolyldiphenylsulfonium trifluoromethanesulfonate, 2,4,6-trimethylphenyldiphenylsulfonium trifluoromethanesulfonate, 4-tert-butylphenyldiphenylsulfonium trifluoromethanesulfonate, 4-phenylthiophenyldiphenylsulfonium hexafluorophosphate, 4-phenylthiophenyldiphenylsulfonium hexafluoroantimonate, 1-(2-naphthoylmethyl)thiolanium hexafluoroantimonate, 1-(2-naphthoylmethyl)thiolanium trifluoroantimonate, 4-hydroxy-1-naphthyldimethylsulfonium hexafluoroantimonate, and 4-hydroxy-1-naphthyldimethylsulfonium trifluoromethanesulfonate.

Specifically, halogen-containing triazine compounds included in the above photoacid generator include, for example, 2-methyl-4,6-bis(trichloromethyl)-1,3,5-triazine, 2,4,6-tris(trichloromethyl)-1,3,5-triazine, 2-phenyl-4,6-bis(trichloromethyl)-1,3,5-triazine, 2-(4-chlorophenyl)-4,6-bis(trichloromethyl)-1,3,5-triazine, 2-(4-methoxyphenyl)-4,6-bis(trichloromethyl)-1,3,5-triazine, 2-(4-methoxy-1-naphthyl)-4,6-bis(trichloromethyl)-1,3,5-triazine, 2-(benzo[d][1,3]dioxolane-5-yl)-4,6-bis(trichloromethyl)-1,3,5-triazine, 2-(4-methoxystyryl)-4,6-bis(trichloromethyl)-1,3,5-triazine, 2-(3,4,5-trimethoxystyryl)-4,6-bis(trichloromethyl)-1,3,5-triazine, 2-(3,4,5-dimethoxystyryl)-4,6-bis(trichloromethyl)-1,3,5-triazine, 2-(2,4-dimethoxystyryl)-4,6-bis(trichloromethyl)-1,3,5-triazine, 2-(2-methoxystyryl)-4,6-bis(trichloromethyl)-1,3,5-triazine, 2-(4-butoxystyryl)-4,6-bis(trichloromethyl)-1,3,5-triazine, and 2-(4-benzyloxystyryl)-4,6-bis(trichloromethyl)-1,3,5-triazine.

Specifically, sulfone compounds included in the above photoacid generator include, for example, diphenyl sulfone, di-p-tolyldisulfone, bis(phenylsulfonyl)diazomethane, bis(4-chlorophenylsulfonyl)diazomethane, bis(p-tolylsulfonyl) diazomethane, bis(4-tert-butylphenylsulfonyl)diazomethane, bis(2,4-xylylsulfonyl)diazomethane, bis(cyclohexylsulfonyl)diazomethane, (benzoyl)(phenylsulfonyl)diazomethane, and phenylsulfonyl acetophenone.

Specifically, aromatic sulfonate compounds included in the above photoacid generator include, for example, α-benzoylbenzyl p-toluenesulfonate (commonly called benzoine tosylate), β-benzoyl-β-hydroxyphenetyl p-toluenesulfonate (commonly called α-methylolbenzoine tosylate), 1,2,3-benzenetoriyl trismethanesulfonate, 2,6-dinitrobenzyl p-toluenesulfonate, 2-nitrobenzyl p-toluenesulfonate, and 4-nitrobenzyl p-toluenesulfonate.

Specifically, sulfonate compounds of N-hydroxyimide included in the above photoacid generator include, for example, N-(phenylsulfonyloxy)succinimide, N-(trifluoromethylsulfonyloxy)succinimide, N-(p-chlorophenylsulfonyloxy)succinimide, N-(cyclohexylsulfonyloxy)succinimide, N-(1-naphthylsulfonyloxy)succinimide, N-(benzylsulfonyloxy)succinimide, N-(10-camphorsulfonyloxy)succinimide, N-(trifluoromethylsulfonyloxy)phthalimide, N-(trifluoromethylsulfonyloxy)-5-norbornene-2,3-dicarboxylmide, N-(trifluoromethylsulfonyloxy)naphthalimide, and N-(10-camphorsulfonyloxy)naphthalimide.

Among the various photoacid generators described above, the sulfonium salt is preferable. Especially, triphenylsulfonium trifluoromethanesulfonate, the sulfone compounds, especially, bis(4-tert-butylphenylsulfonyl) diazomethane, and bis(cyclohexylsulfonyl)diazomethane are preferable.

The above photoacid generators may be used independently or by mixing two or more of the photoacid generators. Although the blend ratio of the photoacid generator is not particularly limited and may be appropriately selected according to the purpose, the blend ratio is preferably 0.1 to 30 parts by mass based on 100 parts by mass of the hyperbranched polymer. More preferably, the blend ratio of the photoacid generator is 0.1 to 10 parts by mass.

The acid diffusion inhibitor included in the resist composition is not particularly limited as long as the inhibitor is a component having an effect of controlling diffusion phenomena of acid generated from the photoacid generator due to exposure during the resist film formation to prevent unfavorable chemical reactions in the non-exposure area. The acid diffusion inhibitor included in the resist composition may be selected appropriately from various known acid diffusion inhibitors according to the purpose.

The acid diffusion inhibitor included in the resist composition includes, for example, nitrogen-containing compounds having one nitrogen atom in the same molecule, compounds having two nitrogen atoms in the same molecule, polyamino compounds and polymers having three or more nitrogen atoms in the same molecule, amide-group-containing compounds, urea compounds, and nitrogen-containing heterocyclic compounds.

Nitrogen-containing compounds having one nitrogen atom in the same molecule and cited as a acid diffusion inhibitor include, for example, mono(cyclo)alkylamine, di(cyclo)alkylamine, tri(cyclo)alkylamine, and aromatic amine. Specifically, the mono(cyclo)alkylamine includes, for example, n-hexylamine, n-heptylamine, n-octylamine, n-nonylamine, n-decylamine, and cyclohexylamine.

Di(cyclo)alkylamine included in the nitrogen-containing compounds having one nitrogen atom in the same molecule includes, for example, di-n-butylamine, di-n-benzylamine, di-n-hexylamine, di-n-heptylamine, di-n-octylamine, di-n-nonylamine, di-n-decylamine, and cyclohexylmethylamine.

Tri(cyclo)alkylamine included in the nitrogen-containing compounds having one nitrogen atom in the same molecule includes, for example, triethylamine, tri-n-propylamine, tri-n-butylamine, tri-n-benzylamine, tri-n-hexylamine, tri-n-heptylamine, tri-n-octylamine, tri-n-nonylamine, tri-n-decylamine, cyclohexyldimethylamine, methyldicyclohexylamine, and tricyclohexylamine.

Aromatic amine included in the nitrogen-containing compounds having one nitrogen atom in the same molecule includes, for example, aniline, N-methylaniline, N,N-dimethylaniline, 2-methylaniline, 3-methylaniline, 4-methylaniline, 4-nitroaniline, diphenylamine, triphenylamine, and naphthylamine.

Nitrogen-containing compounds having two nitrogen atoms in the same molecule and cited as a acid diffusion inhibitor include, for example, ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, 2,2-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis[1-(4-aminophenyl)-1-methylethyl]benzene, 1,3-bis[1-(4-aminophenyl)-1-methylethyl]benzene, bis(2-dimethylaminoethyl)ether, and bis(2-diethylaminoethyl)ether.

Polyamino compounds and polymers having three or more nitrogen atoms in the same molecule and cited as a acid diffusion inhibitor include, for example, polyethylenimine, polyallylamine, and a polymer of n-(2-dimethylaminoethyl)acrylamide.

Amide-group-containing compounds cited as a acid diffusion inhibitor include, for example, N-t-butoxycarbonyl di-n-octylamine, N-t-butoxycarbonyl di-n-nonylamine, N-t-butoxycarbonyl di-n-decylamine, N-t-butoxycarbonyl dicyclohexylamine, N-t-butoxycarbonyl-1-adamantylamine, N-t-butoxycarbonyl-N-methyl-1-adamantylamine, N,N-di-t-butoxycarbonyl-1-adamantylamine, N,N-di-t-butoxycarbonyl-N-methyl-1-adamantylamine, N-t-butoxycarbonyl-4,4,-diaminodiphenylmethane, N,N′-di-t-butoxycarbonylhexamethylenediamine, N,N,N′N′-tetra-t-butoxycarbonylhexamethylenediamine, N,N′-di-t-butoxycarbonyl-1,7-diaminoheptane, N,N′-di-t-butoxycarbonyl-1,8-diaminooctane, N,N′-di-t-butoxycarbonyl-1,9-diaminononane, N,N-di-t-butoxycarbonyl-1,10-diaminodecane, N,N,-di-t-butoxycarbonyl-1,12-diaminododecane, N,N,-di-t-butoxycarbonyl-4,4′-diaminodiphenylmethane, N-t-butoxycarbonylbenzimidazole, N-t-butoxycarbonyl-2-methylbenzimidazole, N-t-butoxycarbonyl-2-phenylbenzimidazole, formamide, N-methylformamide, N,N-dimethylformamide, acetamide, N-methylacetamide, N,N-dimethylacetamide, propionamide, benzamide, pyrrolidone, and N-methylpyrrolidone.

Specifically, urea compounds cited as a acid diffusion inhibitor include, for example, urea, methylurea, 1,1-dimethylurea, 1,3-dimethylurea, 1,1,3,3-tetramethylurea, 1,3-diphenylurea, and tri-n-butylthiourea.

Specifically, nitrogen-containing heterocyclic compounds cited as a acid diffusion inhibitor include, for example, imidazole, 4-methylimidazole, 4-methyl-2-phenylimidazole, benzimidazole, 2-phenylbenzimidazole, pyridine, 2-methylpyridine, 4-methylpyridine, 2-ethylpyridine, 4-ethylpyridine, 2-phenylpyridine, 4-phenylpyridine, 2-methyl-4-phenylpyridine, nicotine, nicotinic acid, nicotinamide, quinoline, 4-hydroxyquinoline, 8-oxyquinoline, acridine, piperazine, 1-(2-hydroxyethyl)piperazine, pyrazine, pyrazole, pyridazine, quinoxaline, purine, pyrrolidine, piperidine, 3-piperidino-1,2-propanediol, morpholine, 4-methylmorpholine, 1,4-dimethylpiperazine, and 1,4-diazabicyclo[2.2.2]octane.

The acid diffusion inhibitors may be used independently or by mixing the two or more inhibitors. The compounding amount of the acid diffusion inhibitor is preferably 0.1 to 1000 parts by mass based on 100 parts by mass of the photoacid generator. More preferably, the compounding amount of the acid diffusion inhibitor is 0.5 to 10 parts by mass based on 100 parts by mass of the photoacid generator. The compounding amount of the acid diffusion inhibitor is not particularly limited and may appropriately be selected according to the purpose.

The surfactant included in the resist composition includes, for example, polyoxyethylene alkyl ether, polyoxyethylene alkyl aryl ether, sorbitan fatty ester, a nonionic surfactant of polyoxyethylene sorbitan fatty ester, a fluorine-containing surfactant, and a silicone-containing surfactant. The surfactant included in the resist composition is not particularly limited as long as the surfactant is a component exhibiting the effect of improving a coating property, striations, a developing property, etc., and may appropriately be selected from known surfactants according to the purpose.

Specifically, the polyoxyethylene alkyl ether cited as the surfactant included in the resist composition includes, for example, polyoxyethylene lauryl ether, polyoxyethylene stearyl ether, polyoxyethylene cetyl ether, and polyoxyethylene oleyl ether. The polyoxyethylene alkyl ether cited as the surfactant included in the resist composition includes, for example, polyoxyethylene octyl phenol ether, and polyoxyethylene nonyl phenol ether.

Specifically, sorbitan fatty ester cited as surfactant included in the resist composition includes, for example, sorbitan monolaurate, sorbitan monopalmitate, sorbitan monostearate, sorbitan monooleate, sorbitan trioleate, and sorbitan tristearate. Specifically, nonionic surfactant of polyoxyethylene sorbitan fatty ester cited as surfactant included in the resist composition includes, for example, polyoxyethylenesorbitan monolaurate, polyoxyethylenesorbitan monopalmitate, polyoxyethylenesorbitan monostearate, polyoxyethylenesorbitan trioleate, and polyoxyethylenesorbitan tristearate.

Specifically, the fluorine-containing surfactant cited as the surfactant included in the resist composition includes, for example, F Top EF301, EF303, and EF352 (manufactured by Shin Akita Kasei Co., Ltd.), Megafac F171, F173, F176, F189, and R08 (manufactured by Dainippon Ink and Chemicals, Inc.), Fluorard FC430 and FC431 (manufactured by Sumitomo 3M Ltd.), Asahi Guard AG710, Surflon S-382, SC101, SX102, SC103, SC104, SC105, and SC106 (manufactured by Asahi Glass Co., Ltd.).

The silicone-containing surfactant cited as the surfactant included in the resist composition includes, for example, organosiloxane KP341 (manufactured by Shin-Etsu Chemical Co., Ltd.). The above various surfactants may be used independently or by mixing the two or more surfactants.

The compounding amount of the above various surfactants is preferably, for example, 0.0001 to 5 parts by mass based on 100 parts by mass of the hyperbranched polymer. More preferably, the compounding amount of the above various surfactants is 0.0002 to 2 parts by mass based on 100 parts by mass of the hyperbranched polymer. The compounding amount of the above various surfactants is not particularly limited and may be selected appropriately according to the purpose.

Other components included in the resist composition include, for example, sensitizers, dissolution controllers, additives having an acid-dissociable group, alkali-soluble resins, dyes, pigments, adhesive auxiliaries, defoamers, stabilizers, and antihalation agents. Specifically, the sensitizers cited as other components included in the resist composition include, for example, acetophenones, benzophenones, naphthalenes, biacetyl, eosin, rose bengal, bylenes, anthracenes, and phenothiazine.

The sensitizers are not particularly limited provided the sensitizers have the effect of increasing the apparent sensitivity of the resist composition by absorbing energy of radiation and transferring the energy to the photoacid generator to cause the increase in the generation amount of acid. The sensitizers may be used independently or by mixing the two or more sensitizers.

Specifically, dissolution controllers cited as other components included in the resist composition include, for example, polyketone and polyspiroketal. The dissolution controllers cited as other components included in the resist composition are not particularly limited as long as the dissolution controllers more appropriately control the dissolution contrast and the dissolution rate when forming a resist. The dissolution controllers cited as other components included in the resist composition may be used independently or by mixing the two or more controllers.

Specifically, additives having an acid-dissociable group and cited as other components included in the resist composition include, for example, t-butyl 1-adamantanecarboxylate, t-butoxycarbonylmethyl 1-adamantanecarboxylate, di-t-butyl 1,3-adamantanedicarboxylate, t-butyl 1-adamantaneacetate, t-butoxycarbonylmethyl 1-adamantaneacetate, di-t-butyl 1,3-adamantanediacetate, t-butyl deoxycholate, t-butoxycarbonylmethyl deoxycholate, 2-ethoxyethyl deoxycholate, 2-cyclohexyloxyethyl deoxycholate, 3-oxocyclohexyl deoxycholate, tetrahydropyranyl deoxycholate, mevalonolactone deoxycholate ester, t-butyl lithocholate, t-butoxycarbonylmethyl lithocholate, 2-ethoxyethyl lithocholate, 2-cyclohexyloxyethyl lithocholate, 3-oxocyclohexyl lithocholate, tetrahydropyranyl lithocholate, and mevalonolactone lithocholate ester. The above various additives having an acid-dissociable group may be used independently or by mixing the two or more additives. The above various additives having an acid-dissociable group are not particularly limited as long as the additives further improve the dry etching resistance, the pattern shapes, the adhesiveness to substrates, etc.

Specifically, alkali-soluble resins cited as other components included in the resist composition include, for example, poly(4-hydroxystyrene), partially hydrogenated poly(4-hydroxystyrene), poly(3-hydroxystyrene), poly(3-hydroxystyrene), 4-hydroxystyrene/3-hydroxystyrene polymer, 4-hydroxystyrene/styrene polymer, novolak resin, polyvinyl alcohol, and polyacrylic acid. The weight-average molecular weights (Mw) of these alkali-soluble resins are typically and preferably 1000 to 1000000. More preferably, the weight-average molecular weights (Mw) of these alkali-soluble resins are 2000 to 100000.

The alkali-soluble resins may be used independently or by mixing the two or more resins. The alkali-soluble resins cited as other components included in the resist composition are not particularly limited as long as the alkali-soluble resins improve the alkali solubility of the resist composition of the present invention.

The dyes or pigments cited as other components included in the resist composition visualize a latent image of the exposed portion. Visualizing of the latent image of the exposed portion may alleviate the effect of the halation at the time of exposure. The adhesive auxiliaries cited as other components included in the resist composition may improve adhesiveness between the resist composition and substrates.

Specifically, solvents cited as other components included in the resist composition includes, for example, ketone, cyclic ketone, propylene glycol monoalkyl ether acetate, alkyl 2-hydroxypropionate, and alkyl 3-alkoxypropionate. The solvents cited as other components included in the resist composition are not particularly limited as long as the solvents is capable of dissolving, for example, other components included in the resist composition and may be selected appropriately from those safely used for the resist composition.

Specifically, the ketone included in the solvents cited as other components included in the resist composition includes, for example, methylisobutylketone, methylethylketone, 2-butanone, 2-pentanone, 3-methyl-2-butanone, 2-hexanone, 4-methyl-2-pentanon, 3-methyl-2-pentanon, 3,3-dimethyl-2-butanone, 2-heptanone, and 2-octanone.

Specifically, the cyclic ketone included in the solvents cited as other components included in the resist composition includes, for example, cyclohexane, cyclopentanone, 3-methylcyclopentanone, 2-methylcyclohexanone, 2,6-dimethylcyclohexanone, and isophorone.

Specifically, the propylene glycol monoalkyl ether acetate included in the solvents cited as other components included in the resist composition includes, for example, propylene glycol monomethyl ether acetate, propylene glycol monoethyl ether acetate, propylene glycol mono-n-propyl ether acetate, propylene glycol mono-1-propyl ether acetate, propylene glycol mono-n-butyl ether acetate, propylene glycol mono-1-butyl ether acetate, propylene glycol mono-sec-butyl ether acetate, and propylene glycol mono-t-butyl ether acetate.

Specifically, the alkyl 2-hydroxypropionate included in the solvents cited as other components included in the resist composition includes, for example, methyl 2-hydroxypropionate, ethyl 2-hydroxypropionate, n-propyl 2-hydroxypropionate, isopropyl 2-hydroxypropionate, n-butyl 2-hydroxypropionate, isobutyl 2-hydroxypropionate, sec-butyl 2-hydroxypropionate, and tert-butyl 2-hydroxypropionate.

The alkyl 3-alkoxypropionate included in the solvents cited as other components included in the resist composition includes, for example, methyl 3-methoxypropionate, ethyl 3-methoxypropionate, methyl 3-ethoxypropionate, and ethyl 3-ethoxypropionate.

Other solvents included in the solvents cited as other components included in the resist composition include, for example, n-propyl alcohol, i-propyl alcohol, n-butyl alcohol, t-butyl alcohol, cyclohexanol, ethylene glycol monomethyl ether, ethylene glycol monoethyl ether, ethylene glycol mono-n-propyl ether, ethylene glycol mono-n-butyl ether, diethylene glycol dimethyl ether, diethylene glycol diethyl ether, diethylene glycol di-n-propyl ether, diethylene glycol di-n-butyl ether, ethylene glycol monomethyl ether acetate, ethylene glycol monoethyl ether acetate, ethylene glycol mono-n-propyl ether acetate, propylene glycol, propylene glycol monomethyl ether, propylene glycol monoethyl ether, propylene glycol mono-n-propyl ether, ethyl 2-hydroxy-2-methyl propionate, ethyl ethoxyacetate, ethyl hydroxyacetate, methyl 2-hydroxy-3-methylbutyrate, 3-methoxybutylacetate, 3-methyl-3-methoxybutylacetate, 3-methyl-3-methoxybutylpropionate, 3-methyl-3-methoxybutylbutyrate, ethyl acetate, n-propyl acetate, n-butyl acetate, methyl acetoacetoate, ethyl acetoacetate, methyl pyruvate, ethyl pyruvate, N-methyl pyrrolidone, N,N-dimethylformamide, N,N-dimethylacetamide, benzyl ethyl ether, di-n-hexyl ether, ethylene glycol monomethyl ether, diethylene glycol monoethyl ether, 7-butyrolactone, toluene, xylene, caproic acid, caprylic acid, octane, 1-octanol, 1-nonanol, benzyl alcohol, benzyl acetate, ethyl benzoate, diethyl oxalate, diethyl maleate, ethylene carbonate, and propylene carbonate. The above solvents may be used independently or by mixing the two or more solvents.

The resist composition including the hyperbranched polymer synthesized with the above method may be exposed in a pattern-like form and developed in a patterning process. The above resist composition may support electron-beam, deep-ultraviolet (DUV), and extreme-ultraviolet (EUV) light sources requiring nano-order surface smoothness and form fine patterns for manufacturing semiconductor integrated circuits. Therefore, the resist composition including the hyperbranched polymer synthesized with the above method may preferably be used in various fields using semiconductor integrated circuits manufactured with the use of light sources applying light having short wavelengths.

If a semiconductor integrated circuit manufactured with the use of the resist composition including the above hyperbranched polymer is exposed, heated, dissolved in developing liquid, and washed with water, etc., when manufactured, substantially no undissolved residue is generated and substantially perpendicular edges can be acquired.

According to the hyperbranched polymer synthesizing method of the embodiment, the rapid increase in the weight-average molecular weight (Mw) of the hyperbranched core polymer, i.e., the molecular weight of the hyperbranched core polymer can be prevented to stably manufacture a large amount of the hyperbranched polymer having the desired molecular weight and branching degree without gelation as described above.

According to the hyperbranched polymer of the embodiment, the resist composition including the hyperbranched polymer with stable performance can be manufactured in large amounts without gelation.

According to the resist composition of the embodiment, high-integration high-capacity semiconductor integrated circuits with stable performance can be manufactured.

The examples of the embodiment of the first chapter above will hereinafter be described. The examples of the embodiment of the first chapter above according to the present invention are not limited to the following specific examples and are not to be construed in a limited way from the following specific examples.

### (Weight-Average Molecular Weight (Mw))

The weight-average molecular weight (Mw) of the core portion of the hyperbranched polymer of the examples will be described. The weight-average molecular weight (Mw) of the core portion of the hyperbranched polymer of the examples is a value obtained by preparing a 0.5 mass % tetrahydrofuran solution and performing measurement with a GPC HCL-8020 apparatus manufactured by Tosoh Corporation and two coupled TSKgel HXL-L columns (manufactured by Tosoh Corporation) under the temperature of 40 degrees C. In the measurement, tetrahydrofuran was used as a mobile solvent. In the measurement, polystyrene was used as a standard substance.

### (Branching Degree (Br))

The branching degree (Br) of the hyperbranched polymer of the examples will be described. The branching degree (Br) of the hyperbranched polymer of the examples was obtained by measuring ¹H-NMR of the product as follows. Specifically, the branching degree (Br) was calculated by carrying out an operation of the equation (A) using an integration ratio H1° of proton of the —CH₂Cl site appearing at 4.6 ppm and an integration ratio H2° of proton of the —CHCl site appearing at 4.8 ppm. If the polymerization proceeds at both the —CH₂Cl site and the —CHCl site and the branching is enhanced, the value of the branching degree (Br) of the hyperbranched polymer approaches 0.5.

### First Example

The hyperbranched polymer of a first example will be described. The hyperbranched polymer of the first example was synthesized according to the following method. First, 6.6 g of 2,2′-bipyridyl, 2.1 g of copper(I) chloride, 160 mL of chlorobenzene, and 17 mL of acetonitrile were charged into a 300-mL four-neck reactor; a reaction apparatus was assembled by attaching a dropping funnel with 32.5 g of chloromethylstyrene measured, a cooling tube, and an agitator; the inside of the reaction apparatus was entirely degassed; and the inside of the reaction apparatus was entirely replaced with argon after the degassing. After the replacement with argon, the above mixture was heated to 115 degrees C. and chloromethylstyrene was dropped into the reactor for one hour. After the dropping was completed, the mixture was heated and agitated for three hours. The reaction time was set to four hours including the time for dropping chloromethylstyrene into the reactor.

After the reaction was completed, 1000 mL of tetrahydrofuran and 200 g of active alumina were added to the reaction mixture and the mixture was agitated for one hour. The active alumina was filtrated off through filtration under reduced pressure and tetrahydrofuran in the filtrate was distilled by an evaporator. Subsequently, 350 mL of methanol was added to the residue for reprecipitation and supernatant liquid was decanted after being left still overnight.

After the decantation, the precipitate was dried under reduced pressure to acquire 23.1 g of poly(chloromethylstyrene). The yield was 71%. The weight-average molecular weight (Mw) of the polymer obtained by the GPC measurement (in terms of polystyrene) was 2000, and the branching degree (Br) obtained by the ¹H-NMR measurement was 0.52 (see Table 1 below).

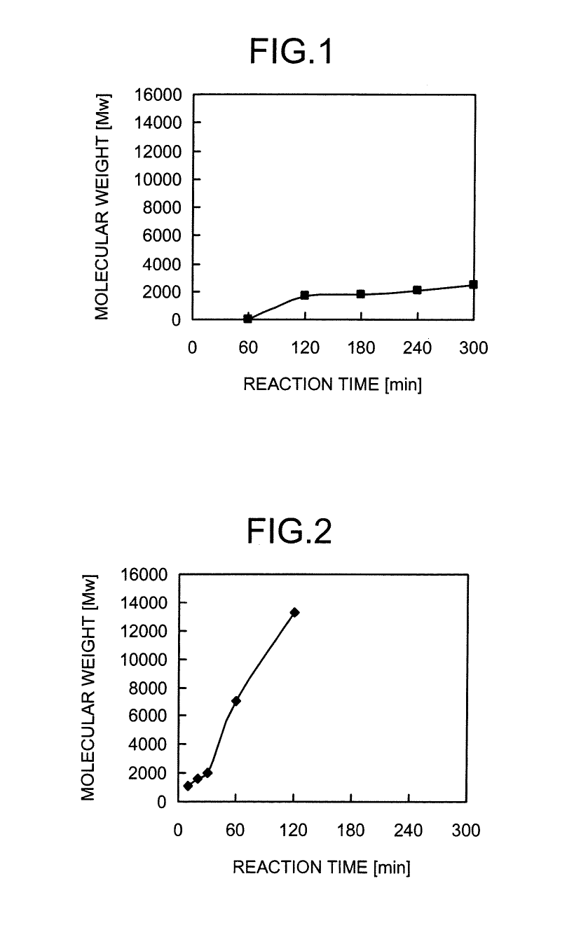

When the polymerization reaction described in the first example was further performed twice, the weight-average molecular weight (Mw) of the polymer obtained from the second reaction was 2000, and the branching degree (Br) obtained by the ¹H-NMR measurement was 0.51. The weight-average molecular weight (Mw) of the polymer obtained from the third reaction was 1900, and the branching degree (Br) obtained by the ¹H-NMR measurement was 0.52 (see Table 1 below). The result of the first example is depicted in FIG. 1. FIG. 1 is a graph indicating, with respect to the reaction time (min), the weight-average molecular weight (Mw) obtained from the reaction according to the method described in the first example.

### Second Example

The hyperbranched polymer of a second example will be described. The hyperbranched polymer of the second example was synthesized according to the following method. First, 6.6 g of 2,2′-bipyridyl, 2.1 g of copper(I) chloride, 160 mL of chlorobenzene, and 25 mL of DMF were charged into a 300-mL four-neck reactor; a reaction apparatus was assembled by attaching a dropping funnel with 32.5 g of chloromethylstyrene measured, a cooling tube, and an agitator; the inside of the reaction apparatus was entirely degassed; and the inside of the reaction apparatus was entirely replaced with argon after the degassing. After the replacement with argon, the above mixture was heated to 125 degrees C. and chloromethylstyrene was dropped into the reactor for one hour. After the dropping was completed, the mixture was heated and agitated for three hours. The reaction time was set to four hours including the time for dropping chloromethylstyrene into the reactor.

After the reaction was completed, 1000 mL of tetrahydrofuran and 200 g of active alumina were added to the reaction mixture and the mixture was agitated for one hour. The active alumina was filtrated off through filtration under reduced pressure and tetrahydrofuran in the filtrate was distilled by an evaporator. Subsequently, 350 mL of methanol was added to the residue for reprecipitation and supernatant liquid was decanted after being left still overnight.

The precipitate was dried under reduced pressure to acquire 19.8 g of poly(chloromethylstyrene). The yield was 61%. The weight-average molecular weight (Mw) of the polymer obtained by the GPC measurement (in terms of polystyrene) was 2000, and the branching degree (Br) obtained by the ¹H-NMR measurement was 0.52 (see Table 1 below).

When the polymerization reaction described in the second example was further performed twice, the weight-average molecular weight (Mw) of the polymer obtained from the second reaction was 2100, and the branching degree (Br) obtained by the ¹H-NMR measurement was 0.52. The weight-average molecular weight (Mw) of the polymer obtained from the third reaction was 1950, and the branching degree (Br) obtained by the ¹H-NMR measurement was 0.52 (see Table 1 below).

### Third Example

The hyperbranched polymer of a third example will be described. The hyperbranched polymer of the third example was synthesized according to the following method. First, 6.6 g of 2,2′-bipyridyl, 2.1 g of copper(I) chloride, 160 mL of chlorobenzene, and 32 mL of benzonitrile were charged into a 300-mL four-neck reactor; a reaction apparatus was assembled by attaching a dropping funnel with 32.5 g of chloromethylstyrene measured, a cooling tube, and an agitator; the inside of the reaction apparatus was entirely degassed; and the inside of the reaction apparatus was entirely replaced with argon after the degassing. After the replacement with argon, the above mixture was heated to 125 degrees C. and chloromethylstyrene was dropped into the reactor for one hour. After the dropping was completed, the mixture was heated and agitated for three hours. The reaction time was set to four hours including the time for dropping chloromethylstyrene into the reactor.

After the reaction was completed, 1000 mL of tetrahydrofuran and 200 g of active alumina were added to the reaction mixture and the mixture was agitated for one hour. The active alumina was filtrated off through filtration under reduced pressure and tetrahydrofuran in the filtrate was distilled by an evaporator. Subsequently, 350 mL of methanol was added to the residue for reprecipitation and supernatant liquid was decanted after being left still overnight.

After decantation, the precipitate was dried under reduced pressure to acquire 19.2 g of poly(chloromethylstyrene). The yield was 59%. The weight-average molecular weight (Mw) of the polymer obtained by the GPC measurement (in terms of polystyrene) was 3100, and the branching degree (Br) obtained by the ¹H-NMR measurement was 0.50 (see Table 1 below).

When the polymerization reaction described in the third example was further performed twice, the weight-average molecular weight (Mw) of the polymer obtained from the second reaction was 3000, and the branching degree (Br) obtained by the ¹H-NMR measurement was 0.50. The weight-average molecular weight (Mw) of the polymer obtained from the third reaction was 3200, and the branching degree (Br) obtained by the ¹H-NMR measurement was 0.50 (see Table 1 below).

### Fourth Example

The hyperbranched polymer of a fourth example will be described. The hyperbranched polymer of the fourth example was synthesized according to the following method. First, 6.6 g of 2,2′-bipyridyl, 2.1 g of copper(I) chloride, 160 mL of chlorobenzene, and 32 mL of propionitrile were charged into a 300-mL four-neck reactor; a reaction apparatus was assembled by attaching a dropping funnel with 32.5 g of chloromethylstyrene measured, a cooling tube, and an agitator; the inside of the reaction apparatus was entirely degassed; and the inside of the reaction apparatus was entirely replaced with argon after the degassing.

After the replacement with argon, the above mixture was heated to 115 degrees C. and chloromethylstyrene was dropped into the reactor for one hour. After the dropping was completed, the mixture was heated and agitated for three hours. The reaction time was set to four hours including the time for dropping chloromethylstyrene into the reactor.

After the reaction was completed, 1000 mL of tetrahydrofuran and 200 g of active alumina were added to the reaction mixture and the mixture was agitated for one hour. The active alumina was filtrated off through filtration under reduced pressure and tetrahydrofuran in the filtrate was distilled by an evaporator. Subsequently, 350 mL of methanol was added to the residue for reprecipitation and supernatant liquid was decanted after being left still overnight.

After decantation, the precipitate was dried under reduced pressure to acquire 17.9 g of poly(chloromethylstyrene). The yield was 55%. The weight-average molecular weight (Mw) of the polymer obtained by the GPC measurement (in terms of polystyrene) was 2900, and the branching degree (Br) obtained by the ¹H-NMR measurement was 0.51 (see Table 1 below).

When the polymerization reaction described in the fourth example was further performed twice, the weight-average molecular weight (Mw) of the polymer obtained from the second reaction was 3000, and the branching degree (Br) obtained by the ¹H-NMR measurement was 0.51. The weight-average molecular weight (Mw) of the polymer obtained from the third reaction was 3000, and the branching degree (Br) obtained by the ¹H-NMR measurement was 0.51 (see Table 1 below).

### Fifth Example

The hyperbranched polymer of a fifth example will be described. The hyperbranched polymer of the fifth example was synthesized according to the following method. First, 6.6 g of 2,2′-bipyridyl, 2.1 g of copper(I) chloride, 160 mL of chlorobenzene, and 17 mL of acetone were charged into a 300-mL four-neck reactor; a reaction apparatus was assembled by attaching a dropping funnel with 32.5 g of chloromethylstyrene measured, a cooling tube, and an agitator; the inside of the reaction apparatus was entirely degassed; and the inside of the reaction apparatus was entirely replaced with argon after the degassing. After the replacement with argon, the above mixture was heated to 115 degrees C. and chloromethylstyrene was dropped into the reactor for one hour. After the dropping was completed, the mixture was heated and agitated for four hours. The reaction time was set to five hours including the time for dropping chloromethylstyrene into the reactor.

After the reaction was completed, 1000 mL of tetrahydrofuran and 200 g of active alumina were added to the reaction mixture and the mixture was agitated for one hour. The active alumina was filtrated off through filtration under reduced pressure and tetrahydrofuran in the filtrate was distilled by an evaporator. Subsequently, 350 mL of methanol was added to the residue for reprecipitation and supernatant liquid was decanted after being left still overnight.

After decantation, the precipitate was dried under reduced pressure to acquire 20.5 g of poly(chloromethylstyrene). The yield was 63%. The weight-average molecular weight (Mw) of the polymer obtained by the GPC measurement (in terms of polystyrene) was 4000, and the branching degree (Br) obtained by the ¹H-NMR measurement was 0.50 (see Table 1 below).

When the polymerization reaction described in the fifth example was further performed twice, the weight-average molecular weight (Mw) of the polymer obtained from the second reaction was 3900, and the branching degree (Br) obtained by the ¹H-NMR measurement was 0.51. The weight-average molecular weight (Mw) of the polymer obtained from the third reaction was 4100, and the branching degree (Br) obtained by the ¹H-NMR measurement was 0.50 (see Table 1 below).

### Sixth Example

The hyperbranched polymer of a sixth example will be described. The hyperbranched polymer of the sixth example was synthesized according to the following method. First, 6.6 g of 2,2′-bipyridyl, 2.1 g of copper(I) chloride, 160 mL of chlorobenzene, and 32 mL of DMSO were charged into a 300-mL four-neck reactor; a reaction apparatus was assembled by attaching a dropping funnel with 32.5 g of chloromethylstyrene measured, a cooling tube, and an agitator; the inside of the reaction apparatus was entirely degassed; and the inside of the reaction apparatus was entirely replaced with argon after the degassing. After the replacement with argon, the above mixture was heated to 125 degrees C. and chloromethylstyrene was dropped into the reactor for one hour. After the dropping was completed, the mixture was heated and agitated for four hours. The reaction time was set to five hours including the time for dropping chloromethylstyrene into the reactor.

After the reaction was completed, 1000 mL of tetrahydrofuran and 200 g of active alumina were added to the reaction mixture and the mixture was agitated for one hour. The active alumina was filtrated off through filtration under reduced pressure and tetrahydrofuran in the filtrate was distilled by an evaporator. Subsequently, 350 mL of methanol was added to the residue for reprecipitation and supernatant liquid was decanted after being left still overnight.

After decantation, the precipitate was dried under reduced pressure to acquire 19.5 g of poly(chloromethylstyrene). The yield was 60%. The weight-average molecular weight (Mw) of the polymer obtained by the GPC measurement (in terms of polystyrene) was 3800, and the branching degree (Br) obtained by the ¹H-NMR measurement was 0.51 (see Table 1 below).

When the polymerization reaction described in the sixth example was further performed twice, the weight-average molecular weight (Mw) of the polymer obtained from the second reaction was 3800, and the branching degree (Br) obtained by the ¹H-NMR measurement was 0.50. The weight-average molecular weight (Mw) of the polymer obtained from the third reaction was 3900, and the branching degree (Br) obtained by the ¹H-NMR measurement was 0.51 (see Table 1 below).

### Seventh Example

The hyperbranched polymer of a seventh example will be described. The hyperbranched polymer of the seventh example was synthesized according to the following method. First, 16.6 g of 2,2′-bipyridyl, 5.3 g of copper(I) chloride, and 160 mL of chlorobenzene were charged into a 300-mL four-neck reactor; a reaction apparatus was assembled by attaching a dropping funnel with 32.5 g of chloromethylstyrene measured, a cooling tube, and an agitator; the inside of the reaction apparatus was entirely degassed; and the inside of the reaction apparatus was entirely replaced with argon after the degassing. After the replacement with argon, the above mixture was heated to 125 degrees C. and chloromethylstyrene was dropped into the reactor for two hours. After the dropping was completed, the mixture was heated and agitated for one hour. The reaction time was set to three hours including the time for dropping chloromethylstyrene into the reactor.

After the reaction was completed, 1000 mL of tetrahydrofuran and 200 g of active alumina were added to the reaction mixture and the mixture was agitated for one hour. The active alumina was filtrated off through filtration under reduced pressure and tetrahydrofuran in the filtrate was distilled by an evaporator. Subsequently, 350 mL of methanol was added to the residue for reprecipitation and supernatant liquid was decanted after being left still overnight.

After decantation, the precipitate was dried under reduced pressure to acquire 16.9 g of poly(chloromethylstyrene). The yield was 52%. The weight-average molecular weight (Mw) of the polymer obtained by the GPC measurement (in terms of polystyrene) was 5900, and the branching degree (Br) obtained by the ¹H-NMR measurement was 0.51 (see Table 1 below).

When the polymerization reaction described in the seventh example was further performed twice, the weight-average molecular weight (Mw) of the polymer obtained from the second reaction was 6000, and the branching degree (Br) obtained by the ¹H-NMR measurement was 0.51. The weight-average molecular weight (Mw) of the polymer obtained from the third reaction was 5800, and the branching degree (Br) obtained by the ¹H-NMR measurement was 0.51 (see Table 1 below).

### Eighth Example

First, 6.6 g of 2,2′-bipyridyl, 2.1 g of copper(I) chloride, 160 mL of chlorobenzene, 32 mL of benzonitrile, and 32.5 g of chloromethylstyrene were charged into a 300-mL four-neck reactor; after a reaction apparatus was assembled by attaching a cooling tube and an agitator, the inside of the reaction apparatus was entirely degassed; and the inside of the reaction apparatus was entirely replaced with argon after the degassing. After the replacement with argon, the above mixture was heated to 125 degrees C. and allowed to react for four hours.

After the reaction was completed, 1000 mL of tetrahydrofuran and 200 g of active alumina were added to the reaction mixture and the mixture was agitated for one hour. The active alumina was filtrated off through filtration under reduced pressure and tetrahydrofuran in the filtrate was distilled by an evaporator. Subsequently, 350 mL of methanol was added to the residue for reprecipitation and supernatant liquid was decanted after being left still overnight.

After decantation, the precipitate was dried under reduced pressure to acquire 26.0 g of poly(chloromethylstyrene). The yield was 80%. The weight-average molecular weight (Mw) of the polymer obtained by the GPC measurement (in terms of polystyrene) was 5000, and the branching degree (Br) obtained by the ¹H-NMR measurement was 0.50 (see Table 1 below).

When the polymerization reaction described in the eighth example was further performed twice, the weight-average molecular weight (Mw) of the polymer obtained from the second reaction was 4900, and the branching degree (Br) obtained by the ¹H-NMR measurement was 0.50. The weight-average molecular weight (Mw) of the polymer obtained from the third reaction was 5000, and the branching degree (Br) obtained by the ¹H-NMR measurement was 0.50 (see Table 1 below).

### Ninth Example

The hyperbranched polymer of a ninth example will be described. The hyperbranched polymer of the ninth example was synthesized according to the following method. First, 6.6 g of 2,2′-bipyridyl, 2.1 g of copper(I) chloride, and 281 mL of benzonitrile were charged into a 300-mL four-neck reactor; a reaction apparatus was assembled by attaching a dropping funnel with 32.5 g of chloromethylstyrene measured, a cooling tube, and an agitator; the inside of the reaction apparatus was entirely degassed; and the inside of the reaction apparatus was entirely replaced with argon after the degassing. After the replacement with argon, the above mixture was heated to 125 degrees C. and chloromethylstyrene was dropped for 30 minutes. After the dropping was completed, the mixture was heated and agitated for 4.5 hours. The reaction time was set to five hours including the time for dropping chloromethylstyrene into the reactor.

After the reaction was completed, 1000 mL of tetrahydrofuran and 200 g of active alumina were added to the reaction mixture and the mixture was agitated for one hour. The active alumina was filtrated off through filtration under reduced pressure and tetrahydrofuran in the filtrate was distilled by an evaporator. Subsequently, a premixed solvent of 700 mL of methanol and 140 mL of water was added to the residue for reprecipitation and supernatant liquid was decanted after being left still overnight.

After decantation, the precipitate was dried under reduced pressure to acquire 16.3 g of poly(chloromethylstyrene). The yield was 50%. The weight-average molecular weight (Mw) of the polymer obtained by the GPC measurement (in terms of polystyrene) was 1000, and the branching degree (Br) obtained by the ¹H-NMR measurement was 0.54 (see Table 1 below).

When the polymerization reaction described in the ninth example was further performed twice, the weight-average molecular weight (Mw) of the polymer obtained from the second reaction was 970, and the branching degree (Br) obtained by the ¹H-NMR measurement was 0.53. The weight-average molecular weight (Mw) of the polymer obtained from the third reaction was 1040, and the branching degree (Br) obtained by the ¹H-NMR measurement was 0.54 (see Table 1 below).

### Tenth Example

The hyperbranched polymer of a tenth example will be described. The hyperbranched polymer of the tenth example was synthesized according to the following method. First, 11.8 g of 2,2′-bipyridyl, 3.5 g of copper(I) chloride, and 345 mL of benzonitrile were charged into a 300-mL four-neck reactor; a reaction apparatus was assembled by attaching a dropping funnel with 54.2 g of chloromethylstyrene measured, a cooling tube, and an agitator; the inside of the reaction apparatus was entirely degassed; and the inside of the reaction apparatus was entirely replaced with argon after the degassing. After the replacement with argon, the above mixture was heated to 125 degrees C. and chloromethylstyrene was dropped for 30 minutes. After the dropping was completed, the mixture was heated and agitated for 3.5 hours. The reaction time was set to four hours including the time for dropping chloromethylstyrene into the reactor.

After the reaction, the reaction solution was filtered through a filter paper with a retaining particle size of 1 μm. Then, the filtered solution was poured into a pre-mixed solution of 844 grams of methanol and 211 grams of ultrapure water to re-precipitate poly(chloromethyl styrene).

After 29 grams of the polymer obtained by the re-precipitation was dissolved in 100 grams of benzonitrile, the resulting solution was added by a mixed solution of 200 grams of methanol and 50 grams of ultrapure water. After the centrifugal separation, the solvents were removed by decantation to recover the polymer. This recovery operation was repeated three times to obtain a deposited polymer.

After decantation, the precipitate was dried under reduced pressure to acquire 14.0 g of poly(chloromethylstyrene). The yield was 26%. The weight-average molecular weight (Mw) of the polymer obtained by the GPC measurement (in terms of polystyrene) was 1140, and the branching degree (Br) obtained by the ¹H-NMR measurement was 0.51 (see Table 1 below).

When the polymerization reaction described in the tenth example was further performed twice, the weight-average molecular weight (Mw) of the polymer obtained from the second reaction was 1070, and the branching degree (Br) obtained by the ¹H-NMR measurement was 0.52. The weight-average molecular weight (Mw) of the polymer obtained from the third reaction was 1040, and the branching degree (Br) obtained by the ¹H-NMR measurement was 0.51 (see Table 1 below).

### First Comparative Example

The hyperbranched polymer of a first comparative example will be described. The hyperbranched polymer of the first comparative example was synthesized according to the following method. First, 16.6 g of 2,2′-bipyridyl, 5.3 g of copper(I) chloride, 160 mL of chlorobenzene, and 32.5 g of chloromethylstyrene were charged into a 300-mL four-neck reactor; after a reaction apparatus was assembled by attaching a cooling tube and an agitator, the inside of the reaction apparatus was entirely degassed; and the inside of the reaction apparatus was entirely replaced with argon after the degassing. After the replacement with argon, the above mixture was heated to 125 degrees C. and agitated for 27 minutes.

After the reaction was completed, 1000 mL of tetrahydrofuran and 200 g of active alumina were added to the reaction mixture and the mixture was agitated for one hour. The active alumina was filtrated off through filtration under reduced pressure and tetrahydrofuran in the filtrate was distilled by an evaporator. Subsequently, 350 mL of methanol was added to the residue for reprecipitation and supernatant liquid was decanted after being left still overnight.

After the decantation, the precipitate was dried under reduced pressure to acquire 25.0 g of poly(chloromethylstyrene). The yield was 77%. The weight-average molecular weight (Mw) of the polymer obtained by the GPC measurement (in terms of polystyrene) was 2000, and the branching degree (Br) obtained by the ¹H-NMR measurement was 0.50 (see Table 1 below).

When the polymerization reaction described in the first comparative example was further performed twice, the weight-average molecular weight (Mw) of the polymer obtained from the second reaction was 4000, and the branching degree (Br) obtained by the ¹H-NMR measurement was 0.51. The weight-average molecular weight (Mw) of the polymer obtained from the third reaction was 2800, and the branching degree (Br) obtained by the ¹H-NMR measurement was 0.50 (see Table 1 below). The result of the first comparative example is depicted in FIG. 2. FIG. 2 is a graph indicating, with respect to the reaction time (min), the weight-average molecular weight (Mw) obtained from the reaction according to the method described in the first comparative example.

### Second Comparative Example

The hyperbranched polymer of a second comparative example will be described. The hyperbranched polymer of the second comparative example was synthesized according to the following method. First, 16.6 g of 2,2′-bipyridyl, 5.3 g of copper(I) chloride, 160 mL of chlorobenzene, and 32.5 g of chloromethylstyrene were charged into a 300-mL four-neck reactor; a reaction apparatus was assembled by attaching a cooling tube and an agitator; the inside of the reaction apparatus was entirely degassed; and the inside of the reaction apparatus was entirely replaced with argon after the degassing. After the replacement with argon, the above mixture was heated to 125 degrees C. and agitated for 240 minutes. The reaction mixture was gelatinized and a polymer insoluble to THF, chloroform, etc., was acquired. The acquired polymer could not be analyzed by GPC and NMR.

### Third Comparative Example

The hyperbranched polymer of a third comparative example will be described. The hyperbranched polymer of the third comparative example was synthesized according to the following method. First, 1.33 g of 2,2′-bipyridyl, 0.42 g of copper(I) chloride, 160 mL of chlorobenzene, and 32.5 g of chloromethylstyrene were charged into a 300-mL four-neck reactor; a reaction apparatus was assembled by attaching a cooling tube and an agitator; the inside of the reaction apparatus was entirely degassed; and the inside of the reaction apparatus was entirely replaced with argon after the degassing. After the replacement with argon, the above mixture was heated to 125 degrees C. and agitated for 300 minutes.

After the reaction was completed, 1000 mL of tetrahydrofuran and 200 g of active alumina were added to the reaction mixture and the mixture was agitated for one hour. The active alumina was filtrated off through filtration under reduced pressure and tetrahydrofuran in the filtrate was distilled by an evaporator. Subsequently, 350 mL of methanol was added to the residue for reprecipitation and supernatant liquid was decanted after being left still overnight.

After, decantation, the precipitate was dried under reduced pressure to acquire 19.5 g of poly(chloromethylstyrene). The yield was 60% (see Table 1 below). The weight-average molecular weight (Mw) of the polymer obtained by the GPC measurement (in terms of polystyrene) was 3000, and the branching degree (Br) obtained by the ¹H-NMR measurement was 0.71 (see Table 1 below).

When the polymerization reaction described in the third comparative example was further performed twice, the weight-average molecular weight (Mw) of the polymer obtained from the second reaction was 2900, and the branching degree (Br) obtained by the ¹H-NMR measurement was 0.70. The weight-average molecular weight (Mw) of the polymer obtained from the third reaction was 3000, and the branching degree (Br) obtained by the ¹H-NMR measurement was 0.74 (see Table 1 below).

As described, in the first to ninth examples, the hyperbranched polymer is generated by performing at least one of the polymerizing methods described as (1′) and (2′) below:

(1′) Adding among compounds represented by formula (1-1) and compounds represented by formula (1-2), at least one type; and

(2′) Dropping and mixing a monomer into a reaction system for a predetermined time period, where each mixing amount of the monomer into the reaction system is less than a total amount of the monomer to be mixed with the reaction system.

Table 1 represents the types of the additives used in the first to tenth examples and the first to third comparative examples, the polymerization conditions, and the measurement results. In Table 1, the polymerization conditions are represented by a catalyst amount, a monomer dropping time, and a reaction time. In Table 1, the measurement results are represented by a molecular weight and a branching degree of each polymerization.

TABLE 1

| | | polymerization condition | | | | | | |
|---|---|---|---|---|---|---|---|---|
| | | catalyst | monomer | | | | | |
| | | amount | dropping | reaction | measurement result | | | |
| | additive | (mol %) | time | time | | first | second | third |
| first | acetonitrile | 10 | 60 | 240 | molecular | 2000 | 2000 | 1900 |
| example | | | minutes | minutes | weight | | | |
| | | | | | branching | 0.52 | 0.51 | 0.52 |
| | | | | | degree | | | |
| second | DMF | 10 | 60 | 240 | molecular | 2000 | 2100 | 1950 |
| example | | | minutes | minutes | weight | | | |
| | | | | | branching | 0.52 | 0.52 | 0.52 |
| | | | | | degree | | | |
| third | benzonitrile | 10 | 60 | 240 | molecular | 3100 | 3000 | 3200 |
| example | | | minutes | minutes | weight | | | |
| | | | | | branching | 0.50 | 0.50 | 0.50 |
| | | | | | degree | | | |
| fourth | propionitrile | 10 | 60 | 240 | molecular | 2900 | 3000 | 3000 |
| example | | | minutes | minutes | weight | | | |
| | | | | | branching | 0.51 | 0.51 | 0.51 |
| | | | | | degree | | | |
| fifth | acetone | 10 | 60 | 300 | molecular | 4000 | 3900 | 4100 |
| example | | | minutes | minutes | weight | | | |
| | | | | | branching | 0.50 | 0.51 | 0.50 |
| | | | | | degree | | | |
| sixth | DMSO | 10 | 60 | 300 | molecular | 3800 | 3800 | 3900 |
| example | | | minutes | minutes | weight | | | |
| | | | | | branching | 0.51 | 0.50 | 0.51 |
| | | | | | degree | | | |
| seventh | — | 25 | 120 | 180 | molecular | 5900 | 6000 | 5800 |
| example | | | minutes | minutes | weight | | | |
| | | | | | branching | 0.51 | 0.51 | 0.51 |
| | | | | | degree | | | |
| eighth | benzonitrile | 10 | 60 | 240 | molecular | 5000 | 4900 | 5000 |
| example | | | minutes | minutes | weight | | | |
| | | | | | branching | 0.50 | 0.50 | 0.50 |
| | | | | | degree | | | |
| ninth | benzonitrile | 10 | 30 | 300 | molecular | 1000 | 970 | 1040 |
| example | | | minutes | minutes | weight | | | |
| | | | | | branching | 0.54 | 0.53 | 0.54 |
| | | | | | degree | | | |
| tenth | benzonitrile | 10 | 30 | 240 | molecular | 1140 | 1070 | 1040 |
| example | | | minutes | minutes | weight | | | |
| | | | | | branching | 0.51 | 0.52 | 0.51 |
| | | | | | degree | | | |
| first | — | 25 | — | 27 | molecular | 2000 | 4000 | 2800 |
| comparative | | | | minutes | weight | | | |
| example | | | | | | | | |
| | | | | | branching | 0.50 | 0.51 | 0.50 |
| | | | | | degree | | | |
| second | — | 25 | — | 240 | molecular | gelation | gelation | gelation |
| comparative | | | | minutes | weight | | | |
| example | | | | | | | | |
| | | | | | branching | gelation | gelation | gelation |
| | | | | | degree | | | |
| third | — | 2 | — | 300 | molecular | 3000 | 2900 | 3000 |
| comparative | | | | minutes | weight | | | |
| example | | | | | | | | |
| | | | | | branching | 0.71 | 0.70 | 0.74 |
| | | | | | degree | | | |

As indicated above, in the first comparative example, although the hyperbranched polymer with a high branching degree can be acquired, the molecular weight rapidly increases. Therefore, if the reaction is divided by time in the synthesis of the hyperbranched polymer, it is difficult to stably acquire a polymer having a constant molecular weight. In the second comparative example, gelation occurs if the reaction time is too long. Although a polymer having a constant molecular weight can stably be acquired by reducing the catalyst amount in the third comparative example, the branching degree is reduced in the hyperbranched polymer due to the reduced catalyst amount, resulting in a polymer difficult to call a hyperbranched polymer.

On the other hand, in the first to tenth examples, high branching degrees can be kept in the generated hyperbranched polymers by performing at least one of the polymerizing methods (1′) and (2′) described above and if the catalysts are added in amounts enabling high branching degrees to be kept, the rapid increase in molecular weight can be prevented to stably acquire approximately similar molecular weights.

### Eleventh Example

The core-shell hyperbranched polymer of an eleventh example will be described. The core-shell hyperbranched polymer of the eleventh example was synthesized with the use of the hyperbranched polymer of the first example according to the following method. Into a 1000-mL four-neck reactor under an argon gas atmosphere, 2.7 g of copper(I) chloride, 8.3 g of 2,2′-bipyridyl, and 16.2 g of the hyperbranched polymer of the first example were introduced, and 401 mL of monochlorobenzene and 78 mL of acrylic acid tert-butyl ester were injected by syringe, respectively. After the substances were injected into the reactor, the mixture in the reactor was heated and agitated at 125 degrees C. for five hours.

After the reaction was completed, 200 mL of ultrapure water was added to the reaction mixture and the reaction mixture was agitated for 20 minutes. A water layer was subsequently removed. This operation was repeated four times to remove copper, which was the reaction catalyst. The acquired light yellow solution was distilled under reduced pressure to acquire a crude product polymer. After the crude product was dissolved in 50 mL of THF, 500 mL of methanol was added for reprecipitation. The reprecipitated solution was centrifuged to separate a solid content. This precipitate was washed with methanol and dried under reduced pressure to acquire 20 g of a light yellow solid substance as a refined product.

The light yellow solid substance acquired as described above was subject to ¹H-NMR measurement to measure a molar rate (core/shell ratio) of a copolymer that was the hyperbranched polymer of the tenth example. As a result of the measurement, the molar rate (core/shell ratio) of the hyperbranched polymer of the eleventh example was 30/70.

### Twelfth Example

The core-shell hyperbranched polymer of a twelfth example will be described. The core-shell hyperbranched polymer of the twelfth example was synthesized with the use of the hyperbranched polymer of the third example according to the following method. Into a 500-mL four-neck reactor under an argon gas atmosphere, 1.6 g of copper(I) chloride, 5.1 g of 2,2′-bipyridyl, and 10.0 g of the hyperbranched polymer of the third example were introduced, and 48 mL of monochlorobenzene, 48 mL of acrylic acid tert-butyl ester, and 20 mL of benzonitrile were injected by syringe, respectively. After the substances were injected into the reactor, the mixture in the reactor was heated and agitated at 125 degrees C. for five hours.

After the reaction was completed, 200 g of active alumina was added to the reaction mixture and the mixture was agitated for one hour. After the agitation, the active alumina was filtrated off through filtration under reduced pressure and the filtrate was condensed by an evaporator. Reprecipitation was caused by adding 350 mL of methanol to the residue and supernatant liquid was decanted after being left still overnight. After the decantation, the precipitate was dissolved in 17 mL of THF, reprecipitated again by adding 195 mL of methanol, and left still. After being left still, supernatant liquid was removed through decantation. After the supernatant liquid was removed, the remaining precipitate was dried under reduced pressure. As a result, 15 g of a light yellow solid substance was acquired.

The light yellow solid substance acquired as described above was subject to ¹H-NMR measurement to measure a molar rate (core/shell ratio) of a copolymer that was the hyperbranched polymer of the eleventh example. As a result of the measurement, the molar rate (core/shell ratio) of the hyperbranched polymer of the twelfth example was 30/70.

### Thirteenth Example

The core-shell hyperbranched polymer of a thirteenth example will be described. The core-shell hyperbranched polymer of the thirteenth example was synthesized with the use of the hyperbranched polymer of the tenth example according to the following method. Into a 500-mL four-neck reactor under an argon gas atmosphere, 1.6 g of copper(I) chloride, 5.1 g of 2,2′-bipyridyl, and 10.0 g of the hyperbranched polymer of the tenth example were introduced, and 248 mL of monochlorobenzene and 48 mL of acrylic acid tert-butyl ester were injected by syringe, respectively. After the substances were injected into the reactor, the mixture in the reactor was heated and agitated at 125 degrees C. for five hours.

After the completion of the above polymerization reaction through the heating and agitation, insoluble substances were removed by filtering the reaction system after the completion of the polymerization reaction. Subsequently, 615 g of mixed acid aqueous solution containing 3 mass % of oxalic acid and 1 mass % of hydrochloric acid prepared with ultrapure water was added to 308 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 62.5 g of a condensed liquid. By sequentially adding 219 g of methanol and 31 g of ultrapure water to the acquired condensed liquid, a solid content was precipitated. The solid content acquired by the precipitation was dissolved into 20 g of THF to acquire a solution, and 200 g of methanol and 29 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 23.8 g. The molar rate of the copolymer (the core-shell hyperbranched polymer with the shell portion formed) was calculated with ¹H-NMR. The core/shell rate of the core-shell hyperbranched polymer with the shell portion formed (hereinafter, “core-shell hyperbranched polymer”) was 30/70 (molar ratio).

The partial degradation of the acid-degradable group of the thirteenth example will be described. In the partial degradation of the acid-degradable group of the thirteenth example, 2.0 g of the copolymer (the above core-shell hyperbranched polymer) was collected in a reactor with a reflux tube and 18.0 g of 1,4-dioxane and 0.2 g of 50-mass % sulfuric acid were added thereto. Subsequently, reflux agitation was performed for 60 minutes while the entire reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.6 g of polymer. A rate of the acid-degradable group and the acid group was 78/22.

### Fourteenth Example

The core-shell hyperbranched polymer of a fourteenth example will be described. The core-shell hyperbranched polymer of the fourteenth example was synthesized with the use of the hyperbranched polymer of the tenth example according to the following method. Into a 500-mL four-neck reactor under an argon gas atmosphere, 1.6 g of copper(I) chloride, 5.1 g of 2,2′-bipyridyl, and 10.0 g of the hyperbranched polymer of the tenth example were introduced, and 248 mL of monochlorobenzene and 81 mL of acrylic acid tert-butyl ester were injected by syringe, respectively. After the substances were injected into the reactor, the mixture in the reactor was heated and agitated at 125 degrees C. for five hours.

After the completion of the above polymerization reaction through the heating and agitation, insoluble substances were removed by filtering the reaction system after the completion of the polymerization reaction. Subsequently, 680 g of mixed acid aqueous solution containing 3 mass % of oxalic acid and 1 mass % of hydrochloric acid prepared with ultrapure water was added to 340 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 88.0 g of a condensed liquid. By sequentially adding 308 g of methanol and 44 g of ultrapure water to the acquired condensed liquid, a solid content was precipitated. The solid content acquired by the precipitation was dissolved into 44 g of THF to acquire a solution, and 440 g of methanol and 63 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 33.6 g. The molar rate of the copolymer (the core-shell hyperbranched polymer with the shell portion formed) was calculated with ¹H-NMR. The core/shell rate of the core-shell hyperbranched polymer with the shell portion formed (hereinafter, “core-shell hyperbranched polymer”) was 19/81 (molar ratio).

The partial degradation of the acid-degradable group of the fourteenth example will be described. In the partial degradation of the acid-degradable group of the fourteenth example, 2.0 g of the copolymer (the above core-shell hyperbranched polymer) was collected in a reactor with a reflux tube and 18.0 g of 1,4-dioxane and 0.2 g of 50-mass % sulfuric acid were added thereto. Subsequently, reflux agitation was performed for 30 minutes while the entire reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.6 g of polymer. A rate of the acid-degradable group and the acid group was 92/8.

### Fifteenth Example

The core-shell hyperbranched polymer of a fifteenth example will be described. The core-shell hyperbranched polymer of the fifteenth example was synthesized with the use of the hyperbranched polymer of the tenth example according to the following method. Into a 1000-mL four-neck reactor under an argon gas atmosphere, 1.6 g of copper(I) chloride, 5.1 g of 2,2′-bipyridyl, and 10.0 g of the hyperbranched polymer of the tenth example were introduced, and 248 mL of monochlorobenzene and 187 mL of acrylic acid tert-butyl ester were injected by syringe, respectively. After the substances were injected into the reactor, the mixture in the reactor was heated and agitated at 125 degrees C. for five hours.

After the completion of the above polymerization reaction through the heating and agitation, insoluble substances were removed by filtering the reaction system after the completion of the polymerization reaction. Subsequently, 880 g of mixed acid aqueous solution containing 3 mass % of oxalic acid and 1 mass % of hydrochloric acid prepared with ultrapure water was added to 440 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 175 g of a condensed liquid. By sequentially adding 613 g of methanol and 88 g of ultrapure water to the acquired condensed liquid, a solid content was precipitated. The solid content acquired by the precipitation was dissolved into 85 g of THF to acquire a solution, and 850 g of methanol and 121 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 65.9 g. The molar rate of the copolymer (the core-shell hyperbranched polymer with the shell portion formed) was calculated with ¹H-NMR. The core/shell rate of the core-shell hyperbranched polymer with the shell portion formed (hereinafter, “core-shell hyperbranched polymer”) was 10/90 (molar ratio).

The partial degradation of the acid-degradable group of the fifteenth example will be described. In the partial degradation of the acid-degradable group of the fifteenth example, 2.0 g of the copolymer (the above core-shell hyperbranched polymer) was collected in a reactor with a reflux tube and 18.0 g of 1,4-dioxane and 0.2 g of 50-mass % sulfuric acid were added thereto. Subsequently, reflux agitation was performed for 15 minutes while the entire reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.7 g of polymer. A rate of the acid-degradable group and the acid group was 95/5.

### Sixteenth Example

The core-shell hyperbranched polymer of a sixteenth example will be described. The core-shell hyperbranched polymer of the sixteenth example was synthesized with the use of the hyperbranched polymer of the tenth example according to the following method. Into a 1000-mL four-neck reactor under an argon gas atmosphere, 1.6 g of copper(I) chloride, 5.1 g of 2,2′-bipyridyl, and 10.0 g of the hyperbranched polymer of the tenth example were introduced, and 248 mL of monochlorobenzene and 14 mL of acrylic acid tert-butyl ester were injected by syringe, respectively. After the substances were injected into the reactor, the mixture in the reactor was heated and agitated at 125 degrees C. for five hours.

After the completion of the above polymerization reaction through the heating and agitation, insoluble substances were removed by filtering the reaction system after the completion of the polymerization reaction. Subsequently, 570 g of mixed acid aqueous solution containing 3 mass % of oxalic acid and 1 mass % of hydrochloric acid prepared with ultrapure water was added to 285 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 32 g of a condensed liquid. By sequentially adding 112 g of methanol and 16 g of ultrapure water to the acquired condensed liquid, a solid content was precipitated. The solid content acquired by the precipitation was dissolved into 16 g of THF to acquire a solution, and 160 g of methanol and 23 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 12.1 g. The molar rate of the copolymer (the core-shell hyperbranched polymer with the shell portion formed) was calculated with ¹H-NMR. The core/shell rate of the core-shell hyperbranched polymer with the shell portion formed (hereinafter, “core-shell hyperbranched polymer”) was 61/39 (molar ratio).

The partial degradation of the acid-degradable group of the sixteenth example will be described. In the partial degradation of the acid-degradable group of the sixteenth example, 2.0 g of the copolymer (the above core-shell hyperbranched polymer) was collected in a reactor with a reflux tube and 18.0 g of 1,4-dioxane and 0.2 g of 50-mass % sulfuric acid were added thereto. Subsequently, reflux agitation was performed for 150 minutes while the entire reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.4 g of polymer. A rate of the acid-degradable group and the acid group was 49/51.

### First Reference Example

### Synthesis of Tert-Butyl 4-Vinylbenzoate

The synthesis was performed according to the following synthesizing method with reference to Synthesis, 833-834 (1982). Into a 1-L reactor with a dropping funnel attached, 91 g of 4-vinylbenzoic acid, 99.5 g of 1,1′-carbodiimidazole, 4-tert-butylpyrocatechol, and 500 g of dehydrated dimethylformamide were added under an argon gas atmosphere, kept at 30 degrees C., and agitated for one hour.

Subsequently, 93 g of 1,8-diazabicyclo[5.4.0]-7-undecene and 91 g of dehydrated 2-methyl-2-propanol were added thereto and agitated for four hours. After the reaction was completed, 300 mL of diethyl ether and 10% potassium carbonate aqueous solution were added to extract the objective substance into the ether layer. The diethyl ether layer was subsequently dried under reduced pressure acquiring light yellow tert-butyl 4-vinylbenzoate. The acquisition of the objective substance was confirmed by ¹H-NMR. The yield was 88%.

### Seventeenth Example

The core-shell hyperbranched polymer of a seventeenth example will be described. The core-shell hyperbranched polymer of the seventeenth example was synthesized with the use of the hyperbranched polymer of the tenth example according to the following method. Into a 1000-mL four-neck reactor under an argon gas atmosphere, 0.8 g of copper(I) chloride, 2.6 g of 2,2′-bipyridyl, and 5.0 g of the hyperbranched polymer of the tenth example were introduced, and 421 mL of monochlorobenzene and 46.8 g of tert-butyl 4-vinylbenzoate were injected by syringe, respectively. After the substances were injected into the reactor, the mixture in the reactor was heated and agitated at 125 degrees C. for 3.5 hours.

After the completion of the above polymerization reaction through the heating and agitation, insoluble substances were removed by filtering the reaction system after the completion of the polymerization reaction. Subsequently, 980 g of mixed acid aqueous solution containing 3 mass % of oxalic acid and 1 mass % of hydrochloric acid prepared with ultrapure water was added to 490 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 41 g of a condensed liquid. By sequentially adding 144 g of methanol and 21 g of ultrapure water to the acquired condensed liquid, a solid content was precipitated. The solid content acquired by the precipitation was dissolved into 21 g of THF to acquire a solution, and 210 g of methanol and 30 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 15.9 g. The molar rate of the copolymer (the core-shell hyperbranched polymer with the shell portion formed) was calculated with ¹H-NMR. The core/shell rate of the core-shell hyperbranched polymer with the shell portion formed (hereinafter, “core-shell hyperbranched polymer”) was 29/71 (molar ratio).

The partial degradation of the acid-degradable group of the seventeenth example will be described. In the partial degradation of the acid-degradable group of the seventeenth example, 2.0 g of the copolymer (the above core-shell hyperbranched polymer) was collected in a reactor with a reflux tube and 18.0 g of 1,4-dioxane and 0.2 g of 50-mass % sulfuric acid were added thereto. Subsequently, reflux agitation was performed for 180 minutes while the entire reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.7 g of polymer. A rate of the acid-degradable group and the acid group was 38/62.

### Eighteenth Example

The core-shell hyperbranched polymer of a eighteenth example will be described. The core-shell hyperbranched polymer of the eighteenth example was synthesized with the use of the hyperbranched polymer of the tenth example according to the following method. Into a 1000-mL four-neck reactor under an argon gas atmosphere, 1.6 g of copper(I) chloride, 5.1 g of 2,2′-bipyridyl, and 5.0 g of the hyperbranched polymer of the tenth example were introduced, and 421 mL of monochlorobenzene and 46.8 g of tert-butyl 4-vinylbenzoate were injected by syringe, respectively. After the substances were injected into the reactor, the mixture in the reactor was heated and agitated at 125 degrees C. for three hours.

After the completion of the above polymerization reaction through the heating and agitation, insoluble substances were removed by filtering the reaction system after the completion of the polymerization reaction. Subsequently, 980 g of mixed acid aqueous solution containing 3 mass % of oxalic acid and 1 mass % of hydrochloric acid prepared with ultrapure water was added to 490 g of the filtrate acquired through the filtration and agitated for 20 minutes. After the agitation, a water layer was removed from the agitated reaction system.

Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 32 g of a condensed liquid. By sequentially adding 224 g of methanol and 32 g of ultrapure water to the acquired condensed liquid, a solid content was precipitated. The solid content acquired by the precipitation was dissolved into 32 g of THF to acquire a solution, and 320 g of methanol and 46 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 24.5 g. The molar rate of the copolymer (the core-shell hyperbranched polymer with the shell portion formed) was calculated with ¹H-NMR. The core/shell rate of the core-shell hyperbranched polymer with the shell portion formed (hereinafter, “core-shell hyperbranched polymer”) was 20/80 (molar ratio).

The partial degradation of the acid-degradable group of the eighteenth example will be described. In the partial degradation of the acid-degradable group of the eighteenth example, 2.0 g of the copolymer (the above core-shell hyperbranched polymer) was collected in a reactor with a reflux tube and 18.0 g of 1,4-dioxane and 0.2 g of 50-mass % sulfuric acid were added thereto. Subsequently, reflux agitation was performed for 90 minutes while the entire reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.7 g of polymer. A rate of the acid-degradable group and the acid group was 71/29.

### Nineteenth Example

The core-shell hyperbranched polymer of a nineteenth example will be described. The core-shell hyperbranched polymer of the nineteenth example was synthesized with the use of the hyperbranched polymer of the tenth example according to the following method. Into a 1000-mL four-neck reactor under an argon gas atmosphere, 1.6 g of copper(I) chloride, 5.1 g of 2,2′-bipyridyl, and 5.0 g of the hyperbranched polymer of the tenth example were introduced, and 530 mL of monochlorobenzene and 60.2 g of tert-butyl 4-vinylbenzoate were injected by syringe, respectively. After the substances were injected into the reactor, the mixture in the reactor was heated and agitated at 125 degrees C. for four hours.

After the completion of the above polymerization reaction through the heating and agitation, insoluble substances were removed by filtering the reaction system after the completion of the polymerization reaction. Subsequently, 1240 g of mixed acid aqueous solution containing 3 mass % of oxalic acid and 1 mass % of hydrochloric acid prepared with ultrapure water was added to 620 g of the filtrate acquired through the filtration and agitated for 20 minutes. After the agitation, a water layer was removed from the agitated reaction system.

Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 130 g of a condensed liquid. By sequentially adding 455 g of methanol and 65 g of ultrapure water to the acquired condensed liquid, a solid content was precipitated. The solid content acquired by the precipitation was dissolved into 65 g of THF to acquire a solution, and 650 g of methanol and 93 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 50.2 g. The molar rate of the copolymer (the core-shell hyperbranched polymer with the shell portion formed) was calculated with ¹H-NMR. The core/shell rate of the core-shell hyperbranched polymer with the shell portion formed (hereinafter, “core-shell hyperbranched polymer”) was 9/91 (molar ratio).

The partial degradation of the acid-degradable group of the nineteenth example will be described. In the partial degradation of the acid-degradable group of the nineteenth example, 2.0 g of the copolymer (the above core-shell hyperbranched polymer) was collected in a reactor with a reflux tube and 18.0 g of 1,4-dioxane and 0.2 g of 50-mass % sulfuric acid were added thereto. Subsequently, reflux agitation was performed for 30 minutes while the entire reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.7 g of polymer. A rate of the acid-degradable group and the acid group was 92/8.

### Twentieth Example

The core-shell hyperbranched polymer of a twentieth example will be described. The core-shell hyperbranched polymer of the twentieth example was synthesized with the use of the hyperbranched polymer of the tenth example according to the following method. Into a 1000-mL four-neck reactor under an argon gas atmosphere, 0.8 g of copper(I) chloride, 2.6 g of 2,2′-bipyridyl, and 5.0 g of the hyperbranched polymer of the tenth example were introduced, and 106 mL of monochlorobenzene and 8.0 g of tert-butyl 4-vinylbenzoate were injected by syringe, respectively. After the substances were injected into the reactor, the mixture in the reactor was heated and agitated at 125 degrees C. for one hour.

After the completion of the above polymerization reaction through the heating and agitation, insoluble substances were removed by filtering the reaction system after the completion of the polymerization reaction. Subsequently, 254 g of mixed acid aqueous solution containing 3 mass % of oxalic acid and 1 mass % of hydrochloric acid prepared with ultrapure water was added to 127 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 19 g of a condensed liquid. By sequentially adding 67 g of methanol and 10 g of ultrapure water to the acquired condensed liquid, a solid content was precipitated. The solid content acquired by the precipitation was dissolved into 10 g of THF to acquire a solution, and 100 g of methanol and 14 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 7.3 g. The molar rate of the copolymer (the core-shell hyperbranched polymer with the shell portion formed) was calculated with ¹H-NMR. The core/shell rate of the core-shell hyperbranched polymer with the shell portion formed (hereinafter, “core-shell hyperbranched polymer”) was 60/40 (molar ratio).

The partial degradation of the acid-degradable group of the twentieth example will be described. In the partial degradation of the acid-degradable group of the twentieth example, 2.0 g of the copolymer (the above core-shell hyperbranched polymer) was collected in a reactor with a reflux tube and 18.0 g of 1,4-dioxane and 0.2 g of 50-mass % sulfuric acid were added thereto. Subsequently, reflux agitation was performed for 240 minutes while the entire reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.4 g of polymer. A rate of the acid-degradable group and the acid group was 22/78.

### (Preparation of Resist Composition)

The preparation of the resist compositions of the examples will be described. In the examples, the resist compositions of the examples were prepared by creating a propylene glycol monomethyl acetate (PEGMEA) solution containing 4.0 mass % of the respective core-shell hyperbranched polymers of the above eleventh to twentieth examples and 0.16 mass % of triphenylsulfonium trifluoromethanesulfonate as a photoacid generator and by filtrating the solution with a filter having a fine pore size of 0.45 μm.

Silicon wafers were spin-coated with the resist compositions prepared as above and the solvent was evaporated by performing one-minute heat treatments at 90 degrees C. for the silicon wafers spin-coated with the resist compositions. As a result, thin films with a thickness of 100 nm were created on the silicon wafers.

### (Measurement of Sensitivity to Ultraviolet Radiation)

The sensitivity to ultraviolet radiation of the resist compositions of the examples will be described. The sensitivity to ultraviolet radiation of the resist compositions of the examples was measured by the following method. In the measurement of sensitivity to ultraviolet radiation of the resist compositions of the examples, a discharge tube type ultraviolet light irradiation apparatus (DF-245 Donafix manufactured by ATTO Corporation) was used as a light source.

The thin films were exposed by applying ultraviolet light having a wavelength of 245 nm to a rectangular portion having a length of 10 mm and width of 3 mm of the thin films formed on the silicon wafers with the use of the above light source. At the time of the exposure, an energy amount was changed from 0 mJ/cm² to 50 mJ/cm². After the exposure, the silicon wafers were treated with heat at 100 degrees C. for four minutes and developed by immersion in 2.4-mass % tetramethylammonium hydroxide (TMAH) aqueous solution at 25 degrees C. for 2 minutes.

After the development, the silicon wafers were washed with water and dried, and the film thickness after the drying was measured to measure applied energy values (sensitivity) when the film thickness after the development was zero. The measurement was performed with the use of a thin film measurement apparatus (film measurement apparatus F20 manufactured by Filmetrics, Inc.). The result of the measurement is depicted in Table 2.

TABLE 2

| | sensitivity (mJ/cm²) |
|---|---|
| eleventh example | 20 |
| twelfth example | 30 |
| thirteenth example | 3 |
| fourteenth example | 2 |
| fifteenth example | 2 |
| sixteenth example | 3 |
| seventeenth example | 15 |
| eighteenth example | 2 |
| nineteenth example | 2 |
| twentieth example | 3 |

### <Second Chapter>

Preferred embodiments of a hyperbranched polymer synthesizing method, a hyperbranched polymer, a resist composition, a semiconductor integrated circuit, and a semiconductor integrated circuit producing method according to the present invention will hereinafter be described in detail with reference to the accompanying drawings.

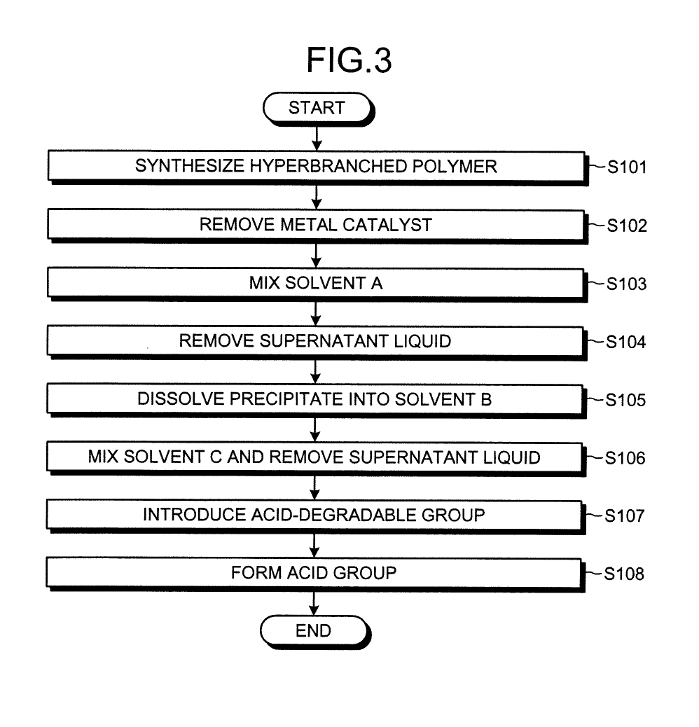

Hyperbranched polymer synthesizing steps of the embodiment of the second chapter will first be described. FIG. 3 is a flowchart of the hyperbranched polymer synthesizing steps of the embodiment. FIG. 3 depicts, in the order of execution, the synthesizing steps of a hyperbranched polymer produced according to the hyperbranched polymer synthesizing method of the embodiment (hereinafter, “hyperbranched polymer”).

As depicted in FIG. 3, in the synthesis of the hyperbranched polymer, first, a hyperbranched polymer is synthesized from a metal catalyst and a raw material monomer (step S101). The hyperbranched polymer synthesized at step S101 implements the core portion of the core-shell hyperbranched polymer.

The metal catalyst is removed from a reaction solvent containing the hyperbranched polymer synthesized at step S101 (step S102). A solvent A is then mixed with the reaction solvent after the metal catalyst is removed (step S103) to precipitate a polymer as a precipitate. This implements a precipitate generating step at step S103.

The supernatant liquid is removed from the solution containing the polymer precipitated by mixing the solvent A at step S103 (step S104) to acquire the hyperbranched polymer. In some cases, the precipitate after the removal is dissolved into a solvent B (step S105) to generate a solution containing the dissolved polymer. A solvent C may subsequently be mixed with the solution containing the dissolved polymer (step S106) to precipitate the hyperbranched polymer as a precipitate.

An acid-degradable group is introduced into a core portion of the hyperbranched polymer acquired at step S104 (or S106) to refine a core-shell hyperbranched polymer including a shell portion having the hyperbranched polymer as the core portion.

A portion of the acid-degradable group constituting the shell portion of the refined core-shell hyperbranched polymer is degraded with the use of an acid catalyst to form an acid group (step S108) to synthesize the core-shell hyperbranched polymer having the acid-degradable group and the acid group in the shell portion, and a series of processes is terminated.

Each of the steps in the synthesis of the core-shell hyperbranched polymer generated in the sequence depicted above in FIG. 3 will be described in detail.

### (Synthesis of Hyperbranched Polymer)

First, step S101 of FIG. 3 above will be described. In the synthesis of the hyperbranched polymer at step S101 of FIG. 3 above, for example, the raw material monomer is subjected to the living radical polymerization in the presence of the metal catalyst in a solvent such as chlorobenzene at 0 to 200 degrees C. for 0.1 to 30 hours to synthesize the hyperbranched polymer (the core portion of the core-shell hyperbranched polymer).

The hyperbranched polymer can be synthesized by causing the living radical polymerization of the raw material monomer in the presence of the metal catalyst in a solvent such as chlorobenzene at 0 to 200 degrees C. for 0.1 to 30 hours, for example. At step S101, for example, the reaction is terminated by adding ultrapure water or a solvent having a hydroxyl group such as methanol to the reaction system.

Step S102 of FIG. 3 above will be described. At step S102 of FIG. 3 above, the metal catalyst is removed from the solution containing the hyperbranched polymer synthesized at step S101. Specifically, at step S102, for example, the insolubilized metal catalyst is removed by filtrating the solution containing the hyperbranched polymer formed at step S101.

At step S102 of FIG. 3 above, the metal catalyst may be removed by the liquid-liquid extraction using water-organic solvent. The organic solvent used at step S102 includes, for example, halogenated hydrocarbon such as chlorobenzene used in the living radical polymerization at step S101 and chloroform as preferred organic solvents. The organic solvent used at step S102 may be the solvent B described later.

### (Precipitation of Polymer)

Step S103 of FIG. 3 above will be described. In the precipitation operation of the polymer at step S103 of FIG. 3 above, it is preferable to use a mixed solvent (the solvent A) consisting of two or more solvents and having a solubility parameter of 10.5 or more. Solvents independently having a solubility parameter of 10.5 or more include methanol, ethanol, 1-propanol, 2-propanol, glycerin, water, etc., and these solvents are included in the solvent A. Specifically, the solvents A includes, ethyl acetate/methanol, ethyl acetate/ethanol, ethyl acetate/1-propanol, ethyl acetate/2-propanol, ethyl acetate/glycerin, tetrahydrofuran/methanol, tetrahydrofuran/ethanol, tetrahydrofuran/1-propanol, tetrahydrofuran/2-propanol, tetrahydrofuran/glycerin, acetone/methanol, acetone/ethanol, acetone/1-propanol, acetone/2-propanol, acetone/glycerin, methyl ethyl ketone/methanol, methyl ethyl ketone/ethanol, methyl ethyl ketone/1-propanol, methyl ethyl ketone/2-propanol, methyl ethyl ketone/glycerin, methanol/ethanol, methanol/1-propanol, methanol/2-propanol, methanol/glycerin, methanol/water, ethanol/1-propanol, ethanol/2-propanol, ethanol/glycerin, ethanol/water, 1-propanol/2-propanol, 1-propanol/glycerin, 1-propanol/water, 2-propanol/glycerin, 2-propanol/water, and glycerin/water.

Among above solvents, methanol/water, methanol/ethanol, ethanol/water, 1-propanol/water, 2-propanol/water, and glycerin/water are preferable. It is particularly preferable to include water and it is preferable to contain 1 to 50 mass %, more preferably 3 to 40 mass % of water relative to the total amount of the solvent A.

The solubility parameter is an index indicative of a polarity of substance and is a value representative of an index for affinity between a solvent and a resin. When a polymer is dissolved into a solvent, the solubility of the polymer into the solvent becomes better as the solubility parameter of the polymer comes closer to the solubility parameter of the solvent. A numeric value indicative of the solubility parameter is an SP value and a larger SP value indicates a larger polarity. The SP value is represented by the square root of an attracting force between polymer molecules and solvent molecules i.e., a cohesive energy density CED. The CED is defined as an amount of energy required for evaporating 1 cc of substance. The same calculation may be applied to the case of a mixed solvent.

At step S103 of FIG. 3 above, an excessive amount of the solvent A is added to the reaction solution. Specifically, at step S103, it is preferable that 0.2 to 10 parts by volume of the solvent A be added to the reaction solution. By adding the solvent A to the reaction solution, a viscous brown polymer is precipitated in the reactor. The supernatant liquid is removed at step S104.

### (Redissolution of Polymer)

Step S105 of FIG. 3 above will be described. In the redissolution of the polymer at step S105, it is preferable to use a solvent having a solubility parameter equal to 7 or more and less than 10.5 as the solvent B dissolving the precipitate after the supernatant liquid is removed at step S104.

Specifically, the solvent B includes, for example, halogenated hydrocarbon, nitro compounds, nitriles, ethers, ketones, esters, carbonates, or a mixed solvent thereof. Specifically, the solvent B includes, for example, halogenated hydrocarbons such as chlorobenzene and chloroform; nitro compounds such as nitromethane and nitroethane; nitrile compounds such as acetonitrile and benzonitrile; ethers such as tetrahydrofuran and 1,4-dioxane; ketones such as methyl ethyl ketone, methyl isobutyl ketone, cyclohexanone, 2-heptanone, and 2-pentanone; esters such as ethyl acetate, n-butyl acetate, and isoamyl acetate; ethylene glycol monoethyl ether acetate, ethylene glycol monobutyl ether acetate, and ethylene glycol monomethyl ether acetate.

The solvent B is preferably ether and one of the most preferable solvents is tetrahydrofuran. It is preferable for 0.1 to 10 mL of the solvent B to be used per 1 g of polymer.

### (Removal of Impurities)

At step S104 (or S106) of FIG. 3 above, impurities such as residual monomer and by-product oligomer are removed. Particularly, substances having a molecular weight equal to a quarter of the weight-average molecular weight Mw of the hyperbranched polymer and the metal catalyst are removed through a series of operations from steps S102 to S104. At step S106, it is preferable to use a solvent having the solubility parameter of 10.5 or more as the solvent C. The solvent C includes, for example, methanol, ethanol, 1-propanol, 2-propanol, glycerin, water, or a mixed solvent thereof. Among the above various solvents, preferable solvents for the solvent C include methanol, ethanol, and mixture thereof with water and include methanol containing water preferably by 1 to 50 mass %, more preferably by 3 to 40 mass % of water, or ethanol containing the water in the above amounts. If the solvent C is a mixed solvent, the solvent A and the solvent C may be identical or different. An amount of the solvent C is preferably 1 to 20 parts by volume based on the solvent B.

### (Degradation of Acid-Degradable Group)

The acid catalysts degrading a portion of the acid-degradable group to an acid group at step S108 of FIG. 3 above includes, for example, hydrochloric acid, sulfuric acid, phosphoric acid, hydrobromic acid, p-toluenesulfonic acid, acetic acid, trifluoroacetic acid, trifluoromethanesulfonic acid, and formic acid. When degrading a portion of the acid-degradable group to an acid group, the degradation can be induced by adding the solid-state resist polymer intermediate generated at step S107 to an appropriate organic solvent containing an acid catalyst, for example, 1,4-dioxane and by heating and agitating the mixture at a temperature of 50 to 150 degrees C. for 10 minutes to 20 hours.

A rate of the acid-degradable group and the acid group in the acquired resist polymer is varied depending on the composition of the resist and is preferably defined such that 5 to 80 mol % of the monomer containing the introduced acid-degradable group is deprotected. The rate of the acid-degradable group and the acid group at such a range is preferable since higher sensitivity and efficient alkali solubility after exposure are achieved. The acquired solid-state resist polymer may be separated from the reaction solvent and dried, to be utilized as a solid-state resist polymer, by removing the solvent through operations such as distillation under reduced pressure.

### (Molecular Structure of Core Portion of Core-Shell Hyperbranched Polymer)

A molecular structure of the hyperbranched polymer (the core portion of the core-shell hyperbranched polymer) will be described. A molecular structure of the hyperbranched polymer will be described in terms of a weight-average molecular weight (Mw), a number-average molecular weight (Mn), and a branching degree (Br) of the core portion of the core-shell hyperbranched polymer synthesized as above.

The weight-average molecular weight (Mw) and the number-average molecular weight (Mn) of the core portion of the core-shell hyperbranched polymer may be obtained by preparing a 0.5 mass % tetrahydrofuran solution and performing the GPC (Gel Permeation Chromatography) measurement at a temperature of 40 degrees C. Tetrahydrofuran may be used as a mobile solvent and styrene may be used as a standard substance.

The branching degree (Br) of the core portion of the core-shell hyperbranched polymer may be obtained by measuring ¹H-NMR of the product as follows. The branching degree (Br) may be calculated by carrying out an operation of above equation (A) using an integration ratio H1° of proton of the —CH₂Cl site appearing at 4.6 ppm and an integration ratio H2° of proton of the —CHCl site appearing at 4.8 ppm. If the polymerization proceeds at both the —CH₂Cl site and the —CHCl site and the branching is enhanced, the value of the branching degree (Br) approaches 0.5.

The weight-average molecular weight (Mw) of the core portion of the core-shell hyperbranched polymer of the present invention is preferably 300 to 8,000. The weight-average molecular weight (Mw) is more preferably 500 to 8,000. The weight-average molecular weight (Mw) is most preferably 1,000 to 8,000.

The weight-average molecular weight (Mw) of the core portion of the core-shell hyperbranched polymer at these ranges is preferable since the core portion takes a spherical form and the solubility into the reaction solvent can be ensured in the acid-degradable group introducing reaction. The weight-average molecular weight (Mw) of the core portion of the core-shell hyperbranched polymer at these ranges is also preferable since an excellent film forming property is achieved and the dissolution of unexposed portions is advantageously prevented in the hyperbranched polymer having the acid-degradable group introduced (induced) when the core-shell hyperbranched polymer is used for a resist composition.

The molecular weight distribution (Mw/Mn) of the core portion of the core-shell hyperbranched polymer is preferably 1 to 5. The molecular weight distribution (Mw/Mn) of the core portion of the core-shell hyperbranched polymer is more preferably 1 to 3. The molecular weight distribution (Mw/Mn) of the core portion of the core-shell hyperbranched polymer is further preferably 1 to 2.5. The molecular weight distribution (Mw/Mn) of the core portion of the core-shell hyperbranched polymer at the above ranges is desirable since adverse effects such as insolubilization of the resist composition are not caused after exposure if the core-shell hyperbranched polymer is used for the resist composition.

The molecular weight distribution (Mw/Mn) of the core portion of the core-shell hyperbranched polymer at the above ranges is preferable since the resist composition having excellent line edge roughness and resistant to baking by heating may be acquired if the core-shell hyperbranched polymer is used for the resist composition The branching degree (Br) of the core portion of the core-shell hyperbranched polymer is preferably 0.3 or more. The branching degree (Br) is more preferably 0.4 to 0.5. The branching degree (Br) is further preferably 0.5. The branching degree (Br) of the core-shell hyperbranched polymer at the above ranges is preferable since the entwining of the core-shell hyperbranched polymer molecules is reduced and surface roughness is prevented on pattern side walls when the hyperbranched polymer is used for the resist composition.

### (Molecular Structure of Core-Shell Hyperbranched Polymer)

A molecular structure of the core-shell hyperbranched polymer will be described. A molecular structure of the core-shell hyperbranched polymer will be described in terms of a weight-average molecular weight (M) of the core-shell hyperbranched polymer synthesized as above.

The weight-average molecular weight (M) of the core-shell hyperbranched polymer of the present invention may be obtained by using ¹H-NMR to obtain introduction rates (component ratios) of the repeating units of the polymer with the acid-degradable group introduced and performing a calculation using the introduction rates of the constituent units and the molecular weights of the constituent units based on the weight-average molecular weight (Mw) of the hyperbranched polymer.

The weight-average molecular weight (M) of the core-shell hyperbranched polymer of the present invention is preferably 500 to 21,000. The weight-average molecular weight (M) is more preferably 2,000 to 21,000. The weight-average molecular weight (M) is most preferably 3,000 to 21,000.

The resist composition containing the core-shell hyperbranched polymer having the weight-average molecular weight (M) at the above ranges has a favorable film forming property and may improve the strength of the process patterns formed at the lithography step to keep the shapes of the patterns. The resist composition containing the core-shell hyperbranched polymer having the weight-average molecular weight (M) at the above ranges can provide excellent dry etching resistance and favorable surface roughness.

### (Substances Used in Synthesis of Core-Shell Hyperbranched Polymer)

The substances used in the synthesis of the core-shell hyperbranched polymer will be described. In the synthesis of the core-shell hyperbranched polymer, a monomer, a metal catalyst, and a solvent are used.

### (Monomer Used in Synthesis of Core Portion of Core-Shell Hyperbranched Polymer)

The monomer used in the synthesis of the core portion of the core-shell hyperbranched polymer will be described. The monomer used in the synthesis of the core portion of the core-shell hyperbranched polymer includes, for example, monomers represented by formula (I) described in the first chapter above.

Y of the formula (I) denotes a straight-chain, branched, or cyclic alkylene group having 1 to 10 carbon atoms. The preferred number of carbon atoms of Y is one to six. Y of the formula (I) may contain a hydroxyl group or a carboxyl group.

Specifically, Y of the formula (I) may denote, for example, a methylene group, an ethylene group, a propylene group, an isopropylene group, a butylene group, an isobutylene group, an amylene group, a hexylene group, and a cyclohexylene group. Y of the formula (I) may denote groups formed by combining the above groups or groups formed by containing “—O—”, “—CO—”, or “—COO—” between the above groups.

Among the above groups, Y of the formula (I) preferably denotes an alkylene group having one to eight carbon atoms. Among the alkylene groups having one to eight carbon atoms, Y of the formula (I) is preferably a straight-chain alkylene group having one to eight carbon atoms. A more preferred alkylene group includes, for example, a methylene group, an ethylene group, a —OCH₂— group, and a —OCH₂CH₂— group. Z of the formula (I) denotes a halogen atom (halogen group) such as a fluorine atom, a chlorine atom, a bromine atom, and an iodine atom. Specifically, Z of the formula (I) is preferably a chlorine atom or a bromine atom among the above halogen atoms.

Among monomers used in the formation of the core portion of the core-shell hyperbranched polymer, specific examples of monomers represented by the formula (I) include chloromethyl styrene, bromomethyl styrene, p-(1-chloroethyl)styrene, bromo(4-vinylphenyl)phenylmethane, 1-bromo-1-(4-vinylphenyl)propane-2-one, and 3-bromo-3-(4-vinylphenyl)propanol. More specifically, among the monomers used in the synthesis of the hyperbranched polymer, the monomers represented by the formula (I) preferably are chloromethyl styrene, bromomethyl styrene, p-(1-chloroethyl)styrene, etc.

Monomers constituting the core portion of the hyperbranched polymer of the present invention may include other monomers in addition to monomers represented by the formula (I). Other monomers are not particularly limited provided the monomer is radically polymerizable, and may be selected according to purpose. Other radically polymerizable monomers include, for example, compounds having a radically polymerizable unsaturated bond and may be selected from among (meth)acrylic acid and (meth)acrylic esters, vinylbenzoic acid, vinylbenzoic esters, styrenes, allyl compounds, vinyl ethers, and vinyl esters.

Specifically, (meth)acrylic esters cited as other radically polymerizable monomers include, for example, tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1 ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1 ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, 8-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl) oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate.

Specifically, vinylbenzoic esters cited as other radically polymerizable monomers include, for example, tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1 n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinylbenzoate, adamantyl vinylbenzoate, 2-(2-methyl)adamantyl vinylbenzoate, chloroethyl vinylbenzoate, 2-hydroxyethyl vinylbenzoate, 2,2-dimethylhydroxypropyl vinylbenzoate, 5-hydroxybenzyl vinylbenzoate, trimethylolpropane vinylbenzoate, glycidyl vinylbenzoate, benzyl vinylbenzoate, phenyl vinylbenzoate, and naphthyl vinylbenzoate.

Specifically, styrenes cited as other radically polymerizable monomers include, for example, styrene, m-methylstyrene, o-methylstyrene, p-methylstyrene, m-ethylstyrene, o-ethylstyrene, p-ethylstyrene, benzylstyrene, trifluoromethylstyrene, acetoxystyrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, 4-fluoro-3-trifluoromethylstyrene, vinylnaphthalene, and divinylbenzene.

Specifically, allyl compounds cited as other radically polymerizable monomers include, for example, allyl acetate, allyl caproate, allyl caprylate, allyl laurate, allyl palmitate, allyl stearate, allyl benzoate, allyl acetoacetate, allyl lactate, and allyloxyethanol.

Specifically, vinyl ethers cited as other radically polymerizable monomers include, for example, hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether, tetrahydrofurfuryl vinyl ether, vinylphenyl vinyl ether, vinyl tolyl ether, vinyl chlorophenyl ether, vinyl-2,4-dichlorophenyl ether, vinyl naphthyl ether, and vinyl anthranyl ether.

Specifically, vinylesters cited as other radically polymerizable monomers include, for example, vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl-β-phenylbutyrate, and vinyl cyclohexylcarboxylate.

Among the various monomers described as the monomers used in the synthesis of the core portion of the core-shell hyperbranched polymer, the monomers used in the synthesis of the hyperbranched polymer of the present invention are preferably (meth)acrylic acid, (meth)acrylic esters, 4-vinylbenzoic acid, 4-vinylbenzoic esters, and styrens.

Among the various monomers, specifically, the monomer corresponding to the core portion of the core-shell hyperbranched polymer is preferably, for example, (meth)acrylic acid, tert-butyl (meth)acrylate, 4-vinylbenzoic acid, tert-butyl 4-vinylbenzoate, styrene, benzylstyrene, chlorostyrene, and vinylnaphthalene.

In the core-shell hyperbranched polymer, the amount of monomer forming the core portion is preferably 10 to 90 mol % relative to the total amount of monomers forming the core-shell hyperbranched polymer at the time of charging.

The amount of monomer forming the core portion is more preferably 10 to 80 mol % relative to the total amount of monomers forming the core-shell hyperbranched polymer at the time of charging. The amount of monomer forming the core portion is yet more preferably 10 to 60 mol % relative to the total amount of monomers forming the core-shell hyperbranched polymer at the time of charging.

The amount of the monomer constituting the core portion of the core-shell hyperbranched polymer is preferable at the above ranges since the resist composition using the hyperbranched polymer has appropriate hydrophobicity to the developing fluid and prevents the dissolution of the non-exposed portion.

The amount of monomer represented by formula (I) is preferably 5 to 100 mol % relative to the total amount of monomers forming the core portion of the core-shell hyperbranched core polymer. The amount of monomer represented by formula (I) is more preferably 20 to 100 mol % relative to the total amount of monomers forming the core portion of the core-shell hyperbranched core polymer.

The amount of monomer represented by formula (I) is more preferably 50 to 100 mol % relative to the total amount of monomers forming the core portion of the core-shell hyperbranched core polymer. When the amount of the monomers represented by formula (I) is at the above ranges relative to the total amount of monomers forming the core portion of the core-shell hyperbranched core polymer, this is preferable since the entwining of molecules can be prevented because the core portion takes a spherical form.

If the core portion of the core-shell hyperbranched polymer is a polymerization product of a monomer represented by formula (I) and another monomer, the amount of monomer represented by formula (I) is preferably 10 to 99 mol % relative to the total amount of monomers constituting the core portion at the time of charging. In this case, the amount of monomer represented by formula (I) is more preferably 20 to 99 mol % relative to the total amount of monomers constituting the core portion at the time of charging. In this case, the amount of monomer represented by formula (I) is yet more preferably 30 to 99 mol % relative to the total amount of monomers constituting the core portion at the time of charging.

If the core portion of the core-shell hyperbranched polymer is a polymerization product of a monomer represented by formula (I) and another monomer, when the amount of monomer represented by formula (I) is at the above ranges relative to the total amount of monomers constituting the core portion, this is preferable since the entwining of molecules can be prevented because the core portion takes a spherical form.

If the amount of monomer represented by formula (I) is at the above ranges relative to the total amount of monomers constituting the core portion, this is preferable since functions such as adhesiveness to substrates and an increase in the glass-transition temperature may be induced while maintaining the spherical form of the core portion. According to purpose, among the total monomer constituting the core portion, respective amounts of monomer represented by formula (I) and other monomers may be adjusted by the ratio of the charging amount at the time of polymerization.

### (Catalyst Used in Synthesis of Core Portion of Core-Shell Hyperbranched Polymer)

The catalyst used in the synthesis of the core portion of the core-shell hyperbranched polymer will be described.

The catalyst used in the synthesis of the core portion of the core-shell hyperbranched polymer may include, for example, a catalyst acquired by combining transition metal such as copper, iron, ruthenium, and chromium, and a ligand consisting of pyridines and bipyridines not substituted or substituted by an alkyl group, an aryl group, an amino group, a halogen group, an ester group, etc., aliphatic polyamines, aliphatic amines, or alkyl and aryl phosphine, etc., for example, copper bipyridyl complex, copper pentamethyldiethylenetriamine complex, and copper tetramethylethylenediamine complex acquired by combining copper(I) chloride or copper (I) bromide and the ligands, and iron tributylphosphine complex, iron triphenylphosphine complex, and iron tributylamine complex acquired by combining iron(II) chloride and the ligands.

Among the various catalysts above, copper bipyridyl complex, copper pentamethyldiethylenetriamine complex, iron tributylphosphine complex, and iron tributylamine complex are particularly preferable for the catalyst used in the synthesis of the core portion of the core-shell hyperbranched polymer of the present invention.

An amount of usage of the metal catalyst used in the synthesis of the core portion of the core-shell hyperbranched polymer in accordance with the above synthesizing method is preferably 0.1 to 70 mol %, more preferably 1 to 60 mol % relative to the total amount of monomers at the time of charging. If the catalyst is used in such an amount, the hyperbranched polymer core portion having a preferred branching degree can be acquired.

If the amount of metal catalyst used is less than the above ranges, the reactivity is considerably reduced and the polymerization may not progress. On the other hand, if the amount of metal catalyst exceeds the above ranges, since the polymerization reaction becomes excessively active, a coupling reaction tends to occur between radicals at the growth ends and the polymerization tends to become difficult to control. If the amount of metal catalyst exceeds the above ranges, the coupling reaction between radicals triggers gelation of the reaction system.

The metal catalyst may be made into a complex compound by mixing the above transition metal compound and the ligand in an apparatus. The metal catalyst consisting of the transition metal compound and the ligand may be added in a state of an active complex to the apparatus. It is more preferable to mix the transition metal compound and the ligand in the apparatus to form a complex since the synthesis operation of the hyperbranched polymer may be simplified.

The method of adding the metal catalyst is not particularly limited and, for example, the metal catalyst may be added at one time before the polymerization of the hyperbranched polymer. Alternatively, after the polymerization starts, additional metal catalyst may be added depending on the level of deactivation of the catalyst. For example, if the distribution of the complex acting as the metal catalyst is not uniform in the reaction system, the transition metal compound may preliminarily be added into the apparatus and only the ligand may be added afterward.

In the presence of the above metal catalyst, the polymerization reaction for synthesizing the hyperbranched polymer is preferably performed in a solvent although the reaction can occur in the absence of solvent. The solvent used for the polymerization reaction of the hyperbranched polymer in the presence of the metal catalyst is not particularly limited and includes, for example, a hydrocarbon solvent such as benzene and toluene, an ether solvent such as diethyl ether, tetrahydrofuran, diphenyl ether, anisole, and dimethoxybenzene, a halogenated hydrocarbon solvent such as methylene chloride, chloroform, and chlorobenzene, a ketone solvent such as acetone, methyl ethyl ketone, and methyl isobutyl ketone, an alcohol solvent such as methanol, ethanol, propanol, and isopropanol, a nitrile solvent such as acetonitrile, propionitrile, and benzonitrile, an ester solvent such as ethyl acetate and butyl acetate, a carbonate solvent such as ethylene carbonate and propylene carbonate, and an amide solvent such as N,N-dimethylformamide and N,N-dimethylacetamide. These solvents may independently be used or two or more of the solvents may concurrently be used.

In the synthesis (core polymerization) of the hyperbranched polymer, the core polymerization is preferably performed in the presence of or in the flow of nitrogen or inert gas or in the absence of oxygen to prevent oxygen from affecting radicals. The core polymerization may be applied to both a batch method and a continuous method. In the core polymerization, all substances used for the core polymerization, i.e., the metal catalyst, the solvent, the monomer, etc., are preferably deoxygenated (degassed) sufficiently by evacuation or blowing-in of an inert gas such as nitrogen or argon to prevent the metal catalyst from being oxidized and deactivated.

The core polymerization may be performed while dropping monomer into a reactor, for example. By controlling the dropping rate of the monomer, a higher branching degree may be maintained and the rapid increase in the molecular weight may be prevented in the hyperbranched core polymer to be synthesized (macroinitiator). By controlling the dropping rate of the monomer, the polymer molecular weight may accurately be controlled while maintaining a higher branching degree in the hyperbranched core polymer to be synthesized. To prevent the rapid increase in the molecular weight of the hyperbranched core polymer, the concentration of the monomer to be dropped is preferably 1 to 50 mass %, more preferably 2 to 20 mass % relative to the total reaction amount.

In the core polymerization, the reaction may be caused by adding the monomer (charged monomer) into the reactor for the polymerization reaction at a later time. Each mixing (addition) amount of the monomer into the reactor (reaction system) is less than the total amount of the monomer to be mixed into the reaction system. To maintain a higher branching degree and prevent the rapid increase in the molecular weight of the hyperbranched core polymer, each amount of the monomer to be mixed into the reaction system is preferably less than 50%, more preferably less than 30% of the total amount of the monomer.

For example, each mixing (addition) amount of the monomer into the reactor (reaction system) is less than the total amount of monomer to be mixed into the reaction system by mixing the monomer into the reaction system according to methods such as a continuous method for mixing the monomer into the reaction system by dropping the monomer for a predetermined time period and a dividing method for mixing the monomer into the reaction system by dividing the total amount of the monomer to be mixed with the reaction system and adding a certain amount of the monomer at certain intervals.

For example, the monomer may be mixed into the reaction system by continuously injecting the monomer for a predetermined time period. In this case, at each unit time, the mixing (addition) amount of the monomer mixed into the reaction system is less than the total amount of the monomer to be mixed into the reaction system.

If the continuous method is used to mix the monomer into the reaction system, the dropping time of the monomer is preferably 5 to 300 minutes. If the continuous method is used to mix the monomer into the reaction system, more preferably the dropping time of the monomer is 15 to 240 minutes. If the continuous method is used to mix the monomer into the reaction system, yet more preferably the dropping time of the monomer is 30 to 180 minutes.

If the dividing method is used to mix the monomer into the reaction system, a given amount of the monomer is mixed at predetermined intervals. The predetermined intervals may be, for example, the time required for the mixed monomer to perform one polymerization reaction, the time required for the mixed monomer to uniformly disperse into the entire reaction system, or the time required for the temperature of the reaction system varied due to the mixing of the monomer to be stabilized.

If the dropping time of the monomer into the reaction system is too short, the rapid increase in the molecular weight may not be prevented sufficiently. If the dropping time of the monomer to the reaction system is too long, this is not preferable since the total polymerization time from the start to the end of the synthesis of the hyperbranched polymer increases and the cost of the synthesis of the hyperbranched polymer accordingly increases.

An additive may be used for the core polymerization. In the core polymerization, among compounds represented by formula (1-1) and compounds represented by (1-2) described in the first chapter, at least one type may be added.

R₁ of formula (1-1) denotes an alkyl group having 1 to 10 carbon atoms, an aryl group having 1 to 10 carbon atoms, or an aralkyl group having 1 to 10 carbon atoms. More particularly, R₁ of formula (1-1) represents hydrogen, an alkyl group having 1 to 10 carbon atoms, an aryl group having 6 to 10 carbon atoms, or an aralkyl group having 7 to 10 carbon atoms. A of formula (1-1) denotes a cyano group, a hydroxyl group, or a nitro group. The compounds represented by formula (1-1) include nitriles, alcohols, and nitro compounds, for example.

Specifically, nitriles included in the compounds represented by formula (1-1) are, for example, acetonitrile, propionitrile, butyronitrile, and benzonitrile. Specifically, alcohols included in the compounds represented by formula (1-1) are, for example, methanol, ethanol, 1-propanol, 2-propanol, 1-butanol, cyclohexyl alcohol, and benzyl alcohol. Specifically, nitro compounds included in the compounds represented by formula (1-1) are, for example, nitromethane, nitroethane, nitropropane, and nitrobenzene. The compounds represented by formula (1-1) are not limited to the above compounds.

R₂ and R₃ of formula (1-2) denote alkyl groups having 1 to 10 carbon atoms, aryl groups having 1 to 10 carbon atoms, aralkyl groups having 1 to 10 carbon atoms, or dialkylamide groups having 1 to 10 carbon atoms and B denotes a carbonyl group or a sulfonyl group. More particularly, R₂ and R₃ of formula (1-2) represent hydrogen, alkyl groups having 1 to 10 carbon atoms, aryl groups having 6 to 10 carbon atoms, aralkyl groups having 7 to 10 carbon atoms, or dialkylamide groups having 1 to 10 carbon atoms. R₂ and R₃ of formula (1-2) may be the same or different.

The compounds represented by formula (1-2) include ketones, sulfoxides, and alkylformamide compounds, for example. Specifically, ketones include, for example, acetone, 2-butanone, 2-pentanone, 3-pentanone, 2-hexanone, cyclohexanone, 2-methylcyclohexanone, acetophenone, and 2-methylacetophenone.

Specifically, sulfoxides included in the compounds represented by formula (1-2) are, for example, dimethyl sulfoxide and diethyl sulfoxide. Specifically, alkylformamide compounds included in the compounds represented by formula (1-2) are, for example, N,N-dimethylformamide, N,N-diethylformamide, and N,N-dibutylformamide.

The compounds represented by formula (1-2) are not limited to the above compounds. The compounds represented by formula (1-1) or formula (1-2) are preferably nitriles, nitro compounds, sulfoxides, ketones, and alkylformamide compounds, and more preferably, acetonitrile, propionitrile, benzonitrile, nitroethane, nitropropane, dimethyl sulfoxide, acetone, and N,N-dimethylformamide.

In the synthesis of the hyperbranched polymer, the compounds represented by formula (1-1) or formula (1-2) may be used independently or two or more of the compounds may be used in combination.

In the synthesis of the hyperbranched polymer, the compounds represented by formula (1-1) or formula (1-2) may be used independently or two or more of the compounds may be used in combination as a solvent.

The amount of the compounds represented by formula (1-1) or formula (1-2) to be added in the synthesis of the hyperbranched polymer is preferably 2 times to 10000 times the amount of the transition metal in the above metal catalyst by molar ratio. The amount of the compounds represented by formula (1-1) or formula (1-2) to be added is more preferably 3 times to 7000 times and yet more preferably 4 times to 5000 times the amount of the transition metal in the above metal catalyst by molar ratio.

If the added amount of the compounds represented by formula (1-1) or formula (1-2) is too small, the rapid increase in the molecular weight may not be controlled sufficiently. On the other hand, if the added amount of the compounds represented by formula (1-1) or formula (1-2) is too large, the reaction rate is slowed and a large amount of oligomers is generated.

The polymerization time of the core polymerization is preferably 0.1 to 30 hours depending on the molecular weight of the polymerization product, more preferably 0.1 to 10 hours, and particularly preferably 1 to 10 hours. In the core polymerization, the reaction temperature is preferably a range of 0 to 200 degrees C., and more preferably a range of 50 to 150 degrees C. If the polymerization is performed at a temperature higher than the boiling point of the solvent to be used, the pressure may be increased within an autoclave, for example.

In the core polymerization, it is preferable for the reaction system to be uniformly distributed. For example, the reaction system is uniformly distributed by agitating the reaction system. A specific example of an agitation condition of the core polymerization is that preferably the power necessary for agitation per unit volume is set as 0.01 kW/m³ or more. In the core polymerization, additional catalyst or a reducing agent regenerating the catalyst may be added depending on the progress in the polymerization and the level of deactivation of the catalyst.

In the core polymerization, the polymerization reaction is terminated when the set molecular weight is attained. A method of terminating the core polymerization is not particularly limited and, for example, a method such as cooling or deactivating the catalyst with the addition of an oxidizing agent or a chelating agent may be used.

According to the hyperbranched polymer synthesizing method of the embodiment, the hyperbranched core polymer molecules can be prevented from forming gel, for example, when at least a compound represented by R₁-A or a compound represented by R₂—B—R₃ is added in the core polymerization as described above.

As described above, a hyperbranched polymer synthesizing method as described above is preferable because the amount of the metal catalyst used can be reduced and the rapid increase in the molecular weight can be prevented, for example, by making each mixing amount of the monomer into the reaction system less than the total amount of the monomer to be mixed with the reaction system, as compared to the case of mixing the total amount of the monomer with the reaction system at one time in the core polymerization.

Therefore, a hyperbranched polymer synthesizing method as described above is preferable because the amount of the metal catalyst can be reduced and the rapid increase in the molecular weight can be prevented to stably produce the hyperbranched polymer having the desired molecular weight and branching degree.

### (Monomer Used in Synthesis of Shell Portion of Core-Shell Hyperbranched Polymer)

The monomer used in the synthesis of the shell portion of the core-shell hyperbranched polymer will be described. The shell portion of the core-shell hyperbranched polymer constitutes the terminal of the polymer molecule. The monomer used in the synthesis of the shell portion of the core-shell hyperbranched polymer includes, for example, a monomer giving the repeating unit represented by formula (II) described in the first chapter, a monomer giving the repeating unit represented by formula (III) described in the first chapter, and a monomer selected from a group consisting of mixtures thereof.

The monomers giving the repeating unit represented by formula (II) described in the first chapter and the repeating unit represented by formula (III) described in the first chapter include, for example, an acid-degradable group degraded by an effect of an organic acid such as acetic acid, maleic acid, and benzoic acid or an inorganic acid such as hydrochloric acid, sulfuric acid, or nitric acid. The repeating unit represented by formula (II) or formula (III) preferably includes an acid-degradable group degraded by an effect of the photoacid generator that generates an acid with optical energy. Degradation of the acid-degradable group to form a hydrophilic group is preferable.

R¹ of formula (II) and R⁴ of formula (III) denote hydrogen atoms or alkyl groups having 1 to 3 carbon atoms. R¹ of formula (II) and R⁴ of formula (III) are preferably hydrogen atoms and methyl groups. R¹ of formula (II) and R⁴ of formula (III) are more preferably hydrogen atoms.

R² of formula (II) denotes a hydrogen atom, an alkyl group or an aryl group. The alkyl group of R² of formula (II) preferably has 1 to 30 carbon atoms, for example. The alkyl group of R² of formula (II) more preferably has 1 to 20 carbon atoms. The alkyl group of R² of formula (II) further more preferably has 1 to 10 carbon atoms. The alkyl group has a straight-chain, branched, or cyclic structure. Specifically, the alkyl group of R² of formula (II) includes, for example, a methyl group, an ethyl group, a propyl group, an isopropyl group, a butyl group, an isobutyl group, a t-butyl group, and a cyclohexyl group.

The aryl group of R² of formula (II) preferably has 6 to 30 carbon atoms, for example. The aryl group of R² of formula (II) more preferably has 6 to 20 carbon atoms. The aryl group of R² of formula (II) further more preferably has 6 to 10 carbon atoms. Specifically, the aryl group of R² of formula (II) includes, for example, a phenyl group, a 4-methylphenyl group, and a naphthyl group. A hydrogen atom, a methyl group, an ethyl group, and a phenyl group are particularly cited among the above groups. A hydrogen atom is cited as one of the most preferable groups for R² of formula (II).

R³ of formula (II) and R⁵ of formula (III) denote hydrogen atoms, alkyl groups, trialkylsilyl groups, oxoalkyl groups, or groups represented by formula (i) described in the first chapter. The alkyl groups of R³ of formula (II) and R⁵ of formula (III) preferably have 1 to 40 carbon atoms. The alkyl groups of R³ of formula (II) and R⁵ of formula (III) more preferably have 1 to 30 carbon atoms. The alkyl groups of R³ of formula (II) and R⁵ of formula (III) further more preferably have 1 to 20 carbon atoms. The alkyl groups of R³ of formula (II) and R⁵ of formula (III) have a straight-chain, branched, or cyclic structure.

Each of the alkyl groups of R³ of formula (II) and R⁵ of formula (III) preferably has 1 to 6 carbon atoms and more preferably has 1 to 4 carbon atoms. The alkyl group of the oxoalkyl groups of R³ of formula (II) and R⁵ of formula (III) preferably has 4 to 20 carbon atoms and more preferably has 4 to 10 carbon atoms.

R⁶ of formula (i) denotes a hydrogen atom or an alkyl group. The alkyl group of R⁶ in the groups represented by formula (i) has a straight-chain, branched-chain, or cyclic structure. The alkyl group of R⁶ in the groups represented by formula (i) preferably has 1 to 10 carbon atoms. The alkyl group of R⁶ in the groups represented by formula (i) more preferably has 1 to 8 carbon atoms and yet more preferably has 1 to 6 carbon atoms.

R⁷ and R⁸ of formula (i) denote hydrogen atoms or alkyl groups. The hydrogen atoms or alkyl groups of R⁷ and R⁸ of formula (i) may be independent of each other or form a ring. The alkyl groups of R⁷ and R⁸ of formula (i) have a straight-chain, branched-chain, or cyclic structure. The alkyl groups of R⁷ and R⁸ of formula (i) preferably have 1 to 10 carbon atoms. The alkyl groups of R⁷ and R⁸ of formula (i) more preferably have 1 to 8 carbon atoms. The alkyl groups of R⁷ and R⁸ of formula (i) yet more preferably have 1 to 6 carbon atoms. Branched alkyl groups having 1 to 20 carbon atoms are preferable for R⁷ and R⁸ of formula (i).

The group represented by formula (i) includes a straight-chain or branched acetal group such as a 1-methoxyethyl group, a 1-ethoxyethyl group, a 1-n-propoxyethyl group, a 1-isopropoxyethyl group, a 1-n-butoxyethyl group, a 1-isobutoxyethyl group, a 1-sec-butoxyethyl group, a 1-tert-butoxyethyl group, a 1-tert-amyloxyethyl group, a 1-ethoxy-n-propyl group, a 1-cyclohexyloxyethyl group, a methoxypropyl group, an ethoxypropyl group, a 1-methoxy-1-methyl-ethyl group, and a 1-ethoxy-1-methyl-ethyl group; and a cyclic acetal group such as a tetrahydrofuranyl group and a tetrahydropyranyl group. The ethoxyethyl group, the butoxyethyl group, the ethoxypropyl group, and the tetrahydropyranyl group are particularly preferred among the above groups for the group represented by formula (i).

R³ of formula (II) and R⁵ of formula (III) preferably denote straight-chain, branched, or cyclic alkyl groups having 1 to 40 carbon atoms, preferably 1 to 30 carbon atoms, and more preferably 1 to 20 carbons. R³ of formula (II) and R⁵ of formula (III) preferably denote branched alkyl groups having 1 to 20 carbon atoms.

The straight-chain, branched, or cyclic alkyl groups of R³ of formula (II) and R⁵ of formula (III) include an ethyl group, a propyl group, an isopropyl group, a butyl group, an isobutyl group, a tert-butyl group, a cyclopentyl group, a cyclohexyl group, a cycloheptyl group, a triethylcarbyl group, a 1-ethylnorbornyl group, a 1-methylcyclohexyl group, an adamantyl group, a 2-(2-methyl)adamantyl group, a tert-amyl group, etc. Among above groups, the tert-butyl group is particularly preferable.

The trialkylsilyl group of R³ of formula (II) and R⁵ of formula (III) includes the alkyl groups having 1 to 6 carbon atoms such as a trimethylsilyl group, a triethylsilyl group, and a dimethyl-tert-butylsilyl group. The oxoalkyl group includes a 3-oxocyclohexyl group, etc.

Monomers giving repeating units represented by formula (II) include, for example, vinylbenzoic acid, tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1 n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinylbenzoate, adamantyl vinylbenzoate, 2-(2-methyl)adamantyl vinylbenzoate, chloroethyl vinylbenzoate, 2-hydroxyethyl vinylbenzoate, 2,2-dimethylhydroxypropyl vinylbenzoate, 5-hydroxybenzyl vinylbenzoate, trimethylolpropane vinylbenzoate, glycidyl vinylbenzoate, benzyl vinylbenzoate, phenyl vinylbenzoate, and naphthyl vinylbenzoate. Among these, a polymer of 4-vinylbenzoic acid and tert-butyl 4-vinylbenzoate is preferable.

Monomers giving repeating units represented by formula (III) include, for example, acrylate, tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1-ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1-ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, methacrylic acid, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl) oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate. Among these, polymers of acrylate and tert-butyl acrylate are preferable.

The monomer corresponding to the shell portion is also preferably a polymer of at least one among 4-vinylbenzoic acid and acrylic acid and at least one among tert-butyl 4-vinylbenzoate and tert-butyl acrylate. In addition to monomers giving repeating units represented by formula (II) and formula (III), a monomer corresponding to the shell portion may be any monomer having a structure with a radically polymerizable unsaturated bond.

In addition to the styrenes above, usable monomers include compounds having a radically polymerizable unsaturated bond and may be selected from among allyl compounds, vinyl ethers, vinyl esters, crotonates, etc.

Specifically, in addition to styrenes cited as monomers usable as a monomer constituting the shell portion include, for example, styrene, tert-butoxystyrene, α-methyl-tert-butoxystyrene, 4-(1-methoxyethoxy)styrene, 4-(1-ethoxyethoxy)styrene, tetrahydropyranyloxystyrene, adamantyloxystyrene, 4-(2-methyl-2-adamantyloxy)styrene, 4-(1-methylcyclohexyloxy)styrene, trimethylsilyloxystyrene, dimethyl-tert-butylsilyloxystyrene, tetrahydropyranyloxystyrene, benzylstyrene, trifluoromethylstyrene, acetoxystyrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, 4-fluoro-3-trifluoromethylstyrene, and vinylnaphthalene.

Specifically, allyl esters cited as monomers usable as a monomer constituting the shell portion include, for example, allyl acetate, allyl caproate, allyl caprylate, allyl laurate, allyl palmitate, allyl stearate, allyl benzoate, allyl acetoacetate, allyl lactate, and allyloxyethanol.

Specifically, vinyl ethers cited as monomers usable as a monomer constituting the shell portion include, for example, hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether, tetrahydrofurfuryl vinyl ether, vinylphenyl vinyl ether, vinyl tolyl ether, vinyl chlorophenyl ether, vinyl-2,4-dichlorophenyl ether, vinyl naphthyl ether, and vinyl anthranyl ether.

Specifically, vinylesters cited as monomers usable as a monomer constituting the shell portion include, for example, vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl-β-phenylbutyrate, and vinyl cyclohexylcarboxylate.

Specifically, crotonates cited as monomers usable as a monomer constituting the shell portion include, for example, butyl crotonate, hexyl crotonate, glycerin monocrotonate, dimethyl itaconate, diethyl itaconate, dibutyl itaconate, dimethyl maleate, dibutyl fumarate, maleic anhydride, maleimide, acrylonitrile, methacrylonitrile, and maleilonitrile.

Specifically, monomers usable as a monomer constituting the shell portion also include, for example, formulas (IV) to (XIII) cited in chapter 1 above.

Among monomers usable as monomer constituting the shell portion, styrenes and crotonates are preferable.

Among monomers usable as monomer constituting the shell portion, styrene, benzylstyrene, chlorostyrene, vinylnaphthalene, butyl crotonate, hexyl crotonate, and maleic anhydride are preferable.

The shell portion of the core-shell hyperbranched polymer may be introduced into the terminals of the hyperbranched polymer synthesized as described by reacting the core portion of the hyperbranched polymer synthesized as described and a monomer containing the acid-degradable group. The monomer containing the acid-degradable group for the core portion of the hyperbranched polymer includes, for example, at least monomer giving the repeating unit represented by formula (II) or monomer giving the repeating unit represented by formula (III). This enables at least the acid-degradable group giving the repeating unit represented by formula (II) or the acid-degradable group giving the repeating unit represented by formula (III) to be introduced into the shell portion of the core-shell hyperbranched polymer.

In the core-shell hyperbranched polymer of the present invention, at least monomer giving a repeating unit represented by formula (II) or monomer giving a repeating unit represented by formula (III) is included. Monomer giving the repeating units above is preferably included at 10 to 90 mol % based on the core-shell hyperbranched polymer. The range is more preferably 20 to 90 mol % and further more preferably at 30 to 90 mol %. Particularly, in the shell portion, at least the repeating unit represented by formula (II) or the repeating unit represented by formula (III) is preferably included at 50 to 100 mol %, and more preferably at 80 to 100 mol %, based on the core-shell hyperbranched polymer.

It is preferable for at least the repeating unit represented by formula (II) or the repeating unit represented by formula (III) to be at the above ranges based on the core-shell hyperbranched polymer since the exposed portion is efficiently dissolved into alkaline solution and removed at the development step of lithography using the resist composition using the core-shell hyperbranched polymer.

When the shell portion of the core-shell hyperbranched polymer is a polymerized product of monomer giving a repeating unit represented by formula (II) and/or monomer giving a repeating unit represented by formula (III) and other monomer, at least monomer giving the repeating unit represented by formula (II) and/or monomer giving the repeating unit represented by formula (III) preferably accounts for 30 to 90 mol %, more preferably 50 to 70 mol % relative to the total amount of monomer constituting the shell portion at the time of charging. At the above ranges, functions such as increases in the etching resistance, the wetting properties, and the glass transition temperature are preferably induced without inhibiting the efficient alkali solubility of the exposed portion.

According to purpose, the ratio of repeating units represented by formula (II) and/or repeating units represented by formula (III) to other repeating units may be adjusted by the molar ratio of the charging amount at the time of introduction of the shell portion.

### (Catalyst Used in Synthesis of Core Portion of Core-Shell Hyperbranched Polymer)

The catalyst used in the synthesis of the shell portion of the core-shell hyperbranched polymer will be described. The catalyst used in the synthesis of the shell portion of the core-shell hyperbranched polymer includes, for example, a transition metal complex catalyst identical to the catalyst used in the synthesis of the core portion of the core-shell hyperbranched polymer as described above. Specifically, the catalyst used in the synthesis of the shell portion of the core-shell hyperbranched polymer includes, for example, copper (monovalent) bipyridyl complex.

The catalyst used in the synthesis of the shell portion of the core-shell hyperbranched polymer causes the living radical polymerization with the double bonds in one or more compounds containing the monomer giving the repeating unit represented by formula (II) and/or the repeating unit represented formula (III) using a multiplicity of halogenated hydrocarbons located at the terminal of the core portion of the above core-shell hyperbranched polymer described above as the starting points to cause the addition polymerization of the shell portion in a straight-chain form. Specifically, the core-shell hyperbranched polymer of the present invention may be synthesized, for example, by reacting the core portion of the above core-shell hyperbranched polymer and one or more compounds containing the monomer giving the repeating unit represented by formula (II) and/or the repeating unit represented formula (III) in a solvent such as chlorobenzene at 0 to 200 degrees C. for 0.1 to 30 hours.

A portion of the acid-degradable group may be degraded to an acid group with the acid catalyst such as hydrochloric acid, sulfuric acid, phosphoric acid, hydrobromic acid, p-toluenesulfonic acid, acetic acid, trifluoroacetic acid, trifluoromethanesulfonic acid, and formic acid by adding the solid-state resist polymer intermediate to an appropriate organic solvent such as 1,4-dioxane containing an acid catalyst and by heating and agitating the mixture normally at a temperature of 50 to 150 degrees C. for 10 minutes to 20 hours.

A rate of the acid-degradable group and the acid group in the acquired resist polymer is varied depending on the composition of the resist and is preferably defined such that 0.1 to 80 mol % of the monomer containing the introduced acid-degradable group is deprotected. The rate of the acid-degradable group and the acid group at such a range is preferable since the higher sensitivity and efficient alkali solubility after exposure are achieved. The acquired solid-state resist polymer may be separated from the reaction solvent and dried for later use.

As described, according to the synthesizing method of the hyperbranched polymer including the core-shell hyperbranched polymer, metal and oligomers may be removed at the same time without using absorbent. Therefore, according to the synthesizing method of the hyperbranched polymer including the core-shell hyperbranched polymer above, impurities such as a metal catalyst and by-product oligomers can be removed easily without using absorbent to easily and stably produce a large amount of the hyperbranched polymer.

According to the synthesizing method of the hyperbranched polymer including the core-shell hyperbranched polymer above, the metal may be removed to the extent that the step of introducing the acid-degradable group into the core portion is not affected. The oligomers removed in the synthesizing method of the hyperbranched polymer including the core-shell hyperbranched polymer above are substances having a molecular weight equal to or less than a quarter of the weight-average molecular weight of the hyperbranched polymer acting as the core portion of the core-shell hyperbranched polymer above.

In the synthesizing method of the hyperbranched polymer including the core-shell hyperbranched polymer above, metal and oligomers may be removed at the same time without using absorbent by adjusting the solubility parameters and amounts of the solvents A to C. Therefore, according to the synthesizing method of the hyperbranched polymer including the core-shell hyperbranched polymer above, impurities such as a metal catalyst and by-product oligomers can be removed easily without using absorbent to easily and stably produce a large amount of the hyperbranched polymer.

As described above, by synthesizing the core-shell hyperbranched polymer with the use of the hyperbranched polymer after impurities such as a metal catalyst and by-product oligomers are easily removed, a large amount of the core-shell hyperbranched polymer having a stable quality can be synthesized easily. By using the synthesizing method described, impurities such as a metal catalyst and by-product oligomers are removed and a large amount of the hyperbranched polymer including the core-shell hyperbranched polymer having a stable quality can be acquired.

According to the resist composition including the core-shell hyperbranched polymer synthesized as described, occurrences of adverse effects such as considerable changes in reactivity and insolubilization after exposure can be reduced.

By using the resist composition including the core-shell hyperbranched polymer synthesized as described, semiconductor integrated circuits can be fabricated with ultrafine circuit patterns formed thereon.

By producing semiconductor integrated circuits with the use of the resist composition including the hyperbranched polymer including the core-shell hyperbranched polymer synthesized as described, semiconductor integrated circuits can be produced easily with ultrafine circuit patterns formed thereon.

Examples of the embodiment of the second chapter above will hereinafter be described. The examples of the embodiment of the second chapter above are not limited to the following specific examples and are not to be construed in a limited way from the following specific examples.

In the examples, the core-shell hyperbranched polymer is synthesized as follows, and a weight-average molecular weight (Mw), a number-average molecular weight (Mn), a branching degree (Br), metal contents, a monomer component reduction rate (%), and a dimer component reduction rate (%) of the synthesized core portion of the core-shell hyperbranched polymer are measured.

### (Weight-Average Molecular Weight (Mw), Number-Average Molecular Weight (Mn))

The weight-average molecular weight (Mw) and the number-average molecular weight (Mn) of the core-shell hyperbranched polymer of the examples will first be described. The weight-average molecular weight (Mw) and the number-average molecular weight (Mn) of the core-shell hyperbranched polymer (core portion) of the examples are values obtained by preparing a 0.5 mass % tetrahydrofuran solution and performing measurement with a GPC HCL-8020 apparatus manufactured by Tosoh Corporation and two coupled TSKgel HXL-L columns (manufactured by Tosoh Corporation) under the temperature of 40 degrees C. In the measurement, tetrahydrofuran was used as a mobile solvent. In the measurement, polystyrene was used as a standard substance.

### (Branching Degree (Br))

The branching degree (Br) of the core-shell hyperbranched polymer of the examples will be described. The branching degree (Br) of the core-shell hyperbranched polymer of the examples was obtained by measuring ¹H-NMR of the product as follows. Specifically, the branching degree (Br) was calculated by carrying out an operation of the following equation (B) using an integration ratio H1° of proton of the —CH₂Cl site appearing at 4.6 ppm and an integration ratio H2° of proton of the —CHCl site appearing at 4.8 ppm. If the polymerization proceeds at both the —CH₂Cl site and the —CHCl site and the branching is enhanced, the Br value approaches 0.5.

### (Metal Contents)

The metal contents of the core-shell hyperbranched polymer of the examples will be described. The metal contents of the core-shell hyperbranched polymer of the examples are determined by preparing a xylene (for atomic absorption) solution containing 1% of polymer and using ICP (Inductively Coupled Plasma) apparatus (Optima 5300 DV manufactured by PerkinElmer) to determine contents of copper (Cu) derived from the catalyst and aluminum (Al) derived from the absorbent with wavelengths of λCu=324.752 nm and λA1=308.215 nm. S-21 (manufactured by CONOSTAN) is used as a standard solution. The detection limit concentrations of the metals in the measurement condition of the examples are 1 ppm for copper and 10 ppm for aluminum (both correspond to polymer)

$$\begin{matrix}[ Equation 2 ] & \\ reduction rate = ( 100 - \frac{ \begin{matrix}contents of monomer component and \\ dimer component after fractionation\end{matrix} }{\begin{matrix}contents of monomer component and \\ dimer component before fractionation\end{matrix}} ) \times 100 & Equation ( B )\end{matrix}$$

Ultrapure water produced by GSR-200 manufactured by Advantec Toyo Kaisha, Ltd., was used in the examples. The ultrapure water has a metal content of 1 ppb or less and a specific resistance value of 18 MΩ·cm at 25 degrees C. In the examples, the following synthesis was performed with reference to synthesizing methods described in Krzysztof Matyjaszewski, Macromolecules., 29, 1079 (1996) and Jean M. J. Frecht, J. Poly. Sci., 36, 955 (1998).

### First Example

### Synthesis of Hyperbranched Polymer (Core Portion A)

The synthesis of the hyperbranched polymer (core portion A) of a first example of the embodiment of the second chapter above will first be described. In the synthesis of the hyperbranched polymer (core portion A) of the first example, first, 6.65 g of 2,2′-bipyridyl and 2.1 g of copper(I) chloride were collected in a 300-mL four-neck reactor with a cooling tube and an agitator attached under argon gas atmosphere; 150 mL of chlorobenzene and 10 mL of acetonitrile were added to the reaction solvent in the four-neck reactor; 32.5 g of chloromethylstyrene was dropped for 60 minutes; and the mixture was heated and agitated while maintaining the inside of the four-neck reactor at 115 degrees C. The reaction time was set to 240 minutes including the dropping time.

After the reaction was completed, the reaction solution was filtered with the use of filter paper having a retention particle size of 1 μm, and the filtrate was reprecipitated by adding 144 mL of methanol/16 ml of water (solvent A: 1 part by volume of the reaction solvent). The yield was 80%.

The weight-average molecular weight (Mw) and the branching degree (Br) of the hyperbranched polymer (core portion A) acquired as described were measured. The metal (copper and aluminum) contents of the hyperbranched polymer (core portion A) acquired as described were measured to calculate the rates relative to the polymer. The result of the core portion A is depicted in Table 3. In Table 3, copper content and aluminum content are represented as “Pppm” and “Qppm”, respectively.

A rate of substances having a molecular weight equal to or less than a quarter of the weight-average molecular weight (Mw) of the hyperbranched polymer (core portion A) is calculated relative to the hyperbranched polymer (core portion A) as a refined product. The result of the core portion A is depicted in Table 3. In Table 3, the rate is represented as “R %”. In the description or Table 3, MeOH, IPA, and THF represents methanol, 2-propanol, and tetrahydrofuran, respectively.

TABLE 3

| | | | | volume | | | | | | | |
|---|---|---|---|---|---|---|---|---|---|---|---|
| | | | volume ratio | ratio of | | | | | | | |
| | | | of solvent A | solvent B | solvent C | | molecular | branching | | | |
| | core | | (to reaction | (to 1 g of | (volume | yield | weight | degree | P | Q | R |
| | portion | operation | solvent) | polymer) | ratio) | (%) | (Mw) | (Br) | (ppm) | (ppm) | (%) |
| first | A | reprecipitated | MeOH/water | — | — | 80 | 1850 | 0.49 | 2 | <1 | 7 |
| example | | 1 time | 0.9/0.1 | | | | | | | | |
| second | B | reprecipitated | MeOH/water | — | — | 85 | 2300 | 0.49 | 2 | <1 | 7 |
| example | | 1 time | 1.8/0.2 | | | | | | | | |
| third | C | reprecipitated | IPA/water | — | — | 71 | 4000 | 0.47 | 5 | <1 | 5 |
| example | | 1 time | 0.9/0.1 | | | | | | | | |
| fourth | D | reprecipitated | THF/MeOH | — | — | 70 | 3000 | 0.49 | 2 | <1 | 6 |
| example | | 1 time | 0.2/1.8 | | | | | | | | |
| fifth | E | reprecipitated | MeOH/water | benzo- | MeOH/water | 26 | 1100 | 0.51 | <1 | <1 | 3 |
| example | | 4 time | 3.1/0.6 | nitrile | (5.1/1) | | | | | | |
| | | | | 3.4 mL | | | | | | | |
| first | F | reprecipitated | hexane 1 | — | — | 45 | 2800 | 0.48 | 980 | <1 | 10 |
| comparative | | 1 time | | | | | | | | | |
| example | | | | | | | | | | | |
| second | G | reprecipitated | toluene 1 | — | — | 0 | — | — | — | — | — |
| comparative | | 1 time | | | | | | | | | |
| example | | | | | | | | | | | |
| third | H | reprecipitated + | MeOH 2 | — | MeOH/THF | 48 | 6000 | 0.46 | 3 | 50 | 5 |
| comparative | | washed | | | (4/1) | | | | | | |
| example | | | | | | | | | | | |

### Second Example

### Synthesis of Hyperbranched Polymer (Core Portion B)

The synthesis of the hyperbranched polymer (core portion B) of a second example will be described. The synthesis of the hyperbranched polymer (core portion B) of the second example was performed in the same way as the synthesis of the hyperbranched polymer core portion A described in the first example above and the polymerization reaction was performed with the reaction time set to 300 minutes.

In the synthesis of the hyperbranched polymer (core portion B) of the second example, as compared to the synthesis of the hyperbranched polymer core portion A described in the first example above, the hyperbranched polymer core portion B was synthesized in the same way as the first example except that the solvent A used at the time of refinement was 288 mL of methanol/32 mL of water (solvent A: 2 parts by volume of the reaction solvent). The yield was 85%.

As is the case with the first example, the weight-average molecular weight (Mw), the branching degree (Br), and the metal contents of the hyperbranched polymer (core portion B) of the second example were measured and a rate of substances having a molecular weight equal to or less than a quarter of the weight-average molecular weight was calculated. The result of the core portion B is depicted in Table 3.

### Third Example

### Synthesis of Hyperbranched Polymer (Core Portion C)

The synthesis of the hyperbranched polymer (core portion C) of a third example will be described. The synthesis of the hyperbranched polymer (core portion C) of the third example was performed in the same way as the synthesis of the hyperbranched polymer core portion A described in the first example above and the polymerization reaction was performed with the reaction time set to 360 minutes.

In the synthesis of the hyperbranched polymer (core portion C) of the third example, as compared to the synthesis of the hyperbranched polymer core portion A described in the first example above, the hyperbranched polymer core portion C was synthesized in the same way as the first example except that methanol is replaced with 2-propanol in the solvent A used at the time of refinement. The yield was 71%.

As is the case with the third example, the weight-average molecular weight (Mw), the branching degree (Br), and the metal contents of the hyperbranched polymer (core portion C) of the second example were measured and a rate of substances having a molecular weight equal to or less than a quarter of the weight-average molecular weight was calculated. The result of the core portion C is depicted in Table 3.

### Fourth Example

### Synthesis of Hyperbranched Polymer (Core Portion D)

The synthesis of the hyperbranched polymer (core portion D) of a fourth example will be described. The synthesis of the hyperbranched polymer (core portion D) of the fourth example was performed in the same way as the synthesis of the hyperbranched polymer core portion A described in the first example above and the polymerization reaction was performed with the reaction time set to 300 minutes.

In the synthesis of the hyperbranched polymer (core portion D) of the fourth example, as compared to the synthesis of the hyperbranched polymer core portion A described in the first example above, the hyperbranched polymer core portion D was synthesized in the same way as the first example except that the solvent A used at the time of refinement was 32 mL of tetrahydrofuran/288 mL of methanol (solvent A: 2 parts by volume of the reaction solvent). The yield was 70%.

As is the case with the fourth example, the weight-average molecular weight (Mw), the branching degree (Br), and the metal contents of the hyperbranched polymer (core portion D) of the second example were measured and a rate of substances having a molecular weight equal to or less than a quarter of the weight-average molecular weight was calculated. The result of the core portion D is depicted in Table 3.

### Fifth Example

### Synthesis of Hyperbranched Polymer (Core Portion E)

The synthesis of the hyperbranched polymer (core portion E) of a fifth example will be described. The hyperbranched polymer (core portion E) of the fifth example was synthesized according to the following method. First, 11.8 g of 2,2′-bipyridyl, 3.5 g of copper(I) chloride, and 345 mL of benzonitrile were charged into a 300-mL four-neck reactor; a reaction apparatus was assembled by attaching a dropping funnel with 54.2 g of chloromethylstyrene measured, a cooling tube, and an agitator; the inside of the reaction apparatus was entirely degassed; and the inside of the reaction apparatus was entirely replaced with argon after the degassing. After the replacement with argon, the above mixture was heated to 125 degrees C. and chloromethylstyrene was dropped for 30 minutes. After the dropping was completed, the mixture was heated and agitated for 3.5 hours. The reaction time was set to four hours including the time for dropping chloromethylstyrene into the reactor.

After the reaction was completed, the reaction solution was filtrated with the use of filter paper having a retention particle size of 1 μm, and poly(chloromethylstyrene) was reprecipitated by adding the filtrate to a mixture solution acquired by preliminarily mixing 844 g of methanol and 211 g of ultrapure water.

After dissolving 29 g of the polymer acquired by the reprecipitation into 100 g of benzonitrile (solvent B: 2 mL per 1 g of polymer), a mixture solution of 200 g of methanol and 50 g of ultrapure water (solvent C: 4 parts by volume of the solvent B) was added and a polymer was collected by removing the solvent through decantation after centrifugal separation. This collection operation was repeated three times to acquire a polymer precipitate.

After the decantation, the precipitate was dried under reduced pressure and 14.0 g of poly(chloromethylstyrene) was acquired. The yield was 26%.

As is the case with the first example, the weight-average molecular weight (Mw), the branching degree (Br), and the metal contents of the hyperbranched polymer (core portion E) of the fifth example were measured and a rate of substances having a molecular weight equal to or less than a quarter of the weight-average molecular weight was calculated. The result of the core portion E is depicted in Table 3.

### First Comparative Example

### Synthesis of Hyperbranched Polymer (Core Portion F)

The synthesis of the hyperbranched polymer (core portion F) of a first comparative example will be described. The synthesis of the hyperbranched polymer (core portion F) of the first comparative example was performed in the same way as the synthesis of the hyperbranched polymer core portion A described in the first example above and the polymerization reaction was performed with the reaction time set to 300 minutes.

In the synthesis of the hyperbranched polymer (core portion F) of the first comparative example, as compared to the synthesis of the hyperbranched polymer core portion A described in the first example above, the hyperbranched polymer core portion F was synthesized in the same way as the first example except that the solvent A used at the time of refinement was 160 mL of hexane (solvent A: 1 part by volume of the reaction solvent). The yield was 45%.

As is the case with the first example, the weight-average molecular weight (Mw), the branching degree (Br), and the metal contents of the hyperbranched polymer (core portion F) of the second comparative example were measured and a rate of substances having a molecular weight equal to or less than a quarter of the weight-average molecular weight was calculated. The result of the core portion F is depicted in Table 3.

### Second Comparative Example

### Synthesis of Hyperbranched Polymer (Core Portion G)

The synthesis of the hyperbranched polymer (core portion G) of a second comparative example will be described. The synthesis of the hyperbranched polymer (core portion G) of the second comparative example was performed in the same way as the synthesis of the hyperbranched polymer core portion A described in the first example above and the polymerization reaction was performed with the reaction time set to 300 minutes.

In the synthesis of the hyperbranched polymer (core portion G) of the second comparative example, as compared to the synthesis of the hyperbranched polymer core portion

A described in the first example above, the hyperbranched polymer core portion G was synthesized in the same way as the first example except that the solvent A used at the time of refinement was 160 mL of toluene (solvent A: 1 part by volume of the reaction solvent). The yield was 0%.

As is the case with the first example, the weight-average molecular weight (Mw), the branching degree (Br), and the metal contents of the hyperbranched polymer (core portion G) of the second comparative example were measured and a rate of substances having a molecular weight equal to or less than a quarter of the weight-average molecular weight was calculated. The result of the core portion G is depicted in Table 3.

### Third Comparative Example

### Synthesis of Hyperbranched Polymer (Core Portion H)

The synthesis of the hyperbranched polymer (core portion H) of a third comparative example will be described. The synthesis of the hyperbranched polymer (core portion H) of the third comparative example was performed in the same way as the synthesis of the hyperbranched polymer core portion A described in the first example above and the polymerization reaction was performed with the reaction time set to 360 minutes.

After the reaction was completed, 1000 mL of tetrahydrofuran and 200 g of active alumina were added to the reaction mixture and the mixture was agitated for one hour. The active alumina was filtered off through filtration under reduced pressure and tetrahydrofuran in the filtrate was distilled by an evaporator. Subsequently, 320 mL of methanol (solvent A: 2 parts by volume of the reaction solvent) was added to the residue for reprecipitation and after being left still overnight, supernatant was decanted.

After the decantation, the precipitate was dried under reduced pressure; 20 g of the polymer acquired by the reprecipitation was added to the mixture solvent of 40 mL of tetrahydrofuran and 160 mL of methanol; and the mixture was agitated for 30 minutes. After the agitation, the agitated solvent was decanted and removed to acquire the hyperbranched polymer (core portion F) as a refined product. The yield was 48%.

The weight-average molecular weight (Mw), the branching degree (Br), and the metal contents of the hyperbranched polymer (core portion H) acquired as above were measured and a rate of substances having a molecular weight equal to or less than a quarter of the weight-average molecular weight was calculated. The result of the core portion H is depicted in Table 3.

### Sixth Example

### Synthesis of Core-Shell Hyperbranched Polymer

The synthesis of the core-shell hyperbranched polymer of a sixth example will be described. In the synthesis of the core-shell hyperbranched polymer of the sixth example, 144 mL of monochlorobenzene and 76 mL of acrylic acid tert-butyl ester were injected by syringe, respectively, into a reactor containing 2.7 g of copper(I) chloride, 8.3 g of 2,2′-bipyridyl, and 16.2 g of the core portion polymer A synthesized in the first example above under the argon gas atmosphere, and the mixture was heated and agitated at 120 degrees C. for five hours.

After the heating and the agitation, 200 mL of ultrapure water was added to the reaction mixture and agitated for 20 minutes and the water layer was removed from the agitated reaction mixture after the agitation. The operations of adding ultrapure water, agitating the reaction mixture, and removing the water layer from the agitated reaction mixture after the agitation were repeated four times to remove copper, which was the reaction catalyst and a light yellow solution was acquired.

The acquired light yellow solution was distilled under reduced pressure acquiring a crude product polymer. After the crude product was dissolved in 50 mL of tetrahydrofuran, 500 mL of methanol was added for reprecipitation, and the re-precipitated solution was centrifuged to separate a solid content. The precipitate in the centrifugally separated reprecipitated solution was washed with methanol acquiring a light yellow solid substance as a refined product. The yield was 18.7 g. A molar rate of the polymer was calculated by ¹H-NMR measurement.

### (Deprotecting Step)

In a reactor with a reflux tube, 0.6 g of the polymer was collected and 30 mL of dioxane and 0.6 mL of hydrochloric acid (30%) were added thereto, and heated and agitated at 90 degrees C. for 60 minutes. A heated and agitated reaction crude product was poured into 300 mL of ultrapure water and reprecipitated. A reprecipitated solid content was dissolved by adding 30 mL of dioxane and a solid content was reprecipitated again. The solid content reprecipitated again was collected and dried to acquire a <polymer 1>. The amount was 0.4 g and the yield was 66%. The structure of the <polymer 1> is depicted by the following formula (XIV).

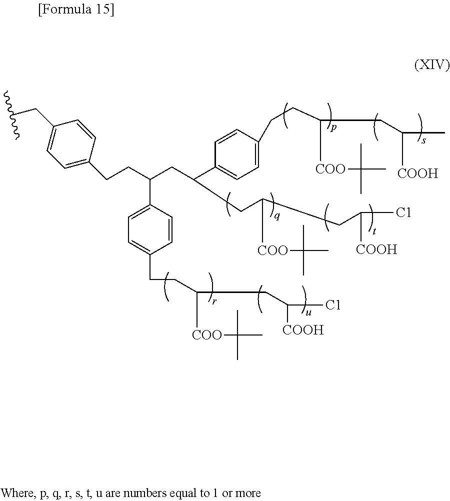

The introduction rates (component ratios) of the constituent units of the <polymer 1> represented by formula (XIV) are obtained by ¹H-NMR. The weight-average molecular weight (M) of the <polymer 1> was calculated using the introduction rates of the constituent units and the molecular weights of the constituent units based on the weight-average molecular weight (Mw) of the core portion A obtained in the first example. Specifically, the weight-average molecular weight (M) of the <polymer 1> was calculated using the following equations (C) and (D). The result is depicted in Table 4.

$$\begin{matrix}[ Equation 3 ] & \\ A = \frac{M w}{b} & Equation ( C ) \\ [ Equation 4 ] & \\ M = M w + \frac{A \times C \times c + A \times D \times d}{B} & Equation ( D )\end{matrix}$$

In the equations (C) and (D), A to D, b to d, Mw, and M are as follows:

A: number of moles of the obtained core portion;

B: molar ratio of a chloromethylstyrene portion obtained by NMR;

C: molar ratio of an acrylic acid tert-butyl ester portion obtained by NMR;

D: molar ratio of an acrylic acid portion obtained by NMR;

b: molecular weight of the chloromethylstyrene portion;

c: molecular weight of the acrylic acid tert-butyl ester portion;

d: molecular weight of the acrylic acid portion;

Mw: weight-average molecular weight of the core portion; and

M: weight-average molecular weight of the hyperbranched polymer.

As is the case with the sixth example, the introduction rates (introduction ratios) and the weight-average molecular weights (M) are obtained for the constituent units of the core-shell hyperbranched polymers <polymer 2> to <polymer 6> of the following seventh to eleventh examples. The results of <polymer 2> to <polymer 6> are depicted in Table 4.

### Seventh Example

### Synthesis of Core-Shell Hyperbranched Polymer

The core-shell hyperbranched polymer of a seventh example will be described. The core-shell hyperbranched polymer of the seventh example was synthesized with the use of the core portion polymer E of the fifth example above in the following method. Into a 500-mL four-neck reactor under an argon gas atmosphere, 1.6 g of copper(I) chloride, 5.1 g of 2,2′-bipyridyl, and 10.0 g of the hyperbranched polymer of the tenth example above were introduced, and 248 mL of monochlorobenzene and 48 mL of acrylic acid tert-butyl ester were injected by syringe, respectively. After the substances were injected into the reactor, the mixture in the reactor was heated and agitated at 125 degrees C. for five hours.

After the completion of the above polymerization reaction through the heating and agitation, insoluble substances were removed by filtering the reaction system after the completion of the polymerization reaction. Subsequently, 615 g of mixed acid aqueous solution containing 3 mass % of oxalic acid and 1 mass % of hydrochloric acid prepared with ultrapure water was added to 308 g of the filtrate acquired through the filtration and agitated for 20 minutes. After the agitation, a water layer was removed from the agitated reaction system. Copper, i.e., the reaction catalyst was removed by repeating four times the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 62.5 g of condensed liquid. By sequentially adding 219 g of methanol and 31 g of ultrapure water to the acquired condensed liquid, a solid content was precipitated. The solid content acquired by the precipitation was dissolved in 20 g of THF to acquire a solution, and 200 g of methanol and 29 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 23.8 g. The molar rate of the copolymer (the core-shell hyperbranched polymer with the shell portion formed) was calculated with ¹H-NMR. The core/shell rate of the core-shell hyperbranched polymer with the shell portion formed was 30/70 (molar ratio).

### Eighth Example

### Synthesis of Core-Shell Hyperbranched Polymer

The core-shell hyperbranched polymer of an eighth example will be described. The core-shell hyperbranched polymer of the eighth example was synthesized by performing the partial degradation (the deprotecting step) of the acid-degradable group of the core-shell hyperbranched polymer of the seventh example above.

### (Deprotecting Step)

The partial degradation of the acid-degradable group of the eighth example will be described. In the partial degradation of the acid-degradable group of the eighth example, first, 2.0 g of the copolymer (the above core-shell hyperbranched polymer) was collected in a reactor with a reflux tube and 18.0 g of 1,4-dioxane and 0.2 g of 50-mass % sulfuric acid were added thereto. Subsequently, reflux agitation was performed for 60 minutes while the entire reaction system including the reactor with the reflux tube was heated at a temperature for reflux. After the reflux agitation, the reaction crude product after the reflux agitation was poured into 180 mL of ultrapure water to precipitate a solid content.

After the solid content acquired by reprecipitation was dissolved in 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.6 g of polymer. A rate of the acid-degradable group and the acid group was 78/22.

### Ninth Example

### Synthesis of Core-Shell Hyperbranched Polymer

The core-shell hyperbranched polymer of a ninth example will be described. The core-shell hyperbranched polymer of the ninth example was synthesized with the use of the core portion polymer E of the fifth example above in the following method. Into a 500-mL four-neck reactor under an argon gas atmosphere, 1.6 g of copper(I) chloride, 5.1 g of 2,2′-bipyridyl, and 10.0 g of the hyperbranched polymer of the tenth example above were introduced, and 248 mL of monochlorobenzene and 81 mL of acrylic acid tert-butyl ester were injected by syringe, respectively. After the substances were injected into the reactor, the mixture in the reactor was heated and agitated at 125 degrees C. for five hours.

After the completion of the above polymerization reaction through the heating and agitation, insoluble substances were removed by filtering the reaction system after the completion of the polymerization reaction. Subsequently, 680 g of mixed acid aqueous solution containing 3 mass % of oxalic acid and 1 mass % of hydrochloric acid prepared with ultrapure water was added to 340 g of the filtrate acquired through the filtration and agitated for 20 minutes. After the agitation, a water layer was removed from the agitated reaction system. Copper, i.e., the reaction catalyst was removed by repeating four times the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 88.0 g of condensed liquid. By sequentially adding 308 g of methanol and 44 g of ultrapure water to the acquired condensed liquid, a solid content was precipitated. The solid content acquired by the precipitation was dissolved in 44 g of THF to acquire a solution, and 400 g of methanol and 63 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 33.6 g. The molar rate of the copolymer (the core-shell hyperbranched polymer with the shell portion formed) was calculated with ¹H-NMR. The core/shell rate of the core-shell hyperbranched polymer with the shell portion formed (hereinafter, “core-shell hyperbranched polymer”) was 19/81 (molar ratio).

### (Deprotecting Step)

The partial degradation of the acid-degradable group of the ninth example will be described. In the partial degradation of the acid-degradable group of the ninth example, 2.0 g of the copolymer (the above core-shell hyperbranched polymer) was collected in a reactor with a reflux tube and 18.0 g of 1,4-dioxane and 0.2 g of 50-mass % sulfuric acid were added thereto. Subsequently, reflux agitation was performed for 30 minutes while the entire reaction system including the reactor with the reflux tube was heated at a temperature for reflux. After the reflux agitation, the reaction crude product after the reflux agitation was poured into 180 mL of ultrapure water to precipitate a solid content.

After the solid content acquired by reprecipitation was dissolved in 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.6 g of polymer. A rate of the acid-degradable group and the acid group was 92/8.

### Tenth Example

### Synthesis of Core-Shell Hyperbranched Polymer

The core-shell hyperbranched polymer of a tenth example will be described. The core-shell hyperbranched polymer of the tenth example was synthesized with the use of the core portion polymer E of the fifth example above in the following method. Into a 1000-mL four-neck reactor under an argon gas atmosphere, 1.6 g of copper(I) chloride, 5.1 g of 2,2′-bipyridyl, and 10.0 g of the hyperbranched polymer of the tenth example above were introduced, and 248 mL of monochlorobenzene and 187 mL of acrylic acid tert-butyl ester were injected by syringe, respectively. After the substances were injected into the reactor, the mixture in the reactor was heated and agitated at 125 degrees C. for five hours.

After the completion of the above polymerization reaction through the heating and agitation, insoluble substances were removed by filtering the reaction system after the completion of the polymerization reaction. Subsequently, 880 g of mixed acid aqueous solution containing 3 mass % of oxalic acid and 1 mass % of hydrochloric acid prepared with ultrapure water was added to 440 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 175 g of condensed liquid. By sequentially adding 613 g of methanol and 88 g of ultrapure water to the acquired condensed liquid, a solid content was precipitated. The solid content acquired by the precipitation was dissolved in 85 g of THF to acquire a solution, and 850 g of methanol and 121 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 65.9 g. The molar rate of the copolymer (the core-shell hyperbranched polymer with the shell portion formed) was calculated with ¹H-NMR. The core/shell rate of the core-shell hyperbranched polymer with the shell portion formed (hereinafter, “core-shell hyperbranched polymer”) was 10/90 (molar ratio).

### (Deprotecting Step)

The partial degradation of the acid-degradable group of the tenth example will be described. In the partial degradation of the acid-degradable group of the tenth example, 2.0 g of the copolymer (the above core-shell hyperbranched polymer) was collected in a reactor with a reflux tube and 18.0 g of 1,4-dioxane and 0.2 g of 50-mass % sulfuric acid were added thereto. Subsequently, reflux agitation was performed for 15 minutes while the entire reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved in 50 g of methyl isobutyl ketone, 50 g of ultrapure water was added and agitated vigorously agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.7 g of polymer. A rate of the acid-degradable group and the acid group was 95/5.

### Eleventh Example

### Synthesis of Core-Shell Hyperbranched Polymer

The core-shell hyperbranched polymer of an eleventh example will be described. The core-shell hyperbranched polymer of the eleventh example was synthesized with the use of the core portion polymer E of the fifth example above in the following method. Into a 1000-mL four-neck reactor under an argon gas atmosphere, 1.6 g of copper(I) chloride, 5.1 g of 2,2′-bipyridyl, and 10.0 g of the hyperbranched polymer of the tenth example above were introduced, and 248 mL of monochlorobenzene and 14 mL of acrylic acid tert-butyl ester were injected by syringe, respectively. After the substances were injected into the reactor, the mixture in the reactor was heated and agitated at 125 degrees C. for five hours.

After the completion of the above polymerization reaction through the heating and agitation, insoluble substances were removed by filtering the reaction system after the completion of the polymerization reaction. Subsequently, 570 g of mixed acid aqueous solution containing 3 mass % of oxalic acid and 1 mass % of hydrochloric acid prepared with ultrapure water was added to 285 g of the filtrate acquired through the filtration and agitated for 20 minutes. After the agitation, a water layer was removed from the agitated reaction system. Copper, i.e., the reaction catalyst was removed by repeating four times the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 32 g of condensed liquid. By sequentially adding 112 g of methanol and 16 g of ultrapure water to the acquired condensed liquid, a solid content was precipitated. The solid content acquired by the precipitation was dissolved in 16 g of THF to acquire a solution, and 160 g of methanol and 23 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 12.1 g. The molar rate of the copolymer (the core-shell hyperbranched polymer with the shell portion formed) was calculated with ¹H-NMR. The core/shell rate of the core-shell hyperbranched polymer with the shell portion formed (hereinafter, “core-shell hyperbranched polymer”) was 61/39 (molar ratio).

### (Deprotecting Step)

The partial degradation of the acid-degradable group of the eleventh example will be described. In the partial degradation of the acid-degradable group of the eleventh example, 2.0 g of the copolymer (the above core-shell hyperbranched polymer) was collected in a reactor with a reflux tube and 18.0 g of 1,4-dioxane and 0.2 g of 50-mass % sulfuric acid were added thereto. Subsequently, reflux agitation was performed for 150 minutes while the entire reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved in 50 g of methyl isobutyl ketone, 50 g of ultrapure water was added and agitated vigorously agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.4 g of polymer. A rate of the acid-degradable group and the acid group was 49/51.

### First Reference Example

### Synthesis of Tert-Butyl 4-Vinylbenzoate

The synthesis was performed according to the following synthesizing method with reference to Synthesis, 833-834 (1982). Into a 1-L reactor with a dropping funnel attached, 91 g of 4-vinylbenzoic acid, 99.5 g of 1,1′-carbodiimidazole, 4-tert-butylpyrocatechol, and 500 g of dehydrated dimethylformamide were added under an argon gas atmosphere, kept at 30 degrees C., and agitated for one hour. Subsequently, 93 g of 1,8-diazabicyclo[5.4.0]-7-undecene and 91 g of dehydrated 2-methyl-2-propanol were added thereto and agitated for four hours. After the reaction was completed, 300 mL of diethyl ether and 10% potassium carbonate aqueous solution were added to extract the objective substance into the ether layer. The diethyl ether layer was subsequently dried under reduced pressure acquiring light yellow tert-butyl 4-vinylbenzoate. The acquisition of the objective substance was confirmed by ¹H-NMR. The yield was 88%.

In the equations (C) and (D), the introduction rates (introduction ratios) and the weight-average molecular weights (M) were obtained for the constituent units of the core-shell hyperbranched polymers <polymer 7> to <polymer 10> of the following twelfth to fifteenth examples in the same way as the sixth example except that acrylic acid tert-butyl ester and acrylic acid were replaced with tert-butyl 4-vinylbenzoate and 4-vinylbenzoic acid, respectively. The results of <polymer 7> to <polymer 10> are depicted in Table 4.

### Twelfth Example

### Synthesis of Core-Shell Hyperbranched Polymer

The core-shell hyperbranched polymer of the twelfth example will be described. The core-shell hyperbranched polymer of the twelfth example was synthesized with the use of the core portion polymer E of the fifth example above in the following method. Into a 1000-mL four-neck reactor under an argon gas atmosphere, 0.8 g of copper(I) chloride, 2.6 g of 2,2′-bipyridyl, and 5.0 g of the hyperbranched polymer of the tenth example above were introduced, and 421 mL of monochlorobenzene and 46.8 g of tert-butyl 4-vinylbenzoate were injected by syringe, respectively.

After the substances were injected into the reactor, the mixture in the reactor was heated and agitated at 125 degrees C. for five hours.

After the completion of the above polymerization reaction through the heating and agitation, insoluble substances were removed by filtering the reaction system after the completion of the polymerization reaction. Subsequently, 980 g of mixed acid aqueous solution containing 3 mass % of oxalic acid and 1 mass % of hydrochloric acid prepared with ultrapure water was added to 490 g of the filtrate acquired through the filtration and agitation was performed for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 41 g of condensed liquid. By sequentially adding 144 g of methanol and 21 g of ultrapure water to the acquired condensed liquid, a solid content was precipitated. The solid content acquired by the precipitation was dissolved in 21 g of THF to acquire a solution, and 210 g of methanol and 30 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 15.9 g. The molar rate of the copolymer (the core-shell hyperbranched polymer with the shell portion formed) was calculated with ¹H-NMR. The core/shell rate of the core-shell hyperbranched polymer with the shell portion formed (hereinafter, “core-shell hyperbranched polymer”) was 29/71 (molar ratio).

### (Deprotecting Step)

The partial degradation of the acid-degradable group of the twelfth example will be described. In the partial degradation of the acid-degradable group of the twelfth example, 2.0 g of the copolymer (the above core-shell hyperbranched polymer) was collected in a reactor with a reflux tube and 18.0 g of 1,4-dioxane and 0.2 g of 50-mass % sulfuric acid were added thereto. Subsequently, reflux agitation was performed for 180 minutes while the entire reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved in 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.7 g of polymer. A rate of the acid-degradable group and the acid group was 38/62.

### Thirteenth Example

### Synthesis of Core-Shell Hyperbranched Polymer

The core-shell hyperbranched polymer of a thirteenth example will be described. The core-shell hyperbranched polymer of the thirteenth example was synthesized with the use of the core portion polymer E of the fifth example above in the following method. Into a 1000-mL four-neck reactor under an argon gas atmosphere, 1.6 g of copper(I) chloride, 5.1 g of 2,2′-bipyridyl, and 5.0 g of the hyperbranched polymer of the tenth example above were introduced, and 421 mL of monochlorobenzene and 46.8 g of tert-butyl 4-vinylbenzoate were injected by syringe, respectively. After the substances were injected into the reactor, the mixture in the reactor was heated and agitated at 125 degrees C. for three hours.

After the completion of the above polymerization reaction through the heating and agitation, insoluble substances were removed by filtering the reaction system after the completion of the polymerization reaction. Subsequently, 980 g of mixed acid aqueous solution containing 3 mass % of oxalic acid and 1 mass % of hydrochloric acid prepared with ultrapure water was added to 490 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 32 g of condensed liquid. By sequentially adding 224 g of methanol and 23 g of ultrapure water to the acquired condensed liquid, a solid content was precipitated. The solid content acquired by the precipitation was dissolved in 32 g of THF to acquire a solution, and 320 g of methanol and 46 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 24.5 g. The molar rate of the copolymer (the core-shell hyperbranched polymer with the shell portion formed) was calculated with ¹H-NMR. The core/shell rate of the core-shell hyperbranched polymer with the shell portion formed (hereinafter, “core-shell hyperbranched polymer”) was 20/80 (molar ratio).

### (Deprotecting Step)

The partial degradation of the acid-degradable group of the thirteenth example will be described. In the partial degradation of the acid-degradable group of the thirteenth example, 2.0 g of the copolymer (the above core-shell hyperbranched polymer) was collected in a reactor with a reflux tube and 18.0 g of 1,4-dioxane and 0.2 g of 50-mass % sulfuric acid were added thereto. Subsequently, reflux agitation was performed for 90 minutes while the entire reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved in 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.7 g of polymer. A rate of the acid-degradable group and the acid group was 71/29.

### Fourteenth Example

### Synthesis of Core-Shell Hyperbranched Polymer

The core-shell hyperbranched polymer of the fourteenth example will be described. The core-shell hyperbranched polymer of the fourteenth example was synthesized with the use of the core portion polymer E of the fifth example above in the following method. Into a 1000-mL four-neck reactor under an argon gas atmosphere, 1.6 g of copper(I) chloride, 5.1 g of 2,2′-bipyridyl, and 5.0 g of the hyperbranched polymer of the tenth example above were introduced, and 530 mL of monochlorobenzene and 60.2 g of tert-butyl 4-vinylbenzoate were injected by syringe, respectively. After the substances were injected into the reactor, the mixture in the reactor was heated and agitated at 125 degrees C. for four hours.

After the completion of the above polymerization reaction through the heating and agitation, insoluble substances were removed by filtering the reaction system after the completion of the polymerization reaction. Subsequently, 1240 g of mixed acid aqueous solution containing 3 mass % of oxalic acid and 1 mass % of hydrochloric acid prepared with ultrapure water was added to 620 g of the filtrate acquired through the filtration and agitated for 20 minutes. After the agitation, a water layer was removed from the agitated reaction system. Copper, i.e., the reaction catalyst was removed by repeating four times the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 130 g of condensed liquid. By sequentially adding 455 g of methanol and 65 g of ultrapure water to the acquired condensed liquid, a solid content was precipitated. The solid content acquired by the precipitation was dissolved in 65 g of THF to acquire a solution, and 650 g of methanol and 93 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 50.2 g. The molar rate of the copolymer (the core-shell hyperbranched polymer with the shell portion formed) was calculated with ¹H-NMR. The core/shell rate of the core-shell hyperbranched polymer with the shell portion formed (hereinafter, “core-shell hyperbranched polymer”) was 9/91 (molar ratio).

### (Deprotecting Step)

The partial degradation of the acid-degradable group of the fourteenth example will be described. In the partial degradation of the acid-degradable group of the fourteenth example, 2.0 g of the copolymer (the above core-shell hyperbranched polymer) was collected in a reactor with a reflux tube and 18.0 g of 1,4-dioxane and 0.2 g of 50-mass % sulfuric acid were added thereto. Subsequently, reflux agitation was performed for 30 minutes while the entire reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved in 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.7 g of polymer. A rate of the acid-degradable group and the acid group was 92/8.

### Fifteenth Example

### Synthesis of Core-Shell Hyperbranched Polymer

The core-shell hyperbranched polymer of the fifteenth example will be described. The core-shell hyperbranched polymer of the fifteenth example was synthesized with the use of the core portion polymer E of the fifth example above in the following method. Into a 1000-mL four-neck reactor under an argon gas atmosphere, 0.8 g of copper(I) chloride, 2.6 g of 2,2′-bipyridyl, and 5.0 g of the hyperbranched polymer of the tenth example above were introduced, and 106 mL of monochlorobenzene and 8.0 g of tert-butyl 4-vinylbenzoate were injected with the use of syringe, respectively. After the substances were injected into the reactor, the mixture in the reactor was heated and agitated at 125 degrees C. for one hour.

After the completion of the above polymerization reaction through the heating and agitation, insoluble substances were removed by filtering the reaction system.

Subsequently, 254 g of mixed acid aqueous solution containing 3 mass % of oxalic acid and 1 mass % of hydrochloric acid prepared with ultrapure water was added to 127 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 19 g of condensed liquid. By sequentially adding 67 g of methanol and 10 g of ultrapure water to the acquired condensed liquid, a solid content was precipitated. The solid content acquired by the precipitation was dissolved in 10 g of THF to acquire a solution, and 100 g of methanol and 14 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 7.3 g. The molar rate of the copolymer (the core-shell hyperbranched polymer with the shell portion formed) was calculated with ¹H-NMR. The core/shell rate of the core-shell hyperbranched polymer with the shell portion formed (hereinafter, “core-shell hyperbranched polymer”) was 60/40 (molar ratio).

### (Deprotecting Step)

The partial degradation of the acid-degradable group of the fifteenth example will be described. In the partial degradation of the acid-degradable group of the fifteenth example, 2.0 g of the copolymer (the above core-shell hyperbranched polymer) was collected in a reactor with a reflux tube and 18.0 g of 1,4-dioxane and 0.2 g of 50-mass % sulfuric acid were added thereto. Subsequently, reflux agitation was performed for 240 minutes while the entire reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved in 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.4 g of polymer. A rate of the acid-degradable group and the acid group was 22/78.

### (Preparation of Resist Composition)

The preparation of the resist compositions of the sixth to fifteenth examples will be described. In the preparation of the resist compositions of the sixth to fifteenth examples, the resist compositions were prepared by creating a propylene glycol monomethyl acetate (PEGMEA) solution containing 4.0 mass % of polymers of the above <polymer 1> to <polymer 10> and 0.16 mass % of triphenylsulfonium trifluoromethanesulfonate as a photoacid generator and by filtrating the solution with a filter having a fine pore size of 0.45 μm. Thin films with a thickness of 100 nm were created by spin-coating silicon wafers with the prepared resist compositions and by evaporating the solvents with one-minute heat treatments at 90 degrees C.

### (Measurement of Sensitivity to Ultraviolet Radiation)

Measurement of sensitivity to ultraviolet radiation will be described. In the measurement of sensitivity to ultraviolet radiation, a discharge tube type ultraviolet light irradiation apparatus (DF-245 Donafix manufactured by ATTO Corporation) was used as a light source. Ultraviolet light having a wavelength of 245 nm is applied to a rectangular portion having a length of 10 mm and width of 3 mm of a sample thin film having a thickness of about 100 nm formed on a silicon wafer with an energy amount changed from 0 mJ/cm² to 50 mJ/cm².

The silicon wafer after the application of the ultraviolet light was treated with heat at 100 degrees C. for four minutes and developed by immersing the heat-treated silicon wafer in 2.4-mass % tetramethylammonium hydroxide (TMAH) aqueous solution at 25 degrees C. for 2 minutes. The developed silicon wafer was washed with water and dried. The film thickness after the drying was measured using a thin film measurement apparatus F20 manufactured by Filmetrics, Inc., to measure a range of the applied energy when the film thickness after the development was zero. The results of the sixth to fifteenth examples are depicted in Table 4.

TABLE 4

| | | | mol of constituent elements of core-shell | | | | | | |
|---|---|---|---|---|---|---|---|---|---|
| | | | hyperbranched polymer | | | | | | |
| | | | | | | 4-vinyl- | | | |
| | | core-shell | | | | benzoic | | weight- | range of |
| | | hyper- | | acrylic | | acid | | average | sensitivity |
| | | branched | chloro- | acid | | tert- | | molecular | (mJ/cm²) to |
| | core | polymer | methyl | tert-butyl | acrylic | butyl | 4-vinylbenzoic | weight | ultraviolet |
| | portion | No. | styrene | ester | acid | ester | acid | (M) | (254 nm) |
| sixth | A | polymer 1 | 32 | 46 | 22 | — | — | 4680 | 2 to 50 |
| example | | | | | | | | | |
| seventh | E | polymer 2 | 30 | 70 | 0 | — | — | 3260 | 7 to 50 |
| example | | | | | | | | | |
| eighth | E | polymer 3 | 30 | 55 | 15 | — | — | 3050 | 3 to 50 |
| example | | | | | | | | | |
| ninth | E | polymer 4 | 19 | 75 | 6 | — | — | 4910 | 2 to 50 |
| example | | | | | | | | | |
| tenth | E | polymer 5 | 10 | 86 | 4 | — | — | 9250 | 2 to 50 |
| example | | | | | | | | | |
| eleventh | E | polymer 6 | 61 | 19 | 20 | — | — | 1580 | 3 to 50 |
| example | | | | | | | | | |
| twelfth | E | polymer 7 | 29 | — | — | 27 | 44 | 4090 | 3 to 50 |
| example | | | | | | | | | |
| thirteenth | E | polymer 8 | 20 | — | — | 57 | 23 | 6520 | 2 to 50 |
| example | | | | | | | | | |
| fourteenth | E | polymer 9 | 9 | — | — | 84 | 7 | 15670 | 2 to 50 |
| example | | | | | | | | | |
| fifteenth | E | polymer 10 | 60 | — | — | 9 | 31 | 1870 | 3 to 50 |
| example | | | | | | | | | |

As depicted in Table 3, the first to fifth examples above exhibit excellent removal performance for metals and oligomers and are preferred for the hyperbranched polymer as compared to the first to third comparative examples. Further, more metal catalysts, monomers, and oligomers can be removed by repetition of the reprecipitation operation. As depicted by Table 4, the first to fifth examples are also preferred for the resist composition when the core-shell hyperbranched polymer is formed.

### <Third Chapter>

### Step (A)

At step (A), a core-shell hyperbranched polymer having an acid-degradable group in the shell portion (hereinafter, “resist polymer intermediate” in some cases) is synthesized with the use of a metal catalyst in the ATRP (atom transfer radical polymerization) method.

### <Core Portion>

The core portion of the hyperbranched polymer of the present invention constitutes the core of the polymer molecule and is formed by polymerizing monomers represented by at least formula (I) described in the first chapter above.

In formula (I), Y denotes a straight-chain, branched, or cyclic alkylene group having 1 to 10 carbon atoms, preferably 1 to 8 carbon atoms, and more preferably 1 to 6 carbon atoms. The preferred number of carbon atoms of Y is 1 to 6 and may denote, for example, a methylene group, an ethylene group, a propylene group, an isopropylene group, a butylene group, an isobutylene group, an amylene group, a hexylene group, a cyclohexylene group, etc., and groups formed by combining the above groups or groups formed by containing “—O—”, “—CO—”, or “—COO—” between the above groups. Among the above groups, an alkylene group having 1 to 8 carbon atoms is preferable; a straight-chain alkylene group having 1 to 8 carbon atoms is more preferable; and a methylene group, an ethylene group, a —OCH₂— group, and a —OCH₂CH₂— group are further preferable. Z denotes a halogen atom such as fluorine, chlorine, bromine, and iodine. Among the atoms above, a chlorine atom or a bromine atom is preferable.

The monomers represented by formula (I) usable in the present invention include, for example, chloromethyl styrene, bromomethyl styrene, p-(1-chloroethyl)styrene, bromo(4-vinylphenyl)phenylmethane, 1-bromo-1-(4-vinylphenyl)propane-2-one, and 3-bromo-3-(4-vinylphenyl)propanol. Among the monomers above, chloromethyl styrene, bromomethyl styrene, and p-(1-chloroethyl)styrene are preferable.

Monomers constituting the core portion of the hyperbranched polymer of the present invention may include other monomers in addition to the monomers represented by formula (I). Other monomers are not particularly limited provided the monomers are radically polymerizable and may be selected according to the purpose.

Other radically polymerizable monomers include, for example, compounds having a radically polymerizable unsaturated bond selected from (meth)acrylic acid and (meth)acrylic esters, vinylbenzoic acid, vinylbenzoic esters, styrenes, allyl compounds, vinyl ethers, and vinyl esters, etc.

Specific examples of (meth)acrylic esters include tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1-ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1-ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl)oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate.

Specific examples of vinylbenzoic esters include tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1 n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinylbenzoate, adamantyl vinylbenzoate, 2-(2-methyl)adamantyl vinylbenzoate, chloroethyl vinylbenzoate, 2-hydroxyethyl vinylbenzoate, 2,2-dimethylhydroxypropyl vinylbenzoate, 5-hydroxybenzyl vinylbenzoate, trimethylolpropane vinylbenzoate, glycidyl vinylbenzoate, benzyl vinylbenzoate, phenyl vinylbenzoate, and naphthyl vinylbenzoate.

Specific examples of styrenes include styrene, benzylstyrene, trifluoromethylstyrene, acetoxystyrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, 4-fluoro-3-trifluoromethylstyrene, and vinylnaphthalene.

Specific examples of allyl compounds include allyl acetate, allyl caproate, allyl caprylate, allyl laurate, allyl palmitate, allyl stearate, allyl benzoate, allyl acetoacetate, allyl lactate, and allyloxyethanol.

Specific examples of vinyl ethers include hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether, tetrahydrofurfuryl vinyl ether, vinylphenyl vinyl ether, vinyl tolyl ether, vinyl chlorophenyl ether, vinyl-2,4-dichlorophenyl ether, vinyl naphthyl ether, and vinyl anthranyl ether.

Specific examples of vinylesters include vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl-β-phenylbutyrate, and vinyl cyclohexylcarboxylate.

Among the monomers above, (meth)acrylic acid, (meth)acrylic esters, 4-vinylbenzoic acid, 4-vinylbenzoic esters, and styrene are preferable; (meth)acrylic acid, tert-butyl (meth)acrylate, 4-vinylbenzoic acid, tert-butyl 4-vinylbenzoate, styrene, benzylstyrene, chlorostyrene, and vinylnaphthalene are particularly preferable.

In the hyperbranched polymer of the present invention, the amount of the monomer constituting the core portion is 10 to 90 mol %, preferably 10 to 80 mol %, and more preferably 10 to 60 mol % relative to the total amount of monomers. The amount of the monomer constituting the core portion is preferable to be at the above ranges since an appropriate hydrophobicity to the developing fluid is induced and the dissolution of the non-exposed portion is prevented.

The amount of monomer represented by formula (I) is 5 to 100 mol %, preferably 20 to 100 mol %, and more preferably 50 to 100 mol % relative to the total amount of monomers forming the core portion of the hyperbranched core polymer of the present invention. Such ranges are preferable since the core portion preferably takes a spherical form advantageous in preventing the entwining of molecules.

If the core portion of the hyperbranched polymer of the present invention is a copolymerization product of a monomer represented by formula (I) and another monomer, the amount of monomer represented by formula (I) is preferably 10 to 99 mol %, more preferably 20 to 99 mol %, and ideally 33 to 99 mol % relative to the total amount of monomers constituting the core portion. Such an amount of the monomer represented by formula (I) is preferable since the core portion takes a spherical form advantageous in preventing the entwining of molecules.

Using such an amount of the monomer represented by formula (I) is preferable since functions such as adhesiveness to substrates and increase in the glass-transition temperature are induced while maintaining the spherical form of the core portion. According to purpose, respective amounts of the monomer represented by formula (I) and of other monomers in the core portion may be adjusted by the ratio of the charging amount at the time of polymerization.

### <Shell Portion>

The shell portion of the hyperbranched polymer of the present invention constitutes the terminal of the polymer molecule and has repeating units represented at least by formula (II) described in the first chapter and/or formula (III) described in the first chapter above. The repeating unit includes an acid-degradable group degraded by an effect of an organic acid such as acetic acid, maleic acid, and benzoic acid or an inorganic acid such as hydrochloric acid, sulfuric acid, or nitric acid, preferably by an effect of the photoacid generator that generates an acid with optical energy and/or by heat. Degradation of the acid-degradable group to form a hydrophilic group is preferable.

R¹ of formula (II) and R⁴ of formula (III) denote hydrogen atoms or alkyl groups having 1 to 3 carbon atoms. Among above groups, hydrogen atoms and methyl groups are preferable and hydrogen atoms are more preferable.

R² of formula (II) denotes a hydrogen atom; a straight-chain, branched, or cyclic alkyl group having 1 to 30 carbon atoms, preferably 1 to 20 carbon atoms, more preferably 1 to 10 carbon atoms; or an aryl group having 6 to 30 carbon atoms, preferably 6 to 20 carbon atoms, more preferably 6 to 10 carbon atoms. The straight-chain, branched, or cyclic alkyl group includes a methyl group, an ethyl group, a propyl group, an isopropyl group, a butyl group, an isobutyl group, a t-butyl group, a cyclohexyl group, etc., and the aryl group includes a phenyl group, a 4-methylphenyl group, and a naphthyl group. Among the groups above, a hydrogen atom, a methyl group, an ethyl group, and a phenyl group are preferable, and a hydrogen atom is most preferable.

R³ of formula (II) and R⁵ of formula (III) denote hydrogen atoms; straight-chain, branched, or cyclic alkyl groups having 1 to 40 carbon atoms, preferably 1 to 30 carbon atoms, more preferably 1 to 20 carbon atoms; trialkylsilyl groups (where each alkyl group has 1 to 6, preferably 1 to 4 carbon atoms); oxoalkyl groups (where an alkyl group has 4 to 20, preferably 4 to 10 carbon atoms); or groups represented by formula (I) described in the first chapter above (where R⁶ denotes a hydrogen atom or a straight-chain, branched-chain, or cyclic alkyl group having 1 to 10 carbon atoms, preferably 1 to 8 carbon atoms, more preferably 1 to 6 carbon atoms, and R⁷ and R⁸ may denote a hydrogen atom or a straight-chain, branched-chain, or cyclic alkyl group having 1 to 10 carbon atoms, preferably 1 to 8 carbon atoms, more preferably 1 to 6 carbon atoms independently of each other or may form a ring together). Among the groups above, the straight-chain, branched, or cyclic alkyl groups having 1 to 40 carbon atoms, preferably 1 to 30 carbon atoms, more preferably 1 to 20 carbon atoms are preferable, and the branched alkyl groups having 1 to 20 carbon atoms are more preferable.

The straight-chain, branched, or cyclic alkyl groups of R³ and R⁵ above include an ethyl group, a propyl group, an isopropyl group, a butyl group, an isobutyl group, a tert-butyl group, a cyclopentyl group, a cyclohexyl group, a cycloheptyl group, a triethylcarbyl group, a 1-ethylnorbornyl group, a 1-methylcyclohexyl group, an adamantyl group, a 2-(2-methyl)adamantyl group, a tert-amyl group, etc. Among above groups, the tert-butyl group is particularly preferable.

The trialkylsilyl group of R³ and R⁵ above includes the alkyl groups having 1 to 6 carbon atoms such as a trimethylsilyl group, a triethylsilyl group, and a dimethyl-tert-butylsilyl group. The oxoalkyl group includes a 3-oxocyclohexyl group, etc.

R⁶ of formula (i) denotes a straight-chain, branched-chain, or cyclic alkyl group having 1 to 10 carbon atoms, and R⁷ and R⁸ may denote a hydrogen atom or a straight-chain, branched-chain, or cyclic alkyl group having 1 to 10 carbon atoms independently of each other or may form a ring together.

The group represented by formula (i) includes a straight-chain or branched acetal group such as a 1-methoxyethyl group, a 1-ethoxyethyl group, a 1-n-propoxyethyl group, a 1-isopropoxyethyl group, a 1-n-butoxyethyl group, a 1-isobutoxyethyl group, a 1-sec-butoxyethyl group, a 1-tert-butoxyethyl group, a 1-tert-amyloxyethyl group, a 1-ethoxy-n-propyl group, a 1-cyclohexyloxyethyl group, a methoxypropyl group, an ethoxypropyl group, a 1-methoxy-1-methyl-ethyl group, and a 1-ethoxy-1-methyl-ethyl group; and a cyclic acetal group such as a tetrahydrofuranyl group and a tetrahydropyranyl group. The ethoxyethyl group, the butoxyethyl group, the ethoxypropyl group, and the tetrahydropyranyl group are particularly preferred among above groups.

Monomers giving repeating units represented by formula (II) include, for example, vinylbenzoic acid, tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1 n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, 8-ethyl-δ-(4-vinylbenzoyl)oxy-δ-valerolactone, 1-methylcyclohexyl vinylbenzoate, adamantyl vinylbenzoate, 2-(2-methyl)adamantyl vinylbenzoate, chloroethyl vinylbenzoate, 2-hydroxyethyl vinylbenzoate, 2,2-dimethylhydroxypropyl vinylbenzoate, 5-hydroxybenzyl vinylbenzoate, trimethylolpropane vinylbenzoate, glycidyl vinylbenzoate, benzyl vinylbenzoate, phenyl vinylbenzoate, and naphthyl vinylbenzoate. Among these, a copolymer of 4-vinylbenzoic acid and tert-butyl 4-vinylbenzoate is preferable.

Monomers giving repeating units represented by formula (III) include, for example, acrylate, tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1-ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1-ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, methacrylic acid, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl)oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate. Among these, copolymers of acrylate and tert-butyl acrylate are preferable. A copolymer of 4-vinylbenzoic acid and/or acrylic acid and tert-butyl 4-vinylbenzoate and/or tert-butyl acrylate is also preferable.

Monomers other than the monomers giving the repeating units represented by formula (II) and formula (III) may be used as monomers forming the shell portion provided the monomers have a structure with a radically polymerizable unsaturated bond.

The usable comonomers include compounds having a radically polymerizable unsaturated bond selected from styrenes other than above, allyl compounds, vinyl ethers, vinyl esters, crotonates, etc.

Specific examples of styrenes include styrene, tert-butoxystyrene, α-methyl-tert-butoxystyrene, 4-(1-methoxyethoxy)styrene, 4-(1-ethoxyethoxy)styrene, tetrahydropyranyloxystyrene, adamantyloxystyrene, 4-(2-methyl-2-adamantyloxy)styrene, 4-(1-methylcyclohexyloxy)styrene, trimethylsilyloxystyrene, dimethyl-tert-butylsilyloxystyrene, tetrahydropyranyloxystyrene, benzylstyrene, trifluoromethylstyrene, acetoxystyrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, 4-fluoro-3-trifluoromethylstyrene, and vinylnaphthalene.

Specific examples of allyl esters include allyl acetate, allyl caproate, allyl caprylate, allyl laurate, allyl palmitate, allyl stearate, allyl benzoate, allyl acetoacetate, allyl lactate, and allyloxyethanol.

Specific examples of vinyl ethers include hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether, tetrahydrofurfuryl vinyl ether, vinylphenyl vinyl ether, vinyl tolyl ether, vinyl chlorophenyl ether, vinyl-2,4-dichlorophenyl ether, vinyl naphthyl ether, and vinyl anthranyl ether.

Specific examples of vinylesters include vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl-β-phenylbutyrate, and vinyl cyclohexylcarboxylate.

Specific examples of crotonates include butyl crotonate, hexyl crotonate, glycerin monocrotonate, dimethyl itaconate, diethyl itaconate, dibutyl itaconate, dimethyl maleate, dibutyl fumarate, maleic anhydride, maleimide, acrylonitrile, methacrylonitrile, and maleilonitrile, in addition to those represented by formulas (IV) to (XIII) in chapter 1.

Among above examples, styrenes and crotonates are preferable, and styrene, benzylstyrene, chlorostyrene, vinylnaphthalene, butyl crotonate, hexyl crotonate, and maleic anhydride are particularly preferable.

In the hyperbranched polymer of the present invention, that monomer giving the repeating unit represented by formula (II) and/or monomer giving the repeating unit represented by formula (III) is preferably included in the polymer at a range of 10 to 90 mol %, preferably 20 to 90 mol %, and more preferably 30 to 90 mol %. Particularly, repeating units represented by formula (II) or formula (III) are included in the shell portion at a range of 50 to 100 mol %, preferably 80 to 100 mol %. At such a range, an exposed portion is preferably efficiently dissolved in alkaline solution and removed at a development step.

When the shell portion of the hyperbranched polymer of the present invention is a copolymerized product of monomer giving a repeating units represented by formula (II) and/or monomer giving a repeating unit represented by formula (III) and other monomer, the amount of monomer giving a repeating unit represented by formula (II) and/or the amount of monomer giving a repeating unit represented by formula (III) preferably accounts for 30 to 90 mol %, more preferably 50 to 70 mol % relative to the total amount of monomers constituting the shell portion. At such a range, functions such as increases in the etching resistance, the wetting properties, and the glass transition temperature are induced without inhibiting the efficient alkali solubility of the exposed portion.

According to purpose, respective amounts of the repeating units represented by formula (II) and/or formula (III) and of other repeating units in the shell portion may be adjusted by the molar ratio of the charging amount at the time of introduction of the shell portion.

### <Metal Catalyst>

The metal catalysts usable in the present invention may include a catalyst acquired by combining transition metal such as copper, iron, ruthenium, and chromium, and a ligand consisting of pyridines and bipyridines not substituted or substituted by an alkyl group, an aryl group, an amino group, a halogen group, an ester group, etc., or alkyl and aryl phosphine, etc., for example, copper (monovalent) bipyridyl complex consisting of copper chloride and bipyridyl, iron triphenylphosphine complex consisting of iron chloride and triphenylphosphine. Among the above catalysts, copper (monovalent) bipyridyl complex is particularly preferable.

The amount of metal catalyst used in the synthesizing method of the present invention is preferably 0.1 to 70 mol %, more preferably 1 to 60 mol % relative to the total amount of monomers. If the catalyst is used in such an amount, the hyperbranched polymer core portion having a preferred branching degree may be acquired.

### <Synthesis of Resist Polymer Intermediate>

The core-shell hyperbranched polymer having the acid-degradable group in the shell portion may be synthesized by inputting a core-portion forming monomer into the reaction system along with the metal catalyst to form the core portion having a branching structure and subsequently inputting an acid-degradable-group forming monomer to form the shell portion.

For the core portion of the core-shell hyperbranched polymer, the core portion of the hyperbranched polymer may normally be synthesized by causing the living radical polymerization reaction of the raw material monomers in a solvent such as chlorobenzene at 0 to 200 degrees C. for 0.1 to 30 hours.

The shell portion of the core-shell hyperbranched polymer can be introduced at the terminal of the polymer by causing the core portion of the hyperbranched polymer synthesized as described above to react with the monomer containing the acid-degradable group.

### <First Method>

After isolating the core portion acquired by the core-portion synthesizing step for the hyperbranched polymer, for example, the monomer giving the repeating unit represented by formula (II) and/or formula (III) can be used for the monomer containing the acid-degradable group to introduce the acid-degradable group represented by formula (II) and/or formula (III) in this method.

The transition metal complex catalyst same as that used in the synthesis of the core portion of the hyperbranched polymer, for example, copper (monovalent) bipyridyl complex is used as the catalyst to cause the living radical polymerization with the double bonds in at least one compound containing monomer giving repeating units represented by formula (II) and/or formula (III) using a multiplicity of halogenated hydrocarbons located at the terminal of the core portion as the starting points to cause the addition polymerization in a straight-chain form. Specifically, the hyperbranched polymer of the present invention can normally be synthesized by reacting the core portion and at least one compound containing the monomer giving the repeating unit represented by formula (II) and/or formula (III) in a solvent such as chlorobenzene at 0 to 200 degrees C. for 0.1 to 30 hours.

### <Second Method>

After the core portion is formed by using the core-portion synthesizing step for the hyperbranched polymer, for example, the monomer giving the repeating unit represented by formula (II) and/or formula (III) can be used as a compound containing the acid-degradable group to introduce the acid-degradable group represented by formula (II) and/or formula (III) without isolating the core portion in this method. In this case, the metal catalyst input at the shell-portion forming step may be the same as or different from the metal catalyst used at the core-portion forming step. The metal catalyst used at the core-portion forming step may be regenerated and used. The regeneration may be performed in a method known in the industry. The metal catalyst used after forming the core portion before forming the shell portion can be removed in the same method as a method performed at a step (B) described later.

The acquired resist polymer intermediate normally contains metal at a range of 0.1 to 5 weight % depending on the amount of the metal catalyst used. It is critical to prevent the metal amount in the resist polymer to 100 ppb or less through refinement to maintain high performance of semiconductors. When copper (monovalent) bipyridyl complex is used as the metal catalyst, the amount of copper contained in the resist polymer intermediate is preferably 50 ppb or less. In the present invention, the metal content may be measured with the use of an ICP mass spectrometer or a flameless atomic absorption spectrometer.

### Step (B)

### <Pure Water>

Pure water used for washing the resist polymer intermediate acquired at step (A) is preferably pure water with a total amount of metal content of 10 ppb or less at 25 degrees C. It is also preferable to use pure water with a specific resistance value of 10 MΩ·cm or more at 25 degrees C. It is more preferable to use ultrapure water with a specific resistance value of 18 MΩ·cm or more at 25 degrees C. It is desirable to reduce an amount of metal in ultrapure water as much as possible to prevent metal derived from water from mixing in the resist polymer intermediate.

The ultrapure water may be manufactured through a combination of methods such as distillation, activated carbon absorption, ion exchanging, filtration, and reverse osmosis with the use of an apparatus such as CSR-200 manufactured by Advantec Toyo Kaisha, Ltd. The washing may be performed with the use of pure water and an aqueous solution of an organic compound having chelating ability such as formic acid, oxalic acid, and acetic acid and/or an aqueous solution of an inorganic acid such as hydrochloric acid and sulfuric acid.

The organic compounds having chelating ability usable in the present invention include organic carboxylic acid such as citric acid, gluconic acid, tartaric acid, and malonic acid, amino carbonate such as nitrilotriacetic acid, ethylenediaminetetraacetic acid, and diethylenetriaminopentaacetic acid, and hydroxyamino carbonate in addition to formic acid, oxalic acid, and acetic acid. Among above compounds, organic carboxylic acid is preferable, and oxalic acid and citric acid are more preferable. The inorganic acid usable in the present invention is preferably hydrochloric acid. Aqueous solutions of the organic compound having chelating ability and the inorganic acid are preferably prepared with the use of pure water, and the concentrations of the aqueous solutions are preferably 0.05 mass % to 10 mass %.

If the pure water, an aqueous solution of the organic compound having chelating ability, and an aqueous solution of the inorganic acid are used, the aqueous solution of the organic compound having chelating ability and the aqueous solution of the inorganic acid may be mixed and used, or may be used separately. An acid aqueous solution with the pH adjusted to, for example, five or less is preferably used. Use of an acidic aqueous solution is preferable since a distribution ratio of dissolution of a metal element into the water layer is improved and the number of times of washing can be reduced markedly as compared to washing with the pure water only.

The temperature of the pure water used for the washing is preferably 5 to 50 degrees C., more preferably 10 to 40 degrees C., and yet more preferably 15 to 30 degrees C. Using the pure water at such a temperature is preferable since the washing efficiency is increased.

### <Washing Process>

The washing process may be executed, after removing the insoluble metal catalyst through filtration from reaction liquid containing the resist polymer intermediate acquired at step (A) and the metal catalyst, by adding the pure water or adding the pure water and the aqueous solution of the organic compound having chelating ability and/or the inorganic acid aqueous solution to perform the liquid-liquid extraction process to remove metal.

If the pure water and the aqueous solution of the organic compound having chelating ability and/or the inorganic acid aqueous solution are used, the aqueous solution of the organic compound having chelating ability and the aqueous solution of the inorganic acid may be mixed and used, or may be used separately as above. Although any order of usage may be employed when used separately, it is preferable to use the inorganic acid aqueous solution later. It is believed that this is because the aqueous solution of the organic compound having chelating ability is effective in removal of a copper catalyst and polyvalent metal; and the inorganic acid aqueous solution is effective in removal of monovalent metal derived from experimental instruments, etc. Therefore, even when the aqueous solution of the organic compound having chelating ability and the inorganic acid aqueous solution are mixed for the washing, it is desirable to solely use the inorganic acid aqueous for the washing after washing with the mixed solvent.

The ratio of the reaction solvent to the pure water at the time of the washing for removal of metal is preferably 1:0.1 to 1:10, more preferably 1:0.5 to 1:5 by volume. If the pure water and the aqueous solution of the organic compound having chelating ability and/or the inorganic acid aqueous solution are used, the ratio of the reaction solvent to each solvent is also preferably at the above ranges when each solvent is independently used, or when a mixed solvent of the aqueous solution of the organic compound having chelating ability and the inorganic acid aqueous solution is used.

The above ranges are preferable not only for the ratio of the reaction solvent to the pure water but also for the ratio of the reaction solvent to the aqueous solution of the organic compound having chelating ability, the ratio of the reaction solvent to the inorganic acid aqueous solution, and the ratio of the reaction solvent to the mixed solvent of the aqueous solution of the organic compound having chelating ability and the inorganic acid aqueous solution. Washing with such a ratio is preferred operationally since the metal can be removed easily by an appropriate number of washings. The concentration by mass of the resist polymer intermediate dissolved in the reaction solvent is approximately 1 to 30 mass % and is preferably adjusted by adding chlorobenzene or chloroform used at the time of copolymerization.

The liquid-liquid extraction process may be executed by adding the reaction solvent and the pure water, or the pure water and the aqueous solution of the organic compound having chelating ability and/or the inorganic acid aqueous solution to the reaction solvent at preferably 10 to 50 degrees C. and more preferably 20 to 40 degrees C., sufficiently mixing the solvent with agitation, etc., separating the solvent into two layers by keeping still or centrifugal separation, and removing a water layer with migrated metal ions through decantation, etc.

It is desirable to reduce the amount of metal by repeating such an extraction process and performing centrifugal separation as needed. Although the number of times the extraction is executed is not particularly limited, if the pure water is solely used, extraction is preferably performed two times or more, more preferably 2 to 30 times, after the blue color of copper ion in the catalyst has disappeared. If the pure water and the aqueous solution of the organic compound having chelating ability and/or the inorganic acid aqueous solution are used, the extraction is desirably performed 2 to 10 times after the blue color of copper ion in the catalyst has disappeared.

After washing with the aqueous solution of the organic compound having chelating ability or after washing with the mixture of the aqueous solution of the organic compound having chelating ability and the inorganic acid aqueous solution, if the washing with the inorganic acid is performed, it is sufficient to execute the washing with only the inorganic acid aqueous solution one to five times. This enables the amount of metal in the hyperbranched polymer to be reduced to 100 ppb or less.

If the washing process is executed with the acid aqueous solution, it is desirable to execute a pure water extraction process at least one to two times, preferably one to five times, after the extraction process using the acid aqueous solution to remove acid. It is preferable that the experimental instruments, especially, those used after copper ion is reduced are used after a preliminary washing to prevent metal derived from the experimental instruments, etc., from being mixed. The method of the preliminary washing is not particularly limited and includes, for example, washing with nitric acid aqueous solution.

The resist polymer intermediate containing solution acquired as above contains residual monomers, by-product oligomers, ligands, etc., along with polymer. Therefore, the solution may be subjected to a reprecipitation operation using a poor solvent such as methanol to remove the residual monomers and the by-product oligomers to form pure resist polymer. Subsequently, the solvent may be removed from the resist polymer intermediate containing solution by operations such as reduced-pressure distillation to acquire and provide the solid-state resist polymer intermediate for later use.

After the above catalyst removal operation is performed, the resist polymer intermediate containing solution or the solid-state resist polymer intermediate may be dissolved in an organic solvent and the pure water or the pure water and the aqueous solution of the organic compound having chelating ability and/or the inorganic acid aqueous solution may be added to remove the metal through the further liquid-liquid extraction or ion exchange by an acid ion-exchange resin or ion-exchange membrane.

If the liquid-liquid extraction is performed, the organic solvent used includes chlorobenzene and chloroform used at the time of the synthesis of the resist polymer intermediate as well as acetic esters such as ethyl acetate, n-butyl acetate, and isoamyl acetate, ketones such as methyl ethyl ketone, methyl isobutyl ketone, cyclohexanone, 2-heptane, and 2-pentanone, glycol ether acetates such as ethylene glycol monoethyl ether acetate, ethylene glycol monobutyl ether acetate, and ethylene glycol monomethyl ether acetate, and aromatic hydrocarbons such as toluene and xylene. Ethyl acetate and methyl isobutyl ketone are more preferable. These solvents may be used independently or as a mixture of the two or more solvents.

An amount of the organic solvent is preferably set such that mass % of the resist polymer intermediate based on the organic solvent is about 1 to 30 mass % and more preferably approximately 5 to 20 mass % as described above. The ration of the reaction solvent to the pure water to be added (in volume) is preferably 1:0.1 to 1:10, more preferably 1:0.5 to 1:5. The same applies to the case of using the pure water and the aqueous solution of the organic compound having chelating ability and/or the inorganic acid aqueous solution. The number of times extraction is executed is not particularly limited and is preferably one to five times, more preferably one to three times. The order of washing is the same as described above.

If the metal is removed with an acid ion-exchange resin or ion-exchange membrane, it is preferable to perform the removal after reducing the amount of the metal impurities to about 1 ppm by washing with the pure water. The usable ion-exchange resin includes a commonly used cation-exchange resin, for example, a styrene vinylbenzene cation-exchange resin, for example, Amberlyst IR, 15 manufactured by Rohm and Haas Company. For the ion-exchange membrane, a membrane acquired by the graft polymerization of a polyethylene porous membrane with an ion-exchange group, for example, Protego CP manufactured by Nihon Mykrolis K.K., may be used.

<Filtration through Microfilter>

To remove particulate metal colloids, it is desirable to perform filtration through a filter in addition to the washing with the pure water preferably after the washing with the pure water. The filter to be used preferably has a pore diameter of 1 μm or less and includes, for example, Mykrolis PCM based on ultrahigh molecular weight polyethylene membrane, Whatman Puradisc based on PTFE (Teflon (registered trademark)), etc. The filtration is normally performed at a flow rate in a range of 1 mL/min to 20 mL/sec.

With such an operation, the amount of metal contained in the resist polymer intermediate can be reduced to 100 ppb or less, and especially when copper chloride is used as the catalyst, the amount may be reduced to 50 ppb or less for copper and to 50 ppb or less for each of other metals. Although the removal of metal through the water washing becomes very difficult since the acid group such as carboxylic acid generated due to the degradation cause complexation with metal impurities if the acid-degradable group is partially degraded without sufficiently removing metal at this step, the method of the present invention can efficiently solve such a problem.

### Step (C)

According to the present invention, by removing metals after the resist polymer intermediate is synthesized and degrading a portion of the acid-degradable group after the metal impurities are considerably reduced, a hyperbranched polymer having a constant ratio of the acid-degradable group to the acid group can be synthesized.

Specific examples of the acid catalyst include hydrochloric acid, sulfuric acid, phosphoric acid, hydrobromic acid, p-toluenesulfonic acid, acetic acid, trifluoroacetic acid, trifluoromethanesulfonic acid, formic acid, etc. Preferably, hydrochloric acid, sulfuric acid, p-toluenesulfonic acid, acetic acid, trifluoroacetic acid, and formic acid are preferred.

### <Degradation of Acid-Degradable Group>

To degrade a portion of the acid-degradable group into the acid group with the acid catalyst, the solid-state resist polymer intermediate is added to a suitable organic solvent such as 1,4-dioxane normally containing 0.001 to 100 equivalents of the acid catalyst based on the acid-degradable group and heated and agitated normally at 50 to 150 degrees C. for 15 minutes to 20 hours.

The ratio of the acid-degradable group to the acid group of the acquired resist polymer is varied depending on the optimum value of the composition of the resist and is preferably defined such that 5 to 80 mol % of the monomer containing the introduced acid-degradable group is deprotected. The ratio of the acid-degradable group to the acid group at such a range is preferable since the sensitivity is increased and efficient alkali solubility is achieved after exposure. The acquired solid-state resist polymer may be separated from the reaction solvent and dried for later use.

The branching degree (Br) of the core portion in the hyperbranched polymer is preferably 0.1 to 0.9, more preferably 0.3 to 0.7, yet more preferably 0.4 to 0.5, and most preferably 0.5. The branching degree of the core portion at such a range is preferable since the entwining of the polymer molecules is reduced and surface roughness is prevented on the pattern side walls.

The branching degree may be obtained by measuring ¹H-NMR of the product as follows. The branching degree may be calculated by the equation (A) using an integration ratio H1° of proton of the —CH₂Cl site appearing at 4.6 ppm and an integration ratio H2° of proton of the —CHCl site appearing at 4.8 ppm. If the polymerization proceeds at both the —CH₂Cl site and the —CHCl site and the branching is enhanced, the value of the Br value approaches 0.5.

The weight-average molecular weight of the core portion of the hyperbranched polymer of the present invention is preferably 300 to 100,000, also preferably 500 to 80,000, more preferably 1,000 to 60,000, yet more preferably 1,000 to 50,000, and most preferably 1,000 to 30,000. The molecular weight of the core portion at such a range is preferable since the core portion takes a spherical form and solubility into the reaction solvent may be ensured in the acid-degradable group introducing reaction. This is also preferable since the excellent film forming property is achieved and the dissolution of unexposed portions is advantageously prevented in the hyperbranched polymer after the acid-degradable group is induced in the core portion at the above molecular weight ranges.

The weight-average molecular weight (M) of the hyperbranched polymer of the present invention is preferably 500 to 150,000, more preferably 2,000 to 150,000, further preferably 1,000 to 100,000, further preferably 2,000 to 60,000, and most preferably 3,000 to 60,000. If the weight-average molecular weight (M) of the hyperbranched polymer is at such a range, a resist containing the hyperbranched polymer has a favorable film forming property and can maintain a shape since a process pattern formed at a lithography step is strong. Excellent dry etching resistance and favorable surface roughness are also achieved.

The weight-average molecular weight (Mw) of the core portion can be obtained by preparing a 0.5 mass % tetrahydrofuran solution and performing the GPC measurement at a temperature of 40 degrees C. Tetrahydrofuran may be used as a mobile solvent and styrene may be used as a standard substance. The weight-average molecular weight (M) of the hyperbranched polymer of the present invention may be obtained by using H¹NMR to obtain introduction rates (component ratios) of the repeating units of the polymer with the acid-degradable group introduced and performing a calculation using the introduction rates of the constituent units and the molecular weights of the constituent units based on the weight-average molecular weight (Mw) of the core portion of the hyperbranched polymer.

Since a small amount of metal impurities may be mixed in the resist polymer from experimental instruments, etc., at the acid-degradable group degrading step, a washing process may be executed with the use of the pure water having a total metal content of 10 ppb or less at 25 degrees C. or a washing process may be executed with the use of the pure water and the aqueous solution of the organic compound having chelating ability and/or the inorganic acid aqueous solution after this step.

With the manufacturing method of the present invention, the metal content in the acquired resist polymer can be reduced to 100 ppb. Reducing the amount of the metal content is preferable since this prevents adverse effects on the electric characteristics due to the metal impurities remaining in patterns. Among the metal content, it is preferable to reduce the concentration of copper used as a catalyst to 50 ppb. The metal content, in the context of the present invention, represents the total amount of metals derived from the metal catalysts, from the pure water used for the washing, and from the experimental instruments.

Examples of the embodiment of the third chapter above will hereinafter be described. The examples of the embodiment of the third chapter are not limited to the following specific examples and are not to be construed in a limited way from the following specific examples.

### First Example

### Synthesis of Resist Polymer Intermediate

Under argon gas atmosphere, 2.3 g of 2,2′-bipyridyl and 0.74 g of copper(I) chloride were collected in a 300-mL three-neck reactor with an agitator and a cooling tube attached; 23 mL of chlorobenzene, the reaction solvent, was added; 4.6 g of chloromethylstyrene was dropped for 5 minutes; and the mixture was heated and agitated while maintaining the inside temperature at 125 degrees C. to synthesize the core portion. The reaction time was set to 25 minutes including the dropping time. Subsequently, 150 mL of chlorobenzene and 17.1 g of 4-vinylbenzoic acid tert-butyl ester were injected by syringe, respectively; heating and agitation at 125 degrees C. was conducted for four hours to introduce the acid-degradable group.

### <Washing Process>

After quenching the reaction mixture, the mixture was transferred into a 1-L reactor; 500 mL of ultrapure water having a specific resistance value of 18 MΩ·cm (produced by GSR-200 manufactured by Advantec Toyo Kaisha, Ltd.; metal content at 25 degrees C.: 1 ppb or less; water temperature: 25 degrees C.) was added; and the mixture was agitated vigorously for 30 minutes and left still for 15 minutes. Since an organic layer containing the polymer intermediate was separated from a water layer, the water layer was removed through decantation. The operation from the addition of 500 mL of the pure water to the separation of the water layer was further repeated 18 times. Subsequently, a micro filter (Optimizer D-300 manufactured by Nihon Mykrolis K.K.) was used to perform filtration while applying pressure such that a flow rate of 4 mL/min was achieved.

Reprecipitation was performed by adding 400 mL of methanol to the resist polymer intermediate layer and supernatant liquid was removed to remove the unreacted monomer and the reaction solvent. The precipitate was washed with a tetrahydrofuran/methanol mixed solution to acquire the light yellow solid-state washed resist polymer intermediate. The metal contents were 40 ppb of copper and 23 ppb of Na. The metal contents in the resist polymer intermediate were measured by an ICP mass spectrometer (P-6000-type MIP-MS manufactured by Hitachi, Ltd.).

### <Degradation of Acid-Degradable Group>

Into a reactor with a reflux tube, 0.6 g of the washed resist polymer intermediate is introduced; 30 mL of 1,4-dioxane and 0.6 mL of hydrochloric acid aqueous solution were added; and the mixture was heated and agitated at 90 degrees C. for 65 minutes to degrade a portion of the 4-vinylbenzoic acid tert-butyl ester portion into the 4-vinylbenzoic acid portion.

The acquired reaction product was poured into 300 ml of the ultrapure water having a specific resistance value of 18 MΩ·cm (produced by GSR-200 manufactured by Advantec Toyo Kaisha, Ltd.; metal content at 25 degrees C.: 1 ppb or less; water temperature: 25 degrees C.) to separate solid content and the acquired solid content was dried to acquire the resist polymer. The yield was 0.44 g. The molar ratio of the 4-vinylbenzoic acid tert-butyl ester portion and the 4-vinylbenzoic acid portion was measured by ¹H-NMR and the ratio was 50:50. Subsequently, the metal content of the acquired resist polymer was measured by the ICPMAS (P-6000-type MIP-MS manufactured by Hitachi, Ltd.). The result is depicted in Table 5.

### <Preparation of Resist Composition>

The resist composition was prepared by creating a propylene glycol monomethyl acetate (PEGMEA) solution containing 4.0 mass % of the acquired resist polymer and 0.16 mass % of triphenylsulfonium trifluoromethanesulfonate as a photoacid generator and by filtrating the solution with a filter having a fine pore size of 0.45 μm. A thin film with a thickness of 100 nm was created by spin-coating a silicon wafer with the acquired resist composition and by evaporating the solvent with a one-minute heat treatment at 90 degrees C.

### <Measurement of Sensitivity to Ultraviolet Radiation>

The discharge tube type ultraviolet light irradiation apparatus (DF-245 Donafix manufactured by Atto Corporation) was used as a light source. Ultraviolet light having a wavelength of 245 nm is applied to expose a rectangular portion having a length of 10 mm and width of 3 mm of a sample thin film having a thickness of about 100 nm formed on a silicon wafer with an energy amount changed from 0 mJ/cm² to 50 mJ/cm². After four minutes of the heat treatment at 100 degrees C., the development was performed by immersion into 2.4-mass % tetramethylammonium hydroxide (TMAH) aqueous solution at 25 degrees C. for 2 minutes. After the thin film was washed with water and dried, the film thickness was measured using the thin film measurement apparatus F20 manufactured by Filmetrics, Inc., and the sensitivity was defined as the minimum energy amount when the film thickness was zero. The result is depicted in Table 5.

### Second Example

### Synthesis of Resist Polymer Intermediate

In a 50-mL reactor, 21 mmol of chloromethyl styrene as a reactive monomer, 13.1 mmol of 2,2-bipyridyl and 6.6 mmol of copper(I) chloride as catalysts, and 8 mL of chlorobenzene as a solvent were placed and, after the inside of the reactor was replaced with argon, a polymerization reaction was performed by agitation at a temperature of 115 degrees C. for 30 minutes. After 50 mL of chloroform was added to this reaction liquid and the polymer was diluted and dissolved, the ultrapure water having a specific resistance value of 18 MΩ·cm (produced by GSR-200 manufactured by Advantec Toyo Kaisha, Ltd.; metal content at 25 degrees C.: 1 ppb or less; water temperature: 25 degrees C.) was added to remove the solvent through the liquid-liquid extraction. After the filtrate was condensed, the polymer is precipitated by adding 200 mL of methanol and the supernatant was removed to remove the unreacted monomer and the reaction solvent. Subsequently, the operations of dissolving the precipitated polymer into 20 mL of tetrahydrofuran and adding 500 mL of methanol to cause reprecipitation were repeated twice to synthesize the core portion (the yield was 60%).

In a 50-mL reactor, 1 g of the core portion as raw material polymer, 33 mmol of tert-butyl acrylate as a compound containing the acid-degradable group, 4.1 mmol of 2,2-bipyridyl and 2.1 mmol of copper(I) chloride as catalysts, and 13 mL of chlorobenzene as a solvent were placed and, after the inside of the reactor was replaced with argon, polymerization was performed by agitation at a temperature of 125 degrees C. for 30 minutes and the shell portion was introduced to acquire a solution containing the resist polymer intermediate.

### <Washing Process>

After adding 10 mL of chlorobenzene, the reaction liquid was transferred to a 300-mL reactor. The ultrapure water having a specific resistance value of 18 MΩ·cm and having a metal content of 1 ppb or less at 25 degrees C. (produced by GSR-200 manufactured by Advantec Toyo Kaisha, Ltd.; metal content at 25 degrees C.: 1 ppb or less; water temperature: 25 degrees C.) was added and the mixture was agitated vigorously for 30 minutes and left still for 15 minutes. Since an organic layer containing the polymer intermediate was separated from a water layer, the water layer was removed through decantation. The operation from the addition of 1000 mL of the pure water to the separation of the water layer was further repeated 14 times.

Reprecipitation was performed by adding 400 mL of methanol to the resist polymer intermediate layer and a solid content was separated. The precipitate was washed with a tetrahydrofuran/methanol mixed solution to acquire a light yellow solid substance. The solid substance was dissolved in 30 ml of ethyl acetate; the ultrapure water having a specific resistance value of 18 MΩ·cm (produced by GSR-200 manufactured by Advantec Toyo Kaisha, Ltd.; metal content at 25 degrees C.: 1 ppb or less; water temperature: 25 degrees C.) was added; and the mixture was agitated vigorously for 30 minutes and left still for 15 minutes. Since an organic layer containing the polymer intermediate was separated from a water layer, the water layer was removed. The operation from the addition of 100 mL of the pure water to the separation of the water layer was further repeated 12 times.

Subsequently, the micro filter (Optimizer D-300 manufactured by Nihon Mykrolis K.K.) was used to perform filtration while applying pressure such that a flow rate of 4 mL/min was achieved. The solvent was removed from the solution under reduced pressure to acquire the light yellow solid-state washed resist polymer intermediate. The metal contents were 30 ppb of copper and 27 ppb of Na.

### <Degradation of Acid-Degradable Group>

Subsequently, the acid-degradable group was degraded according to the method described in the first example. The molar ratio of the tert-butyl acrylate portion and the acrylic acid portion was measured by ¹H-NMR and the ratio was 70:30. The metal contents of the acquired resist polymer were measured. The result is depicted in Table 5.

### <Preparation of Resist Composition and Measurement of Sensitivity to Ultraviolet Radiation>

The resist composition was prepared in the same way as the first example and the sensitivity was measured in the ultraviolet light (254 nm) exposure experiment. The result is depicted in Table 5.

### Third Example

### Synthesis of Resist Polymer Intermediate

Under argon gas atmosphere, 2.3 g of 2,2′-bipyridyl and 0.74 g of copper(I) chloride were collected in a 300-mL three-neck reactor with an agitator and a cooling tube attached; 23 mL of chlorobenzene as the reaction solvent was added; 4.6 g of chloromethylstyrene was dropped for 5 minutes; and the mixture was heated and agitated while maintaining the inside temperature at 125 degrees C. to synthesize the core portion. The reaction time was set to 40 minutes including the dropping time. Subsequently, 150 mL of chlorobenzene and 17.1 g of 4-vinylbenzoic acid tert-butyl ester were injected by syringe, respectively, and heated and agitated at 125 degrees C. for four hours to introduce the acid-degradable group.

### <Washing Process>

After quenching the reaction mixture, the mixture was transferred into a 1-L reactor; 500 mL of ultrapure water having a specific resistance value of 18 MΩ·cm (produced by GSR-200 manufactured by Advantec Toyo Kaisha, Ltd.; metal content at 25 degrees C.: 1 ppb or less; water temperature: 25 degrees C.) was added; and the mixture was agitated vigorously for 30 minutes and left still for 15 minutes. Since an organic layer containing the polymer intermediate was separated from a water layer, the water layer was removed through decantation. The operation from the addition of 500 mL of the pure water to the separation of the water layer was further repeated 14 times.

Reprecipitation was performed by adding 400 mL of methanol to the resist polymer intermediate layer and supernatant liquid was removed to remove the unreacted monomer and the reaction solvent. The precipitate was washed with a tetrahydrofuran/methanol mixed solution to acquire a light yellow solid substance. The solid substance was dissolved in 30 ml of ethyl acetate and was pressurized and brought into contact with an ion-exchange membrane of Protego CP manufactured by Nihon Mykrolis K.K., such that the polymer solution flows at a flow rate of 0.5 to 10 mL/min.

Subsequently, the micro filter (Optimizer D-300 manufactured by Nihon Mykrolis K.K.) was used to perform filtration while applying pressure such that a flow rate of 4 mL/min was achieved. The solvent was removed from the acquired solution under reduced pressure to acquire the light yellow solid-state washed resist polymer intermediate. The metal contents were 20 ppb of copper and 18 ppb of Na.

### <Degradation of Acid-Degradable Group>

Subsequently, the acid-degradable group was degraded in the method described in the first example; the acquired solid substance was dissolved in ethyl acetate to achieve a concentration of 10 mass %; the ultrapure water having a specific resistance value of 18 MΩ·cm (produced by GSR-200 manufactured by Advantec Toyo Kaisha, Ltd.; metal content at 25 degrees C.: 1 ppb or less; water temperature: 25 degrees C.) and three times the volume of ethyl acetate was added; and the mixture was agitated vigorously for 30 minutes and left still for 15 minutes. Since an organic layer containing the polymer intermediate was separated from a water layer, the water layer was removed. The operation from the addition of the pure water to the separation of the water layer was further repeated twice.

The solvent was removed from the acquired solution under reduced pressure to acquire the solid-state resist polymer. The molar ratio of the 4-vinylbenzoic acid tert-butyl ester portion and the 4-vinylbenzoic acid portion was measured by ¹H-NMR and the ratio was 50:50. The result of measurement of the metal content in the resist polymer is depicted in Table 5.

### <Preparation of Resist Composition and Measurement of Sensitivity to Ultraviolet Radiation>

The resist composition was prepared in the same way as the first example and the sensitivity was measured in the ultraviolet light (254 nm) exposure experiment. The result is depicted in Table 5.

### First Comparative Example

### Synthesis of Resist Polymer Intermediate

Under argon gas atmosphere, 2.3 g of 2,2′-bipyridyl and 0.74 g of copper(I) chloride were collected in a 300-mL three-neck reactor with an agitator and a cooling tube attached; 23 mL of chlorobenzene, the reaction solvent, was added; 4.6 g of chloromethylstyrene was dropped for 5 minutes; and the mixture was heated and agitated while maintaining the inside temperature at 125 degrees C. to synthesize the core portion. The reaction time was set to 40 minutes including the dropping time. Subsequently, 150 mL of chlorobenzene and 17.1 g of 4-vinylbenzoic acid tert-butyl ester were injected by syringe, respectively, and heated and agitated at 125 degrees C. for four hours to introduce the acid-degradable group.

### <Washing Process>

After quenching the reaction mixture, the mixture was transferred into a 1-L reactor; 500 mL of ultrapure water having a specific resistance value of 18 MΩ·cm (produced by GSR-200 manufactured by Advantec Toyo Kaisha, Ltd.; metal content at 25 degrees C.: 1 ppb or less; water temperature: 25 degrees C.) was added; and the mixture was agitated vigorously for 30 minutes and left still for 15 minutes. Since an organic layer containing the polymer intermediate was separated from a water layer, the water layer was removed through decantation. The operation from the addition of 500 mL of the pure water to the separation of the water layer was further repeated twice. The water layer indicated slightly the blue color of copper ion.

Reprecipitation was performed by adding 400 mL of methanol to the resist polymer intermediate layer and supernatant liquid was removed to remove the unreacted monomer and the reaction solvent. The precipitate was washed with a tetrahydrofuran/methanol mixed solution to acquire a light yellow solid substance as a refined product. The metal contents were 400 ppm of copper and 100 ppm of Na.

### <Degradation of Acid-Degradable Group>

The deprotection was subsequently performed according to the method described in the third example to acquire a light yellow solid substance as a refined product. The molar ratio of the 4-vinylbenzoic acid tert-butyl ester portion and the 4-vinylbenzoic acid portion was measured by ¹H-NMR and the ratio was 50:50. The solid substance was dissolved in 30 ml of ethyl acetate and was pressurized and brought into contact with an ion-exchange membrane of Protego CP manufactured by Nihon Mykrolis K.K., such that the polymer solution flows at a flow rate of 0.5 to 10 mL/min and the solvent was removed from the acquired solution under reduced pressure to acquire a light yellow solid substance as a refined product. The molar ratio of the 4-vinylbenzoic acid tert-butyl ester portion and the 4-vinylbenzoic acid portion was measured by ¹H-NMR and the ratio was 30:70. The amounts of metals in the acquired resist polymer were then measured. The result is depicted in Table 5.

### <Preparation of Resist Composition and Measurement of Sensitivity to Ultraviolet Radiation>

The resist composition was prepared in the same way as the first example and the sensitivity was measured in the ultraviolet light (254 nm) exposure experiment. The result is depicted in Table 5.

TABLE 5

| | metal contents | | | | sensitivity (mJ/cm²) |
|---|---|---|---|---|---|
| | (ppb) | | | | to ultraviolet |
| | Cu | Na | Fe | Ca | light (254 nm) |
| first example | 35 | 18 | 15 | 14 | 1 |
| second example | 28 | 24 | 18 | 16 | 1 |
| third example | 20 | 15 | 15 | 18 | 1 |
| first comparative | 212 | 107 | 59 | 84 | unexposed portion was |
| example | | | | | dissolved |

In the first comparative example, the metal was not sufficiently removed since the metal was chelated by the carboxylic acid group at the polymer terminal and introduced in an amount much greater than the ion exchanging amount of the ion-exchange resin, and a large amount of acid exchanged with the metal was generated since the ion exchanging was performed with a large amount of the metal contained, resulting in the degradation of carboxylic acid ester and the dissolution of the unexposed portion.

### Fourth Example

### Synthesis of Resist Polymer Intermediate

The core portion was synthesized in the same way as described in the first example and the acid-degradable group was introduced to synthesize the resist polymer intermediate.

### <Washing Process>

After quenching the reaction mixture and removing the metal catalyst as insoluble contents through filtration, the mixture was transferred into a 1-L reactor; 500 mL of 3-wt % oxalic acid aqueous solution (using ultrapure water having a specific resistance value of 18 MΩ·cm (produced by GSR-200 manufactured by Advantec Toyo Kaisha, Ltd.; metal content at 25 degrees C.: 1 ppb or less; water temperature: 25 degrees C.)) was added; and the mixture was agitated vigorously for 30 minutes and left still for 15 minutes. Since an organic layer containing the polymer intermediate was separated from a water layer, the water layer was removed through decantation. The operation from the addition of 500 mL of the 3-wt % oxalic acid aqueous solution to the separation of the water layer was further repeated three times. Subsequently, 500 mL of 3-wt % hydrochloric acid aqueous solution (using ultrapure water having a specific resistance value of 18 MΩ·cm (produced by GSR-200 manufactured by Advantec Toyo Kaisha, Ltd.; metal content at 25 degrees C.: 1 ppb or less; water temperature: 25 degrees C.)) was added and the mixture was agitated vigorously for 30 minutes and left still for 15 minutes. Since an organic layer containing the polymer intermediate was separated from a water layer, the water layer was removed through decantation. The operation from the addition of 500 mL of the 3-wt % hydrochloric acid aqueous solution to the separation of the water layer was further repeated twice.

Subsequently, 500 mL of pure water (using ultrapure water having a specific resistance value of 18 MΩ·cm (produced by GSR-200 manufactured by Advantec Toyo Kaisha, Ltd.; metal content at 25 degrees C.: 1 ppb or less; water temperature: 25 degrees C.) was added and the mixture was agitated vigorously for 30 minutes and left still for 15 minutes. Since an organic layer containing the polymer intermediate was separated from a water layer, the water layer was removed through decantation. The operation from the addition of 500 mL of the pure water to the separation of the water layer was further repeated four times. Subsequently, the micro filter (Optimizer D-300 manufactured by Nihon Mykrolis K.K.) was used to perform filtration while applying pressure such that a flow rate of 4 mL/min was achieved.

Reprecipitation was performed by adding 400 mL of methanol to the resist polymer intermediate layer and supernatant liquid was removed to remove the unreacted monomer and the reaction solvent. The precipitate was washed with a tetrahydrofuran/methanol mixed solution to acquire the light yellow solid-state washed resist polymer intermediate. The metal contents were not greater than the detection limit for each of Na, Cu, Ca, and Fe. In the fourth to sixth example, the resist polymer intermediate and the metal contents in the resist polymer intermediate are measured by acid-decomposition-flameless atomic absorption spectrometry (available from PerkinElmer, Inc.).

### <Degradation of Acid-Degradable Group>

The acid-degradable group was degraded as described in the first example to acquire the resist polymer. The yield was 0.44 g. The molar ratio of the 4-vinylbenzoic acid tert-butyl ester portion and the 4-vinylbenzoic acid portion was measured by ¹H-NMR and the ratio was 50:50.

The metal (Na, Cu, Ca, and Fe) contents in the acquired resist polymer were measured and each of the metal contents was not greater than the detection limit (20 ppb). The result is depicted in Table 6.

### <Preparation of Resist Composition and Measurement of Sensitivity to Ultraviolet Radiation>

The resist composition was prepared in the same way as the first example and the sensitivity was measured. The result is depicted in Table 6.

### Fifth Example

### Synthesis of Resist Polymer Intermediate

The core portion was synthesized in the same way as described in the second example and the acid-degradable group was introduced to synthesize the resist polymer intermediate.

### <Washing Process>

After removing the metal catalyst as insoluble contents from the reaction liquid through filtration, 10 mL of chlorobenzene was added and the mixture was transferred into a 300-mL reactor. A mixed solvent of 50 mL of 3-wt % oxalic acid aqueous solution and 50 mL of 1-wt % hydrochloric acid aqueous solution (using ultrapure water having a specific resistance value of 18 MΩ·cm (produced by GSR-200 manufactured by Advantec Toyo Kaisha, Ltd.; metal content at 25 degrees C.: 1 ppb or less; water temperature: 25 degrees C.)) was added and the mixture was agitated vigorously for 30 minutes and left still for 15 minutes. Since an organic layer containing the polymer intermediate was separated from a water layer, the water layer was removed through decantation. The operation from the addition of 50 mL of 3-wt % oxalic acid aqueous solution and 50 mL of 1-wt % hydrochloric acid aqueous solution to the separation of the water layer was further repeated twice.

Subsequently, 100 mL of 3-wt % hydrochloric acid aqueous solution (using ultrapure water having a specific resistance value of 18 MΩcm (produced by GSR-200 manufactured by Advantec Toyo Kaisha, Ltd.; metal content at 25 degrees C.: 1 ppb or less; water temperature: 25 degrees C.)) was added and the mixture was agitated vigorously for 30 minutes and left still for 15 minutes. Since an organic layer containing the polymer intermediate was separated from a water layer, the water layer was removed through decantation. The operation from the addition of 500 mL of the 3-wt % hydrochloric acid aqueous solution to the separation of the water layer was further repeated once. Furthermore, 100 mL of pure water (using ultrapure water having a specific resistance value of 18 MΩcm (produced by GSR-200 manufactured by Advantec Toyo Kaisha, Ltd.; metal content at 25 degrees C.: 1 ppb or less; water temperature: 25 degrees C.) was added and the mixture was agitated vigorously for 30 minutes and left still for 15 minutes. Since an organic layer containing the polymer intermediate was separated from a water layer, the water layer was removed through decantation. The operation from the addition of 100 mL of the pure water to the separation of the water layer was further repeated three times.

Reprecipitation was performed by adding 400 mL of methanol to the resist polymer intermediate layer and solid content was separated. The precipitate was washed with a tetrahydrofuran/methanol mixed solution to acquire a light yellow solid substance. The solid substance was dissolved in 30 ml of ethyl acetate; the ultrapure water having a specific resistance value of 18 MΩ·cm (produced by GSR-200 manufactured by Advantec Toyo Kaisha, Ltd.; metal content at 25 degrees C.: 1 ppb or less; water temperature: 25 degrees C.) was added; and the mixture was agitated vigorously for 30 minutes and left still for 15 minutes. Since an organic layer containing the polymer intermediate was separated from a water layer, the water layer was removed through decantation. The operation from the addition of 100 mL of the pure water to the separation of the water layer was further repeated twice.

Subsequently, the micro filter (Optimizer D-300 manufactured by Nihon Mykrolis K.K.) was used to perform filtration while applying pressure such that a flow rate of 4 mL/min was achieved. The solvent was removed from the solution under reduced pressure to acquire the light yellow solid-state washed resist polymer intermediate. The metal contents were not greater than the detection limit for each of Na, Cu, Ca, and Fe.

### <Degradation of Acid-Degradable Group>

The acid-degradable group was degraded as described in the first example to acquire the resist polymer. The molar ratio of the tert-butyl acrylate portion and the acrylic acid portion was measured by ¹H-NMR and the ratio was 70:30. The metal (Na, Cu, Ca, and Fe) contents in the acquired resist polymer were measured and each of the metal contents was not greater than the detection limit (20 ppb). The result is depicted in Table 6.

### <Preparation of Resist Composition and Measurement of Sensitivity to Ultraviolet Radiation>

The resist composition was prepared in the same way as the fourth example and the sensitivity was measured in the ultraviolet light (254 nm) exposure experiment. The result is depicted in Table 6.

### Sixth Example

### Synthesis of Resist Polymer Intermediate

The core portion was synthesized in the same way as described in the third example and the acid-degradable group was introduced to synthesize the resist polymer intermediate.

### <Washing Process>

After quenching the reaction mixture and removing the metal catalyst as insoluble contents through filtration, the mixture was transferred into a 1-L reactor; 500 mL of 3-wt % citric acid aqueous solution (using ultrapure water having a specific resistance value of 18 MΩ·cm (produced by GSR-200 manufactured by Advantec Toyo Kaisha, Ltd.; metal content at 25 degrees C.: 1 ppb or less; water temperature: 25 degrees C.)) was added; and the mixture was agitated vigorously for 30 minutes and left still for 15 minutes. Since an organic layer containing the polymer intermediate was separated from a water layer, the water layer was removed through decantation. The operation from the addition of 500 mL of pure water to the separation of the water layer was further repeated three times. Subsequently, 500 mL of 3-wt % hydrochloric acid aqueous solution (using ultrapure water having a specific resistance value of 18 MΩ·cm (produced by GSR-200 manufactured by Advantec Toyo Kaisha, Ltd.; metal content at 25 degrees C.: 1 ppb or less; water temperature: 25 degrees C.)) was added and the mixture was agitated vigorously for 30 minutes and left still for 15 minutes. Since an organic layer containing the polymer intermediate was separated from a water layer, the water layer was removed through decantation. The operation from the addition of 500 mL of the 3-wt % hydrochloric acid aqueous solution to the separation of the water layer was further repeated twice.

Subsequently, 500 mL of pure water (using ultrapure water having a specific resistance value of 18 MΩ·cm (produced by GSR-200 manufactured by Advantec Toyo Kaisha, Ltd.; metal content at 25 degrees C.: 1 ppb or less; water temperature: 25 degrees C.)) was added and the mixture was agitated vigorously for 30 minutes and left still for 15 minutes. Since an organic layer containing the polymer intermediate was separated from a water layer, the water layer was removed through decantation. The operation from the addition of 500 mL of the pure water to the separation of the water layer was further repeated four times.

Reprecipitation was performed by adding 400 mL of methanol to the resist polymer intermediate layer and supernatant liquid was removed to remove the unreacted monomer and the reaction solvent. The precipitate was washed with a tetrahydrofuran/methanol mixed solution to acquire a light yellow solid substance. The solid substance was dissolved in 30 ml of ethyl acetate and was pressurized and brought into contact with an ion-exchange membrane of Protego CP manufactured by Nihon Mykrolis K.K., such that the polymer solution flows at a flow rate of 0.5 to 10 mL/min.

Subsequently, the micro filter (Optimizer D-300 manufactured by Nihon Mykrolis K.K.) was used to perform filtration while applying pressure such that a flow rate of 4 mL/min was achieved. The solvent was removed from the acquired solution under reduced pressure to acquire the light yellow solid-state washed resist polymer intermediate. The metal contents were not greater than the detection limit for each of Na, Cu, Ca, and Fe.

### <Degradation of Acid-Degradable Group>

The acid-degradable group was degraded as described in the fourth example to acquire the resist polymer. The molar ratio of the 4-vinylbenzoic acid tert-butyl ester portion and the 4-vinylbenzoic acid portion was measured by ¹H-NMR and the ratio was 50:50. The metal (Na, Cu, Ca, and

Fe) contents in the acquired resist polymer were measured and each of the metal contents was not greater than the detection limit (20 ppb). The result is depicted in Table 6.

### <Preparation of Resist Composition and Measurement of Sensitivity to Ultraviolet Radiation>

The resist composition was prepared in the same way as the fourth example and the sensitivity was measured in the ultraviolet light (254 nm) exposure experiment. The result is depicted in Table 6.

TABLE 6

| | metal contents | | | | sensitivity (mJ/cm²) |
|---|---|---|---|---|---|
| | (ppb) | | | | to ultraviolet |
| | Cu | Na | Fe | Ca | light (254 nm) |
| detection limit | 20 | 20 | 20 | 20 | |
| fourth example | ND | ND | ND | ND | 1 |
| fifth example | ND | ND | ND | ND | 1 |
| sixth example | ND | ND | ND | ND | 1 |

### Effects of the Invention

According to the present invention, the hyperbranched polymer having a lower amount of metal can be synthesized easily using a metal catalyst at the time of polymerization highly reduced. According to the method of the present invention, a hyperbranched polymer having a constant ratio of acid groups and acid-degradable groups in the shell portion can be acquired easily. The hyperbranched polymer acquired from the method of the present invention has favorable sensitivity to an ultraviolet light source as well as favorable sensitivity to an extreme ultraviolet light source. The method of the present invention can reduce contamination and adverse effects on electric characteristics in the plasma process of the acquired hyperbranched polymer. The hyperbranched polymer acquired from the method of the present invention has favorable adhesiveness to substrates.

### <Fourth Chapter>

Preferred embodiments of the hyperbranched polymer synthesizing method according to the present invention will hereinafter be described in detail with reference to the accompanying drawings.

### (Substances Used in Synthesis of Hyperbranched Polymer)

First, substances used in the synthesis of a hyperbranched polymer synthesized with the use of the hyperbranched polymer synthesizing method (hereinafter, “hyperbranched polymer”) will be described. Monomers, a metal catalyst, a polar solvent, and other solvents are used in the synthesis of the hyperbranched polymer.

### (Monomers)

First, the monomers used in the synthesis of the hyperbranched polymer will be described. If the core-shell hyperbranched polymer is synthesized, the monomers used in the hyperbranched polymer are roughly classified into monomers corresponding to the core portion and monomers corresponding to the shell portion.

### <Monomers Corresponding to Core Portion>

Among the monomers used in the synthesis of the hyperbranched polymer, the monomers corresponding to the core portion will first be described. The core portion of the hyperbranched polymer constitutes the core of the hyperbranched polymer molecule. The core portion of the hyperbranched polymer is formed by polymerizing the monomers represented at least by formula (I) described in the first chapter above.

Y of the formula (I) denotes a straight-chain, branched, or cyclic alkylene group having 1 to 10 carbon atoms. The preferred number of carbon atoms of Y is one to six. Y of the formula (I) may contain a hydroxyl group or a carboxyl group.

Specifically, Y of the formula (I) may denote, for example, a methylene group, an ethylene group, a propylene group, an isopropylene group, a butylene group, an isobutylene group, an amylene group, a hexylene group, and a cyclohexylene group. Y of the formula (I) may denote groups formed by combining the above groups or groups formed by containing “—O—”, “—CO—”, or “—COO—” between the above groups.

Among the above groups, Y of the formula (I) preferably denotes an alkylene group having one to eight carbon atoms. Among the alkylene groups having one to eight carbon atoms, Y of the formula (I) is preferably a straight-chain alkylene group having one to eight carbon atoms. A more preferred alkylene group includes, for example, a methylene group, an ethylene group, a OCH₂— group, and a —OCH₂CH₂— group. Monomers corresponding to the formula (I) denotes a halogen atom (halogen group) such as a fluorine atom, a chlorine atom, a bromine atom, and an iodine atom. Specifically, monomers corresponding to the formula (I) are preferably a chlorine atom or a bromine atom among the above halogen atoms.

Specifically, among monomers used to form the hyperbranched polymer include monomers represented by the formula (I), such as chloromethyl styrene, bromomethyl styrene, p-(1-chloroethyl)styrene, bromo(4-vinylphenyl)phenylmethane, 1-bromo-1-(4-vinylphenyl)propane-2-one, and 3-bromo-3-(4-vinylphenyl)propanol. More specifically, among the monomers used in the synthesis of the hyperbranched polymer, the monomers represented by the formula (I) preferably are chloromethyl styrene, bromomethyl styrene, p-(1-chloroethyl)styrene, etc.

Monomers corresponding to the core portion of the hyperbranched polymer may include other monomers in addition to monomers represented by the formula (I). Other monomers are not particularly limited provided the monomer is radically polymerizable, and may be selected according to purpose. Other radically polymerizable monomers include, for example, compounds having a radically polymerizable unsaturated bond and may be selected from among (meth)acrylic acid and (meth)acrylic esters, vinylbenzoic acid, vinylbenzoic esters, styrenes, allyl compounds, vinyl ethers, and vinyl esters.

Specifically, (meth)acrylic esters cited as other radically polymerizable monomers include, for example, tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1-ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1 ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl)oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate.

Specifically, vinylbenzoic esters cited as other radically polymerizable monomers include, for example, tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1 n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinylbenzoate, adamantyl vinylbenzoate, 2-(2-methyl)adamantyl vinylbenzoate, chloroethyl vinylbenzoate, 2-hydroxyethyl vinylbenzoate, 2,2-dimethylhydroxypropyl vinylbenzoate, 5-hydroxybenzyl vinylbenzoate, trimethylolpropane vinylbenzoate, glycidyl vinylbenzoate, benzyl vinylbenzoate, phenyl vinylbenzoate, and naphthyl vinylbenzoate.

Specifically, styrenes cited as other radically polymerizable monomers include, for example, styrene, benzylstyrene, trifluoromethylstyrene, acetoxystyrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, 4-fluoro-3-trifluoromethylstyrene, and vinylnaphthalene.

Specifically, allyl compounds cited as other radically polymerizable monomers include, for example, allyl acetate, allyl caproate, allyl caprylate, allyl laurate, allyl palmitate, allyl stearate, allyl benzoate, allyl acetoacetate, allyl lactate, and allyloxyethanol.

Specifically, vinyl ethers cited as other radically polymerizable monomers include, for example, hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether, tetrahydrofurfuryl vinyl ether, vinylphenyl vinyl ether, vinyl tolyl ether, vinyl chlorophenyl ether, vinyl-2,4-dichlorophenyl ether, vinyl naphthyl ether, and vinyl anthranyl ether.

Specifically, vinylesters cited as other radically polymerizable monomers include, for example, vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl-□-phenylbutyrate, and vinyl cyclohexylcarboxylate.

Among the above various monomers, the monomers corresponding to the core portion of the hyperbranched polymer are preferably (meth)acrylic acid, (meth)acrylic esters, 4-vinylbenzoic acid, 4-vinylbenzoic esters, and styrenes. Among the above various monomers, specifically, the monomers corresponding to the core portion of the hyperbranched polymer are preferably, for example, (meth)acrylic acid, tert-butyl (meth)acrylate, 4-vinylbenzoic acid, tert-butyl 4-vinylbenzoate, styrene, benzylstyrene, chlorostyrene, and vinylnaphthalene.

In the hyperbranched polymer, the amount of monomers corresponding to the core portion is preferably 10 to 90 mol % relative to the total amount of monomers used for the synthesis of the hyperbranched polymer at the time of charging. In the hyperbranched polymer, the amount monomers corresponding to the core portion is more preferably 10 to 80 mol % relative to the total amount of monomers used for the synthesis of the hyperbranched polymer at the time of charging. In the hyperbranched polymer, the amount of monomers corresponding to the core portion is yet more preferably 10 to 60 mol % relative to the total amount of monomers used for the synthesis of the hyperbranched polymer at the time of charging.

For example, if the hyperbranched polymer is utilized for a resist composition containing the hyperbranched polymer, appropriate hydrophobicity may be induced to the developing fluid of the hyperbranched polymer by preparing the hyperbranched polymer such that the amount of the monomers corresponding to the core portion is at the above ranges. This is preferable since the resist composition containing the hyperbranched polymer can be used to prevent the dissolution of the unexposed portion at the time of the microfabrication when manufacturing semiconductor integrated circuits, flat panel displays, and printed-wiring boards, for example.

In the hyperbranched polymer, the amount of monomers represented by formula (I) is preferably 5 to 100 mol % relative to the total amount of monomers used for the synthesis of the hyperbranched polymer at the time of charging. In the hyperbranched polymer, the amount of monomers corresponding to the core portion is more preferably 20 to 100 mol % relative to the total amount of monomers used for the synthesis of the hyperbranched polymer at the time of charging.

In the hyperbranched polymer, the amount of monomers corresponding to the core portion is yet more preferably 50 to 100 mol % relative to the total amount of monomers used for the synthesis of the hyperbranched polymer at the time of charging. When the amount of the monomers represented by formula (I) is at the above ranges in the hyperbranched polymer, this is preferable since the entwining of molecules is advantageously prevented because the core portion takes a spherical form.

If the core portion of the hyperbranched polymer is a copolymerization product of a monomer represented by formula (I) and another monomer, the amount of monomer represented by formula (I) is preferably 10 to 99 mol % relative to the total amount of monomers constituting the core portion. If the core portion of the hyperbranched polymer is a copolymerization product of a monomer represented by formula (I) and another monomer, the amount of monomer represented by formula (I) is more preferably 20 to 99 mol % relative to the total amount of monomers constituting the core portion.

If the core portion of the hyperbranched polymer is a copolymerization product of a monomer represented by formula (I) and another monomer, the amount of monomer represented by formula (I) is yet more preferably 30 to 99 mol % relative to the total amount of monomers constituting the core portion at the time of charging. In the hyperbranched polymer, an amount of the monomer represented by formula (I) at the above ranges is preferable since the entwining of molecules is advantageously prevented because the core portion takes a spherical form.

In the hyperbranched polymer, an amount of the monomer represented by formula (I) at the above ranges is preferable since functions such as adhesiveness to substrates and increase in the glass-transition temperature are induced while maintaining the spherical form of the core portion. According to purpose, the respective amounts of the monomer represented by formula (I) and other monomers in the core portion may be adjusted by the ratio of the charging amount at the time of polymerization.

### <Monomers Corresponding to Shell Portion>

Among the monomers used in the synthesis of the hyperbranched polymer, the monomers corresponding to the shell portion will be described. The shell portion of the hyperbranched polymer constitutes the terminal of the polymer molecule and has the repeating units represented by at least one of the formulas (II) and (III) described in the first chapter above.

The repeating units represented by the formulas (II) and (III) described in the first chapter above include an acid-degradable group degraded by an effect of an organic acid such as acetic acid, maleic acid, and benzoic acid or an inorganic acid such as hydrochloric acid, sulfuric acid, or nitric acid, preferably by an effect of the photoacid generator that generates an acid by optical energy. Degradation of the acid-degradable group to form a hydrophilic group is preferable. Degradation of the acid-degradable group to form a hydrophilic group is preferable.

R¹ of formula (II) and R⁴ of formula (III) denote hydrogen atoms or alkyl groups having 1 to 3 carbon atoms. R¹ of formula (II) and R⁴ of formula (III) are preferably hydrogen atoms and methyl groups. R¹ of formula (II) and R⁴ of formula (III) are more preferably hydrogen atoms.

R² of formula (II) denotes a hydrogen atom, an alkyl group, or an aryl group. The alkyl group of R² of formula (II) preferably has 1 to 30 carbon atoms. The alkyl group of R² of formula (II) more preferably has 1 to 20 carbon atoms. The alkyl group of R² of formula (II) yet more preferably has 1 to 10 carbon atoms. The alkyl group has a straight-chain, branched, or cyclic structure. Specifically, the alkyl group of R² of formula (II) includes, for example, a methyl group, an ethyl group, a propyl group, an isopropyl group, a butyl group, an isobutyl group, a t-butyl group, and a cyclohexyl group.

The aryl group of R² of formula (II) preferably has 6 to 30 carbon atoms, for example. The aryl group of R² of formula (II) more preferably has 6 to 20 carbon atoms. The aryl group of R² of formula (II) yet more preferably has 6 to 10 carbon atoms. Specifically, the aryl group of R² of formula (II) includes, for example, a phenyl group, a 4-methylphenyl group, and a naphthyl group. A hydrogen atom, a methyl group, an ethyl group, and a phenyl group are particularly cited among the above groups. A hydrogen atom is cited as one of the most preferable groups for R² of formula (II).

R³ of formula (II) and R⁵ of formula (III) denote hydrogen atoms, alkyl groups, trialkylsilyl groups, oxoalkyl groups, or groups represented by formula (i). The alkyl groups of R³ of formula (II) and R⁵ of formula (III) preferably have 1 to 40 carbon atoms. The alkyl groups of R³ of formula (II) and R⁵ of formula (III) more preferably have 1 to 30 carbon atoms.

The alkyl groups of R³ of formula (II) and R⁵ of formula (III) further more preferably have 1 to 20 carbon atoms. The alkyl groups of R³ of formula (II) and R⁵ of formula (III) have a straight-chain, branched, or cyclic structure. Branched alkyl groups having 1 to 20 carbon atoms are more preferable for R³ of formula (II) and R⁵ of formula (III).

Each of the alkyl groups of R³ of formula (II) and R⁵ of formula (III) preferably has 1 to 6 carbon atoms and more preferably has 1 to 4 carbon atoms. The alkyl group of the oxoalkyl groups of R³ of formula (II) and R⁵ of formula (III) preferably has 4 to 20 carbon atoms and more preferably has 4 to 10 carbon atoms.

R⁶ of formula (i) denotes a hydrogen atom or an alkyl group. The alkyl group of R⁶ in the groups represented by formula (i) has a straight-chain, branched-chain, or cyclic structure. The alkyl group of R⁶ in the groups represented by formula (i) preferably has 1 to 10 carbon atoms. The alkyl group of R⁶ in the groups represented by formula (i) more preferably has 1 to 8 carbon atoms and yet more preferably has 1 to 6 carbon atoms.

R⁷ and R⁸ of formula (i) denote hydrogen atoms or alkyl groups. The hydrogen atoms or alkyl groups of R⁷ and R⁸ of formula (i) may be independent of each other or form a ring together. The alkyl groups of R⁷ and R⁸ of formula (i) have a straight-chain, branched-chain, or cyclic structure. The alkyl groups of R⁷ and R⁸ of formula (i) preferably have 1 to 10 carbon atoms. The alkyl groups of R⁷ and R⁸ of formula (i) more preferably have 1 to 8 carbon atoms. The alkyl groups of R⁷ and R⁸ of formula (i) further more preferably have 1 to 6 carbon atoms. Branched alkyl groups having 1 to 20 carbon atoms are preferable for R⁷ and R⁸ of formula (i).

The group represented by formula (i) includes a straight-chain or branched acetal group such as a 1-methoxyethyl group, a 1-ethoxyethyl group, a 1-n-propoxyethyl group, a 1-isopropoxyethyl group, a 1-n-butoxyethyl group, a 1-isobutoxyethyl group, a 1-sec-butoxyethyl group, a 1-tert-butoxyethyl group, a 1-tert-amyloxyethyl group, a 1-ethoxy-n-propyl group, a 1-cyclohexyloxyethyl group, a methoxypropyl group, an ethoxypropyl group, a 1-methoxy-1-methyl-ethyl group, and a 1-ethoxy-1-methyl-ethyl group; and a cyclic acetal group such as a tetrahydrofuranyl group and a tetrahydropyranyl group. The ethoxyethyl group, the butoxyethyl group, the ethoxypropyl group, and the tetrahydropyranyl group are particularly preferred among the above groups for the group represented by formula (i).

The straight-chain, branched, or cyclic alkyl groups of R³ of formula (II) and R⁵ of formula (III) include an ethyl group, a propyl group, an isopropyl group, a butyl group, an isobutyl group, a tert-butyl group, a cyclopentyl group, a cyclohexyl group, a cycloheptyl group, a triethylcarbyl group, a 1-ethylnorbornyl group, a 1-methylcyclohexyl group, an adamantyl group, a 2-(2-methyl)adamantyl group, a tert-amyl group, etc. Among above groups, the tert-butyl group is particularly preferable.

The trialkylsilyl group of R³ of formula (II) and R⁵ of formula (III) includes the alkyl groups having 1 to 6 carbon atoms such as a trimethylsilyl group, a triethylsilyl group, and a dimethyl-tert-butylsilyl group. The oxoalkyl group includes a 3-oxocyclohexyl group, etc.

Monomers giving repeating units represented by formula (II) include, for example, vinylbenzoic acid, tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1 n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinylbenzoate, adamantyl vinylbenzoate, 2-(2-methyl)adamantyl vinylbenzoate, chloroethyl vinylbenzoate, 2-hydroxyethyl vinylbenzoate, 2,2-dimethylhydroxypropyl vinylbenzoate, 5-hydroxybenzyl vinylbenzoate, trimethylolpropane vinylbenzoate, glycidyl vinylbenzoate, benzyl vinylbenzoate, phenyl vinylbenzoate, and naphthyl vinylbenzoate. Among these, a polymer of 4-vinylbenzoic acid and tert-butyl 4-vinylbenzoate is preferable.

Monomers giving repeating units represented by formula (III) include, for example, acrylate, tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1-ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1-ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, methacrylic acid, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl) oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate. Among these, polymers of acrylate and tert-butyl acrylate are preferable.

The monomer corresponding to the shell portion is also preferably a polymer of at least one among 4-vinylbenzoic acid and acrylic acid and at least one among tert-butyl 4-vinylbenzoate and tert-butyl acrylate. In addition to monomers giving repeating units represented by formula (II) and formula (III), a monomer constituting the shell portion may be any monomer having a structure with a radically polymerizable unsaturated bond.

In addition to the styrenes above, usable comonomers include compounds having a radically polymerizable unsaturated bond and may be selected from among allyl compounds, vinyl ethers, vinyl esters, crotonates, etc.

Specifically, in addition to styrenes cited above as comonomers usable as a monomer corresponding to the shell portion include, for example, styrene, tert-butoxystyrene, α-methyl-tert-butoxystyrene, 4-(1-methoxyethoxy)styrene, 4-(1-ethoxyethoxy)styrene, tetrahydropyranyloxystyrene, adamantyloxystyrene, 4-(2-methyl-2-adamantyloxy)styrene, 4-(1-methylcyclohexyloxy)styrene, trimethylsilyloxystyrene, dimethyl-tert-butylsilyloxystyrene, tetrahydropyranyloxystyrene, benzylstyrene, trifluoromethylstyrene, acetoxystyrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, 4-fluoro-3-trifluoromethylstyrene, and vinylnaphthalene.

Specifically, allyl esters cited above as comonomers usable as a monomer corresponding to the shell portion include, for example, allyl acetate, allyl caproate, allyl caprylate, allyl laurate, allyl palmitate, allyl stearate, allyl benzoate, allyl acetoacetate, allyl lactate, and allyloxyethanol.

Specifically, vinyl ethers cited as comonomers usable as a monomer corresponding to the shell portion include, for example, hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether, tetrahydrofurfuryl vinyl ether, vinylphenyl vinyl ether, vinyl tolyl ether, vinyl chlorophenyl ether, vinyl-2,4-dichlorophenyl ether, vinyl naphthyl ether, and vinyl anthranyl ether.

Specifically, vinylesters cited as comonomers usable as a monomer corresponding to the shell portion include, for example, vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl-β-phenylbutyrate, and vinyl cyclohexylcarboxylate.

Specifically, crotonates cited as comonomers usable as a monomer corresponding to the shell portion include, for example, butyl crotonate, hexyl crotonate, glycerin monocrotonate, dimethyl itaconate, diethyl itaconate, dibutyl itaconate, dimethyl maleate, dibutyl fumarate, maleic anhydride, maleimide, acrylonitrile, methacrylonitrile, and maleilonitrile.

Specifically, comonomers usable as a monomer corresponding to the shell portion also include, for example, the formulas (IV) to (XIII) cited in chapter 1.

Among formulas (IV) to (XII) of comonomers usable as monomer corresponding to the shell portion, styrenes and crotonates are preferable. Among comonomers usable as monomer constituting the shell portion, styrene, benzylstyrene, chlorostyrene, vinylnaphthalene, butyl crotonate, hexyl crotonate, and maleic anhydride are preferable.

In the hyperbranched polymer, at least monomer giving a repeating unit represented by formula (II) or monomer giving a repeating unit represented by formula (III) is preferably 10 to 90 mol, relative to the total charging amount of monomer used for the synthesis of the hyperbranched polymer at the time of charging. Monomer giving the above repeating units may more preferably be included at 20 to 90 mol, relative to the total charging amount of monomer used for the synthesis of the hyperbranched polymer at the time of charging.

Monomer giving the above repeating units is further preferably included at 30 to 90 mol % relative to the total charging amount of monomer used for the synthesis of the hyperbranched polymer at the time of charging. Particularly, it is preferred that the repeating unit represented by formula (II) or the repeating unit represented by formula (III) be included in the shell portion at 50 to 100 mol %, preferably at 80 to 100 mol % relative to the total charging amount of monomer used for the synthesis of the hyperbranched polymer at the time of charging. When monomer giving the above repeating units is at the above ranges relative to the total charging amount of monomer used for the synthesis of the hyperbranched polymer at the time of charging, this is preferable since an exposed portion is efficiently dissolved into alkaline solution and removed at a development step of lithography using a resist composition containing the hyperbranched polymer.

If the shell portion of the hyperbranched polymer of the present invention is a polymerized product of monomer giving repeating units represented by formula (II) or monomer giving repeating units represented by formula (III) and other monomer, the amount of monomer giving repeating units represented by formula (II) and/or the amount of monomer giving repeating units represented by formula (III) preferably accounts for 30 to 90 mol %, more preferably 50 to 70 mol % relative to the total monomer forming the shell portion. If at least the monomer giving repeating units represented by formula (II) or the monomer giving repeating units represented by formula (III) is at the above ranges relative to the total monomer constituting the shell portion, functions such as increases in the etching resistance, the wetting properties, and the glass transition temperature are induced without inhibiting the efficient alkali solubility of the exposed portion.

According to purpose, the ratio of the repeating unit represented by formula (II) and/or the repeating unit represented by formula (III) to other repeating units in the shell portion may be adjusted by the molar ratio of the charging amount at the time of introduction of the shell portion.

Metal catalysts used in the formation of the hyperbranched polymer will be described. Metal catalysts used when synthesizing the hyperbranched polymer include a metal catalyst consisting of a combination of a transition metal compound such as copper, iron, ruthenium, and chromium, and a ligand, for example. The transition metal compound includes, for example, cuprous chloride, cuprous bromide, cuprous iodide, cuprous cyanide, cuprous oxide, cuprous perchlorate, ferrous chloride, ferrous bromide, and ferrous iodide.

The ligand includes pyridines, bipyridines, polyamines, phosphines, etc., not substituted or substituted by an alkyl group, an aryl group, an amino group, a halogen group, an ester group, etc. A preferred metal catalyst may be, for example, a copper(I) bipyridyl complex and a copper(I) pentamethyldiethylenetriamine complex constituted by copper chloride and a ligand, an iron(II) triphenylphosphine complex and an iron(II) tributylamine complex constituted by iron chloride and a ligand, etc.

An amount of usage of the metal catalyst used for the synthesis of the hyperbranched polymer is preferably 0.01 to 70 mol % relative to the total amount of monomers used for the synthesis of the hyperbranched polymer at the time of charging. An amount of usage of the metal catalyst used for the synthesis of the hyperbranched polymer is more preferably 0.1 to 60 mol % relative to the total amount of monomers used for the synthesis of the hyperbranched polymer at the time of charging. If an amount of usage of the metal catalyst used for the synthesis of the hyperbranched polymer is the above amount, the reactivity can be improved to synthesize the hyperbranched polymer having a preferred branching degree.

If the amount of usage of the metal catalyst used for the synthesis of the hyperbranched polymer is less than the above ranges, the reactivity is considerably reduced and the polymerization may not progress. On the other hand, if the amount of usage of the metal catalyst used for the synthesis of the hyperbranched polymer exceeds the above ranges, since the polymerization reaction becomes excessively active, the coupling reaction tends to occur between radicals at the growth ends and the polymerization tends to become difficult to control. If the amount of usage of the metal catalyst used for the synthesis of the hyperbranched polymer exceeds the above ranges, the coupling reaction between radicals triggers gelation of the reaction system.

The metal catalyst may be complexed by mixing the above transition metal compound and the ligand in an apparatus. The metal catalyst consisting of the transition metal compound and the ligand may be added in a state of an active complex to the apparatus. It is more preferable to mix the transition metal compound and the ligand in the apparatus to form a complex since the synthesis operation of the hyperbranched polymer may be simplified.

A method of adding the metal catalyst is not particularly limited and, for example, the metal catalyst may be added at one time before the shell polymerization.

Alternatively, after the polymerization starts, the metal catalyst may additionally be applied depending on the level of deactivation of the catalyst. For example, if the distribution of the complex acting as the metal catalyst is not uniform in the reaction system, the transition metal compound may preliminarily be added into the apparatus and only the ligand may be added afterward.

### (Polar Solvent)

Additives used for the synthesis of the hyperbranched polymer will be described. In the synthesis of the hyperbranched polymer, at least one of the compounds represented by formula (1-1) or (1-2) described in the first chapter above may be added when polymerizing the above monomers.

R₁ of formula (1-1) denotes hydrogen, an alkyl group having 1 to 10 carbon atoms, an aryl group having 6 to 10 carbon atoms, or an aralkyl group having 7 to 10 carbon atoms. More particularly, R₁ of formula (1-1) represents hydrogen, an alkyl group having 1 to 10 carbon atoms, an aryl group having 6 to 10 carbon atoms, or an aralkyl group having 7 to 10 carbon atoms. A of formula (1-1) denotes a cyano group, a hydroxyl group, or a nitro group. The compounds represented by formula (1-1) include nitriles, alcohols, and nitro compounds, for example.

Specifically, nitriles included in the compounds represented by formula (1-1) are, for example, acetonitrile, propionitrile, butyronitrile, and benzonitrile. Specifically, alcohols included in the compounds represented by formula (1-1) are, for example, methanol, ethanol, 1-propanol, 2-propanol, 1-butanol, cyclohexyl alcohol, and benzyl alcohol. Specifically, nitro compounds included in the compounds represented by formula (1-1) are, for example, nitromethane, nitroethane, nitropropane, and nitrobenzene. The compounds represented by formula (1-1) are not limited to the above compounds.

R₂ and R₃ of formula (1-2) denote hydrogen, alkyl groups having 1 to 10 carbon atoms, aryl groups having 6 to 10 carbon atoms, aralkyl groups having 7 to 10 carbon atoms, or dialkylamino groups having 1 to 10 carbon atoms and B denotes a carbonyl group and a sulfonyl group. More particularly, R₂ and R₃ of formula (1-2) represent hydrogen, alkyl groups having 1 to 10 carbon atoms, aryl groups having 6 to 10 carbon atoms, aralkyl groups having 7 to 10 carbon atoms, or dialkylamino groups having 2 to 10 carbon atoms. R₂ and R₃ of formula (1-2) may be the same or different.

The compounds represented by formula (1-2) include ketones, sulfoxides, and alkylformamide compounds, for example. Specifically, ketones include, for example, acetone, 2-butanone, 2-pentanone, 3-pentanone, 2-hexanone, cyclohexanone, 2-methylcyclohexanone, acetophenone, and 2-methylacetophenone.

Specifically, sulfoxides included in the compounds represented by formula (1-2) are, for example, dimethyl sulfoxide and diethyl sulfoxide. Specifically, alkylformamide compounds included in the compounds represented by formula (1-2) are, for example, N,N-dimethylformamide, N,N-diethylformamide, and N,N-dibutylformamide.

The compounds represented by formula (1-2) are not limited to the above compounds. The compounds represented by formula (1-1) or formula (1-2) are preferably nitriles, nitro compounds, ketones, sulfoxides, and alkylformamide compounds, and more preferably, acetonitrile, propionitrile, benzonitrile, nitroethane, nitropropane, dimethyl sulfoxide, acetone, and N,N-dimethylformamide.

In the synthesis of the hyperbranched polymer, the compounds represented by formula (1-1) or formula (1-2) may be used independently or two or more of the compounds may be used concurrently.

In the synthesis of the hyperbranched polymer, the compounds represented by formula (1-1) or formula (1-2) may be used independently or two or more of the compounds may be used concurrently as a solvent.

The amount of the compounds represented by formula (1-1) or formula (1-2) added for the synthesis of the hyperbranched polymer is preferably equal to or greater than two times and not greater than 10000 times the amount of the transition metal atoms in the above metal catalyst by molar ratio. The adding amount of the compounds represented by formula (1-1) or formula (1-2) is more preferably equal to or greater than three times and not greater than 7000 times and yet more preferably equal to or greater than four times and not greater than 5000 times of the amount of the transition metal atoms in the above metal catalyst by molar ratio.

If the added amount of the compounds represented by formula (1-1) or formula (1-2) is too small, the rapid increase in the molecular weight may not be prevented sufficiently. On the other hand, if the added amount of the compounds represented by formula (1-1) or formula (1-2) is too much, the reaction rate becomes slow and a large amount of oligomers is generated.

### (Other Solvents)

Other solvents used in the synthesis of the hyperbranched polymer will be described. Although the polymerization reaction of the hyperbranched polymer may occur in the absence of solvent, the reaction is desirably achieved in the following carious solvents. Other solvent types used in the synthesis of the hyperbranched polymer are not particularly limited and include, for example, a hydrocarbon solvent, an ether solvent, a halogenated hydrocarbon solvent, a ketone solvent, an alcohol solvent, a nitrile solvent, an ester solvent, a carbonate solvent, and an amide solvent. The various solvents described above as the solvents used in the synthesis of the hyperbranched polymer may be used independently or two or more of the solvents may be used concurrently.

Specifically, the hydrocarbon solvents used as other solvents in the synthesis of the hyperbranched polymer include, for example, benzene and toluene. Specifically, the ether solvents used as the solvents in the synthesis of the hyperbranched polymer include diethyl ether, tetrahydrofuran, diphenyl ether, anisole, and dimethoxybenzene.

Specifically, the halogenated hydrocarbon solvents used as other solvents in the synthesis of the hyperbranched polymer include, for example, methylene chloride, chloroform, and chlorobenzene. Specifically, the ketone solvents used as the solvents in the synthesis of the hyperbranched polymer include, for example, acetone, methyl ethyl ketone, and methyl isobutyl ketone. Specifically, the alcohol solvents used as the solvents in the synthesis of the hyperbranched polymer include, for example, methanol, ethanol, propanol, and isopropanol.

Specifically, the nitrile solvents used as other solvents in the synthesis of the hyperbranched polymer include, for example, acetonitrile, propionitrile, and benzonitrile. Specifically, the ester solvents used as the solvents in the synthesis of the hyperbranched polymer include, for example, ethyl acetate and butyl acetate. Specifically, the carbonate solvents used as the solvents in the synthesis of the hyperbranched polymer include, for example, ethylene carbonate and propylene carbonate.

Specifically, the amide solvents used as other solvents in the synthesis of the hyperbranched polymer include, for example, N,N-dimethylformamide and N,N-dimethylacetamide.

### (Method of Preparing Metal Catalyst)

The method of preparing the metal catalyst used in the synthesis of the hyperbranched polymer will be described. The metal catalyst used in the synthesis of the hyperbranched polymer consists of a transition metal compound and a ligand and the metal catalyst may be complexed by mixing the transition metal compound and the ligand in an apparatus in the polymerization reaction of the synthesis of the hyperbranched polymer. The metal catalyst consisting of the transition metal compound and the ligand may be added in a state of an active complex to the apparatus. It is more preferable to mix the transition metal compound and the ligand in the apparatus to form a complex since the synthesis operation of the hyperbranched polymer can be simplified.

All the substances used for the polymerization, i.e., the metal catalyst, the solvent, the monomer, etc., are preferably deoxygenated sufficiently by decompression or blowing-in of an inert gas such as nitrogen or argon to prevent the catalyst from being oxidized and deactivated.

### (Method of Adding Metal Catalyst)

The method of adding the metal catalyst used in the synthesis of the hyperbranched polymer will be described. The method of adding the metal catalyst used in the synthesis of the hyperbranched polymer is not particularly limited and, for example, the metal catalyst may be added at one time before the polymerization. Alternatively, after the polymerization starts, the metal catalyst may be applied additionally depending on the level of deactivation of the metal catalyst. For example, if the distribution of the complex acting as the metal catalyst is not uniform in the reaction system, the transition metal compound may be added preliminarily into the apparatus and only the ligand may be added afterward.

The steps of the synthesis of the hyperbranched polymer will be described in detail.

### (Core Polymerization)

First, the core polymerization for synthesizing the core portion of the hyperbranched polymer will be described.

The core polymerization is preferably performed in the presence of or in the flow of nitrogen or inert gas or in the absence of oxygen to prevent oxygen from affecting radicals. The core polymerization may be applied to both a batch method and a continuous method.

The core polymerization may be performed while dropping a monomer into a reactor, for example. By controlling the dropping rate, a higher branching degree can be maintained in the core portion to be synthesized if an amount of the catalyst is low. By controlling the dropping rate of the monomer, an amount of usage of the metal catalyst can be reduced while maintaining a higher branching degree in the hyperbranched core polymer to be synthesized (macroinitiator). To maintain a higher branching degree in the core portion to be synthesized, the concentration of the monomer to be dropped is preferably 1 to 50 mass % relative to the total reaction amount. The concentration of the monomer to be dropped is more preferably 2 to 20 mass % relative to the total reaction amount.

The polymerization time is preferably between 0.1 to 10 hours depending on the molecular weight of the polymerization product. In the core polymerization, the reaction temperature is preferably 0 to 200 degrees C. In the core polymerization, the reaction temperature is more preferably 50 to 150 degrees C. If the polymerization is caused at a temperature higher than the boiling point of the solvent to be used, the pressure may be increased within an autoclave, for example.

In the core polymerization, the reaction system is preferably uniformly distributed. For example, the reaction system is uniformly distributed by agitating the reaction system. The specific agitation condition of the core polymerization is preferably that the power necessary for agitation per unit volume is set as 0.01 kW/m³ or more, for example. In the core polymerization, a catalyst may be added or a reducing agent regenerating the catalyst may be added depending on the progress in the polymerization and the level of deactivation of the catalyst.

In the core polymerization, the polymerization reaction is terminated when the core polymerization attains the set molecular weight. A method of terminating the core polymerization is not particularly limited and, for example, a method such as cooling-down or deactivating the catalyst with the addition of an oxidizing agent or a chelating agent may be used.

### (Shell Polymerization)

The shell polymerization for synthesizing the shell portion of the hyperbranched polymer will be described.

The core polymerization is preferably performed in the presence of or in the flow of nitrogen or inert gas or in the absence of oxygen to prevent oxygen from affecting radicals. In the embodiment, a shell-portion forming step is implemented by the shell polymerization. The shell polymerization may be applied to both a batch method and a continuous method.

The shell polymerization may be performed continuously after the above core polymerization or may be performed by removing the metal catalyst and monomers and adding a catalyst again after the above core polymerization.

In the shell polymerization, the synthesized core portion (core macromer) is used and, for example, the metal catalyst is preliminarily provided in a reaction system before starting the shell polymerization, and the core portion and the monomer are dropped into this reaction system. Specifically, for example, the metal catalyst is preliminarily provided on the inner surface of a furnace for the reaction and the core portion and the monomer are dropped into the furnace for the reaction. Specifically, for example, the above monomer corresponding to the shell portion may be dropped into the furnace where the core portion and the reaction catalyst are in advance.

In the shell polymerization, dropping the monomer into the generated core portion may efficiently prevent the gelation in the case of high reaction concentration. The concentration of the core portion in the shell polymerization is preferably 0.1 to 30 mass % based on a total reaction amount at the time of charging. The concentration of the core portion in the shell polymerization is more preferably 1 to 20 mass % based on a total reaction amount at the time of charging.

The concentration of the monomer corresponding to the shell portion in the shell polymerization is preferably 0.5 to 20 mole equivalents based on the reaction active sites of the core portion at the time of charging. The concentration of the monomer corresponding to the shell portion in the shell polymerization is more preferably 1 to 15 mole equivalents based on the reaction active sites of the core portion at the time of charging. A core/shell ratio in the hyperbranched polymer may be controlled by appropriately controlling the amount of the monomer corresponding to the shell portion in the shell polymerization.

The polymerization time for the shell polymerization is preferably, for example, 0.1 to 10 hours depending on the molecular weight of the polymerized product. The reaction temperature for the shell polymerization is preferably 0 to 200 degrees C. The reaction temperature for the shell polymerization is more preferably 50 to 150 degrees C. If the polymerization is caused at a temperature higher than the boiling point of the solvent to be used, the pressure may be increased within an autoclave, for example.

In the shell polymerization, the reaction system is uniformed. For example, the reaction system may be uniformed by agitating the reaction system. The specific agitation condition for the shell polymerization is preferably that the power necessary for agitation per unit volume is set as 0.01 kW/m³ or more, for example.

In the shell polymerization, the metal catalyst may be added or a reducing agent regenerating the metal catalyst may be added depending on the progress in the polymerization and the level of deactivation of the metal catalyst. The shell polymerization is terminated when the shell polymerization attains the set molecular weight. A method of terminating the shell polymerization is not particularly limited and, for example, a method such as cooling-down or deactivating the catalyst with the addition of an oxidizing agent or a chelating agent may be used.

### (Refinement)

The refinement of the hyperbranched polymer will be described. The refinement of the hyperbranched polymer includes the removal of the metal catalyst, the removal of the monomer, and the removal of the trace metal.

### <Removal of Metal Catalyst>

In the refinement of the hyperbranched polymer, the metal catalyst is removed after the shell polymerization is terminated. A method of removing the metal catalyst may be performed, for example, as one or a combination of the following methods (a) to (c):

(a) using various absorbents such as Kyoward manufactured by Kyowa Chemical Industry Co., Ltd;

(b) removing insoluble substances by filtration or centrifugation; and

(c) extraction with aqueous solution containing an acid and/or a substance having a chelating effect.

The substances having a chelating effect used in the catalyst removal using the method of (c) includes, for example, organic carboxylic acid such as formic acid, acetic acid, oxalic acid, citric acid, gluconic acid, tartaric acid, and malonic acid, amino carbonate such as nitrilotriacetic acid, ethylenediaminetetraacetic acid, and diethylenetriaminopentaacetic acid, and hydroxyamino carbonate. The substances having a chelating effect used in the catalyst removal using the method of (c) includes, for example, an inorganic acid such as hydrochloric acid and sulfuric acid. The concentration of the substance having chelating ability in aqueous solution varies depending on the chelating ability of the compound and is preferably 0.05 mass % to 10 mass %, for example.

The removal of the monomer may be performed after the above removal of the metal catalyst or after the removal of the trace metal following the removal of the metal catalyst is performed. In the removal of the monomer, among the monomer dropped at the time of the core polymerization and the shell polymerization at step S102 described above, the unreacted monomer is removed. A method of removing the unreacted monomer may be performed, for example, with one or a combination of the following methods (d) to (e):

(d) adding a poor solvent to a reaction product dissolved in a good solvent to precipitate the polymer; and

(e) washing the polymer with a mixed solvent of a good solvent and a poor solvent.

In (d) to (e) above, the good solvent includes, for example, halogenated hydrocarbon, nitro compound, nitrile, ether, ketone, ester, carbonate, or a mixed solvent containing these solvents. Specifically, for example, tetrahydrofuran, chlorobenzene, and chloroform are included.

The poor solvent includes, for example, methanol, ethanol, 1-propanol, 2-propanol, water, or a solvent obtained by combining these solvents. A method of removing unreacted monomers is not particularly limited to the method described above.

### <Removal of Trace Metal>

The removal of the trace metal in the hyperbranched polymer will be described. The removal of the trace metal is performed after the removal of the metal catalyst above to reduce trace amounts of residual metal in the polymer. A method of reducing trace amounts of residual metal in the reaction system having the hyperbranched polymer with the shell portion formed by the above shell polymerization may be performed, for example, with one or a combination of the following methods (f) to (g):

(f) performing the liquid-liquid extraction with aqueous solution of an organic compound having chelating ability, inorganic acid aqueous solution, and pure water; and

(g) using an absorbent and an ion-exchange resin.

The organic solvent used in the liquid-liquid extraction of (f) preferably includes, for example, halogenated hydrocarbon such as chlorobenzene and chloroform; acetic esters such as ethyl acetate, n-butyl acetate, and isoamyl acetate; ketones such as methyl ethyl ketone, methyl isobutyl ketone, cyclohexanone, 2-heptane, and 2-pentanone; glycol ether acetates such as ethylene glycol monoethyl ether acetate, ethylene glycol monobutyl ether acetate, and ethylene glycol monomethyl ether acetate; and aromatic hydrocarbons such as toluene and xylene.

More preferably, the organic solvent used in the liquid-liquid extraction of (f) includes, for example, chloroform, methyl isobutyl ketone, and ethyl acetate. These solvents may be used independently or two or more of the solvents may be mixed and used. In the liquid-liquid extraction in the case of following (f) above, mass % of the refined hyperbranched polymer in (f) based on the organic solvent is preferably about 1 to 30 mass %. More preferably, mass % of the resist polymer based on the organic solvent is about 5 to 20 mass %.

The organic compound having chelating ability used in the liquid-liquid extraction in the case of (f) above preferably includes, for example, organic carboxylic acid such as formic acid, acetic acid, oxalic acid, citric acid, gluconic acid, tartaric acid, and malonic acid, amino carbonate such as nitrilotriacetic acid, ethylenediaminetetraacetic acid, and diethylenetriaminopentaacetic acid, and hydroxyamino carbonate. The inorganic acid used in the liquid-liquid extraction of (1) preferably includes, for example, hydrochloric acid and sulfuric acid.

In the liquid-liquid extraction in the case of (f) above, the concentrations of the organic compound having chelating ability and the inorganic acid in aqueous solution are preferably about 0.05 to 10 mass %. The concentration of the organic compound having chelating ability in the liquid-liquid extraction of (f) varies depending on the chelating ability of the compound. The concentration of the inorganic acid varies depending on the level of acidity.

In the removal of trace metal, if the aqueous solution of the organic compound having chelating ability and the inorganic acid aqueous solution are used, the aqueous solution of the organic compound having chelating ability and the inorganic acid aqueous solution may be mixed and used or the aqueous solution of the organic compound having chelating ability and the inorganic acid aqueous solution may be used separately. If the aqueous solution of the organic compound having chelating ability and the inorganic acid aqueous solution are used separately, either the aqueous solution of the organic compound having chelating ability or the inorganic acid aqueous solution may be used first.

In the removal of trace metal, if the aqueous solution of the organic compound having chelating ability and the inorganic acid aqueous solution are used separately, it is more preferable to use the inorganic acid aqueous solution in the latter half. This is because the aqueous solution of the organic compound having chelating ability is effective in the removal of a copper catalyst and polyvalent metal; and the inorganic acid aqueous solution is effective in removal of monovalent metal derived from experimental instruments, etc.

Even when the aqueous solution of the organic compound having chelating ability and the inorganic acid aqueous solution are mixed and used, it is desirable to solely use the inorganic acid aqueous to wash the shell portion in the latter half. Although the number of times of extraction is not particularly limited, it is desirable to perform the extraction two to five times, for example. In particular, the experimental instruments used with copper ion reduced are preferably used after preliminary washing to prevent metal derived from the experimental instruments, etc., from being mixed. A method of the preliminary washing is not particularly limited and includes, for example, washing with nitric acid aqueous solution.

The number of washings only with the inorganic acid aqueous solution is preferably one to five. By performing the washing with the inorganic acid aqueous solution one to five times, monovalent metal can be removed sufficiently. To remove residual acid components, it is preferable to perform the extraction process with pure water last to completely remove acid. The number of times of the washing with the pure water is preferably one to five. By performing the washing with the pure water one to five times, the residual acid can be removed sufficiently.

In the removal of trace metal, the ratio of a reaction solvent containing the refined hyperbranched polymer (hereinafter, simply “reaction solvent”) to the aqueous solution of the organic compound having chelating ability, the inorganic acid aqueous solution, and pure water is preferably 1:0.1 to 1:10 by volume. The ratio is more preferably 1:0.5 to 1:5 by volume. By using the solvent in such a ratio for the washing, the metal can be removed easily by an appropriate number of times. This enables the facilitation of the operation and the simplification of the operation and is preferred for the efficient synthesis of the hyperbranched polymer. It is preferable that the concentration by mass of a resist polymer intermediate dissolved in the reaction solvent by normally approximately 1 to 30 mass % relative to the solvent.

The liquid-liquid extraction process of (f) is performed, for example, by separating a mixed solvent of the aqueous solution of the organic compound having chelating ability, the inorganic acid aqueous solution, and the pure water (hereinafter, simply “mixed solvent”) into two layers and removing a water layer with migrated metal ions through decantation, etc.

A method of separating the mixed solvent into two layers is performed, for example, by adding the aqueous solution of the organic compound having chelating ability, the inorganic acid aqueous solution, and the pure water to the reaction solvent, sufficiently mixing the solvent with agitation, etc., and keeping still. For example, a centrifugal separation method may be used for the method of separating the mixed solvent into two layers.

The liquid-liquid extraction process of (f) is performed, for example, preferably at 10 to 50 degrees C. and more preferably at 20 to 40 degrees C.

The deprotection of the hyperbranched polymer will be described. In the deprotection, after the removal of the trace metal described above, the acid-degradable group may be partially degraded as needed. In the partial degradation of the acid-degradable group, for example, a portion of the acid-degradable group is degraded into an acid group with the use of the acid catalyst described above. In the embodiment, this implements an acid-group forming step.

In the degradation of the portion of the acid-degradable group into an acid group with the use of the acid catalyst described above (the partial degradation of the acid-degradable group), 0.001 to 100 equivalents of the acid catalyst are normally used for the acid-degradable group in the core-shell hyperbranched polymer. The acid catalyst includes, for example, hydrochloric acid, sulfuric acid, phosphoric acid, hydrobromic acid, p-toluenesulfonic acid, acetic acid, trifluoroacetic acid, trifluoromethanesulfonic acid, and formic acid.

The organic solvent used for the reaction of partially degrading the acid-degradable group is desirably a solvent capable of dissolving the hyperbranched polymer after the removable of the trace metal and having compatibility with water. Specifically, the organic solvent used for the reaction of partially degrading the acid-degradable group is preferably a solvent selected from a group consisting of 1,4-dioxane, tetrahydrofuran, acetone, methyl ethyl ketone, diethyl ketone and a mixture thereof because of availability and manageability.

An amount of the organic solvent used for the reaction of partially degrading the acid-degradable group is not particularly limited if the hyperbranched polymer after the removal of the trace metal and the acid catalyst are dissolved and is preferably 5 to 500 times by mass based on the hyperbranched polymer after the removal of the trace metal.

An amount of the organic solvent used for the reaction of partially degrading the acid-degradable group is more preferably 8 to 200 times by mass based on the hyperbranched polymer after the removal of the trace metal. The reaction of partially degrading the acid-degradable group can be caused by heating and agitation at 50 to 150 degrees C. for 10 minutes to 20 hours.

The ratio of the acid-degradable group to the acid group in the deprotected hyperbranched polymer is preferably defined such that 0.1 to 80 mol % of the monomer containing the introduced acid-degradable group is deprotected and converted into the acid group. If the rate of the acid-degradable group to the acid group is at such a range, this is preferable since higher sensitivity and efficient alkali solubility are achieved after exposure.

For example, if the deprotected hyperbranched polymer is utilized for a resist composition such as photoresist, the optimum value for the rate of the acid-degradable group and the acid group in the hyperbranched polymer is varied depending on the composition of the resist composition.

The ratio of the acid-degradable group to the acid group may be adjusted by appropriately determining the amount of acid catalyst, temperature, and reaction time.

After the reaction of partially degrading the acid-degradable group, the solution containing the hyperbranched polymer with an acid group formed after the reaction of partially degrading the acid-degradable group (hereinafter, “reaction liquid”) is mixed with ultrapure water to precipitate the hyperbranched polymer after the partial degradation of the acid-degradable group and the solution containing the precipitated hyperbranched polymer is subjected to centrifugal separation, filtration, decantation, etc., to separate the hyperbranched polymer after the reaction of partially degrading the acid-degradable group. Subsequently the precipitated hyperbranched polymer is dissolved into the organic solvent again, and the liquid-liquid extraction is performed with the use of the solution having the precipitated hyperbranched polymer dissolved and ultrapure water to remove the residual acid catalyst.

The organic solvent used in the above liquid-liquid extraction is preferably a solvent capable of dissolving the precipitated hyperbranched polymer and having low compatibility or no compatibility with water. The organic solvent used in the above liquid-liquid extraction is not particularly limited as long as the solvent has such a nature and includes, for example, methyl isobutyl ketone and ethyl acetate.

The solubility of the precipitated hyperbranched polymer to the organic solvent used in the above liquid-liquid extraction varies depending on the ratio of the acid-degradable group to the acid group in the hyperbranched polymer molecules. Therefore, the concentration of the precipitated hyperbranched polymer in the organic solvent used in the above liquid-liquid extraction is not particularly limited and is preferably 1 to 40 mass %, for example.

The ultrapure water used in the above liquid-liquid extraction is preferably used at a range of ultrapure water/organic solvent=0.1/1 to 1/0.1 based on the organic solvent. At this range, when a portion of the acid-degradable group is degraded with the use of the acid catalyst described above, the ultrapure water used in the above liquid-liquid extraction is preferably used at a range of ultrapure water/organic solvent=0.5/1 to 1/0.5 since an amount of waste liquid may be reduced.

The above liquid-liquid extraction is preferably repeated until the pH of the water layer exhibits a neutral pH of 10 to 50 degrees C. Although the number of times of extraction is determined depending on the concentration of the acid used, the number of times is preferably 1 to 10 times to prevent increase in the waste liquid associated with the up scaling of the synthesis of the hyperbranched polymer for the industrialization. After the above liquid-liquid extraction, the organic solvent used in the liquid-liquid extraction is distilled and removed, and the polymer is dried. As a result, the hyperbranched polymer with a desired structure can be acquired.

### (Filtration)

Subsequently, the solution after the liquid-liquid extraction is filtrated. In the filtration, a filter with a pore size of 0.1 μm or less is used. A pore size of the filter is preferably equal to or greater than 0.01 μm and not greater than 0.1 μm so as to prevent slowing down of the filtration rate due to clogging, etc. A pore size of the filter is not limited to the above pore size and, for example, filters having pore sizes of 0.2 μm and 0.5 μm may be used. In the filtration, for example, a filter made of super-high density polyethylene having a specific gravity of 0.91 or greater may be used.

### (Molecular Structure)

A molecular structure of the hyperbranched polymer will be described. The branching degree (Br) of the core portion in the above core-shell hyperbranched polymer is preferably 0.3 to 0.5. The branching degree (Br) is more preferably 0.4 to 0.5. The branching degree (Br) of the core portion in the core-shell hyperbranched polymer at the above ranges is preferable since the entwining of the polymer molecules is reduced and surface roughness is prevented on pattern side walls when the core-shell hyperbranched polymer synthesized with the use of the hyperbranched core polymer is used for the resist composition.

The branching degree (Br) of the core portion in the core-shell hyperbranched polymer may be obtained by measuring ¹H-NMR of the product as follows. The branching degree (Br) may be calculated by carrying out an operation of the equation (A) described in the first chapter above using an integration ratio H1° of proton of the —CH₂Cl site appearing at 4.6 ppm and an integration ratio H2° of proton of the —CHCl site appearing at 4.8 ppm. If the polymerization proceeds at both the —CH₂Cl site and the —CHCl site and the branching is enhanced, the value of the branching degree (Br) approaches 0.5.

A weight-average molecular weight (Mw) of the core portion of the core-shell hyperbranched polymer is preferably 300 to 8,000, also preferably 5000 to 6,000, and most preferably 1,000 to 4,000. The molecular weight of the core portion of such a range is preferable since the core portion takes a spherical form and solubility in the reaction solvent may be ensured in the acid-degradable group introducing reaction. This is also preferable since an excellent film forming property is achieved and the dissolution of unexposed portions is advantageously prevented in the hyperbranched polymer after the acid-degradable group is induced in the core portion at the above molecular weight ranges.

A polydispersity (Mw/Mn) of the core portion of the hyperbranched polymer is preferably 1 to 3 and more preferably 1 to 2.5. At such a range, adverse effects such as insolubilization after exposure are not caused, which is desirable.

A weight-average molecular weight (M) of the core-shell hyperbranched polymer is preferably 500 to 21,000, more preferably 2,000 to 21,000, and most preferably 3,000 to 21,000. If the weight-average molecular weight (M) of the hyperbranched polymer is at such ranges, a resist composition containing the hyperbranched polymer has a favorable film forming property and may keep a shape since a process pattern formed at a lithography step is strong. The resist composition containing the hyperbranched polymer has an excellent dry etching resistance and favorable surface roughness.

The weight-average molecular weight (Mw) of the core portion of the core-shell hyperbranched polymer may be obtained by preparing a 0.5-mass % tetrahydrofuran solution and performing the GPC measurement at a temperature of 40 degrees C. Tetrahydrofuran may be used as a mobile solvent and styrene may be used as a standard substance.

The weight-average molecular weight (M) of the core-shell hyperbranched polymer may be obtained by using ¹H-NMR to obtain introduction rates (component ratios) of the repeating units of the polymer with the acid-degradable group introduced and performing a calculation using the introduction rates of the constituent units and the molecular weights of the constituent units based on the weight-average molecular weight (Mw) of the core portion of the core-shell hyperbranched polymer.

### (Uses of Hyperbranched Polymer)

The uses of the hyperbranched polymer are not particularly limited and, for example, the hyperbranched polymer is used for a photoresist polymer, an ink-jet processing resin such as a color filter and a biochip, a cross-linking agent such as a powder coating, a base material for a solid electrolyte, and a pour-point depressant for BDF.

For example, if the hyperbranched polymer is used for a photoresist polymer, the excellent photoresist polymer with reduced unevenness of the pattern side walls and high alkali solubility after exposure, i.e., high sensitivity to light may be acquired by using the hyperbranched polymer as the core portion and introducing the acid-degradability as the shell portion at the terminal of the hyperbranched polymer. In such a use, for example, t-butyl acrylate may be polymerized as the shell portion with the above core-shell hyperbranched polymer through the atom transfer radical polymerization.

The above resist composition may support electron-beam, deep-ultraviolet (DUV), and extreme-ultraviolet (EUV) light sources requiring nano-order surface smoothness and form fine patterns for manufacturing semiconductor integrated circuits. Therefore, the resist composition including the hyperbranched polymer synthesized with the method according to the present invention may be used preferably in various fields using semiconductor integrated circuits manufactured with the use of light sources applying light having short wavelengths.

If a semiconductor integrated circuit manufactured with the use of the resist composition including the hyperbranched polymer of the embodiment is exposed, heated, dissolved in developing liquid, and washed with water, etc., when manufactured, substantially no undissolved residue is generated and substantially perpendicular edges can be acquired. This enables acquisition of a fine semiconductor integrated circuit exhibiting stable performance and supporting the electron-beam, deep-ultraviolet (DUV), and extreme-ultraviolet (EUV) light sources.

### (Resist Composition)

The resist composition using the hyperbranched polymer will be described. In the resist composition using the hyperbranched polymer (hereinafter, simply “resist composition”), a compounding amount of the core-shell hyperbranched polymer (resist polymer) is preferably 4 to 40 mass %, more preferably 4 to 20 mass % based on a total amount of the resist composition.

The resist composition contains the above core-shell hyperbranched polymer and a photoacid generator. The resist composition may also contain an acid diffusion inhibitor (acid trapping agent), a surfactant, other components, a solvent, etc., as needed.

The photoacid generator included in the resist composition is not particularly limited as long as an acid is generated, for example, when ultraviolet light, X-ray, electron ray, etc., are applied, and may be appropriately selected from known various photoacid generators according to the purpose. Specifically, the photoacid generator includes, for example, onium salts, sulfonium salts, halogen-containing triazine compounds, sulfone compounds, sulfonate compounds, aromatic sulfonate compounds, and sulfonate compounds of N-hydroxyimide.

Onium salts included in the above photoacid generator include, for example, diaryliodonium salts, triarylselenonium salts, and triarylsulfonium salts. The diaryliodonium salts include, for example, diphenyliodonium trifluoromethanesulfonate, 4-methoxyphenylphenyliodonium hexafluoroantimonate, 4-methoxyphenylphenyliodonium trifluoromethanesulfonate, bis(4-tert-butylphenyl)iodonium tetrafluoroborate, bis(4-tert-butylphenyl)iodonium hexafluorophosphate, bis(4-tert-butylphenyl)iodonium hexafluoroantimonate, and bis(4-tert-butylphenyl)iodonium trifluoromethanesulfonate.

Specifically, triarylselenonium salts included in the above onium salts include, for example, a triphenylselenoniumhexafluorophosphonium salt, a triphenylselenoniumfluoroboric salt, and a triphenylselenoniumhexafluoroantimonate salt. Triarylsulfonium salts included in the above onium salts include, for example, a triphenylsulfonium hexafluorophosphonium salt, a triphenylsulfonium hexafluoroantimonate salt, a diphenyl-4-thiophenoxyphenylsulfonium hexafluoroantimonate salt, and a diphenyl-4-thiophenoxyphenylsulfonium pentafluoro hydroxyantimonate salt.

Sulfonium salts included in the above photoacid generator include, for example, triphenylsulfonium hexafluorophosphate, triphenylsulfonium hexafluoroantimonate, triphenylsulfonium trifluoromethanesulfonate, 4-methoxyphenyldiphenylsulfonium hexafluoroantimonate, 4-methoxyphenyldiphenylsulfonium trifluoromethanesulfonate, p-tolyldiphenylsulfonium trifluoromethanesulfonate, 2,4,6-trimethylphenyldiphenylsulfonium trifluoromethanesulfonate, 4-tert-butylphenyldiphenylsulfonium trifluoromethanesulfonate, 4-phenylthiophenyldiphenylsulfonium hexafluorophosphate, 4-phenylthiophenyldiphenylsulfonium hexafluoroantimonate, 1-(2-naphthoylmethyl)thiolanium hexafluoroantimonate, 1-(2-naphthoylmethyl)thiolanium trifluoroantimonate, 4-hydroxy-1-naphthyldimethylsulfonium hexafluoroantimonate, and 4-hydroxy-1-naphthyldimethylsulfonium trifluoromethanesulfonate.

Specifically, halogen-containing triazine compounds included in the above photoacid generator include, for example, 2-methyl-4,6-bis(trichloromethyl)-1,3,5-triazine, 2,4,6-tris(trichloromethyl)-1,3,5-triazine, 2-phenyl-4,6-bis(trichloromethyl)-1,3,5-triazine, 2-(4-chlorophenyl)-4,6-bis(trichloromethyl)-1,3,5-triazine, 2-(4-methoxyphenyl)-4,6-bis(trichloromethyl)-1,3,5-triazine, 2-(4-methoxy-1-naphthyl)-4,6-bis(trichloromethyl)-1,3,5-triazine, 2-(benzo[d][1,3]dioxolane-5-yl)-4,6-bis(trichloromethyl)-1,3,5-triazine, 2-(4-methoxystyryl)-4,6-bis(trichloromethyl)-1,3,5-triazine, 2-(3,4,5-trimethoxystyryl)-4,6-bis(trichloromethyl)-1,3,5-triazine, 2-(3,4,5-dimethoxystyryl)-4,6-bis(trichloromethyl)-1,3,5-triazine, 2-(2,4-dimethoxystyryl)-4,6-bis(trichloromethyl)-1,3,5-triazine, 2-(2-methoxystyryl)-4,6-bis(trichloromethyl)-1,3,5-triazine, 2-(4-butoxystyryl)-4,6-bis(trichloromethyl)-1,3,5-triazine, and 2-(4-benzyloxystyryl)-4,6-bis(trichloromethyl)-1,3,5-triazine.

Specifically, sulfone compounds included in the above photoacid generator include, for example, diphenyl sulfone, di-p-tolyldisulfone, bis(phenylsulfonyl)diazomethane, bis(4-chlorophenylsulfonyl)diazomethane, bis(p-tolylsulfonyl) diazomethane, bis(4-tert-butylphenylsulfonyl)diazomethane, bis(2,4-xylylsulfonyl)diazomethane, bis(cyclohexylsulfonyl)diazomethane, (benzoyl)(phenylsulfonyl)diazomethane, and phenylsulfonyl acetophenone.

Specifically, aromatic sulfonate compounds included in the above photoacid generator include, for example, α-benzoylbenzyl p-toluenesulfonate (commonly called benzoine tosylate), β-benzoyl-β-hydroxyphenetyl p-toluenesulfonate (commonly called α-methylolbenzoine tosylate), 1,2,3-benzenetoriyl trismethanesulfonate, 2,6-dinitrobenzyl p-toluenesulfonate, 2-nitrobenzyl p-toluenesulfonate, and 4-nitrobenzyl p-toluenesulfonate.

Specifically, sulfonate compounds of N-hydroxyimide included in the above photoacid generator include, for example, N-(phenylsulfonyloxy)succinimide, N-(trifluoromethylsulfonyloxy)succinimide, N-(p-chlorophenylsulfonyloxy)succinimide, N-(cyclohexylsulfonyloxy)succinimide, N-(1-naphthylsulfonyloxy)succinimide, N-(benzylsulfonyloxy) succinimide, N-(10-camphorsulfonyloxy)succinimide, N-(trifluoromethylsulfonyloxy)phthalimide, N-(trifluoromethylsulfonyloxy)-5-norbornene-2,3-dicarboxylmide, N-(trifluoromethylsulfonyloxy)naphthalimide, and N-(10-camphorsulfonyloxy)naphthalimide.

Among the various photoacid generators described above, the sulfonium salt is preferable. Especially, triphenylsulfonium trifluoromethanesulfonate, the sulfone compounds, especially, bis(4-tert-butylphenylsulfonyl)diazomethane, and bis(cyclohexylsulfonyl)diazomethane are preferable.

The above photoacid generators may be used independently or by mixing two or more of the photoacid generators. Although the blend ratio of the photoacid generator is not particularly limited and may be appropriately selected according to the purpose, the blend ratio is preferably 0.1 to 30 parts by mass based on 100 parts by mass of the hyperbranched polymer. More preferably, the blend ratio of the photoacid generator is 0.1 to 10 parts by mass.

The acid diffusion inhibitor included in the resist composition is not particularly limited as long as the inhibitor is a component having an effect of controlling diffusion phenomena of acid generated from the photoacid generator due to exposure during the resist film formation to prevent unfavorable chemical reactions in the non-exposure area. The acid diffusion inhibitor included in the resist composition may be selected appropriately from various known acid diffusion inhibitors according to the purpose.

The acid diffusion inhibitor included in the resist composition includes, for example, nitrogen-containing compounds having one nitrogen atom in the same molecule, compounds having two nitrogen atoms in the same molecule, polyamino compounds and polymers having three or more nitrogen atoms in the same molecule, amide-group-containing compounds, urea compounds, and nitrogen-containing heterocyclic compounds.

Nitrogen-containing compounds having one nitrogen atom in the same molecule and cited as a acid diffusion inhibitor include, for example, mono(cyclo)alkylamine, di(cyclo)alkylamine, tri(cyclo)alkylamine, and aromatic amine. Specifically, the mono(cyclo)alkylamine includes, for example, n-hexylamine, n-heptylamine, n-octylamine, n-nonylamine, n-decylamine, and cyclohexylamine.

Di(cyclo)alkylamine included in the nitrogen-containing compounds having one nitrogen atom in the same molecule includes, for example, di-n-butylamine, di-n-benzylamine, di-n-hexylamine, di-n-heptylamine, di-n-octylamine, di-n-nonylamine, di-n-decylamine, and cyclohexylmethylamine.

Tri(cyclo)alkylamine included in the nitrogen-containing compounds having one nitrogen atom in the same molecule includes, for example, triethylamine, tri-n-propylamine, tri-n-butylamine, tri-n-benzylamine, tri-n-hexylamine, tri-n-heptylamine, tri-n-octylamine, tri-n-nonylamine, tri-n-decylamine, cyclohexyldimethylamine, methyldicyclohexylamine, and tricyclohexylamine.

Aromatic amine included in the nitrogen-containing compounds having one nitrogen atom in the same molecule includes, for example, aniline, N-methylaniline, N,N-dimethylaniline, 2-methylaniline, 3-methylaniline, 4-methylaniline, 4-nitroaniline, diphenylamine, triphenylamine, and naphthylamine.

Nitrogen-containing compounds having two nitrogen atoms in the same molecule and cited as a acid diffusion inhibitor include, for example, ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, 2,2-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis[1-(4-aminophenyl)-1-methylethyl]benzene, 1,3-bis[1-(4-aminophenyl)-1-methylethyl]benzene, bis(2-dimethylaminoethyl)ether, and bis(2-diethylaminoethyl)ether.

Polyamino compounds and polymers having three or more nitrogen atoms in the same molecule and cited as a acid diffusion inhibitor include, for example, polyethylenimine, polyallylamine, and a polymer of n-(2-dimethylaminoethyl)acrylamide.

Amide-group-containing compounds cited as a acid diffusion inhibitor include, for example, N-t-butoxycarbonyl di-n-octylamine, N-t-butoxycarbonyl di-n-nonylamine, N-t-butoxycarbonyl di-n-decylamine, N-t-butoxycarbonyl dicyclohexylamine, N-t-butoxycarbonyl-1-adamantylamine, N-t-butoxycarbonyl-N-methyl-1-adamantylamine, N,N-di-t-butoxycarbonyl-1-adamantylamine, N,N-di-t-butoxycarbonyl-N-methyl-1-adamantylamine, N-t-butoxycarbonyl-4,4,-diaminodiphenylmethane, N,N′-di-t-butoxycarbonylhexamethylenediamine, N,N,N′N′-tetra-t-butoxycarbonylhexamethylenediamine, N,N′-di-t-butoxycarbonyl-1,7-diaminoheptane, N,N′-di-t-butoxycarbonyl-1,8-diaminooctane, N,N′-di-t-butoxycarbonyl-1,9-diaminononane, N,N-di-t-butoxycarbonyl-1,10-diaminodecane, N,N,-di-t-butoxycarbonyl-1,12-diaminododecane, N,N,-di-t-butoxycarbonyl-4,4′-diaminodiphenylmethane, N-t-butoxycarbonylbenzimidazole, N-t-butoxycarbonyl-2-methylbenzimidazole, N-t-butoxycarbonyl-2-phenylbenzimidazole, formamide, N-methylformamide, N,N-dimethylformamide, acetamide, N-methylacetamide, N,N-dimethylacetamide, propionamide, benzamide, pyrrolidone, and N-methylpyrrolidone.

Specifically, urea compounds cited as a acid diffusion inhibitor include, for example, urea, methylurea, 1,1-dimethylurea, 1,3-dimethylurea, 1,1,3,3-tetramethylurea, 1,3-diphenylurea, and tri-n-butylthiourea.

Specifically, nitrogen-containing heterocyclic compounds cited as a acid diffusion inhibitor include, for example, imidazole, 4-methylimidazole, 4-methyl-2-phenylimidazole, benzimidazole, 2-phenylbenzimidazole, pyridine, 2-methylpyridine, 4-methylpyridine, 2-ethylpyridine, 4-ethylpyridine, 2-phenylpyridine, 4-phenylpyridine, 2-methyl-4-phenylpyridine, nicotine, nicotinic acid, nicotinamide, quinoline, 4-hydroxyquinoline, 8-oxyquinoline, acridine, piperazine, 1-(2-hydroxyethyl)piperazine, pyrazine, pyrazole, pyridazine, quinoxaline, purine, pyrrolidine, piperidine, 3-piperidino-1,2-propanediol, morpholine, 4-methylmorpholine, 1,4-dimethylpiperazine, and 1,4-diazabicyclo[2.2.2]octane.

The acid diffusion inhibitors may be used independently or by mixing the two or more inhibitors. Although a compounding amount of the acid diffusion inhibitor is not particularly limited and may appropriately be selected according to the purpose, the amount is preferably 0.1 to 1000 parts by mass and more preferably 0.5 to 100 parts by mass based on 100 parts by mass of the photoacid generator.

The surfactant included in the resist composition includes, for example, polyoxyethylene alkyl ether, polyoxyethylene alkyl aryl ether, sorbitan fatty ester, a nonionic surfactant of polyoxyethylene sorbitan fatty ester, a fluorine-containing surfactant, and a silicone-containing surfactant. The surfactant included in the resist composition is not particularly limited as long as the surfactant is a component exhibiting the effect of improving a coating property, striations, a developing property, etc., and may appropriately be selected from known surfactants according to the purpose.

Specifically, the polyoxyethylene alkyl ether cited as the surfactant included in the resist composition includes, for example, polyoxyethylene lauryl ether, polyoxyethylene stearyl ether, polyoxyethylene cetyl ether, and polyoxyethylene oleyl ether. The polyoxyethylene alkyl ether cited as the surfactant included in the resist composition includes, for example, polyoxyethylene octyl phenol ether, and polyoxyethylene nonyl phenol ether.

Specifically, sorbitan fatty ester cited as surfactant included in the resist composition includes, for example, sorbitan monolaurate, sorbitan monopalmitate, sorbitan monostearate, sorbitan monooleate, sorbitan trioleate, and sorbitan tristearate. Specifically, nonionic surfactant of polyoxyethylene sorbitan fatty ester cited as surfactant included in the resist composition includes, for example, polyoxyethylenesorbitan monolaurate, polyoxyethylenesorbitan monopalmitate, polyoxyethylenesorbitan monostearate, polyoxyethylenesorbitan trioleate, and polyoxyethylenesorbitan tristearate.

Specifically, the fluorine-containing surfactant cited as the surfactant included in the resist composition includes, for example, F Top EF301, EF303, and EF352 (manufactured by Shin Akita Kasei Co., Ltd.), Megafac F171, F173, F176, F189, and R08 (manufactured by Dainippon Ink and Chemicals, Inc.), Fluorard FC430 and FC431 (manufactured by Sumitomo 3M Ltd.), Asahi Guard AG710, Surflon S-382, SC101, SX102, SC103, SC104, SC105, and SC106 (manufactured by Asahi Glass Co., Ltd.).

The silicone-containing surfactant cited as the surfactant included in the resist composition includes, for example, organosiloxane polymer KP341 (manufactured by Shin-Etsu Chemical Co., Ltd.). The various surfactants above may be used independently or by mixing the two or more surfactants. The compounding amount of the above various surfactants is preferably, for example, 0.0001 to 5 parts by mass based on 100 parts by mass of the hyperbranched polymer generated with the use of the synthesizing method according to the present invention.

More preferably, the compounding amount of the above various surfactants is 0.0002 to 2 parts by mass based on 100 parts by mass of the hyperbranched polymer generated with the use of the synthesizing method according to the present invention. The compounding amount of the above various surfactants is not particularly limited and may appropriately be selected according to the purpose.

Other components included in the resist composition include, for example, sensitizers, dissolution controllers, additives having an acid-dissociable group, alkali-soluble resins, dyes, pigments, adhesive auxiliaries, defoamers, stabilizers, and antihalation agents. Specifically, the sensitizers cited as other components included in the resist composition include, for example, acetophenones, benzophenones, naphthalenes, biacetyl, eosin, rose bengal, bylenes, anthracenes, and phenothiazine.

The sensitizers are not particularly limited provided the sensitizers have the effect of increasing the apparent sensitivity of the resist composition by absorbing energy of radiation and transferring the energy to the photoacid generator to cause the increase in the generation amount of acid. The sensitizers may be used independently or by mixing the two or more sensitizers.

Specifically, dissolution controllers cited as other components included in the resist composition include, for example, polyketone and polyspiroketal. The dissolution controllers cited as other components included in the resist composition are not particularly limited as long as the dissolution controllers more appropriately control the dissolution contrast and the dissolution rate when forming a resist. The dissolution controllers cited as other components included in the resist composition may be used independently or by mixing the two or more controllers.

Specifically, additives having an acid-dissociable group and cited as other components included in the resist composition include, for example, t-butyl 1-adamantanecarboxylate, t-butoxycarbonylmethyl 1-adamantanecarboxylate, di-t-butyl 1,3-adamantanedicarboxylate, t-butyl 1-adamantaneacetate, t-butoxycarbonylmethyl 1-adamantaneacetate, di-t-butyl 1,3-adamantanediacetate, t-butyl deoxycholate, t-butoxycarbonylmethyl deoxycholate, 2-ethoxyethyl deoxycholate, 2-cyclohexyloxyethyl deoxycholate, 3-oxocyclohexyl deoxycholate, tetrahydropyranyl deoxycholate, mevalonolactone deoxycholate ester, t-butyl lithocholate, t-butoxycarbonylmethyl lithocholate, 2-ethoxyethyl lithocholate, 2-cyclohexyloxyethyl lithocholate, 3-oxocyclohexyl lithocholate, tetrahydropyranyl lithocholate, and mevalonolactone lithocholate ester. The above various additives having an acid-dissociable group may be used independently or by mixing the two or more additives. The above various additives having an acid-dissociable group are not particularly limited as long as the additives further improve the dry etching resistance, the pattern shapes, the adhesiveness to substrates, etc.

Specifically, alkali-soluble resins cited as other components included in the resist composition include, for example, poly(4-hydroxystyrene), partially hydrogenated poly(4-hydroxystyrene), poly(3-hydroxystyrene), poly(3-hydroxystyrene), 4-hydroxystyrene/3-hydroxystyrene polymer, 4-hydroxystyrene/styrene polymer, novolak resin, polyvinyl alcohol, and polyacrylic acid.

The weight-average molecular weights (Mw) of the alkali-soluble resins are typically 1000 to 1000000 and preferably 2000 to 100000. The alkali-soluble resins may be used independently or by mixing the two or more resins. The alkali-soluble resins cited as other components included in the resist composition are not particularly limited as long as the alkali-soluble resins improve the alkali solubility of the resist composition of the present invention.

The dyes or pigments cited as other components included in the resist composition visualize a latent image of the exposed portion. Visualizing of the latent image of the exposed portion may alleviate the effect of the halation at the time of exposure. The adhesive auxiliaries cited as other components included in the resist composition may improve adhesiveness between the resist composition and substrates.

Specifically, solvents cited as other components included in the resist composition includes, for example, ketone, cyclic ketone, propylene glycol monoalkyl ether acetate, alkyl 2-hydroxypropionate, and alkyl 3-alkoxypropionate. The solvents cited as other components included in the resist composition are not particularly limited as long as the solvents is capable of dissolving, for example, other components included in the resist composition and may be selected appropriately from those safely used for the resist composition.

Specifically, the ketone included in the solvents cited as other components included in the resist composition includes, for example, methylisobutylketone, methylethylketone, 2-butanone, 2-pentanone, 3-methyl-2-butanone, 2-hexanone, 4-methyl-2-pentanon, 3-methyl-2-pentanon, 3,3-dimethyl-2-butanone, 2-heptanone, and 2-octanone.

Specifically, the cyclic ketone included in the solvents cited as other components included in the resist composition includes, for example, cyclohexane, cyclopentanone, 3-methylcyclopentanone, 2-methylcyclohexanone, 2,6-dimethylcyclohexanone, and isophorone.

Specifically, the propylene glycol monoalkyl ether acetate included in the solvents cited as other components included in the resist composition includes, for example, propylene glycol monomethyl ether acetate, propylene glycol monoethyl ether acetate, propylene glycol mono-n-propyl ether acetate, propylene glycol mono-1-propyl ether acetate, propylene glycol mono-n-butyl ether acetate, propylene glycol mono-1-butyl ether acetate, propylene glycol mono-sec-butyl ether acetate, and propylene glycol mono-t-butyl ether acetate.

Specifically, the alkyl 2-hydroxypropionate included in the solvents cited as other components included in the resist composition includes, for example, methyl 2-hydroxypropionate, ethyl 2-hydroxypropionate, n-propyl 2-hydroxypropionate, i-propyl 2-hydroxypropionate, n-butyl 2-hydroxypropionate, i-butyl 2-hydroxypropionate, sec-butyl 2-hydroxypropionate, and tert-butyl 2-hydroxypropionate.

The alkyl 3-alkoxypropionate included in the solvents cited as other components included in the resist composition includes, for example, methyl 3-methoxypropionate, ethyl 3-methoxypropionate, methyl 3-ethoxypropionate, and ethyl 3-ethoxypropionate.

Other solvents included in the solvents cited as other components included in the resist composition include, for example, n-propyl alcohol, i-propyl alcohol, n-butyl alcohol, t-butyl alcohol, cyclohexanol, ethylene glycol monomethyl ether, ethylene glycol monoethyl ether, ethylene glycol mono-n-propyl ether, ethylene glycol mono-n-butyl ether, diethylene glycol dimethyl ether, diethylene glycol diethyl ether, diethylene glycol di-n-propyl ether, diethylene glycol di-n-butyl ether, ethylene glycol monomethyl ether acetate, ethylene glycol monoethyl ether acetate, ethylene glycol mono-n-propyl ether acetate, propylene glycol, propylene glycol monomethyl ether, propylene glycol monoethyl ether, propylene glycol mono-n-propyl ether, ethyl 2-hydroxy-2-methyl propionate, ethyl ethoxyacetate, ethyl hydroxyacetate, methyl 2-hydroxy-3-methylbutyrate, 3-methoxybutylacetate, 3-methyl-3-methoxybutylacetate, 3-methyl-3-methoxybutylpropionate, 3-methyl-3-methoxybutylbutyrate, ethyl acetate, n-propyl acetate, n-butyl acetate, methyl acetoacetoate, ethyl acetoacetate, methyl pyruvate, ethyl pyruvate, N-methyl pyrrolidone, N,N-dimethylformamide, N,N-dimethylacetamide, benzyl ethyl ether, di-n-hexyl ether, ethylene glycol monomethyl ether, diethylene glycol monoethyl ether, 7-butyrolactone, toluene, xylene, caproic acid, caprylic acid, octane, 1-octanol, 1-nonanol, benzyl alcohol, benzyl acetate, ethyl benzoate, diethyl oxalate, diethyl maleate, ethylene carbonate, and propylene carbonate. The above solvents may be used independently or by mixing the two or more solvents.

As described, according to the hyperbranched polymer synthesizing method of the embodiment, the rapid increase in the molecular weight can be prevented to acquire a hyperbranched polymer having a desired molecular weight and branching degree and the increase in the molecular weight due to temporal progress in the polymerization of the hyper branch polymer can be prevented by using the polar solvent. This enables the provision of a hyperbranched polymer synthesizing method capable of improving the temporal stability of the resolving performance of the hyperbranched polymer available for the resist composition.

The hyperbranched polymer synthesizing method of the embodiment enables the provision of a hyperbranched polymer synthesizing method capable of preventing the increase in the molecular weight due to temporal progress in the polymerization of the hyper branch polymer including the shell portion with the acid-degradable group and improving the temporal stability of the resolving performance of the hyperbranched polymer available for the resist composition.

According to the hyperbranched polymer synthesizing method of the embodiment, the increase in the molecular weight due to temporal progress in the polymerization of the hyper branch polymer can be prevented by using ultrapure water to remove the acid catalyst used for introducing the acid-degradable group. This enables the provision of a hyperbranched polymer synthesizing method capable of improving the temporal stability of the resolving performance of the hyperbranched polymer available for the resist composition.

The resist composition including the hyperbranched polymer of the embodiment may be exposed in a pattern-like form and developed in a patterning process. The resist composition may support electron beams, deep ultraviolet (DUV), and extreme ultraviolet (EUV) requiring nano-order surface smoothness and form fine patterns for manufacturing semiconductor integrated circuits. Therefore, the resist composition including the core-shell hyperbranched polymer generated with the synthesizing method of the present invention may preferably be used in various fields using semiconductor integrated circuits manufactured by applying light having short wavelengths.

If a semiconductor integrated circuit manufactured with the use of the resist composition including the core-shell hyperbranched polymer generated with the synthesizing method of the present invention is exposed, heated, dissolved in developing liquid, and washed with water, etc., when manufactured, substantially no undissolved residue is generated and substantially perpendicular edges can be acquired.

The embodiment of the fourth chapter above according to the present invention will hereinafter specifically be described with the following examples. The present invention is not to be construed in a limited way from the following examples.

### (Weight-Average Molecular Weight (Mw))

The weight-average molecular weight (Mw) of the core portion of the hyperbranched polymer of the examples will be described. The weight-average molecular weight (Mw) of the core portion of the hyperbranched polymer of the examples is a value obtained by preparing a 0.5 mass % tetrahydrofuran solution and performing measurement with a GPC HCL-8020 apparatus manufactured by Tosoh Corporation and two coupled TSKgel HXL-L columns (manufactured by Tosoh Corporation) under the temperature of 40 degrees C. In the measurement, tetrahydrofuran was used as a mobile solvent. In the measurement, styrene was used as a standard substance.

### (Branching Degree (Br))

The branching degree (Br) of the core portion of the hyperbranched polymer according to the examples will be described. The branching degree (Br) of the core portion of the hyperbranched polymer according to the examples was obtained by measuring ¹H-NMR of the product as follows. Specifically, the branching degree (Br) was calculated by carrying out an operation of the equation (A) using an integration ratio H1° of proton of the —CH₂Cl site appearing at 4.6 ppm and an integration ratio H2° of proton of the —CHCl site appearing at 4.8 ppm. If the polymerization proceeds at both the —CH₂Cl site and the —CHCl site and the branching is enhanced, the value of the branching degree (Br) approaches 0.5.

The core/shell rate of the core-shell hyperbranched polymer of the examples will be described. The core/shell rate of the core-shell hyperbranched polymer of the examples was obtained by measuring ¹H-NMR of the product as follows. The core/shell rate was calculated by using an integration ratio of proton of a t-butyl site appearing at 1.4 to 1.6 ppm and an integration ratio of proton of a aromatic site appearing near 7.2 ppm.

### (Trace Metal Analysis)

The metal contents in the core-shell hyperbranched polymer were measured by an ICP mass spectrometer (P-6000-type MIP-MS manufactured by Hitachi, Ltd.) or a flameless atomic absorption spectrometry available from PerkinElmer, Inc.

### (Ultrapure Water)

The ultrapure water used for the synthesis of the hyperbranched polymer of the examples will be described. The ultrapure water used for the synthesis of the hyperbranched polymer of the examples was ultrapure water produced by GSR-200 manufactured by Advantec Toyo Kaisha, Ltd., containing 1 ppb or less of metal contents at 25 degrees C., and having a specific resistance value of 18 MΩ·cm.

In the synthesis of the core portion of the hyperbranched polymer of the examples, the following synthesis was performed (in a constant-temperature room at 25 degrees C.) with reference to synthesizing methods described in Krzysztof Matyjaszewski, Macromolecules., 29, 1079 (1996) and Jean M. J. Frecht, J. Poly. Sci., 36, 955 (1998).

### First Example

### Core-Shell Hyperbranched Polymer Synthesizing Method

### (Synthesis of Core Portion of Hyperbranched Polymer)

The synthesis of the core portion of the hyperbranched polymer of a first example will be described. The core portion of the hyperbranched polymer of the first example (hereinafter, “hyperbranched core polymer”) was synthesized according to the following method. First, 18.3 g of 2,2′-bipyridyl, 5.8 g of copper(I) chloride, 441 mL of chlorobenzene, and 49 mL of acetonitrile were charged into a 1-L four-neck reactor; a reaction apparatus was assembled by attaching a dropping funnel with 90.0 g of chloromethylstyrene measured, a cooling tube, and an agitator; the inside of the reaction apparatus was entirely degassed; and the inside of the reaction apparatus was entirely replaced with argon after the degassing. After the replacement with argon, the above mixture was heated to 115 degrees C. and chloromethylstyrene was dropped into the reactor for one hour. After the dropping was completed, the mixture was heated and agitated for three hours. The reaction time was set to four hours including the time for dropping chloromethylstyrene into the reactor.

After the completion of the reaction through the heating and agitation, insoluble substances were removed by filtering the reaction system after the completion of the reaction. After the filtration, 500 mL of 3-mass % oxalic acid aqueous solution prepared with ultrapure water was added to the filtrate after the filtration and agitated for 20 minutes. After the agitation, a water layer was removed from the agitated solution. Copper, i.e., the reaction catalyst was removed by repeating, four times, the operations of adding the 3-mass % oxalic acid aqueous solution prepared with ultrapure water to the solution after the water layer was removed, agitating the solution, and removing a water layer from the agitated solution.

To the solution after the removal of copper, 700 mL of methanol was added to reprecipitate a solid content and 500 mL of a mixed solvent of THF (tetrahydrofuran):methanol=2:8 was added to the solid content acquired by reprecipitation to wash the solid content. After the washing, the solvent was removed through decantation from the solution after the washing. The operation of adding 500 mL of a mixed solvent of THF:methanol=2:8 to the solid content acquired by reprecipitation to wash the solid content was further repeated twice.

The solid content was then dried under vacuum condition of 0.1 Pa at 25 degrees C. for two hours. As a result, 64.8 g of the hyperbranched core polymer of the first example was acquired as a refined product. The yield of the acquired hyperbranched core polymer was 72%. The weight-average molecular weight (Mw) of the acquired hyperbranched core polymer was 2000, and the branching degree (Br) was 0.50.

### (Synthesis of Shell Portion of Hyperbranched Polymer)

The synthesis of the shell portion of the hyperbranched polymer of the first example will be described. In the synthesis of the shell portion of the hyperbranched polymer of the first example, first, 10 g of the hyperbranched core polymer of the first example, 5.1 g of 2,2′-bipyridyl, and 1.6 g of copper(I) chloride were measured and placed into a 1-L four-neck reactor with an agitator and a cooling tube attached and the whole reaction system including the reactor was vacuumed and sufficiently degassed. Under argon gas atmosphere, after 250 mL of chlorobenzene was added as a reaction solvent, 48 mL of acrylic acid tert-butyl ester was injected with by syringe and the mixture was heated and agitated at 120 degrees C. for five hours.

After the completion of the above polymerization reaction through the heating and agitation, insoluble substances were removed by filtering the reaction system after the completion of the polymerization reaction. After the filtration, 300 mL of 3-mass % oxalic acid aqueous solution was added to the filtrate after the filtration and agitated for 20 minutes. After the agitation, a water layer was removed from the agitated solution. Copper, i.e., the reaction catalyst was removed by repeating, four times, the operations of adding the 3-mass % oxalic acid aqueous solution prepared with ultrapure water to the solution after the water layer was removed, agitating the solution, and removing a water layer from the agitated solution.

### (Refinement)

The refinement of the first example will be described. The solvent was distilled and removed from the light yellow solution acquired after the removal of copper and 700 mL of methanol was added to the solution after the solvent was distilled and removed to reprecipitate a solid content. After the operations of dissolving the solid content acquired by the reprecipitation into 50 mL of THF and adding 500 mL of methanol to reprecipitate a solid content were further repeated twice, the solid content was dried under vacuum condition of 0.1 Pa at 25 degrees C. for three hours.

As a result, 17.1 g of a light yellow solid substance, i.e., the core-shell hyperbranched polymer was acquired as a refined product. The yield of the acquired light yellow solid substance was 76%. A molar rate of the acquired core-shell hyperbranched polymer was calculated with ¹H-NMR. As a result, the core/shell ratio of the core-shell hyperbranched polymer was 40/60 (molar ratio).

### (Removal of Trace Metal)

The removal of the trace metal of the example will be described. In the removal of the trace metal of the example, a solution acquired by dissolving 6 g of the above core-shell hyperbranched polymer with the shell portion formed into chloroform was mixed with 100 g of 3-mass % oxalic acid aqueous solution prepared with ultrapure water and was agitated vigorously for 30 minutes. After the agitation, an organic layer was extracted from the agitated solution and the extracted organic layer was mixed again with 100 g of 3-mass % oxalic acid aqueous solution prepared with ultrapure water and was agitated vigorously for 30 minutes. After the agitation, an organic layer was extracted from the agitated solution.

The operations of mixing the extracted organic layer with 3-mass % oxalic acid aqueous solution prepared with ultrapure water again and intensely agitating the mixture was repeated five times in total. The agitated solution was mixed with 100 g of 3-mass % hydrochloric acid aqueous solution and agitated vigorously for 30 minutes and an organic layer was extracted from the agitated solution.

Subsequently, the operations of mixing the solution after extracting the organic later with 100 g of the ultrapure water, intensely agitating the mixture, and extracting an organic later from the agitated solution were repeated three times. The finally acquired organic layer was distilled to remove the solvent and dried under vacuum condition of 0.1 Pa at 25 degrees C. for three hours, and the metal contents in the solid content after the removal of the solvent were measured as above. As a result, amounts of copper, sodium, iron, and aluminum contained in the solid content after the removal of the solvent were not greater than 10 ppb.

### (Deprotection)

The deprotection of the first example will be described. In the deprotection of the third example, 0.6 g of the solid content after the removal of the solvent above was collected in a reactor with a reflux tube, and 30 mL of dioxane and 0.6 mL of hydrochloric acid (30%) were added thereto and heated and agitated at 90 degrees C. for 60 minutes. The reaction crude product acquired by the heating and agitation was poured into 300 mL of ultrapure water and reprecipitated.

The reprecipitated solid content was dissolved by adding 30 mL of dioxane and a solid content was reprecipitated again by pouring the solution into 300 mL of ultrapure water.

### (Filtration)

The solid content acquired by the reprecipitation was dissolved by adding 100 mL of tetrahydrofuran and the solution was filtrated with pressure at a filtration rate of 4 mL/min with the use of a super-high density polyethylene filter (Optimizer D-300 manufactured by Nihon Mykrolis K.K.) having a pore diameter of 0.02 μm. The solvent was distilled and removed from the filtrate under reduced pressure and the acquired solid content was dried under vacuum condition of 0.1 Pa at 25 degrees C. for three hours to acquire the core-shell hyperbranched polymer of the first example. The amount of the core-shell hyperbranched polymer of the first example was 0.4 g and the yield was 66%. A rate of the acid-degradable group and the acid group was 78/22 (molar ratio).

### Second Example

### Core-Shell Hyperbranched Polymer Synthesizing Method

### (Synthesis of Core Portion of Hyperbranched Polymer)

The core portion of the hyperbranched polymer of a second example will be described. The core portion of the hyperbranched polymer of the second example (hereinafter, “hyperbranched core polymer”) was synthesized according to the following method. First, 11.8 g of 2,2′-bipyridyl, 3.5 g of copper(I) chloride, and 345 mL of benzonitrile were charged into a 1-L four-neck reactor; a reaction apparatus was assembled by attaching a dropping funnel with 54.2 g of chloromethylstyrene measured, a cooling tube, and an agitator; the inside of the reaction apparatus was entirely degassed; and the inside of the reaction apparatus was entirely replaced with argon after the degassing. After the replacement with argon, the above mixture was heated to 125 degrees C. and chloromethylstyrene was dropped for 30 minutes. After the dropping was completed, the mixture was heated and agitated for 3.5 hours. The reaction time was set to four hours including the time for dropping chloromethylstyrene into the reactor.

After the reaction was completed, the reaction solution was filtrated with the use of filter paper having a retention particle size of 1 μm, and the filtrate was added to a mixed solution acquired by preliminarily mixing 844 g of methanol and 211 g of the ultrapure water to reprecipitate poly(chloromethylstyrene).

After dissolving 29 g of the polymer acquired by the reprecipitation into 100 g of benzonitrile, a mixed solution of 200 g of methanol and 50 g of ultrapure water was added and the solvent was removed through decantation after centrifugal separation to collect the polymer. This collecting operation was repeated three times to acquire a polymer precipitate.

After the decantation, the precipitate was dried under reduced pressure acquiring 14.0 g of poly(chloromethylstyrene). The yield was 26%. The weight-average molecular weight (Mw) of the polymer obtained by the GPC measurement (in terms of polystyrene) was 1140, and the branching degree (Br) obtained by the ¹H-NMR measurement was 0.51.

### (Synthesis of Shell Portion of Hyperbranched Polymer)

The synthesis of the shell portion of the hyperbranched polymer of the second example will be described. The shell portion of the hyperbranched polymer of the second example was synthesized with the use of the core portion of the hyperbranched polymer above (hereinafter, “hyperbranched core polymer”) according to the following method. Into a 500-mL four-neck reactor under the argon gas atmosphere and containing 1.6 g of copper(I) chloride, 5.1 g of 2,2′-bipyridyl, and 10.0 g of the hyperbranched core polymer, 248 mL of monochlorobenzene and 48 mL of acrylic acid tert-butyl ester were injected by syringe, respectively. After the substances were injected into the reactor, the mixture in the reactor was heated and agitated at 125 degrees C. for five hours.

### (Refinement)

The refinement of the second example will be described. After the completion of the above polymerization reaction through the heating and agitation, insoluble substances were removed by filtering the reaction system after the completion of the polymerization reaction. Subsequently, 615 g of mixed acid aqueous solution containing 3 mass % of oxalic acid and 1 mass % of hydrochloric acid prepared with ultrapure water was added to 308 g of the filtrate acquired through the filtration and agitated for 20 minutes. After the agitation, a water layer was removed from the agitated reaction system. Copper, i.e., the reaction catalyst was removed by repeating four times the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 62.5 g of condensed liquid. By sequentially adding 219 g of methanol and 31 g of ultrapure water to the acquired condensed liquid, a solid content was precipitated. The solid content acquired by the precipitation was dissolved into 20 g of THF to acquire a solution, and 200 g of methanol and 29 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 23.8 g. The molar rate of the copolymer (the core-shell hyperbranched polymer with the shell portion formed) was calculated with ¹H-NMR. The core/shell ratio of the core-shell hyperbranched polymer with the shell portion formed was 30/70.

### (Filtration)

The hyperbranched polymer acquired by the drying was dissolved by adding 100 mL of tetrahydrofuran and the solution was filtrated with pressure at a filtration rate of 4 mL/min with the use of a super-high density polyethylene filter (Optimizer D-300 manufactured by Nihon Mykrolis K.K.) having a pore diameter of 0.02 μm. The solvent was distilled and removed from the filtrate under reduced pressure and the acquired solid content was dried under vacuum condition of 0.1 Pa at 25 degrees C. for three hours to acquire the core-shell hyperbranched polymer of the second example. The yield of the core-shell hyperbranched polymer of the second example was 21.4 g.

### Third Example

### Core-Shell Hyperbranched Polymer Synthesizing Method

The core-shell hyperbranched polymer of a third example will be described. For the core-shell hyperbranched polymer of the third example, the deprotection was performed with the use of the core-shell hyperbranched polymer of the second example before the filtration.

### (Deprotection)

The deprotection of the third example will be described. In the deprotection of the third example, first, 2.0 g of the copolymer (the core-shell hyperbranched polymer before deprotection in the second example) was collected in a reactor with a reflux tube and 18.0 g of 1,4-dioxane and 0.2 g of 50-mass % sulfuric acid were added thereto. Subsequently, reflux agitation was performed for 60 minutes while the whole reaction system including the reactor with the reflux tube was heated at a temperature for reflux. After the reflux agitation, the reaction crude product after the reflux agitation was poured into 180 mL of ultrapure water to precipitate a solid content.

After the solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.6 g of polymer.

### (Filtration)

The hyperbranched polymer acquired by the drying was dissolved by adding 100 mL of tetrahydrofuran and the solution was filtrated with pressure at a filtration rate of 4 mL/min with the use of a super-high density polyethylene filter (Optimizer D-300 manufactured by Nihon Mykrolis K.K.) having a pore diameter of 0.02 μm. The solvent was distilled and removed from the filtrate under reduced pressure and the acquired solid content was dried under vacuum condition of 0.1 Pa at 25 degrees C. for three hours to acquire the core-shell hyperbranched polymer of the third example. The yield of the core-shell hyperbranched polymer of the third example was 1.5 g. A rate of the acid-degradable group and the acid group was 78/22 (molar ratio).

### Fourth Example

### Core-Shell Hyperbranched Polymer Synthesizing Method

### (Synthesis of Shell Portion of Hyperbranched Polymer)

The core-shell hyperbranched polymer of a fourth example will be described. The core-shell hyperbranched polymer of the fourth example was synthesized with the use of the core portion of the hyperbranched polymer of the second example above (hereinafter, “hyperbranched core polymer”) in the following method. By syringe, 248 mL of monochlorobenzene and 81 mL of acrylic acid tert-butyl ester were injected respectively into a 500-mL four-neck reactor under an argon gas atmosphere and containing 1.6 g of copper(I) chloride, 5.1 g of 2,2′-bipyridyl, and 10.0 g of the hyperbranched core polymer of the second example above. After the substances were injected into the reactor, the mixture in the reactor was heated and agitated at 125 degrees C. for five hours.

### (Refinement)

The refinement of the fourth example will be described. After the completion of the above polymerization reaction through the heating and agitation, insoluble substances were removed by filtering the reaction system after the completion of the polymerization reaction. Subsequently, 680 g of mixed acid aqueous solution containing 3 mass % of oxalic acid and 1 mass % of hydrochloric acid prepared with ultrapure water was added to 340 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 88.0 g of condensed liquid. By sequentially adding 308 g of methanol and 44 g of ultrapure water to the acquired condensed liquid, a solid content was precipitated. The solid content acquired by the precipitation was dissolved into 44 g of THF to acquire a solution, and 440 g of methanol and 63 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 33.6 g. The molar rate of the copolymer (the core-shell hyperbranched polymer with the shell portion formed) was calculated with ¹H-NMR. The core/shell rate of the core-shell hyperbranched polymer with the shell portion formed was 19/81 (molar ratio).

### (Deprotection)

The deprotection of the fourth example will be described. In the deprotection of the fourth example, first, 2.0 g of the copolymer (the core-shell hyperbranched polymer before deprotection in the fourth example) was collected in a reactor with a reflux tube and 18.0 g of 1,4-dioxane and 0.2 g of 50-mass % sulfuric acid were added thereto. Subsequently, reflux agitation was performed for 30 minutes while the whole reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.6 g of polymer.

### (Filtration)

The hyperbranched polymer acquired by the drying was dissolved by adding 100 mL of tetrahydrofuran and the solution was filtrated with pressure at a filtration rate of 4 mL/min with the use of a super-high density polyethylene filter (Optimizer D-300 manufactured by Nihon Mykrolis K.K.) having a pore diameter of 0.02 μm. The solvent was distilled and removed from the filtrate under reduced pressure and the acquired solid content was dried under vacuum condition of 0.1 Pa at 25 degrees C. for three hours to acquire the core-shell hyperbranched polymer of the fourth example. The yield of the core-shell hyperbranched polymer of the fourth example was 1.5 g. A rate of the acid-degradable group and the acid group was 92/8 (molar ratio).

### Fifth Example

### Core-Shell Hyperbranched Polymer Synthesizing Method

(Synthesis of Shell Portion of Hyperbranched polymer)

The core-shell hyperbranched polymer of a fifth example will be described. The core-shell hyperbranched polymer of the fifth example was synthesized with the use of the core portion of the hyperbranched polymer of the second example above (hereinafter, “hyperbranched core polymer”) in the following method. By syringe, 248 mL of monochlorobenzene and 187 mL of acrylic acid tert-butyl ester were injected respectively into a 1000-mL four-neck reactor under an argon gas atmosphere and containing 1.6 g of copper(I) chloride, 5.1 g of 2,2′-bipyridyl, and 10.0 g of the hyperbranched core polymer of the fourth example above. After the substances were injected into the reactor, the mixture in the reactor was heated and agitated at 125 degrees C. for five hours.

### (Refinement)

The refinement of the fifth example will be described. After the completion of the above polymerization reaction through the heating and agitation, insoluble substances were removed by filtering the reaction system after the completion of the polymerization reaction. Subsequently, 880 g of mixed acid aqueous solution containing 3 mass % of oxalic acid and 1 mass % of hydrochloric acid prepared with ultrapure water was added to 440 g of the filtrate acquired through the filtration and agitated for 20 minutes. After the agitation, a water layer was removed from the agitated reaction system. Copper, i.e., the reaction catalyst was removed by repeating four times the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 175 g of condensed liquid. By sequentially adding 613 g of methanol and 88 g of ultrapure water to the acquired condensed liquid, a solid content was precipitated. The solid content acquired by the precipitation was dissolved into 85 g of THF to acquire a solution, and 850 g of methanol and 121 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 65.9 g. The molar rate of the copolymer (the core-shell hyperbranched polymer with the shell portion formed) was calculated with ¹H-NMR. The core/shell rate of the core-shell hyperbranched polymer with the shell portion formed was 10/90 (molar ratio).

### (Deprotection)

The deprotection of the fifth example will be described. In the deprotection of the fifth example, first, 2.0 g of the copolymer (the core-shell hyperbranched polymer before deprotection in the fifth example) was collected in a reactor with a reflux tube and 18.0 g of 1,4-dioxane and 0.2 g of 50-mass % sulfuric acid were added thereto. Subsequently, reflux agitation was performed for 15 minutes while the whole reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.7 g of polymer.

### (Filtration)

The hyperbranched polymer acquired by the drying was dissolved by adding 100 mL of tetrahydrofuran and the solution was filtrated with pressure at a filtration rate of 4 mL/min with the use of a super-high density polyethylene filter (Optimizer D-300 manufactured by Nihon Mykrolis K.K.) having a pore diameter of 0.02 μm. The solvent was distilled and removed from the filtrate under reduced pressure and the acquired solid content was dried under vacuum condition of 0.1 Pa at 25 degrees C. for three hours to acquire the core-shell hyperbranched polymer of the fourth example. The yield of the core-shell hyperbranched polymer of the fifth example was 1.5 g. A rate of the acid-degradable group and the acid group was 95/5 (molar ratio).

### Sixth Example

### Core-Shell Hyperbranched Polymer Synthesizing Method

### (Synthesis of Shell Portion of Hyperbranched Polymer)

The core-shell hyperbranched polymer of a sixth example will be described. The core-shell hyperbranched polymer of the sixth example was synthesized with the use of the core portion of the hyperbranched polymer of the second example above (hereinafter, “hyperbranched core polymer”) according to the following method. By syringe, 248 mL of monochlorobenzene and 14 mL of acrylic acid tert-butyl ester were injected respectively into a 500-mL four-neck reactor under an argon gas atmosphere and containing 1.6 g of copper(I) chloride, 5.1 g of 2,2′-bipyridyl, and 10.0 g of the hyperbranched core polymer of the fourth example above. After the substances were injected into the reactor, the mixture in the reactor was heated and agitated at 125 degrees C. for five hours.

### (Refinement)

The refinement of the sixth example will be described. After the completion of the above polymerization reaction through the heating and agitation, insoluble substances were removed by filtering the reaction system after the completion of the polymerization reaction. Subsequently, 570 g of mixed acid aqueous solution containing 3 mass % of oxalic acid and 1 mass % of hydrochloric acid prepared with ultrapure water was added to 285 g of the filtrate acquired through the filtration and agitated for 20 minutes. After the agitation, a water layer was removed from the agitated reaction system. Copper, i.e., the reaction catalyst was removed by repeating four times the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 32 g of condensed liquid. By sequentially adding 112 g of methanol and 16 g of ultrapure water to the acquired condensed liquid, a solid content was precipitated. The solid content acquired by the precipitation was dissolved into 16 g of THF to acquire a solution, and 160 g of methanol and 23 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 12.1 g. The molar rate of the copolymer (the core-shell hyperbranched polymer with the shell portion formed) was calculated with ¹H-NMR. The core/shell rate of the core-shell hyperbranched polymer with the shell portion formed was 61/39 (molar ratio).

### (Deprotection)

The deprotection of the sixth example will be described. In the deprotection of the sixth example, first, 2.0 g of the copolymer (the core-shell hyperbranched polymer before deprotection in the sixth example) was collected in a reactor with a reflux tube and 18.0 g of 1,4-dioxane and 0.2 g of 50-mass % sulfuric acid were added thereto. Subsequently, reflux agitation was performed for 150 minutes while the whole reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.4 g of polymer.

### (Filtration)

The hyperbranched polymer acquired by the drying was dissolved by adding 100 mL of tetrahydrofuran and the solution was filtrated with pressure at a filtration rate of 4 mL/min with the use of a super-high density polyethylene filter (Optimizer D-300 manufactured by Nihon Mykrolis K.K.) having a pore diameter of 0.02 μm. The solvent was distilled and removed from the filtrate under reduced pressure and the acquired solid content was dried under vacuum condition of 0.1 Pa at 25 degrees C. for three hours to acquire the core-shell hyperbranched polymer of the fourth example. The yield of the core-shell hyperbranched polymer of the sixth example was 1.3 g. A rate of the acid-degradable group and the acid group was 49/51 (molar ratio).

### First Reference Example

### Synthesis of Tert-Butyl 4-Vinylbenzoate

The synthesis was performed according to the following synthesizing method with reference to Synthesis, 833-834 (1982). Into a 1-L reactor with a dropping funnel attached, 91 g of 4-vinylbenzoic acid, 99.5 g of 1,1′-carbodiimidazole, 2.4 g of 4-tert-butylpyrocatechol, and 500 g of dehydrated dimethylformamide were added under an argon gas atmosphere, kept at 30 degrees C., and agitated for one hour. Subsequently, 93 g of 1,8-diazabicyclo[5.4.0]-7-undecene and 91 g of dehydrated 2-methyl-2-propanol were added thereto and agitated for four hours. After the reaction was completed, 300 mL of diethyl ether and 10% potassium carbonate aqueous solution were added to extract the objective substance into the ether layer. The diethyl ether layer was subsequently dried under reduced pressure to acquire light yellow tert-butyl 4-vinylbenzoate. The acquisition of the objective substance was confirmed by ¹H-NMR. The yield was 88%.

### Seventh Example

### Core-Shell Hyperbranched Polymer Synthesizing Method

### (Synthesis of Shell Portion of Hyperbranched Polymer)

The core-shell hyperbranched polymer of a seventh example will be described. The core-shell hyperbranched polymer of the seventh example was synthesized with the use of the core portion of the hyperbranched polymer of the second example above (hereinafter, “hyperbranched core polymer”) in the following method. By syringe, 421 mL of monochlorobenzene and 46.8 g of tert-butyl 4-vinylbenzoate were injected respectively into a 1000-mL four-neck reactor under an argon gas atmosphere and containing 0.8 g of copper(I) chloride, 2.6 g of 2,2′-bipyridyl, and 5.0 g of the hyperbranched core polymer of the fourth example above. After the substances were injected into the reactor, the mixture in the reactor was heated and agitated at 125 degrees C. for 3.5 hours.

### (Refinement)

The refinement of the seventh example will be described. After the completion of the above polymerization reaction through the heating and agitation, insoluble substances were removed by filtering the reaction system after the completion of the polymerization reaction. Subsequently, 980 g of mixed acid aqueous solution containing 3 mass % of oxalic acid and 1 mass % of hydrochloric acid prepared with ultrapure water was added to 490 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 41 g of condensed liquid. By sequentially adding 144 g of methanol and 21 g of ultrapure water to the acquired condensed liquid, a solid content was precipitated. The solid content acquired by the precipitation was dissolved into 21 g of THF to acquire a solution, and 210 g of methanol and 30 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 15.9 g. The molar rate of the copolymer (the core-shell hyperbranched polymer with the shell portion formed) was calculated with ¹H-NMR. The core/shell rate of the core-shell hyperbranched polymer with the shell portion formed was 29/71 (molar ratio).

### (Deprotection)

The deprotection of the seventh example will be described. In the deprotection of the seventh example, first, 2.0 g of the copolymer (the core-shell hyperbranched polymer before deprotection in the seventh example) was collected in a reactor with a reflux tube and 18.0 g of 1,4-dioxane and 0.2 g of 50-mass % sulfuric acid were added thereto. Subsequently, reflux agitation was performed for 180 minutes while the whole reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.7 g of polymer.

### (Filtration)

The hyperbranched polymer acquired by the drying was dissolved by adding 100 mL of tetrahydrofuran and the solution was filtrated with pressure at a filtration rate of 4 mL/min with the use of a super-high density polyethylene filter (Optimizer D-300 manufactured by Nihon Mykrolis K.K.) having a pore diameter of 0.02 μm. The solvent was distilled and removed from the filtrate under reduced pressure and the acquired solid content was dried under vacuum condition of 0.1 Pa at 25 degrees C. for three hours to acquire the core-shell hyperbranched polymer of the fourth example. The yield of the core-shell hyperbranched polymer of the seventh example was 1.5 g. A rate of the acid-degradable group and the acid group was 38/62 (molar ratio).

### Eighth Example

### Core-Shell Hyperbranched Polymer Synthesizing Method

### (Synthesis of Shell Portion of Hyperbranched Polymer)

The core-shell hyperbranched polymer of an eighth example will be described. The core-shell hyperbranched polymer of the eighth example was synthesized with the use of the core portion of the hyperbranched polymer of the second example above (hereinafter, “hyperbranched core polymer”) in the following method. By syringe, 421 mL of monochlorobenzene and 46.8 g of tert-butyl 4-vinylbenzoate were injected respectively into a 1000-mL four-neck reactor under an argon gas atmosphere and containing 1.6 g of copper(I) chloride, 5.1 g of 2,2′-bipyridyl, and 5.0 g of the hyperbranched core polymer of the fourth example above. After the substances were injected into the reactor, the mixture in the reactor was heated and agitated at 125 degrees C. for three hours.

### (Refinement)

The refinement of the eighth example will be described. After the completion of the above polymerization reaction through the heating and agitation, insoluble substances were removed by filtering the reaction system after the completion of the polymerization reaction. Subsequently, 980 g of mixed acid aqueous solution containing 3 mass % of oxalic acid and 1 mass % of hydrochloric acid prepared with ultrapure water was added to 490 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 64 g of condensed liquid. By sequentially adding 224 g of methanol and 32 g of ultrapure water to the acquired condensed liquid, a solid content was precipitated. The solid content acquired by the precipitation was dissolved into 32 g of THF to acquire a solution, and 320 g of methanol and 46 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 24.5 g. The molar rate of the copolymer (the core-shell hyperbranched polymer with the shell portion formed) was calculated with ¹H-NMR. The core/shell rate of the core-shell hyperbranched polymer with the shell portion formed was 20/80 (molar ratio).

### (Deprotection)

The deprotection of the eighth example will be described. In the deprotection of the eighth example, first, 2.0 g of the copolymer (the core-shell hyperbranched polymer before deprotection in the eighth example) was collected in a reactor with a reflux tube and 18.0 g of 1,4-dioxane and 0.2 g of 50-mass % sulfuric acid were added thereto. Subsequently, reflux agitation was performed for 90 minutes while the whole reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.7 g of polymer.

### (Filtration)

The hyperbranched polymer acquired by the drying was dissolved by adding 100 mL of tetrahydrofuran and the solution was filtrated with pressure at a filtration rate of 4 mL/min with the use of a super-high density polyethylene filter (Optimizer D-300 manufactured by Nihon Mykrolis K.K.) having a pore diameter of 0.02 μm. The solvent was distilled and removed from the filtrate under reduced pressure and the acquired solid content was dried under vacuum condition of 0.1 Pa at 25 degrees C. for three hours to acquire the core-shell hyperbranched polymer of the fourth example. The yield of the core-shell hyperbranched polymer of the eighth example was 1.5 g. A rate of the acid-degradable group and the acid group was 71/29 (molar ratio).

### Ninth Example

### Core-Shell Hyperbranched Polymer Synthesizing Method

### (Synthesis of Shell Portion of Hyperbranched Polymer)

The core-shell hyperbranched polymer of a ninth example will be described. The core-shell hyperbranched polymer of the ninth example was synthesized with the use of the core portion of the hyperbranched polymer of the second example above (hereinafter, “hyperbranched core polymer”) in the following method. By syringe, 530 mL of monochlorobenzene and 60.2 g of tert-butyl 4-vinylbenzoate were injected respectively into a 1000-mL four-neck reactor under an argon gas atmosphere and containing 1.6 g of copper(I) chloride, 5.1 g of 2,2′-bipyridyl, and 5.0 g of the hyperbranched core polymer of the tenth example above. After the substances were injected into the reactor, the mixture in the reactor was heated and agitated at 125 degrees C. for four hours.

### (Refinement)

The refinement of the ninth example will be described. After the completion of the above polymerization reaction through the heating and agitation, insoluble substances were removed by filtering the reaction system after the completion of the polymerization reaction. Subsequently, 1240 g of mixed acid aqueous solution containing 3 mass % of oxalic acid and 1 mass % of hydrochloric acid prepared with ultrapure water was added to 620 g of the filtrate acquired through the filtration and agitated for 20 minutes. After the agitation, a water layer was removed from the agitated reaction system. Copper, i.e., the reaction catalyst was removed by repeating four times the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 130 g of condensed liquid. By sequentially adding 455 g of methanol and 65 g of ultrapure water to the acquired condensed liquid, a solid content was precipitated. The solid content acquired by the precipitation was dissolved into 65 g of THF to acquire a solution, and 650 g of methanol and 93 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 50.2 g. The molar rate of the copolymer (the core-shell hyperbranched polymer with the shell portion formed) was calculated with ¹H-NMR. The core/shell rate of the core-shell hyperbranched polymer with the shell portion formed was 9/91 (molar ratio).

### (Deprotection)

The deprotection of the ninth example will be described. In the deprotection of the ninth example, first, 2.0 g of the copolymer (the core-shell hyperbranched polymer before deprotection in the ninth example) was collected in a reactor with a reflux tube and 18.0 g of 1,4-dioxane and 0.2 g of 50-mass % sulfuric acid were added thereto. Subsequently, reflux agitation was performed for 30 minutes while the whole reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.7 g of polymer.

### (Filtration)

The hyperbranched polymer acquired by the drying was dissolved by adding 100 mL of tetrahydrofuran and the solution was filtrated with pressure at a filtration rate of 4 mL/min with the use of a super-high density polyethylene filter (Optimizer D-300 manufactured by Nihon Mykrolis K.K.) having a pore diameter of 0.02 μm. The solvent was distilled and removed from the filtrate under reduced pressure and the acquired solid content was dried under vacuum condition of 0.1 Pa at 25 degrees C. for three hours to acquire the core-shell hyperbranched polymer of the fourth example. The yield of the core-shell hyperbranched polymer of the ninth example was 1.5 g. A rate of the acid-degradable group and the acid group was 92/8 (molar ratio).

### Tenth Example

### Core-Shell Hyperbranched Polymer Synthesizing Method

### (Synthesis of Shell Portion of Hyperbranched Polymer)

The core-shell hyperbranched polymer of a tenth example will be described. The core-shell hyperbranched polymer of the tenth example was synthesized with the use of the core portion of the hyperbranched polymer of the second example above (hereinafter, “hyperbranched core polymer”) in the following method. By syringe, 106 mL of monochlorobenzene and 8.0 g of tert-butyl 4-vinylbenzoate were injected respectively into a 1000-mL four-neck reactor under an argon gas atmosphere and containing 0.8 g of copper(I) chloride, 2.6 g of 2,2′-bipyridyl, and 5.0 g of the hyperbranched core polymer of the fourth example above. After the substances were injected into the reactor, the mixture in the reactor was heated and agitated at 125 degrees C. for one hour.

### (Refinement)

The refinement of the tenth example will be described. After the completion of the above polymerization reaction through the heating and agitation, insoluble substances were removed by filtering the reaction system after the completion of the polymerization reaction. Subsequently, 254 g of mixed acid aqueous solution containing 3 mass % of oxalic acid and 1 mass % of hydrochloric acid prepared with ultrapure water was added to 127 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 19 g of condensed liquid. By sequentially adding 67 g of methanol and 10 g of ultrapure water to the acquired condensed liquid, a solid content was precipitated. The solid content acquired by the precipitation was dissolved into 10 g of THF to acquire a solution, and 100 g of methanol and 14 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 7.3 g. The molar rate of the copolymer (the core-shell hyperbranched polymer with the shell portion formed) was calculated with ¹H-NMR. The core/shell rate of the core-shell hyperbranched polymer with the shell portion formed was 60/40 (molar ratio).

### (Deprotection)

The deprotection of the tenth example will be described. In the deprotection of the tenth example, first, 2.0 g of the copolymer (the core-shell hyperbranched polymer before deprotection in the tenth example) was collected in a reactor with a reflux tube and 18.0 g of 1,4-dioxane and 0.2 g of 50-mass % sulfuric acid were added thereto. Subsequently, reflux agitation was performed for 240 minutes while the whole reaction system including the reactor with the reflux tube was heated at a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.4 g of polymer.

### (Filtration)

The hyperbranched polymer acquired by the drying was dissolved by adding 100 mL of tetrahydrofuran and the solution was filtrated with pressure at a filtration rate of 4 mL/min with the use of a super-high density polyethylene filter (Optimizer D-300 manufactured by Nihon Mykrolis K.K.) having a pore diameter of 0.02 μm. The solvent was distilled and removed from the filtrate under reduced pressure and the acquired solid content was dried under vacuum condition of 0.1 Pa at 25 degrees C. for three hours to acquire the core-shell hyperbranched polymer of the fourth example. The yield of the core-shell hyperbranched polymer of the tenth example was 1.3 g. A rate of the acid-degradable group and the acid group was 22/78 (molar ratio).

### —Preparation of Resist Composition—

The resist compositions of the first to tenth examples will be described. The resist compositions of the first to tenth examples contain 4.8 mass % of the core-shell hyperbranched polymer synthesized with the above method, 10 mass % of triphenyl sulfonium bisnonaflate as the photoacid generator, 8 mol % of trioctylamine as a quencher based on the photoacid generator, and residual propylene glycol monomethyl acetate.

### —Storage Conditions of Resist Compositions—

The resist compositions of the first to tenth examples were placed into light-shielding glass bottles and the glass bottles were stored at rest in cabinets at temperatures of 23 degrees C. and 5 degrees C.

### First Comparative Example

### Core-Shell Hyperbranched Polymer Synthesizing Method

The hyperbranched polymer of a first comparative example will be described. In the synthesis of the hyperbranched polymer of the first comparative example, the hyperbranched polymer was synthesized as is the case with the first example except that the filtration was not performed as compared to the core-shell hyperbranched polymer synthesizing method described in the first example above. The core/shell ratio of the core-shell hyperbranched polymer of the first comparative example was 40/60 (molar ratio). The rate of the acid-degradable group and the acid group was 78/22 (molar ratio).

### Second Comparative Example

### Core-Shell Hyperbranched Polymer Synthesizing Method

The hyperbranched polymer of a second comparative example will be described. In the synthesis of the hyperbranched polymer of the second comparative example, the hyperbranched polymer was synthesized as is the case with the second example except that the filtration was not performed as compared to the core-shell hyperbranched polymer synthesizing method described in the second example above. The core/shell ratio of the core-shell hyperbranched polymer of the second comparative example was 30/70 (molar ratio).

### Third Comparative Example

### Core-Shell Hyperbranched Polymer Synthesizing Method

The hyperbranched polymer of a third comparative example will be described. In the synthesis of the hyperbranched polymer of the third comparative example, the hyperbranched polymer was synthesized as is the case with the third example except that the filtration was not performed as compared to the core-shell hyperbranched polymer synthesizing method described in the third example above. The core/shell ratio of the core-shell hyperbranched polymer of the third comparative example was 30/70 (molar ratio). The rate of the acid-degradable group and the acid group was 78/22 (molar ratio).

### Fourth Comparative Example

### Core-Shell Hyperbranched Polymer Synthesizing Method

The hyperbranched polymer of a fourth comparative example will be described. In the synthesis of the hyperbranched polymer of the fourth comparative example, synthesis of the hyperbranched polymer was identical to the seventh example except that the filtration was not performed as compared to the core-shell hyperbranched polymer synthesizing method described in the seventh example above. The core/shell ratio of the core-shell hyperbranched polymer of the fourth comparative example was 30/70 (molar ratio). The rate of the acid-degradable group and the acid group was 38/62 (molar ratio).

### —Preparation of Resist Compositions—

The preparation of the resist compositions of the first to fourth comparative examples was identical to the preparation of the resist compositions of the first to tenth examples above.

### —Storage Conditions of Resist Compositions—

The storage conditions of the first to fourth comparative examples were identical to the storage conditions of the first to tenth examples above.

### —Evaluation of Resist Resolutions—

The evaluation of the resist resolutions will be described. In the evaluation of the resist resolutions, the resist compositions having a thickness of 100 nm were formed on silicon wafers by spin-coating. The spin-coating condition was 1900 rpm for 1 min. An electron beam lithography apparatus was CABL9000 of CRESTEC Corp. The accelerating voltage was 50 KeV. An exposure process condition was PB: 140 degrees C. for 1 min, PEB: 115 degrees C. for 3 min, development: dipping in 2.38-mass % tetramethylammonium hydroxide aqueous solution at 23 degrees C. for 2 min, and rinse: dipping in ultrapure water for 1 min. To identify the resolutions, FE-SEM S4800 manufactured by Hitachi High-Technologies Corporation was used to obtain a storage period until the resolution was recognized at a resolution L/S=30 nm. The results of the resist compositions of the first to fourth comparative examples and the first to tenth resist compositions are depicted in Table 7.

TABLE 7

| | storage temperature | storage period for |
|---|---|---|
| | (degrees C.) | obtaining L/=30 nm |
| first comparative | 5 | 6 months |
| example | 23 | 6 months |
| second comparative | 5 | 6 months |
| example | 23 | 6 months |
| third comparative | 5 | 6 months |
| example | 23 | 6 months |
| fourth comparative | 5 | 6 months |
| example | 23 | 6 months |
| first example | 5 | 1 year |
| | 23 | 1 year |
| second example | 5 | 1 year |
| | 23 | 1 year |
| third example | 5 | 1 year |
| | 23 | 1 year |
| fourth example | 5 | 1 year |
| | 23 | 1 year |
| fifth example | 5 | 1 year |
| | 23 | 1 year |
| sixth example | 5 | 1 year |
| | 23 | 1 year |
| seventh example | 5 | 1 year |
| | 23 | 1 year |
| eighth example | 5 | 1 year |
| | 23 | 1 year |
| ninth example | 5 | 1 year |
| | 23 | 1 year |
| tenth example | 5 | 1 year |
| | 23 | 1 year |

### <Fifth Chapter>

A core-shell hyperbranched polymer of an embodiment of a fifth chapter according to the present invention has a structure with a core portion that is a hyperbranched core polymer acting as a macroinitiator and a shell portion covering the core portion.

The hyperbranched core polymer is synthesized by the atom transfer radical polymerization method (ATRP), which is a kind of the living radical polymerization. Monomers used in the synthesis of the hyperbranched core polymer include monomers represented at least by the above chemical formula (I).

Y of the formula (I) denotes a straight-chain, branched, or cyclic alkylene group having 1 to 10 carbon atoms. The preferred number of carbon atoms of Y is one to six. Y of the formula (I) may contain a hydroxyl group or a carboxyl group.

Specifically, Y of the formula (I) may denote, for example, a methylene group, an ethylene group, a propylene group, an isopropylene group, a butylene group, an isobutylene group, an amylene group, a hexylene group, and a cyclohexylene group. Y of the formula (I) may denote groups formed by combining the above groups or groups formed by containing “—O—”, “—CO—”, or “—COO—” between the above groups.

Among the above groups, Y of the formula (I) preferably denotes an alkylene group having one to eight carbon atoms. Among the alkylene groups having one to eight carbon atoms, Y of the formula (I) is preferably a straight-chain alkylene group having one to eight carbon atoms. A more preferred alkylene group includes, for example, a methylene group, an ethylene group, a —OCH₂—group, and a —OCH₂CH₂— group. Z of the formula (I) denotes a halogen atom (halogen group) such as a fluorine atom, a chlorine atom, a bromine atom, and an iodine atom. Specifically, Z of the formula (I) is preferably a chlorine atom or a bromine atom among the above halogen atoms.

Specifically, monomers represented by the formula (I) include, for example, chloromethyl styrene, bromomethyl styrene, p-(1-chloroethyl)styrene, bromo(4-vinylphenyl)phenylmethane, 1-bromo-1-(4-vinylphenyl)propane-2-one, and 3-bromo-3-(4-vinylphenyl)propanol. More specifically, among the monomers used in the synthesis of the hyperbranched polymer, the monomers represented by the formula (I) preferably are chloromethyl styrene, bromomethyl styrene, p-(1-chloroethyl)styrene, etc.

Monomers constituting the core portion of the hyperbranched polymer of the present invention may include other monomers in addition to monomers represented by the formula (I). Other monomers are not particularly limited provided the monomer is radically polymerizable, and may be selected according to purpose. Other radically polymerizable monomers include, for example, compounds having a radically polymerizable unsaturated bond and may be selected from among (meth)acrylic acid and (meth)acrylic esters, vinylbenzoic acid, vinylbenzoic esters, styrenes, allyl compounds, vinyl ethers, and vinyl esters.

Specifically, (meth)acrylic esters cited as other radically polymerizable monomers include, for example, tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1-ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1 ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl) oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate.

Specifically, vinylbenzoic esters cited as other radically polymerizable monomers include, for example, tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1 n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinylbenzoate, adamantyl vinylbenzoate, 2-(2-methyl)adamantyl vinylbenzoate, chloroethyl vinylbenzoate, 2-hydroxyethyl vinylbenzoate, 2,2-dimethylhydroxypropyl vinylbenzoate, 5-hydroxybenzyl vinylbenzoate, trimethylolpropane vinylbenzoate, glycidyl vinylbenzoate, benzyl vinylbenzoate, phenyl vinylbenzoate, and naphthyl vinylbenzoate.

Specifically, styrenes cited as other radically polymerizable monomers include, for example, styrene, benzylstyrene, trifluoromethylstyrene, acetoxystyrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, 4-fluoro-3-trifluoromethylstyrene, and vinylnaphthalene.

Specifically, allyl compounds cited as other radically polymerizable monomers include, for example, allyl acetate, allyl caproate, allyl caprylate, allyl laurate, allyl palmitate, allyl stearate, allyl benzoate, allyl acetoacetate, allyl lactate, and allyloxyethanol.

Specifically, vinyl ethers cited as other radically polymerizable monomers include, for example, hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether, tetrahydrofurfuryl vinyl ether, vinylphenyl vinyl ether, vinyl tolyl ether, vinyl chlorophenyl ether, vinyl-2,4-dichlorophenyl ether, vinyl naphthyl ether, and vinyl anthranyl ether.

Specifically, vinylesters cited as other radically polymerizable monomers include, for example, vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl-β-phenylbutyrate, and vinyl cyclohexylcarboxylate.

Specifically, other radically polymerizable monomers constituting the hyperbranched core polymer preferably include, for example, (meth)acrylic acid, tert-butyl (meth)acrylate, 4-vinylbenzoic acid, tert-butyl 4-vinylbenzoate, styrene, benzylstyrene, chlorostyrene, and vinylnaphthalene.

The amount of monomer constituting the hyperbranched core polymer is preferably 10 to 90 mol %, more preferably 10 to 80 mol %, and yet more preferably 10 to 60 mol % relative to the total amount of monomers used for the synthesis of the hyperbranched polymer.

For example, if the core-shell hyperbranched polymer having the hyperbranched core polymer as the core portion is utilized for a resist composition, appropriate hydrophobicity may be induced to the developing fluid of the hyperbranched polymer by adjusting the amount of monomer constituting the hyperbranched core polymer to be at the above ranges. This is preferable since the resist composition containing the hyperbranched polymer may be used to prevent the dissolution of the unexposed portion at the time of the microfabrication when manufacturing semiconductor integrated circuits, flat panel displays, and printed-wiring boards, for example.

The amount of monomer represented by the formula (I) is preferably 5 to 100 mol %, more preferably 20 to 100 mol %, and yet more preferably 50 to 100 mol % relative to the total amount of monomer used for the synthesis of the hyperbranched core polymer. When the amount of monomer represented by the formula (I) is at the above ranges in the hyperbranched core polymer, this is preferable since the entwining of molecules is advantageously prevented because the hyperbranched core polymer takes a spherical form.

If the hyperbranched core polymer is a copolymer of a monomer represented by formula (I) and another monomer, the amount of monomer represented by formula (I) is preferably 10 to 99 mol %, more preferably 20 to 99 mol %, and yet more preferably 30 to 99 mol % relative to the total amount of monomer constituting the hyperbranched core polymer. If the amount of monomer represented by formula (I) is at the above ranges in the hyperbranched core polymer, since the hyperbranched core polymer takes a spherical form, this advantageously constrains entwining of molecules and induces functions such as adhesiveness to substrates and an increase in the glass-transition temperature, which is preferable. According to purpose, the amount of the monomer represented by the formula (I) and the amount of other monomers in the core portion may be adjusted by the ratio of the charging amount at the time of polymerization.

A metal catalyst is used when synthesizing the hyperbranched core polymer. The metal catalyst includes a metal catalyst consisting of a combination of a transition metal compound such as copper, iron, ruthenium, and chromium, and a ligand, for example. The transition metal compound includes, for example, cuprous chloride, cuprous bromide, cuprous iodide, cuprous cyanide, cuprous oxide, cuprous perchlorate, ferrous chloride, ferrous bromide, and ferrous iodide.

The ligand includes pyridines, bipyridines, polyamines, phosphines, etc., not substituted or substituted by an alkyl group, an aryl group, an amino group, a halogen group, an ester group, etc. A preferred metal catalyst may be, for example, a copper(I) bipyridyl complex and a copper(I) pentamethyldiethylenetriamine complex constituted by copper chloride and a ligand, an iron(II) triphenylphosphine complex and an iron(II) tributylamine complex constituted by iron chloride and a ligand, etc. Ligands described in Chem. rev. 2001, 101, 3689—may also be used for the ligand.

The amount of metal catalyst used is preferably 0.01 to 70 mol %, more preferably 0.1 to 60 mol % relative to the total amount of monomer used for the synthesis of the hyperbranched polymer. If the catalyst is used at such ranges, the reactivity may be improved to synthesize a hyperbranched core polymer having a preferred branching degree.

If the amount of metal catalyst used is less than the above ranges, the reactivity is considerably reduced and the polymerization may not progress. On the other hand, if the amount of metal catalyst exceeds the above ranges, since the polymerization reaction becomes excessively active, a coupling reaction tends to occur between radicals at the growth ends and the polymerization tends to become difficult to control. If the amount of metal catalyst exceeds the above ranges, the coupling reaction between radicals triggers gelation of the reaction system.

The metal catalyst may be made into a complex compound by mixing the above transition metal compound and the ligand in an apparatus. The metal catalyst consisting of the transition metal compound and the ligand may be added in a state of an active complex to the apparatus. The transition metal compound and the ligand can be in the apparatus to form a complex, thereby simplifying the synthesis operation of the hyperbranched polymer.

The method of adding the metal catalyst is not particularly limited and, for example, the metal catalyst may be added at one time before the polymerization of the hyperbranched polymer. Alternatively, after the polymerization starts, additional metal catalyst may be added depending on the level of deactivation of the catalyst. For example, if the distribution of the complex acting as the metal catalyst is not uniform in the reaction system, the transition metal compound may preliminarily be added into the apparatus and only the ligand may be added afterward.

In the presence of the above metal catalyst, the polymerization reaction for synthesizing the hyperbranched core polymer is preferably performed in a solvent although the reaction can occur in the absence of solvent. The solvent used for the polymerization reaction of the hyperbranched core polymer in the presence of the metal catalyst is not particularly limited and includes, for example, a hydrocarbon solvent such as benzene and toluene, an ether solvent such as diethyl ether, tetrahydrofuran, diphenyl ether, anisole, and dimethoxybenzene, a halogenated hydrocarbon solvent such as methylene chloride, chloroform, and chlorobenzene, a ketone solvent such as acetone, methyl ethyl ketone, and methyl isobutyl ketone, an alcohol solvent such as methanol, ethanol, propanol, and isopropanol, a nitrile solvent such as acetonitrile, propionitrile, and benzonitrile, an ester solvent such as ethyl acetate and butyl acetate, a carbonate solvent such as ethylene carbonate and propylene carbonate, and an amide solvent such as N,N-dimethylformamide and N,N-dimethylacetamide. These solvents may independently be used or two or more of the solvents may concurrently be used.

In the synthesis of the hyperbranched core polymer, the core polymerization is preferably performed in the presence of or in the flow of nitrogen or inert gas or in the absence of oxygen to prevent oxygen from affecting radicals. The core polymerization may be applied to both a batch method and a continuous method.

In the synthesis of the hyperbranched core polymer, in a polymerization reactor with the metal catalyst introduced in advance, the monomer may be added later to cause the reaction. Each addition amount of the monomer added to the metal catalyst at a later time is less than the total amount of the monomer to be added to the metal catalyst.

For example, each addition amount of the monomer added to the metal catalyst at a later time may be less than the total amount of the monomer to be added to the metal catalyst by following the methods such as a continuous method for mixing the monomer with the metal catalyst by dropping the monomer for a predetermined time period and a dividing method for dividing the total amount of the monomer to be mixed with the metal catalyst and adding a given amount of the monomer at given intervals.

For example, the monomer may be added to the metal catalyst by continuously injecting the monomer for a predetermined time period. In this case, an addition amount of the monomer mixed with the metal catalyst for each unit time is less than the total amount of the monomer to be mixed with the metal catalyst.

If the continuous method is used to mix the monomer into the reaction system, the dropping time of the monomer is preferably 5 to 300 minutes. If the continuous method is used to mix the monomer with the metal catalyst, a dropping time of the monomer is 15 to 240 minutes is more preferable. If the continuous method is used to mix the monomer with the metal catalyst, a dropping time of the monomer is 30 to 180 minutes is yet more preferable.

If the dividing method is used to mix the monomer into the reaction system, after each amount of the monomer is mixed, an amount of the monomer is mixed subsequently at predetermined intervals. The predetermined interval of time may be, for example, the time required for the mixed monomer to perform one polymerization reaction, the time required for the mixed monomer to uniformly disperse or dissolve into the entire reaction system, or the time required for the temperature of the reaction system varied due to the mixing of the monomer to be stabilized.

If the dropping time of the monomer to the metal catalyst is too short, the effect of preventing the rapid increase in the molecular weight may not be achieved sufficiently. If the dropping time of the monomer to the reaction system is too long, this is not preferable since the total polymerization time from the start to the end of the synthesis of the hyperbranched polymer is increased and the cost of the synthesis of the hyperbranched polymer is increased.

In the core polymerization, an additive may be used for the polymerization. In the core polymerization, at least one of the compounds represented by formula (1-1) or (1-2) described in the first chapter may be added.

R₁ of formula (1-1) denotes an alkyl group having 1 to 10 carbon atoms, an aryl group having 6 to 10 carbon atoms, or an aralkyl group having 7 to 10 carbon atoms. A of formula (1-1) denotes a cyano group, a hydroxyl group, or a nitro group. The compounds represented by formula (1-1) include nitriles, alcohols, and nitro compounds, for example.

Specifically, nitriles included in the compounds represented by formula (1-1) are, for example, acetonitrile, propionitrile, butyronitrile, and benzonitrile.

Specifically, alcohols included in the compounds represented by formula (1-1) are, for example, methanol, ethanol, 1-propanol, 2-propanol, 1-butanol, cyclohexyl alcohol, and benzyl alcohol. Specifically, nitro compounds included in the compounds represented by formula (1-1) are, for example, nitromethane, nitroethane, nitropropane, and nitrobenzene. The compounds represented by formula (1-1) are not limited to the above compounds.

R₂ and R₃ of formula (1-2) denote alkyl groups having 1 to 10 carbon atoms, aryl groups having 1 to 10 carbon atoms, aralkyl groups having 1 to 10 carbon atoms, or dialkylamide groups having 1 to 10 carbon atoms and B denotes a carbonyl group or a sulfonyl group. More particularly, R₂ and R₃ of formula (1-2) represent hydrogen, alkyl groups having 1 to 10 carbon atoms, aryl groups having 6 to 10 carbon atoms, aralkyl groups having 7 to 10 carbon atoms, or dialkylamide groups having 1 to 10 carbon atoms. R₂ and R₃ of formula (1-2) may be the same or different.

The compounds represented by formula (1-2) include ketones, sulfoxides, and alkylformamide compounds, for example. Specifically, ketones include, for example, acetone, 2-butanone, 2-pentanone, 3-pentanone, 2-hexanone, cyclohexanone, 2-methylcyclohexanone, acetophenone, and 2-methylacetophenone.

Specifically, sulfoxides included in the compounds represented by formula (1-2) are, for example, dimethyl sulfoxide and diethyl sulfoxide. Specifically, alkylformamide compounds included in the compounds represented by formula (1-2) are, for example, N,N-dimethylformamide, N,N-diethylformamide, and N,N-dibutylformamide.

The compounds represented by formula (1-2) are not limited to the above compounds. The compounds represented by formula (1-1) or formula (1-2) are preferably nitriles, nitro compounds, sulfoxides, ketones, and alkylformamide compounds, and more preferably, acetonitrile, propionitrile, benzonitrile, nitroethane, nitropropane, dimethyl sulfoxide, acetone, and N,N-dimethylformamide.

In the synthesis of the hyperbranched polymer, the compounds represented by formula (1-1) or formula (1-2) may be used independently or two or more of the compounds may be used in combination.

In the synthesis of the hyperbranched core polymer, the compounds represented by formula (1-1) or formula (1-2) may be used independently or two or more of the compounds may be used in combination as a solvent.

The amount of the compounds represented by formula (1-1) or formula (1-2) to be added in the synthesis of the hyperbranched polymer is preferably 2 times to 10000 times the amount of the transition metal in the above metal catalyst by molar ratio. The amount of the compounds represented by formula (1-1) or formula (1-2) to be added is more preferably 3 times to 7000 times and yet more preferably 4 times to 5000 times the amount of the transition metal in the above metal catalyst by molar ratio.

If the added amount of the compounds represented by formula (1-1) or formula (1-2) is too small, the rapid increase in the molecular weight may not be controlled sufficiently. On the other hand, if the added amount of the compounds represented by formula (1-1) or formula (1-2) is too large, the reaction rate is slowed and a large amount of oligomers is generated.

The core polymerization may be performed while dropping a monomer into a reactor, for example. By controlling the dropping rate, a higher branching degree can be maintained in a macroinitiator to be synthesized if an amount of the metal catalyst is low. By controlling the dropping rate of the monomer, the amount of metal catalyst used can be reduced while maintaining a higher branching degree in the hyperbranched core polymer to be synthesized (macroinitiator). To maintain a higher branching degree in the hyperbranched core polymer, the concentration of the monomer to be dropped is preferably 1 to 50 mass %, more preferably 2 to 20 mass %, relative to the total reaction amount.

The polymerization time of the core polymerization is preferably 0.1 to 10 hours depending on the molecular weight of the polymerization product. In the core polymerization, the reaction temperature is preferably a range of 0 to 200 degrees C., and more preferably a range of 50 to 150 degrees C. If the polymerization is performed at a temperature higher than the boiling point of the solvent to be used, the pressure may be increased within an autoclave, for example.

In the core polymerization, it is preferable for the reaction system to be uniformly distributed. For example, the reaction system is uniformly distributed by agitating the reaction system. A specific example of an agitation condition of the core polymerization is that preferably the power necessary for agitation per unit volume is set as 0.01 kW/m³ or more. In the core polymerization, additional catalyst or a reducing agent regenerating the catalyst may be added depending on the progress in the polymerization and the level of deactivation of the catalyst.

In the synthesis of the hyperbranched core polymer, the polymerization reaction is terminated when the set molecular weight is attained. A method of terminating the core polymerization is not particularly limited and, for example, a method such as cooling or deactivating the catalyst with the addition of an oxidizing agent or a chelating agent may be used.

The core-shell hyperbranched polymer according to the embodiment has a shell portion constituted by molecular terminals of the hyperbranched core polymer synthesized as described above. The shell portion of the hyperbranched polymer includes at least a repeating unit represented by the formula (II) or a repeating unit represented by formula (III).

The repeating unit represented by formulas (II), (III) described in chapter 1 includes an acid-degradable group degraded by an effect of an organic acid such as acetic acid, maleic acid, and benzoic acid or an inorganic acid such as hydrochloric acid, sulfuric acid, and nitric acid or by an effect of a photoacid generator that generates an acid using optical energy. Degradation of the acid-degradable group to form a hydrophilic group is preferable.

R¹ of formula (II) and R⁴ of formula (III) denote hydrogen atoms or alkyl groups having 1 to 3 carbon atoms. R¹ of formula (II) and R⁴ of formula (III) are preferably hydrogen atoms and methyl groups. R¹ of formula (II) and R⁴ of formula (III) are more preferably hydrogen atoms.

R² of formula (II) denotes a hydrogen atom, an alkyl group, or an aryl group. The alkyl group of R² of formula (II) preferably has 1 to 30 carbon atoms, more preferably has 1 to 20 carbon atoms, and yet more preferably has 1 to 10 carbon atoms, for example. The alkyl group has a straight-chain, branched, or cyclic structure. Specifically, the alkyl group of R² of formula (II) includes, for example, a methyl group, an ethyl group, a propyl group, an isopropyl group, a butyl group, an isobutyl group, a t-butyl group, a cyclohexyl group, etc.

The aryl group of R² of formula (II) preferably has 6 to 30 carbon atoms, for example. The aryl group of R² of formula (II) more preferably has 6 to 20 carbon atoms and yet more preferably has 6 to 10 carbon atoms. Specifically, the aryl group of R² of formula (II) includes, for example, a phenyl group, a 4-methylphenyl group, and a naphthyl group. A hydrogen atom, a methyl group, an ethyl group, and a phenyl group are particularly cited among the above groups. A hydrogen atom is cited as one of the most preferable groups for R² of formula (II).

R³ of formula (II) and R⁵ of formula (III) denote hydrogen atoms, alkyl groups, trialkylsilyl groups, oxoalkyl groups, or groups represented by the following formula (I). The alkyl groups of R³ of formula (II) and R⁵ of formula (III) preferably have 1 to 40 carbon atoms. The alkyl groups of R³ of formula (II) and R⁵ of formula (III) more preferably have 1 to 30 carbon atoms.

The alkyl groups of R³ of formula (II) and R⁵ of formula (III) yet more preferably have 1 to 20 carbon atoms. The alkyl groups of R³ of formula (II) and R⁵ of formula (III) have a straight-chain, branched, or cyclic structure. Branched alkyl groups having 1 to 20 carbon atoms are more preferable for R³ of formula (II) and R⁵ of formula (III).

Each of the alkyl groups of R³ of formula (II) and R⁵ of formula (III) preferably has 1 to 6 carbon atoms and more preferably has 1 to 4 carbon atoms. The alkyl group of the oxoalkyl groups of R³ of formula (II) and R⁵ of formula (III) preferably has 4 to 20 carbon atoms and more preferably has 4 to 10 carbon atoms.

R⁶ of formula (i) denotes a hydrogen atom or an alkyl group. The alkyl group of R⁶ in the groups represented by formula (i) has a straight-chain, branched-chain, or cyclic structure. The alkyl group of R⁶ in the groups represented by formula (i) preferably has 1 to 10 carbon atoms. The alkyl group of R⁶ in the groups represented by formula (i) more preferably has 1 to 8 carbon atoms and yet more preferably has 1 to 6 carbon atoms.

R⁷ and R⁸ of formula (i) denote hydrogen atoms or alkyl groups. The hydrogen atoms or alkyl groups of R⁷ and R⁸ of formula (i) may be independent of each other or form a ring. The alkyl groups of R⁷ and R⁸ of formula (i) have a straight-chain, branched-chain, or cyclic structure. The alkyl groups of R⁷ and R⁸ of formula (i) preferably have 1 to 10 carbon atoms. The alkyl groups of R⁷ and R⁸ of formula (i) more preferably have 1 to 8 carbon atoms. The alkyl groups of R⁷ and R⁸ of formula (i) yet more preferably have 1 to 6 carbon atoms. Branched alkyl groups having 1 to 20 carbon atoms are preferable for R⁷ and R⁸ of formula (i).

The group represented by formula (i) includes a straight-chain or branched acetal group such as a 1-methoxyethyl group, a 1-ethoxyethyl group, a 1-n-propoxyethyl group, a 1-isopropoxyethyl group, a 1-n-butoxyethyl group, a 1-isobutoxyethyl group, a 1-sec-butoxyethyl group, a 1-tert-butoxyethyl group, a 1-tert-amyloxyethyl group, a 1-ethoxy-n-propyl group, a 1-cyclohexyloxyethyl group, a methoxypropyl group, an ethoxypropyl group, a 1-methoxy-1-methyl-ethyl group, and a 1-ethoxy-1-methyl-ethyl group; and a cyclic acetal group such as a tetrahydrofuranyl group and a tetrahydropyranyl group. The ethoxyethyl group, the butoxyethyl group, the ethoxypropyl group, and the tetrahydropyranyl group are particularly preferred among the above groups for the group represented by formula (i).

The straight-chain, branched, or cyclic alkyl groups of R³ of formula (II) and R⁵ of formula (III) include an ethyl group, a propyl group, an isopropyl group, a butyl group, an isobutyl group, a tert-butyl group, a cyclopentyl group, a cyclohexyl group, a cycloheptyl group, a triethylcarbyl group, a 1-ethylnorbornyl group, a 1-methylcyclohexyl group, an adamantyl group, a 2-(2-methyl)adamantyl group, a tert-amyl group, etc. Among above groups, the tert-butyl group is particularly preferable.

The trialkylsilyl group of R³ of formula (II) and R⁵ of formula (III) includes the alkyl groups having 1 to 6 carbon atoms such as a trimethylsilyl group, a triethylsilyl group, and a dimethyl-tert-butylsilyl group. The oxoalkyl group includes a 3-oxocyclohexyl group, etc.

Monomers giving repeating units represented by formula (II) include, for example, vinylbenzoic acid, tert-butyl vinylbenzoate, 2-methylbutyl vinylbenzoate, 2-methylpentyl vinylbenzoate, 2-ethylbutyl vinylbenzoate, 3-methylpentyl vinylbenzoate, 2-methylhexyl vinylbenzoate, 3-methylhexyl vinylbenzoate, triethylcarbyl vinylbenzoate, 1-methyl-1-cyclopentyl vinylbenzoate, 1-ethyl-1-cyclopentyl vinylbenzoate, 1-methyl-1-cyclohexyl vinylbenzoate, 1-ethyl-1-cyclohexyl vinylbenzoate, 1-methylnorbornyl vinylbenzoate, 1-ethylnorbornyl vinylbenzoate, 2-methyl-2-adamantyl vinylbenzoate, 2-ethyl-2-adamantyl vinylbenzoate, 3-hydroxy-1-adamantyl vinylbenzoate, tetrahydrofuranyl vinylbenzoate, tetrahydropyranyl vinylbenzoate, 1-methoxyethyl vinylbenzoate, 1-ethoxyethyl vinylbenzoate, 1 n-propoxyethyl vinylbenzoate, 1-isopropoxyethyl vinylbenzoate, n-butoxyethyl vinylbenzoate, 1-isobutoxyethyl vinylbenzoate, 1-sec-butoxyethyl vinylbenzoate, 1-tert-butoxyethyl vinylbenzoate, 1-tert-amyloxyethyl vinylbenzoate, 1-ethoxy-n-propyl vinylbenzoate, 1-cyclohexyloxyethyl vinylbenzoate, methoxypropyl vinylbenzoate, ethoxypropyl vinylbenzoate, 1-methoxy-1-methyl-ethyl vinylbenzoate, 1-ethoxy-1-methyl-ethyl vinylbenzoate, trimethylsilyl vinylbenzoate, triethylsilyl vinylbenzoate, dimethyl-tert-butylsilyl vinylbenzoate, α-(4-vinylbenzoyl)oxy-γ-butyrolactone, β-(4-vinylbenzoyl)oxy-γ-butyrolactone, γ-(4-vinylbenzoyl)oxy-γ-butyrolactone, α-methyl-α-(4-vinylbenzoyl)oxy-γ-butyrolactone, β-methyl-β-(4-vinylbenzoyl)oxy-γ-butyrolactone, γ-methyl-γ-(4-vinylbenzoyl)oxy-γ-butyrolactone, α-ethyl-α-(4-vinylbenzoyl)oxy-γ-butyrolactone, β-ethyl-β-(4-vinylbenzoyl)oxy-γ-butyrolactone, γ-ethyl-γ-(4-vinylbenzoyl)oxy-γ-butyrolactone, α-(4-vinylbenzoyl)oxy-δ-valerolactone, β-(4-vinylbenzoyl)oxy-δ-valerolactone, γ-(4-vinylbenzoyl)oxy-δ-valerolactone, δ-(4-vinylbenzoyl)oxy-δ-valerolactone, α-methyl-α-(4-vinylbenzoyl)oxy-δ-valerolactone, β-methyl-β-(4-vinylbenzoyl)oxy-δ-valerolactone, γ-methyl-γ-(4-vinylbenzoyl)oxy-δ-valerolactone, δ-methyl-δ-(4-vinylbenzoyl)oxy-δ-valerolactone, α-ethyl-α-(4-vinylbenzoyl)oxy-δ-valerolactone, β-ethyl-β-(4-vinylbenzoyl)oxy-δ-valerolactone, γ-ethyl-γ-(4-vinylbenzoyl)oxy-δ-valerolactone, δ-ethyl-δ-(4-vinylbenzoyl)oxy-δ-valerolactone, 1-methylcyclohexyl vinylbenzoate, adamantyl vinylbenzoate, 2-(2-methyl)adamantyl vinylbenzoate, chloroethyl vinylbenzoate, 2-hydroxyethyl vinylbenzoate, 2,2-dimethylhydroxypropyl vinylbenzoate, 5-hydroxybenzyl vinylbenzoate, trimethylolpropane vinylbenzoate, glycidyl vinylbenzoate, benzyl vinylbenzoate, phenyl vinylbenzoate, and naphthyl vinylbenzoate. Among the monomers above, 4-vinylbenzoic acid and tert-butyl 4-vinylbenzoate is preferable.

Monomers giving repeating units represented by formula (III) include, for example, acrylate, tert-butyl acrylate, 2-methylbutyl acrylate, 2-methylpentyl acrylate, 2-ethylbutyl acrylate, 3-methylpentyl acrylate, 2-methylhexyl acrylate, 3-methylhexyl acrylate, triethylcarbyl acrylate, 1-methyl-1-cyclopentyl acrylate, 1-ethyl-1-cyclopentyl acrylate, 1-methyl-1-cyclohexyl acrylate, 1-ethyl-1-cyclohexyl acrylate, 1-methylnorbornyl acrylate, 1-ethylnorbornyl acrylate, 2-methyl-2-adamantyl acrylate, 2-ethyl-2-adamantyl acrylate, 3-hydroxy-1-adamantyl acrylate, tetrahydrofuranyl acrylate, tetrahydropyranyl acrylate, 1-methoxyethyl acrylate, 1-ethoxyethyl acrylate, 1-n-propoxyethyl acrylate, 1-isopropoxyethyl acrylate, n-butoxyethyl acrylate, 1-isobutoxyethyl acrylate, 1-sec-butoxyethyl acrylate, 1-tert-butoxyethyl acrylate, 1-tert-amyloxyethyl acrylate, 1-ethoxy-n-propyl acrylate, 1-cyclohexyloxyethyl acrylate, methoxypropyl acrylate, ethoxypropyl acrylate, 1-methoxy-1-methyl-ethyl acrylate, 1-ethoxy-1-methyl-ethyl acrylate, trimethylsilyl acrylate, triethylsilyl acrylate, dimethyl-tert-butylsilyl acrylate, α-(acroyl)oxy-γ-butyrolactone, β-(acroyl)oxy-γ-butyrolactone, γ-(acroyl)oxy-γ-butyrolactone, α-methyl-α-(acroyl)oxy-γ-butyrolactone, β-methyl-β-(acroyl)oxy-γ-butyrolactone, γ-methyl-γ-(acroyl)oxy-γ-butyrolactone, α-ethyl-α-(acroyl)oxy-γ-butyrolactone, β-ethyl-β-(acroyl)oxy-γ-butyrolactone, γ-ethyl-γ-(acroyl)oxy-γ-butyrolactone, α-(acroyl)oxy-δ-valerolactone, β-(acroyl)oxy-δ-valerolactone, γ-(acroyl)oxy-δ-valerolactone, δ-(acroyl)oxy-δ-valerolactone, α-methyl-α-(4-vinylbenzoyl)oxy-δ-valerolactone, β-methyl-β-(acroyl)oxy-δ-valerolactone, γ-methyl-γ-(acroyl)oxy-δ-valerolactone, δ-methyl-δ-(acroyl)oxy-δ-valerolactone, α-ethyl-α-(acroyl)oxy-δ-valerolactone, β-ethyl-β-(acroyl)oxy-δ-valerolactone, γ-ethyl-γ-(acroyl)oxy-δ-valerolactone, δ-ethyl-δ-(acroyl)oxy-δ-valerolactone, 1-methylcyclohexyl acrylate, adamantyl acrylate, 2-(2-methyl)adamantyl acrylate, chloroethyl acrylate, 2-hydroxyethyl acrylate, 2,2-dimethylhydroxypropyl acrylate, 5-hydroxybenzyl acrylate, trimethylolpropane acrylate, glycidyl acrylate, benzyl acrylate, phenyl acrylate, naphthyl acrylate, methacrylic acid, tert-butyl methacrylate, 2-methylbutyl methacrylate, 2-methylpentyl methacrylate, 2-ethylbutyl methacrylate, 3-methylpentyl methacrylate, 2-methylhexyl methacrylate, 3-methylhexyl methacrylate, triethylcarbyl methacrylate, 1-methyl-1-cyclopentyl methacrylate, 1-ethyl-1-cyclopentyl methacrylate, 1-methyl-1-cyclohexyl methacrylate, 1-ethyl-1-cyclohexyl methacrylate, 1-methylnorbornyl methacrylate, 1-ethylnorbornyl methacrylate, 2-methyl-2-adamantyl methacrylate, 2-ethyl-2-adamantyl methacrylate, 3-hydroxy-1-adamantyl methacrylate, tetrahydrofuranyl methacrylate, tetrahydropyranyl methacrylate, 1-methoxyethyl methacrylate, 1-ethoxyethyl methacrylate, 1-n-propoxyethyl methacrylate, 1-isopropoxyethyl methacrylate, n-butoxyethyl methacrylate, 1-isobutoxyethyl methacrylate, 1-sec-butoxyethyl methacrylate, 1-tert-butoxyethyl methacrylate, 1-tert-amyloxyethyl methacrylate, 1-ethoxy-n-propyl methacrylate, 1-cyclohexyloxyethyl methacrylate, methoxypropyl methacrylate, ethoxypropyl methacrylate, 1-methoxy-1-methyl-ethyl methacrylate, 1-ethoxy-1-methyl-ethyl methacrylate, trimethylsilyl methacrylate, triethylsilyl methacrylate, dimethyl-tert-butylsilyl methacrylate, α-(methacroyl) oxy-γ-butyrolactone, β-(methacroyl)oxy-γ-butyrolactone, γ-(methacroyl)oxy-γ-butyrolactone, α-methyl-α-(methacroyl)oxy-γ-butyrolactone, β-methyl-β-(methacroyl)oxy-γ-butyrolactone, γ-methyl-γ-(methacroyl)oxy-γ-butyrolactone, α-ethyl-α-(methacroyl)oxy-γ-butyrolactone, β-ethyl-β-(methacroyl)oxy-γ-butyrolactone, γ-ethyl-γ-(methacroyl)oxy-γ-butyrolactone, α-(methacroyl)oxy-δ-valerolactone, β-(methacroyl)oxy-δ-valerolactone, γ-(methacroyl)oxy-δ-valerolactone, δ-(methacroyl)oxy-δ-valerolactone, α-methyl-α-(4-vinylbenzoyl)oxy-δ-valerolactone, β-methyl-β-(methacroyl)oxy-δ-valerolactone, γ-methyl-γ-(methacroyl)oxy-δ-valerolactone, δ-methyl-δ-(methacroyl)oxy-δ-valerolactone, α-ethyl-α-(methacroyl)oxy-δ-valerolactone, β-ethyl-β-(methacroyl)oxy-δ-valerolactone, γ-ethyl-γ-(methacroyl)oxy-δ-valerolactone, δ-ethyl-δ-(methacroyl)oxy-δ-valerolactone, 1-methylcyclohexyl methacrylate, adamantyl methacrylate, 2-(2-methyl)adamantyl methacrylate, chloroethyl methacrylate, 2-hydroxyethyl methacrylate, 2,2-dimethylhydroxypropyl methacrylate, 5-hydroxybenzyl methacrylate, trimethylolpropane methacrylate, glycidyl methacrylate, benzyl methacrylate, phenyl methacrylate, and naphthyl methacrylate. Among these, acrylate and tert-butyl acrylate are preferable.

In addition to the monomers giving repeating units represented by formula (II) and formula (III), the monomer constituting the shell portion may be any monomers having a structure with a radically polymerizable unsaturated bond.

In addition to the styrenes above, usable comonomers include compounds having a radically polymerizable unsaturated bond and may be selected from among allyl compounds, vinyl ethers, vinyl esters, crotonates, etc.

Specifically, in addition to styrenes cited as comonomers usable as a monomer constituting the shell portion include, for example, styrene, tert-butoxystyrene, α-methyl-tert-butoxystyrene, 4-(1-methoxyethoxy)styrene, 4-(1-ethoxyethoxy)styrene, tetrahydropyranyloxystyrene, adamantyloxystyrene, 4-(2-methyl-2-adamantyloxy)styrene, 4-(1-methylcyclohexyloxy)styrene, trimethylsilyloxystyrene, dimethyl-tert-butylsilyloxystyrene, tetrahydropyranyloxystyrene, benzylstyrene, trifluoromethylstyrene, acetoxystyrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, 4-fluoro-3-trifluoromethylstyrene, and vinylnaphthalene.

Specifically, allyl esters cited above as comonomers usable as a monomer constituting the shell portion include, for example, allyl acetate, allyl caproate, allyl caprylate, allyl laurate, allyl palmitate, allyl stearate, allyl benzoate, allyl acetoacetate, allyl lactate, and allyloxyethanol.

Specifically, vinyl ethers cited as comonomers usable as a monomer constituting the shell portion include, for example, hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether, tetrahydrofurfuryl vinyl ether, vinylphenyl vinyl ether, vinyl tolyl ether, vinyl chlorophenyl ether, vinyl-2,4-dichlorophenyl ether, vinyl naphthyl ether, and vinyl anthranyl ether.

Specifically, vinylesters cited as comonomers usable as a monomer constituting the shell portion include, for example, vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl-β-phenylbutyrate, and vinyl cyclohexylcarboxylate.

Specifically, crotonates cited as comonomers usable as a monomer constituting the shell portion include, for example, butyl crotonate, hexyl crotonate, glycerin monocrotonate, dimethyl itaconate, diethyl itaconate, dibutyl itaconate, dimethyl maleate, dibutyl fumarate, maleic anhydride, maleimide, acrylonitrile, methacrylonitrile, and maleilonitrile.

Specifically, comonomers usable as a monomer constituting the shell portion also include, for example, formulas (IV) to (XIII) described in chapter 1.

Among comonomers usable as monomer constituting the shell portion, styrenes and crotonates are preferable. Among comonomers usable as monomer constituting the shell portion, styrene, benzylstyrene, chlorostyrene, vinylnaphthalene, butyl crotonate, hexyl crotonate, and maleic anhydride are preferable.

In the hyperbranched polymer, at least monomer giving a repeating unit represented by formula (II) or monomer giving a repeating unit represented by formula (III) is preferably 10 to 90 mol % relative to the total charging amount of monomer used for the synthesis of the hyperbranched polymer at the time of charging. Monomer giving the above repeating units may more preferably be included at 20 to 90 mol % relative to the total charging amount of monomer used for the synthesis of the hyperbranched polymer at the time of charging.

Monomer giving the above repeating units is further preferably included at 30 to 90 mol % relative to the total charging amount of monomer used for the synthesis of the hyperbranched polymer at the time of charging. Particularly, it is preferred that the repeating unit represented by formula (II) or the repeating unit represented by formula (III) be included in the shell portion at 50 to 100 mol %, preferably at 80 to 100 mol % relative to the total charging amount of monomer used for the synthesis of the hyperbranched polymer at the time of charging. When monomer giving the above repeating units is at the above ranges relative to the total charging amount of monomer used for the synthesis of the hyperbranched polymer at the time of charging, this is preferable since an exposed portion is efficiently dissolved into alkaline solution and removed at a development step of lithography using a resist composition containing the hyperbranched polymer.

If the shell portion of the core-shell hyperbranched polymer is a polymerized product of monomer giving a repeating unit represented by formula (II) or monomer giving a repeating unit represented by formula (III) and other monomer, the amount of monomer giving a repeating unit represented by formula (II) and/or the amount of monomer giving a repeating unit represented by formula (III) preferably accounts for 30 to 90 mol %, more preferably 50 to 70 mol % relative to the total amount of monomer constituting the shell portion.

If at least monomer giving a repeating unit represented by formula (II) or monomer giving a repeating unit represented by formula (III) is at the above ranges relative to the total amount of monomer constituting the shell portion, functions such as increases in the etching resistance, wetting properties, and glass transition temperature are preferably induced without inhibiting efficient alkali solubility of the exposed portion. According to purpose, the ratio of the repeating units represented by formula (II) and/or the repeating units represented by formula (III) to other repeating units in the shell portion may be adjusted by the charging amount (molar ratio) at the time of introduction of the shell portion.

If the shell portion is polymerized with the hyperbranched core polymer (shell polymerization), the polymerization is preferably performed in the presence of or in the flow of nitrogen or inert gas or in the absence of oxygen to prevent oxygen from affecting radicals. The shell polymerization may be applied to both a batch method and a continuous method. The shell polymerization may continuously be performed after the above core polymerization or may be performed by removing the catalyst and monomers and adding a catalyst again after the above core polymerization. The shell polymerization may be performed after drying the hyperbranched core polymer synthesized by the core polymerization.

The shell polymerization is performed in the presence of a metal catalyst. The same metal catalyst as the metal catalyst used for the above core polymerization may be used for the shell polymerization. In the shell polymerization, for example, the metal catalyst is preliminarily provided in a reaction system for the shell polymerization before starting the shell polymerization, and the hyperbranched core polymer synthesized by the core polymerization and the monomer constituting the shell portion are dropped into the reaction system. Specifically, for example, the metal catalyst is preliminarily provided on the inner surface of a furnace for the reaction, and the hyperbranched core polymer and the monomer are dropped into the furnace for the reaction. Specifically, for example, the above monomer constituting the shell portion may be dropped into the furnace for the reaction where the metal catalyst and the hyperbranched core polymer have been injected in advance. The monomer, the metal catalyst, and the solvent used in the shell polymerization are preferably deoxygenated(degassed) sufficiently as is the case with the core polymerization.

Metal catalyst used when synthesizing the shell polymer includes a metal catalyst consisting of a combination of a transition metal compound such as copper, iron, ruthenium, and chromium, and a ligand, for example. The transition metal compound includes, for example, cuprous chloride, cuprous bromide, cuprous iodide, cuprous cyanide, cuprous oxide, cuprous perchlorate, ferrous chloride, ferrous bromide, and ferrous iodide.

The ligand includes pyridines, bipyridines, polyamines, phosphines, etc., not substituted or substituted by an alkyl group, an aryl group, an amino group, a halogen group, an ester group, etc. A preferred metal catalyst may be, for example, a copper(I) bipyridyl complex and a copper(I) pentamethyldiethylenetriamine complex constituted by copper chloride and a ligand, an iron(II) triphenylphosphine complex and an iron(II) tributylamine complex constituted by iron chloride and a ligand, etc.

The amount of metal catalyst used is preferably 0.01 to 70 mol %, more preferably 0.1 to 60 mol % relative to the reaction active sites of the hyperbranched core polymer used in the shell polymerization. If the catalyst is used at such ranges, the reactivity may be improved to synthesize a core/shell hyperbranched polymer having a preferred branching degree.

If the amount of metal catalyst used is less than the above ranges, the reactivity is considerably reduced and the polymerization may not progress. On the other hand, if the amount of metal catalyst exceeds the above ranges, since the polymerization reaction becomes excessively active, a coupling reaction tends to occur between radicals at the growth ends and the polymerization tends to become difficult to control. If the amount of metal catalyst exceeds the above ranges, the coupling reaction between radicals triggers gelation of the reaction system.

The metal catalyst may be made into a complex compound by mixing the above transition metal compound and the ligand in an apparatus. The metal catalyst consisting of the transition metal compound and the ligand may be added in a state of an active complex to the apparatus. The transition metal compound and the ligand may be mixed in the apparatus to form a complex, thereby simplifying the synthesis operation of the hyperbranched polymer.

The method of adding the metal catalyst is not particularly limited and, for example, the metal catalyst may be added at one time before the shell polymerization. Alternatively, after the polymerization starts, additional metal catalyst may be added depending on the level of deactivation of the catalyst. For example, if the distribution of the complex acting as the metal catalyst is not uniform in the reaction system, the transition metal compound may preliminarily be added into the apparatus and only the ligand may be added afterward.

In the presence of the above metal catalyst, the shell polymerization reaction is preferably performed in a solvent although the reaction can occur in the absence of solvent. The solvent used for the shell polymerization reaction in the presence of the metal catalyst is not particularly limited and includes, for example, a hydrocarbon solvent such as benzene and toluene, an ether solvent such as diethyl ether, tetrahydrofuran, diphenyl ether, anisole, and dimethoxybenzene, a halogenated hydrocarbon solvent such as methylene chloride, chloroform, and chlorobenzene, a ketone solvent such as acetone, methyl ethyl ketone, and methyl isobutyl ketone, an alcohol solvent such as methanol, ethanol, propanol, and isopropanol, a nitrile solvent such as acetonitrile, propionitrile, and benzonitrile, an ester solvent such as ethyl acetate and butyl acetate, a carbonate solvent such as ethylene carbonate and propylene carbonate, and an amide solvent such as N,N-dimethylformamide and N,N-dimethylacetamide. These solvents may independently be used or two or more of the solvents may concurrently be used.

In the shell polymerization, the shell polymerization is preferably performed in the presence of or in the flow of nitrogen or inert gas or in the absence of oxygen to prevent oxygen from affecting radicals. The shell polymerization may be applied to both the batch method and the continuous method.

An additive may be used for the shell polymerization. In the shell polymerization, at least one of the compounds represented by the above formula (1-1) or (1-2) described in the first chapter may be added.

R₁ of formula (1-1) denotes hydrogen, an alkyl group having 1 to 10 carbon atoms, an aryl group having 6 to 10 carbon atoms, or an aralkyl group having 7 to 10 carbon atoms. More particularly, R₁ of formula (1-1) represents hydrogen, an alkyl group having 1 to 10 carbon atoms, an aryl group having 6 to 10 carbon atoms, or an aralkyl group having 7 to 10 carbon atoms. A of formula (1-1) denotes a cyano group, a hydroxyl group, or a nitro group. The compounds represented by formula (1-1) include nitriles, alcohols, and nitro compounds, for example.

Specifically, nitriles included in the compounds represented by formula (1-1) are, for example, acetonitrile, propionitrile, butyronitrile, and benzonitrile. Specifically, alcohols included in the compounds represented by formula (1-1) are, for example, methanol, ethanol, 1-propanol, 2-propanol, 1-butanol, cyclohexyl alcohol, and benzyl alcohol. Specifically, nitro compounds included in the compounds represented by formula (1-1) are, for example, nitromethane, nitroethane, nitropropane, and nitrobenzene. The compounds represented by formula (1-1) are not limited to the above compounds.

R₂ and R₃ of formula (1-2) denote hydrogen, alkyl groups having 1 to 10 carbon atoms, aryl groups having 6 to 10 carbon atoms, aralkyl groups having 7 to 10 carbon atoms, or dialkylamide groups having 1 to 10 carbon atoms and B denotes a carbonyl group or a sulfonyl group. R₂ and R₃ of formula (1-2) may be the same or different.

The compounds represented by formula (1-2) include ketones, sulfoxides, and alkylformamide compounds, for example. Specifically, ketones include, for example, acetone, 2-butanone, 2-pentanone, 3-pentanone, 2-hexanone, cyclohexanone, 2-methylcyclohexanone, acetophenone, and 2-methylacetophenone.

Specifically, sulfoxides included in the compounds represented by formula (1-2) are, for example, dimethyl sulfoxide and diethyl sulfoxide. Specifically, alkylformamide compounds included in the compounds represented by formula (1-2) are, for example, N,N-dimethylformamide, N,N-diethylformamide, and N,N-dibutylformamide. The compounds represented by formula (1-2) are not limited to the above compounds. The compounds represented by formula (1-1) or formula (1-2) are preferably nitriles, nitro compounds, sulfoxides, ketones, and alkylformamide compounds, and more preferably, acetonitrile, propionitrile, benzonitrile, nitroethane, nitropropane, dimethyl sulfoxide, acetone, and N,N-dimethylformamide.

In the shell polymerization, the compounds represented by formula (1-1) or formula (1-2) may be used independently or two or more of the compounds may be used in combination.

In the shell polymerization, the compounds represented by formula (1-1) or formula (1-2) may be used independently or two or more of the compounds may be used in combination as a solvent.

The amount of the compounds represented by formula (1-1) or formula (1-2) to be added in the shell polymerization is preferably 2 times to 10000 times the amount of the transition metal in the above metal catalyst by molar ratio. The amount of the compounds represented by formula (1-1) or formula (1-2) to be added is more preferably 3 times to 7000 times and yet more preferably 4 times to 5000 times the amount of the transition metal in the above metal catalyst by molar ratio.

If the added amount of the compounds represented by formula (1-1) or formula (1-2) is too small, the rapid increase in the molecular weight may not be controlled sufficiently. On the other hand, if the added amount of the compounds represented by formula (1-1) or formula (1-2) is too large, the reaction rate is slowed and the reaction time can be prolonged.

By performing the shell polymerization as described above, the gelation can be efficiently prevented regardless of the concentration of the hyperbranched core polymer. The concentration of the hyperbranched core polymer in the shell polymerization is preferably 0.1 to 30 mass %, more preferably 1 to 20 mass % relative to the total reaction amount including the hyperbranched core polymer and the monomer at the time of charging.

The concentration of the monomer in the shell polymerization is preferably 0.5 to 20 mole equivalents based on the reaction active sites of the hyperbranched core polymer. The concentration of the monomer in the shell polymerization is more preferably 1 to 15 mole equivalents based on the reaction active sites of the hyperbranched core polymer. The core/shell ratio can be controlled by appropriately controlling the monomer amount relative to the reaction active sites of the hyperbranched core polymer.

The polymerization time for the shell polymerization is preferably 0.1 to 30 hours, more preferably 0.1 to 10 hours, particularly preferably 1 to 10 hours depending on the molecular weight of the polymerized product. The reaction temperature for the shell polymerization is preferably 0 to 200 degrees C. The reaction temperature for the shell polymerization is more preferably 50 to 150 degrees C. If the polymerization is caused at a temperature higher than the boiling point of the solvent to be used, the pressure may be increased within an autoclave, for example.

In the shell polymerization, the reaction system is uniformly distributed. For example, the reaction system is uniformly distributed by agitating the reaction system. The specific agitation condition of the shell polymerization is preferably that the power necessary for agitation per unit volume is set as 0.01 kW/m³ or more, for example.

In the shell polymerization, a catalyst may be added or a reducing agent regenerating the catalyst may be added depending on the progress in the polymerization and the level of deactivation of the catalyst. The shell polymerization is terminated when the shell polymerization attains the set molecular weight. A method of terminating the shell polymerization is not particularly limited and, for example, a method such as cooling-down or deactivating the catalyst with the addition of an oxidizing agent or a chelating agent may be used.

The synthesis of the core-shell hyperbranched polymer includes removal of the metal catalyst, removal of the monomer, and removal of trace metal performed after the shell polymerization. The metal catalyst is removed after the shell polymerization is terminated. A method of removing the metal catalyst may be performed, for example, with one or a combination of the following methods (a) to (c):

(a) using various absorbents such as Kyoward manufactured by Kyowa Chemical Industry Co., Ltd;

(b) removing insoluble substances by filtration or centrifugation; and

(c) extraction with aqueous solution containing an acid and/or a substance having a chelating effect.

The acid used in the case of the method (c) includes, for example, p-toluenesulfonic acid, acetic acid, trifluoroacetic acid, trifluoromethanesulfonic acid, formic acid, hydrochloric acid, and sulfuric acid. The substances having a chelating effect include, for example, organic carboxylic acid such as oxalic acid, citric acid, gluconic acid, tartaric acid, and malonic acid; amino carbonate such as nitrilotriacetic acid, ethylenediaminetetraacetic acid, and diethylenetriaminopentaacetic acid, and hydroxyamino carbonate. The concentration of the acid in aqueous solution varies depending on the kind of acid and is preferably 0.03 mass % to 20 mass %. The concentration of the substance having chelating ability in aqueous solution varies depending on the chelating ability of the compound and is preferably 0.05 mass % to 10 mass %, for example. The acid and the substance having chelating ability may be used separately or in combination.

The removal of the monomer may be performed after the above removal of the metal catalyst or after removal of trace metal (“metal cleaning” in the present specification) following the removal of the metal catalyst is performed. In the removal of the monomer, among the monomer dropped at the time of the core polymerization and the shell polymerization described above, the unreacted monomer is removed. A method of removing the unreacted monomer may be performed, for example, with one or a combination of the following methods (d) to (e):

(d) adding a poor solvent to a reaction product dissolved in a good solvent to precipitate the polymer; and

(e) washing the polymer with a mixed solvent of a good solvent and a poor solvent.

In (d) to (e) above, the good solvent includes, for example, hydrocarbon, halogenated hydrocarbon, nitro compound, nitrile, ether, ketone, ester, carbonate, or a mixed solvent containing these solvents. Specifically, for example, tetrahydrofuran, toluene, xylene chlorobenzene, and chloroform are included. The poor solvent includes, for example, methanol, ethanol, 1-propanol, 2-propanol, water, or a solvent obtained by combining these solvents.

As described above, after the monomer is removed, the drying is performed. The drying may be performed after the removal of the trace metal following the removal of the monomer. In the embodiment, this implements a drying step. The drying method is not particularly limited and includes, for example, drying methods such as vacuum drying and spray drying. In the drying, a temperature of the hyperbranched polymer after the removal of the monomer and an environment including the hyperbranched polymer (hereinafter, “drying temperature”) is preferably set at 10 to 70 degrees C. In the drying, the drying temperature is more preferably set at 15 to 40 degrees C.

In the drying, the environment including the hyperbranched polymer after the removal of the monomer is preferably vacuumed. The degree of vacuum for the drying is preferably 20 Pa or less. The drying time is preferably 1 to 20 hours and more preferably, 1 to 12 hours. The degree of vacuum and the drying time for the drying are not limited to the above values and set such that the above drying temperature is appropriately maintained.

In the synthesis of the core-shell hyperbranched polymer, trace amounts of residual metal in the polymer are removed after the removal of the metal catalyst and monomer as described above. This may be performed, for example, with one or a combination of the following methods (f) to (g):

(f) performing the liquid-liquid extraction with aqueous solution of an organic compound having chelating ability, an acidic aqueous solution and/or pure water; and

(g) using an absorbent and an ion-exchange resin.

The organic solvent used in the liquid-liquid extraction of (f) preferably includes, for example, halogenated hydrocarbon such as chlorobenzene and chloroform; acetic esters such as ethyl acetate, n-butyl acetate, and isoamyl acetate; ketones such as methyl ethyl ketone, methyl isobutyl ketone, cyclohexanone, 2-heptane, and 2-pentanone; glycol ether acetates such as ethylene glycol monoethyl ether acetate, ethylene glycol monobutyl ether acetate, and ethylene glycol monomethyl ether acetate; and aromatic hydrocarbons such as toluene and xylene.

More preferably, the organic solvent used in the liquid-liquid extraction of (f) includes, for example, chloroform, methyl isobutyl ketone, and ethyl acetate. These solvents may independently be used or two or more of the solvents may be mixed and used. In the liquid-liquid extraction in the case of (f) above, mass % of the core-shell hyperbranched polymer based on the organic solvent is preferably about 1 to 30 mass %. Mass % of the core-shell hyperbranched polymer based on the organic solvent is more preferably about 5 to 20 mass %.

The organic compound having chelating ability used in the liquid-liquid extraction in the case of (f) above preferably includes, for example, organic carboxylic acid such as formic acid, acetic acid, oxalic acid, citric acid, gluconic acid, tartaric acid, and malonic acid, amino carbonate such as nitrilotriacetic acid, ethylenediaminetetraacetic acid, and diethylenetriaminopentaacetic acid, and hydroxyamino carbonate. The inorganic acid used in the liquid-liquid extraction of (f) preferably includes, for example, formic acid, acetic acid, phosphoric acid, hydrochloric acid, and sulfuric acid.

In the liquid-liquid extraction in the case of (f) above, the concentrations of the organic compound having chelating ability and the inorganic acid in aqueous solution are preferably about 0.05 to 10 mass %.

In the removal of metal catalyst, if the aqueous solution of the organic compound having chelating ability is used, the aqueous solution of the organic compound having chelating ability and an acidic aqueous solution may be mixed and used or the aqueous solution of the organic compound having chelating ability and the acidic aqueous solution may be used separately. If the aqueous solution of the organic compound having chelating ability and the inorganic acid aqueous solution are used separately, either the aqueous solution of the organic compound having chelating ability or the inorganic acid aqueous solution may be used first.

In the removal of metal, if the aqueous solution of the organic compound having chelating ability and the acidic aqueous solution are used separately, it is more preferable to use the acidic aqueous solution in the latter half. This is because the aqueous solution of the organic compound having chelating ability is effective in the removal of a copper catalyst and polyvalent metal; and the acidic aqueous solution is effective in removal of monovalent metal derived from experimental instruments, etc.

Although the number of times extractions is not particularly limited, it is desirable to perform the extraction two to five times, for example. Especially, the experimental instruments used with copper ion reduced are preferably used after preliminary washing to prevent metal derived from the experimental instruments, etc., from being mixed. A method of the preliminary washing is not particularly limited and includes, for example, washing with nitric acid aqueous solution.

The number of times of the washing only with the acid aqueous solution is preferably one to five. By performing the washing with the acid aqueous solution one to five times, monovalent metal can be removed sufficiently. To remove residual acid components, it is preferable to perform the extraction process with pure water lastly to completely remove acid. The number of washings with the pure water is preferably one to five. By performing the washing with the pure water 1 to 5 times, the remaining acid can be removed sufficiently.

In the removal of trace metal, a rate of a core-shell hyperbranched polymer solution to each of the aqueous solution of the organic compound having chelating ability, the acid aqueous solution, and/or pure water is preferably 1:0.1 to 1:10 by volume. The rate is more preferably 1:0.5 to 1:5 by volume. By using the solvent at such a rate for the washing, the metal can be removed easily by an appropriate number of times. This enables the facilitation of the operation and the simplification of the operation and is preferred for the efficient synthesis of the hyperbranched polymer. It is preferable that the concentration by mass of a resist polymer intermediate dissolved in the reaction solvent is normally approximately 1 to 30 mass % relative to the solvent.

The liquid-liquid extraction process of (f) is performed, for example, by separating a mixed solvent of the aqueous solution of the organic compound having chelating ability, the inorganic acid aqueous solution, and the pure water (hereinafter, simply “mixed solvent”) into two layers and removing a water layer with migrated metal ions through decantation, etc.

A method of separating the mixed solvent into two layers is performed, for example, by adding the aqueous solution of the organic compound having chelating ability, the inorganic acid aqueous solution, and the pure water to the reaction solvent, sufficiently mixing the solvent with agitation, etc., and keeping still. For example, a centrifugal separation method may be used for the method of separating the mixed solvent into two layers.

The liquid-liquid extraction process of (f) is performed, for example, preferably at 10 to 50 degrees C. and more preferably at 20 to 40 degrees C.

In the synthesis of the core-shell hyperbranched polymer, after the removal of metal, the deprotection is performed. In the deprotection, a portion of the acid-degradable group is degraded into an acid group (acid-degradable group is induced) with the use of the acid catalyst. In the partial degradation of the acid-degradable group, 0.001 to 0.1 equivalents of the acid catalyst are normally used for the acid-degradable group in the core-shell hyperbranched polymer. In the partial degradation of the acid-degradable group, a substance dissolving uniformly with the hyperbranched polymer after the removal of the trace metal above and the organic solvent dissolving the hyperbranched polymer is used as the acid catalyst.

Specifically, the acid catalyst used for the deprotection preferably includes, for example, hydrochloric acid, sulfuric acid, p-Toluenesulfonic acid, acetic acid, and trifluoroacetic acid, and trifluoromethanesulfonic acid. Among various acid catalysts above, hydrochloric acid and sulfuric acid are more preferable because of favorable reactivity and sulfuric acid is more preferable since sulfuric acid has no possibility of vaporization when heated and refluxed, and dissolves uniformly with the hyperbranched polymer after the removal of the trace metal above and the organic solvent dissolving the hyperbranched polymer, regardless of temperature.

The organic solvent used for the deprotection is preferably capable of dissolving the hyperbranched polymer and the acid catalyst and has the compatibility with water regardless of temperature. The organic solvent used for the deprotection is preferably selected from a group consisting of 1,4-dioxane, tetrahydrofuran, methyl ethyl ketone, methyl isobutyl ketone, diethyl ketone, and a mixture thereof because of availability and manageability. Among various organic solvents above, the organic solvent used for the deprotection is preferably dioxane since dioxane enables high-temperature reflux at 90 degrees C. or greater and has high compatibility with water.

In the synthesis of the hyperbranched polymer, the reflux at high temperature is critical for making the best use of the effect of acid and efficiently perform the acid degradation. The compatibility with water is a critical factor of the organic solvent used for the synthesis of the hyperbranched polymer when the reprecipitation operation is performed by adding an excessive amount of water to the organic solvent after the acid degradation.

The amount of the organic solvent used for the deprotection is not particularly limited if the core-shell hyperbranched polymer with the metal removed and the acid catalyst are dissolved and is preferably 3 to 50 times by mass, more preferably 5 to 20 times by mass based on the polymer with the metal removed, for example.

If the amount of the organic solvent relative to the core-shell hyperbranched polymer with the metal removed is less than the above ranges, the viscosity of the reaction system is increased and the handling becomes poor. On the other hand, if an amount of the organic solvent relative to the core-shell hyperbranched polymer with the metal removed exceeds the above ranges, the cost of the synthesis tends to increase and this is not preferable from the viewpoint of the cost increase.

The concentration of the core-shell hyperbranched polymer with the metal removed in the organic solvent used for the deprotection is preferably lower than the saturated concentration of the core-shell hyperbranched polymer at a room temperature (25 degrees C.) and set to the highest concentration of those satisfying the concentration condition that the viscosity does not markedly increase or effect the agitation when heated for the reaction. The reaction temperature for the deprotection is preferably 50 to 150 degrees C., more preferably 70 to 110 degrees C. The reaction time for the deprotection is preferably 10 minutes to 20 hours, more preferably 10 minutes to 3 hours.

A rate of the acid-degradable group and the acid group in the deprotected core-shell hyperbranched polymer is preferably defined such that 5 to 80 mol % of the monomer containing the acid-degradable group introduced into the core-shell hyperbranched polymer is deprotected and converted to the acid group. The rate of the acid-degradable group and the acid group at such a range is preferable since the higher sensitivity and efficient alkali solubility after exposure are achieved.

The rates of the acid-degradable group and the acid group in the core-shell hyperbranched polymer after the deprotection has an optimum value that varies depending on the rate of composition of the resist composition when the core-shell hyperbranched polymer is utilized as the resist composition and is not particularly limited to the above range. The rates of the acid-degradable group and the acid group in the core-shell hyperbranched polymer after the deprotection may be adjusted by controlling the reaction time.

Although the rates of the acid-degradable group and the acid group in the hyperbranched polymer after the deprotection can be adjusted by controlling the reaction temperature and the reaction time for the deprotection as needed, the rate can be most easily adjusted by controlling the reaction time.

After the deprotection, the reaction liquid containing the deprotected core-shell hyperbranched polymer is mixed with ultrapure water to precipitate the deprotected core-shell hyperbranched polymer and is subjected to, for example, centrifugal separation, filtration, and decantation to separate the polymer. To remove the residual acid catalyst, the polymer is preferably brought into contact and washed with an organic solvent and water as needed.

The above drying may be performed before the shell polymerization when a polymer polymerized in the core polymerization (hyperbranched core polymer) is acquired. By performing the drying between the core polymerization and the shell polymerization, the polymer (hyperbranched core polymer) can be supplied to the shell polymerization while gelation is prevented, ensuring prevention of the gelation in the shell polymerization with certainty.

The above drying may be performed after the acid-degradable group is partially degraded, ensuring prevention of the gelation of the core-shell hyperbranched polymer which is the above hyperbranched polymer provided with the shell portion consisting of the acid-degradable group and the acid group.

### (Molecular Structure)

A molecular structure of the core-shell hyperbranched polymer will be described. The branching degree (Br) of the core portion in the core-shell hyperbranched polymer is preferably 0.3 to 0.5, more preferably 0.4 to 0.5, and the branching degree (Br) of the core portion in the core-shell hyperbranched polymer at the above ranges is preferable since the entwining of the polymer molecules is reduced and surface roughness is prevented on pattern side walls.

The branching degree (Br) of the hyperbranched core polymer in the core-shell hyperbranched polymer may be obtained by measuring ¹H-NMR of the product as follows. For example, if chloromethylstyrene is used as the monomer used for the synthesis of the hyperbranched core polymer, the branching degree (Br) may be calculated by carrying out an operation of the following equation (A) using an integration ratio H1° of proton of a —CH₂Cl site appearing at 4.6 ppm and an integration ratio H2° of proton of a —CHCl site appearing at 4.8 ppm. If the polymerization proceeds at both the —CH₂Cl site and the —CHCl site and the branching is enhanced, the value of the branching degree (Br) approaches 0.5.

A weight-average molecular weight (Mw) of the hyperbranched core polymer is preferably 300 to 8,000, also preferably 5000 to 6,000, and most preferably 1,000 to 4,000. The weight-average molecular weight (Mw) of the hyperbranched core polymer at such a range is preferable since solubility into the reaction solvent can be ensured in the acid-degradable group introducing reaction. This is also preferable since an excellent film forming property is achieved and the dissolution of unexposed portions is advantageously prevented in the core-shell hyperbranched polymer with the acid-degradable group partially degraded (the acid-degradable group induced) after the acid-degradable group is introduced into the hyperbranched core polymer at the above molecular weight ranges.

A polydispersity (Mw/Mn) of the hyperbranched core polymer is preferably 1 to 3 and more preferably 1 to 2.5. The polydispersity (Mw/Mn) of the hyperbranched core polymer at such a range is desirable since adverse effects such as insolubilization of the core/shell hyperbranched polymer are not caused after exposure if the core-shell hyperbranched polymer synthesized with the use of the hyperbranched core polymer is used for the resist composition.

A weight-average molecular weight (M) of the core-shell hyperbranched polymer is preferably 500 to 21,000, more preferably 2,000 to 21,000, and most preferably 3,000 to 21,000. If the weight-average molecular weight (M) of the core-shell hyperbranched polymer is at the above ranges, a resist containing the hyperbranched polymer has a favorable film forming property and may keep a shape since a process pattern formed at a lithography step is strong. The resist composition containing the core-shell hyperbranched polymer has an excellent dry etching resistance and favorable surface roughness.

The weight-average molecular weight (Mw) of the hyperbranched core polymer can be obtained by preparing a 0.5-mass % tetrahydrofuran solution and performing the GPC measurement at a temperature of 40 degrees C. Tetrahydrofuran may be used as a mobile solvent and styrene may be used as a standard substance.

The weight-average molecular weight (M) of the core-shell hyperbranched polymer can be obtained by using ¹H-NMR to obtain introduction rates (component ratios) of the repeating units of the polymer with the acid-degradable group introduced and performing a calculation using the introduction rates of the constituent units and the molecular weights of the constituent units based on the weight-average molecular weight (Mw) of the core portion of the core-shell hyperbranched polymer.

The core-shell hyperbranched polymer synthesized described above is used for a resist composition, for example. In the resist composition using the core-shell hyperbranched polymer (hereinafter, simply “resist composition”), a compounding amount of the core-shell hyperbranched polymer is preferably 4 to 40 weight %, more preferably 4 to 20 weight % relative to total amount of the resist composition.

The resist composition contains the above core-shell hyperbranched polymer and a photoacid generator. The resist composition may also contain an acid diffusion inhibitor (acid trapping agent), a surfactant, other components, a solvent, etc., as needed.

The photoacid generator included in the resist composition is not particularly limited as long as an acid is generated, for example, when ultraviolet light, X-ray, electron ray, etc., are applied, and may be appropriately selected from known various photoacid generators according to the purpose. Specifically, the photoacid generator includes, for example, onium salts, sulfonium salts, halogen-containing triazine compounds, sulfone compounds, sulfonate compounds, aromatic sulfonate compounds, and sulfonate compounds of N-hydroxyimide.

Onium salts included in the above photoacid generator include, for example, diaryliodonium salts, triarylselenonium salts, and triarylsulfonium salts. The diaryliodonium salts include, for example, diphenyliodonium trifluoromethanesulfonate, 4-methoxyphenylphenyliodonium hexafluoroantimonate, 4-methoxyphenylphenyliodonium trifluoromethanesulfonate, bis(4-tert-butylphenyl)iodonium tetrafluoroborate, bis(4-tert-butylphenyl)iodonium hexafluorophosphate, bis(4-tert-butylphenyl)iodonium hexafluoroantimonate, and bis(4-tert-butylphenyl)iodonium trifluoromethanesulfonate.

Specifically, triarylselenonium salts included in the above onium salts include, for example, a triphenylselenoniumhexafluorophosphonium salt, a triphenylselenoniumfluoroboric salt, and a triphenylselenoniumhexafluoroantimonate salt. Triarylsulfonium salts included in the above onium salts include, for example, a triphenylsulfonium hexafluorophosphonium salt, a triphenylsulfonium hexafluoroantimonate salt, a diphenyl-4-thiophenoxyphenylsulfonium hexafluoroantimonate salt, and a diphenyl-4-thiophenoxyphenylsulfonium pentafluoro hydroxyantimonate salt.

Sulfonium salts included in the above photoacid generator include, for example, triphenylsulfonium hexafluorophosphate, triphenylsulfonium hexafluoroantimonate, triphenylsulfonium trifluoromethanesulfonate, 4-methoxyphenyldiphenylsulfonium hexafluoroantimonate, 4-methoxyphenyldiphenylsulfonium trifluoromethanesulfonate, p-tolyldiphenylsulfonium trifluoromethanesulfonate, 2,4,6-trimethylphenyldiphenylsulfonium trifluoromethanesulfonate, 4-tert-butylphenyldiphenylsulfonium trifluoromethanesulfonate, 4-phenylthiophenyldiphenylsulfonium hexafluorophosphate, 4-phenylthiophenyldiphenylsulfonium hexafluoroantimonate, 1-(2-naphthoylmethyl)thiolanium hexafluoroantimonate, 1-(2-naphthoylmethyl)thiolanium trifluoroantimonate, 4-hydroxy-1-naphthyldimethylsulfonium hexafluoroantimonate, and 4-hydroxy-1-naphthyldimethylsulfonium trifluoromethanesulfonate.

Specifically, halogen-containing triazine compounds included in the above photoacid generator include, for example, 2-methyl-4,6-bis(trichloromethyl)-1,3,5-triazine, 2,4,6-tris(trichloromethyl)-1,3,5-triazine, 2-phenyl-4,6-bis(trichloromethyl)-1,3,5-triazine, 2-(4-chlorophenyl)-4,6-bis(trichloromethyl)-1,3,5-triazine, 2-(4-methoxyphenyl)-4,6-bis(trichloromethyl)-1,3,5-triazine, 2-(4-methoxy-1-naphthyl)-4,6-bis(trichloromethyl)-1,3,5-triazine, 2-(benzo[d][1,3]dioxolane-5-yl)-4,6-bis(trichloromethyl)-1,3,5-triazine, 2-(4-methoxystyryl)-4,6-bis(trichloromethyl)-1,3,5-triazine, 2-(3,4,5-trimethoxystyryl)-4,6-bis(trichloromethyl)-1,3,5-triazine, 2-(3,4,5-dimethoxystyryl)-4,6-bis(trichloromethyl)-1,3,5-triazine, 2-(2,4-dimethoxystyryl)-4,6-bis(trichloromethyl)-1,3,5-triazine, 2-(2-methoxystyryl)-4,6-bis(trichloromethyl)-1,3,5-triazine, 2-(4-butoxystyryl)-4,6-bis(trichloromethyl)-1,3,5-triazine, and 2-(4-benzyloxystyryl)-4,6-bis(trichloromethyl)-1,3,5-triazine.

Specifically, sulfone compounds included in the above photoacid generator include, for example, diphenyl sulfone, di-p-tolyldisulfone, bis(phenylsulfonyl)diazomethane, bis(4-chlorophenylsulfonyl)diazomethane, bis(p-tolylsulfonyl)diazomethane, bis(4-tert-butylphenylsulfonyl)diazomethane, bis(2,4-xylylsulfonyl)diazomethane, bis(cyclohexylsulfonyl)diazomethane, (benzoyl)(phenylsulfonyl)diazomethane, and phenylsulfonyl acetophenone.

Specifically, aromatic sulfonate compounds included in the above photoacid generator include, for example, α-benzoylbenzyl p-toluenesulfonate (commonly called benzoine tosylate), β-benzoyl-β-hydroxyphenetyl p-toluenesulfonate (commonly called α-methylolbenzoine tosylate), 1,2,3-benzenetoriyl trismethanesulfonate, 2,6-dinitrobenzyl p-toluenesulfonate, 2-nitrobenzyl p-toluenesulfonate, and 4-nitrobenzyl p-toluenesulfonate.

Specifically, sulfonate compounds of N-hydroxyimide included in the above photoacid generator include, for example, N-(phenylsulfonyloxy)succinimide, N-(trifluoromethylsulfonyloxy)succinimide, N-(p-chlorophenylsulfonyloxy)succinimide, N-(cyclohexylsulfonyloxy)succinimide, N-(1-naphthylsulfonyloxy)succinimide, N-(benzylsulfonyloxy)succinimide, N-(10-camphorsulfonyloxy)succinimide, N-(trifluoromethylsulfonyloxy)phthalimide, N-(trifluoromethylsulfonyloxy)-5-norbornene-2,3-dicarboxylmide, N-(trifluoromethylsulfonyloxy)naphthalimide, and N-(10-camphorsulfonyloxy)naphthalimide.

Among the various photoacid generators described above, the sulfonium salt is preferable. Especially, triphenylsulfonium trifluoromethanesulfonate, the sulfone compounds, especially, bis(4-tert-butylphenylsulfonyl) diazomethane, and bis(cyclohexylsulfonyl)diazomethane are preferable.

The above photoacid generators may be used independently or by mixing two or more of the photoacid generators. Although the blend ratio of the photoacid generator is not particularly limited and may be selected appropriately according to the purpose, the blend ratio is preferably 0.1 to 30 parts by weight based on 100 parts by weight of the hyperbranched polymer. More preferably, the blend ratio of the photoacid generator is 0.1 to 10 parts by weight.

The acid diffusion inhibitor included in the resist composition is not particularly limited as long as the inhibitor is a component having an effect of controlling diffusion phenomena of acid generated from the photoacid generator due to exposure during the resist film formation to prevent unfavorable chemical reactions in the non-exposure area. The acid diffusion inhibitor included in the resist composition may be selected appropriately from various known acid diffusion inhibitors according to the purpose.

The acid diffusion inhibitor included in the resist composition includes, for example, nitrogen-containing compounds having one nitrogen atom in the same molecule, compounds having two nitrogen atoms in the same molecule, polyamino compounds and polymers having three or more nitrogen atoms in the same molecule, amide-group-containing compounds, urea compounds, and nitrogen-containing heterocyclic compounds.

Nitrogen-containing compounds having one nitrogen atom in the same molecule and cited as a acid diffusion inhibitor include, for example, mono(cyclo)alkylamine, di(cyclo)alkylamine, tri(cyclo)alkylamine, and aromatic amine. Specifically, the mono(cyclo)alkylamine includes, for example, n-hexylamine, n-heptylamine, n-octylamine, n-nonylamine, n-decylamine, and cyclohexylamine.

Di(cyclo)alkylamine included in the nitrogen-containing compounds having one nitrogen atom in the same molecule includes, for example, di-n-butylamine, di-n-benzylamine, di-n-hexylamine, di-n-heptylamine, di-n-octylamine, di-n-nonylamine, di-n-decylamine, and cyclohexylmethylamine.

Tri(cyclo)alkylamine included in the nitrogen-containing compounds having one nitrogen atom in the same molecule includes, for example, triethylamine, tri-n-propylamine, tri-n-butylamine, tri-n-benzylamine, tri-n-hexylamine, tri-n-heptylamine, tri-n-octylamine, tri-n-nonylamine, tri-n-decylamine, cyclohexyldimethylamine, methyldicyclohexylamine, and tricyclohexylamine.

Aromatic amine included in the nitrogen-containing compounds having one nitrogen atom in the same molecule includes, for example, aniline, N-methylaniline, N,N-dimethylaniline, 2-methylaniline, 3-methylaniline, 4-methylaniline, 4-nitroaniline, diphenylamine, triphenylamine, and naphthylamine.

Nitrogen-containing compounds having two nitrogen atoms in the same molecule and cited as a acid diffusion inhibitor include, for example, ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, 2,2-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis[1-(4-aminophenyl)-1-methylethyl]benzene, 1,3-bis[1-(4-aminophenyl)-1-methylethyl]benzene, bis(2-dimethylaminoethyl)ether, and bis(2-diethylaminoethyl)ether.

Polyamino compounds and polymers having three or more nitrogen atoms in the same molecule and cited as a acid diffusion inhibitor include, for example, polyethylenimine, polyallylamine, and a polymer of n-(2-dimethylaminoethyl)acrylamide.

Amide-group-containing compounds cited as a acid diffusion inhibitor include, for example, N-t-butoxycarbonyl di-n-octylamine, N-t-butoxycarbonyl di-n-nonylamine, N-t-butoxycarbonyl di-n-decylamine, N-t-butoxycarbonyl dicyclohexylamine, N-t-butoxycarbonyl-1-adamantylamine, N-t-butoxycarbonyl-N-methyl-1-adamantylamine, N,N-di-t-butoxycarbonyl-1-adamantylamine, N,N-di-t-butoxycarbonyl-N-methyl-1-adamantylamine, N-t-butoxycarbonyl-4,4,-diaminodiphenylmethane, N,N′-di-t-butoxycarbonylhexamethylenediamine, N,N,N′N′-tetra-t-butoxycarbonylhexamethylenediamine, N,N′-di-t-butoxycarbonyl-1,7-diaminoheptane, N,N′-di-t-butoxycarbonyl-1,8-diaminooctane, N,N′-di-t-butoxycarbonyl-1,9-diaminononane, N,N-di-t-butoxycarbonyl-1,10-diaminodecane, N,N,-di-t-butoxycarbonyl-1,12-diaminododecane, N,N,-di-t-butoxycarbonyl-4,4′-diaminodiphenylmethane, N-t-butoxycarbonylbenzimidazole, N-t-butoxycarbonyl-2-methylbenzimidazole, N-t-butoxycarbonyl-2-phenylbenzimidazole, formamide, N-methylformamide, N,N-dimethylformamide, acetamide, N-methylacetamide, N,N-dimethylacetamide, propionamide, benzamide, pyrrolidone, and N-methylpyrrolidone.

Specifically, urea compounds cited as a acid diffusion inhibitor include, for example, urea, methylurea, 1,1-dimethylurea, 1,3-dimethylurea, 1,1,3,3-tetramethylurea, 1,3-diphenylurea, and tri-n-butylthiourea.

Specifically, nitrogen-containing heterocyclic compounds cited as a acid diffusion inhibitor include, for example, imidazole, 4-methylimidazole, 4-methyl-2-phenylimidazole, benzimidazole, 2-phenylbenzimidazole, pyridine, 2-methylpyridine, 4-methylpyridine, 2-ethylpyridine, 4-ethylpyridine, 2-phenylpyridine, 4-phenylpyridine, 2-methyl-4-phenylpyridine, nicotine, nicotinic acid, nicotinamide, quinoline, 4-hydroxyquinoline, 8-oxyquinoline, acridine, piperazine, 1-(2-hydroxyethyl)piperazine, pyrazine, pyrazole, pyridazine, quinoxaline, purine, pyrrolidine, piperidine, 3-piperidino-1,2-propanediol, morpholine, 4-methylmorpholine, 1,4-dimethylpiperazine, and 1,4-diazabicyclo[2.2.2]octane.

The acid diffusion inhibitors may be used independently or by mixing the two or more inhibitors. The compounding amount of the acid diffusion inhibitor is preferably 0.1 to 1000 parts by weight based on 100 parts by mass of the photoacid generator. More preferably, the compounding amount of the acid diffusion inhibitor is 0.5 to 10 parts by weight based on 100 parts by weight of the photoacid generator. The compounding amount of the acid diffusion inhibitor is not particularly limited and may appropriately be selected according to the purpose.

The surfactant included in the resist composition includes, for example, polyoxyethylene alkyl ether, polyoxyethylene alkyl aryl ether, sorbitan fatty ester, a nonionic surfactant of polyoxyethylene sorbitan fatty ester, a fluorine-containing surfactant, and a silicone-containing surfactant. The surfactant included in the resist composition is not particularly limited as long as the surfactant is a component exhibiting the effect of improving a coating property, striations, a developing property, etc., and may appropriately be selected from known surfactants according to the purpose.

Specifically, the polyoxyethylene alkyl ether cited as the surfactant included in the resist composition includes, for example, polyoxyethylene lauryl ether, polyoxyethylene stearyl ether, polyoxyethylene cetyl ether, and polyoxyethylene oleyl ether. The polyoxyethylene alkyl ether cited as the surfactant included in the resist composition includes, for example, polyoxyethylene octyl phenol ether, and polyoxyethylene nonyl phenol ether.

Specifically, sorbitan fatty ester cited as surfactant included in the resist composition includes, for example, sorbitan monolaurate, sorbitan monopalmitate, sorbitan monostearate, sorbitan monooleate, sorbitan trioleate, and sorbitan tristearate. Specifically, nonionic surfactant of polyoxyethylene sorbitan fatty ester cited as surfactant included in the resist composition includes, for example, polyoxyethylenesorbitan monolaurate, polyoxyethylenesorbitan monopalmitate, polyoxyethylenesorbitan monostearate, polyoxyethylenesorbitan trioleate, and polyoxyethylenesorbitan tristearate.

Specifically, the fluorine-containing surfactant cited as the surfactant included in the resist composition includes, for example, F Top EF301, EF303, and EF352 (manufactured by Shin Akita Kasei Co., Ltd.), Megafac F171, F173, F176, F189, and R08 (manufactured by Dainippon Ink and Chemicals, Inc.), Fluorard FC430 and FC431 (manufactured by Sumitomo 3M Ltd.), Asahi Guard AG710, Surflon S-382, SC101, SX102, SC103, SC104, SC105, and SC106 (manufactured by Asahi Glass Co., Ltd.).

The silicone-containing surfactant cited as the surfactant included in the resist composition includes, for example, organosiloxane KP341 (manufactured by Shin-Etsu Chemical Co., Ltd.). The above various surfactants may be used independently or by mixing the two or more surfactants.

The compounding amount of the above various surfactants is preferably, for example, 0.0001 to 5 parts by weight based on 100 parts by weight of the core-shell hyperbranched polymer. More preferably, the compounding amount of the above various surfactants is 0.0002 to 2 parts by weight based on 100 parts by weight of the hyperbranched polymer. The compounding amount of the above various surfactants is not particularly limited and may be selected appropriately according to the purpose.

Other components included in the resist composition include, for example, sensitizers, dissolution controllers, additives having an acid-dissociable group, alkali-soluble resins, dyes, pigments, adhesive auxiliaries, defoamers, stabilizers, and antihalation agents. Specifically, the sensitizers cited as other components included in the resist composition include, for example, acetophenones, benzophenones, naphthalenes, biacetyl, eosin, rose bengal, bylenes, anthracenes, and phenothiazine.

The sensitizers are not particularly limited provided the sensitizers have the effect of increasing the apparent sensitivity of the resist composition by absorbing energy of radiation and transferring the energy to the photoacid generator to cause the increase in the generation amount of acid. The sensitizers may be used independently or by mixing the two or more sensitizers.

Specifically, dissolution controllers cited as other components included in the resist composition include, for example, polyketone and polyspiroketal. The dissolution controllers cited as other components included in the resist composition are not particularly limited as long as the dissolution controllers more appropriately control the dissolution contrast and the dissolution rate when forming a resist. The dissolution controllers cited as other components included in the resist composition may be used independently or by mixing the two or more controllers.

Specifically, additives having an acid-dissociable group and cited as other components included in the resist composition include, for example, t-butyl 1-adamantanecarboxylate, t-butoxycarbonylmethyl 1-adamantanecarboxylate, di-t-butyl 1,3-adamantanedicarboxylate, t-butyl 1-adamantaneacetate, t-butoxycarbonylmethyl 1-adamantaneacetate, di-t-butyl 1,3-adamantanediacetate, t-butyl deoxycholate, t-butoxycarbonylmethyl deoxycholate, 2-ethoxyethyl deoxycholate, 2-cyclohexyloxyethyl deoxycholate, 3-oxocyclohexyl deoxycholate, tetrahydropyranyl deoxycholate, mevalonolactone deoxycholate ester, t-butyl lithocholate, t-butoxycarbonylmethyl lithocholate, 2-ethoxyethyl lithocholate, 2-cyclohexyloxyethyl lithocholate, 3-oxocyclohexyl lithocholate, tetrahydropyranyl lithocholate, and mevalonolactone lithocholate ester. The above various additives having an acid-dissociable group may be used independently or by mixing the two or more additives. The above various additives having an acid-dissociable group are not particularly limited as long as the additives further improve the dry etching resistance, the pattern shapes, the adhesiveness to substrates, etc.

Specifically, alkali-soluble resins cited as other components included in the resist composition include, for example, poly(4-hydroxystyrene), partially hydrogenated poly(4-hydroxystyrene), poly(3-hydroxystyrene), poly(3-hydroxystyrene), 4-hydroxystyrene/3-hydroxystyrene copolymer, 4-hydroxystyrene/styrene copolymer, novolak resin, polyvinyl alcohol, and polyacrylic acid. The weight-average molecular weights (Mw) of these alkali-soluble resins are typically and preferably 1000 to 1000000. More preferably, the weight-average molecular weights (Mw) of these alkali-soluble resins are 2000 to 100000.

The alkali-soluble resins may be used independently or by mixing the two or more resins. The alkali-soluble resins cited as other components included in the resist composition are not particularly limited as long as the alkali-soluble resins improve the alkali solubility of the resist composition of the present invention.

The dyes or pigments cited as other components included in the resist composition visualize a latent image of the exposed portion. Visualizing of the latent image of the exposed portion may alleviate the effect of the halation at the time of exposure. The adhesive auxiliaries cited as other components included in the resist composition may improve adhesiveness between the resist composition and substrates.

Specifically, solvents cited as other components included in the resist composition includes, for example, ketone, cyclic ketone, propylene glycol monoalkyl ether acetate, alkyl 2-hydroxypropionate, and alkyl 3-alkoxypropionate. The solvents cited as other components included in the resist composition are not particularly limited as long as the solvents is capable of dissolving, for example, other components included in the resist composition and may be selected appropriately from those safely used for the resist composition.

Specifically, the ketone included in the solvents cited as other components included in the resist composition includes, for example, methylisobutylketone, methylethylketone, 2-butanone, 2-pentanone, 3-methyl-2-butanone, 2-hexanone, 4-methyl-2-pentanon, 3-methyl-2-pentanon, 3,3-dimethyl-2-butanone, 2-heptanone, and 2-octanone.

Specifically, the cyclic ketone included in the solvents cited as other components included in the resist composition includes, for example, cyclohexane, cyclopentanone, 3-methylcyclopentanone, 2-methylcyclohexanone, 2,6-dimethylcyclohexanone, and isophorone.

Specifically, the propylene glycol monoalkyl ether acetate included in the solvents cited as other components included in the resist composition includes, for example, propylene glycol monomethyl ether acetate, propylene glycol monoethyl ether acetate, propylene glycol mono-n-propyl ether acetate, propylene glycol mono-1-propyl ether acetate, propylene glycol mono-n-butyl ether acetate, propylene glycol mono-1-butyl ether acetate, propylene glycol mono-sec-butyl ether acetate, and propylene glycol mono-t-butyl ether acetate.

Specifically, the alkyl 2-hydroxypropionate included in the solvents cited as other components included in the resist composition includes, for example, methyl 2-hydroxypropionate, ethyl 2-hydroxypropionate, n-propyl 2-hydroxypropionate, i-propyl 2-hydroxypropionate, n-butyl 2-hydroxypropionate, i-butyl 2-hydroxypropionate, sec-butyl 2-hydroxypropionate, and t-butyl 2-hydroxypropionate.

The alkyl 3-alkoxypropionate included in the solvents cited as other components included in the resist composition includes, for example, methyl 3-methoxypropionate, ethyl 3-methoxypropionate, methyl 3-ethoxypropionate, and ethyl 3-ethoxypropionate.

Other solvents included in the solvents cited as other components included in the resist composition include, for example, n-propyl alcohol, i-propyl alcohol, n-butyl alcohol, t-butyl alcohol, cyclohexanol, ethylene glycol monomethyl ether, ethylene glycol monoethyl ether, ethylene glycol mono-n-propyl ether, ethylene glycol mono-n-butyl ether, diethylene glycol dimethyl ether, diethylene glycol diethyl ether, diethylene glycol di-n-propyl ether, diethylene glycol di-n-butyl ether, ethylene glycol monomethyl ether acetate, ethylene glycol monoethyl ether acetate, ethylene glycol mono-n-propyl ether acetate, propylene glycol, propylene glycol monomethyl ether, propylene glycol monoethyl ether, propylene glycol mono-n-propyl ether, ethyl 2-hydroxy-2-methyl propionate, ethyl ethoxyacetate, ethyl hydroxyacetate, methyl 2-hydroxy-3-methylbutyrate, 3-methoxybutylacetate, 3-methyl-3-methoxybutylacetate, 3-methyl-3-methoxybutylpropionate, 3-methyl-3-methoxybutylbutyrate, ethyl acetate, n-propyl acetate, n-butyl acetate, methyl acetoacetoate, ethyl acetoacetate, methyl pyruvate, ethyl pyruvate, N-methyl pyrrolidone, N,N-dimethylformamide, N,N-dimethylacetamide, benzyl ethyl ether, di-n-hexyl ether, ethylene glycol monomethyl ether, diethylene glycol monoethyl ether, γ-butyrolactone, toluene, xylene, caproic acid, caprylic acid, octane, 1-octanol, 1-nonanol, benzyl alcohol, benzyl acetate, ethyl benzoate, diethyl oxalate, diethyl maleate, ethylene carbonate, and propylene carbonate. The above solvents may be used independently or by mixing the two or more solvents.

The resist composition including the core-shell hyperbranched polymer synthesized with the above method may be exposed in a pattern-like form and developed in a patterning process. The above resist composition may support electron-beam, deep-ultraviolet (DUV), and extreme-ultraviolet (EUV) light sources requiring nano-order surface smoothness and form fine patterns for manufacturing semiconductor integrated circuits. Therefore, the resist composition including the core-shell hyperbranched polymer synthesized with the above method may preferably be used in various fields using semiconductor integrated circuits manufactured with the use of light sources applying light having short wavelengths.

If a semiconductor integrated circuit manufactured with the use of the resist composition including the above core-shell hyperbranched polymer is exposed, heated, dissolved in developing liquid, and washed with water, etc., when manufactured, substantially no undissolved residue is generated and substantially perpendicular edges can be acquired.

As described above. according to the core-shell hyperbranched polymer synthesizing method of the embodiment, the core-shell hyperbranched polymer can be produced stably in large amounts without gelation.

According to the hyperbranched polymer of the embodiment, the resist composition including the core-shell hyperbranched polymer with stable performance can be manufactured in large amounts without gelation.

The present invention and the embodiment of the fifth chapter above according to the present invention will hereinafter specifically be described with the following examples. The present invention and the embodiment according to the present invention are not to be construed in a limited way from the following examples.

### (Weight-Average Molecular Weight (Mw))

The weight-average molecular weight (Mw) of the core portion of the hyperbranched polymer of the examples in chapter 5 will be described. The weight-average molecular weight (Mw) of the hyperbranched core polymer of the examples is a value obtained by preparing a 0.5 mass % tetrahydrofuran solution and performing measurement with a GPC HCL-8020 apparatus manufactured by Tosoh Corporation and two coupled TSKgel HXL-L columns (manufactured by Tosoh Corporation) under the temperature of 40 degrees C. In the measurement, tetrahydrofuran was used as a mobile solvent. In the measurement, styrene was used as a standard substance.

### (Branching Degree (Br) of Hyperbranched Core Polymer)

The branching degree (Br) of the hyperbranched core polymer according to the examples will be described. The branching degree (Br) of the hyperbranched core polymer according to the examples was obtained by measuring ¹H-NMR of the product as follows. Specifically, the branching degree (Br) was calculated according to equation (A) in chapter 1 using an integration ratio H1° of proton of the —CH₂Cl site appearing at 4.6 ppm and an integration ratio H2° of proton of the —CHCl site appearing at 4.8 ppm. If the polymerization proceeds at both the —CH₂Cl site and the —CHCl site and the branching is enhanced, the value of the branching degree (Br) approaches 0.5.

The core/shell rate of the core-shell hyperbranched polymer of the examples will be described. The core/shell rate of the core-shell hyperbranched polymer of the examples was obtained by measuring ¹H-NMR of the product as follows. The core/shell rate was calculated by using an integration ratio of proton of a t-butyl site appearing at 1.4 to 1.6 ppm and an integration ratio of proton of a aromatic site appearing near 7.2 ppm.

### (Trace Metal Analysis)

The metal contents in the core-shell hyperbranched polymer were measured by an ICP mass spectrometer (P-6000-type MIP-MS manufactured by Hitachi, Ltd.) or a flameless atomic absorption spectrometry available from PerkinElmer, Inc.

### (Ultrapure Water)

The ultrapure water of the examples will be described. The ultrapure water was produced by GSR-200 manufactured by Advantec Toyo Kaisha, Ltd., and contained 1 ppb or less of metal contents at 25 degrees C., and having a specific resistance value of 18 MΩ·cm.

In the synthesis of the hyperbranched core polymer of the examples, the following synthesis was performed with reference to synthesizing methods described in Krzysztof Matyjaszewski, Macromolecules., 29, 1079 (1996) and Jean M. J. Frecht, J. Poly. Sci., 36, 955 (1998).

### First Example

### Core-Shell Hyperbranched Polymer Synthesizing Method

### (Synthesis of Core Portion of Hyperbranched Polymer)

The synthesis of the core portion of the hyperbranched polymer (herein, hyperbranched core polymer) of a first example will be described. The core portion of the hyperbranched polymer of the first example (hereinafter, “hyperbranched core polymer”) was synthesized according to the following method. First, 18.3 g of 2,2′-bipyridyl, 5.8 g of copper(I) chloride, 441 mL of chlorobenzene, and 49 mL of acetonitrile were charged into a 1-L four-neck reactor; a reaction apparatus was assembled by attaching a dropping funnel with 90.0 g of chloromethylstyrene measured, a cooling tube, and an agitator; the inside of the reaction apparatus was entirely degassed; and the inside of the reaction apparatus was entirely replaced with argon after the degassing. After the replacement with argon, the above mixture was heated to 115 degrees C. and chloromethylstyrene was dropped into the reactor for one hour. After the dropping was completed, the mixture was heated and agitated for three hours. The reaction time was set to four hours including the time for dropping chloromethylstyrene into the reactor.

After the completion of the reaction through the heating and agitation, insoluble substances were removed by filtering the reaction system after the completion of the reaction. After the filtration, 500 mL of 3-mass % oxalic acid aqueous solution prepared with ultrapure water was added to the filtrate after the filtration and agitated for 20 minutes. After the agitation, a water layer was removed from the agitated solution. Copper, i.e., the reaction catalyst was removed by repeating, four times, the operations of adding the 3-mass % oxalic acid aqueous solution prepared with ultrapure water to the solution after the water layer was removed, agitating the solution, and removing a water layer from the agitated solution.

To the solution after the removal of copper, 700 mL of methanol was added to reprecipitate a solid content and 500 mL of a mixed solvent of THF (tetrahydrofuran):methanol=2:8 was added to the solid content acquired by reprecipitation to wash the solid content. After the washing, the solvent was removed through decantation from the solution after the washing. The operation of adding 500 mL of a mixed solvent of THF:methanol=2:8 to the solid content acquired by reprecipitation to wash the solid content was further repeated twice.

The solid content was then dried under vacuum condition of 0.1 Pa at 25 degrees C. for two hours. As a result, 64.8 g of the hyperbranched core polymer of the first example was acquired as a refined product. The yield of the acquired hyperbranched core polymer was 72%. The weight-average molecular weight (Mw) of the acquired hyperbranched core polymer was 2000, and the branching degree (Br) was 0.50.

### (Synthesis of Shell Portion of Core-Shell Hyperbranched Polymer)

The synthesis of the shell portion of the core-shell hyperbranched polymer of the first example will be described. In the synthesis of the shell portion of the core-shell hyperbranched polymer of the first example, first, 10 g of the hyperbranched core polymer of the first example, 5.1 g of 2,2′-bipyridyl, and 1.6 g of copper(I) chloride were measured and placed into a 1-L four-neck reactor with an agitator and a cooling tube attached and the whole reaction system including the reactor was vacuumed and sufficiently degassed. Under argon gas atmosphere, after 250 mL of chlorobenzene was added as a reaction solvent, 48 mL of acrylic acid tert-butyl ester was injected with by syringe and the mixture was heated and agitated at 120 degrees C. for five hours.

After the completion of the above polymerization reaction through the heating and agitation, insoluble substances were removed by filtering the reaction system after the completion of the polymerization reaction. After the filtration, 300 mL of 3-mass % oxalic acid aqueous solution was added to the filtrate after the filtration and agitated for 20 minutes. After the agitation, a water layer was removed from the agitated solution. Copper, i.e., the reaction catalyst was removed by repeating, four times, the operations of adding the 3-mass % oxalic acid aqueous solution prepared with ultrapure water to the solution after the water layer was removed, agitating the solution, and removing a water layer from the agitated solution.

Subsequently, the solvent was distilled and removed from the light yellow solution acquired after the removal of copper and 700 mL of methanol was added to the solution after the solvent was distilled and removed to reprecipitate a solid content. After the operations of dissolving the solid content acquired by the reprecipitation into 50 mL of THF and adding 500 mL of methanol to reprecipitate a solid content were further repeated twice, the solid content was dried under vacuum condition of 0.1 Pa at 25 degrees C. for three hours.

As a result, 17.1 g of a light yellow solid substance, i.e., the core-shell hyperbranched polymer was acquired as a refined product. The yield of the acquired light yellow solid substance was 76%. A molar rate of the acquired core-shell hyperbranched polymer was calculated with ¹H-NMR. As a result, the core/shell ratio of the core-shell hyperbranched polymer was 40/60 (molar ratio).

### (Removal of Trace Metal)

The removal of the trace metal of the example will be described. In the removal of the trace metal of the example, a solution acquired by dissolving 6 g of the above core-shell hyperbranched polymer with the shell portion formed into chloroform was mixed with 100 g of 3-mass % oxalic acid aqueous solution prepared with ultrapure water and was agitated vigorously for 30 minutes. After the agitation, an organic layer was extracted from the agitated solution and the extracted organic layer was mixed again with 100 g of 3-mass % oxalic acid aqueous solution prepared with ultrapure water and was agitated vigorously for 30 minutes. After the agitation, an organic layer was extracted from the agitated solution.

The operations of mixing the extracted organic layer with 3-mass % oxalic acid aqueous solution prepared with ultrapure water again and intensely agitating the mixture was repeated five times in total. The agitated solution was mixed with 100 g of 3-mass % hydrochloric acid aqueous solution and agitated vigorously for 30 minutes and an organic layer was extracted from the agitated solution.

Subsequently, the operations of mixing the solution after extracting the organic later with 100 g of the ultrapure water, intensely agitating the mixture, and extracting an organic later from the agitated solution were repeated three times. The finally acquired organic layer was distilled to remove the solvent and dried under vacuum condition of 0.1 Pa at 25 degrees C. for three hours, and the metal contents in the solid content after the removal of the solvent were measured as above. As a result, amounts of copper, sodium, iron, and aluminum contained in the solid content after the removal of the solvent were not greater than 10 ppb.

### (Deprotection)

The deprotection of the first example will be described. In the deprotection of the third example, 0.6 g of the solid content after the removal of the solvent above was collected in a reactor with a reflux tube, and 30 mL of dioxane and 0.6 mL of hydrochloric acid (30%) were added thereto and heated and agitated at 90 degrees C. for 60 minutes. The reaction crude product acquired by the heating and agitation was poured into 300 mL of ultrapure water and reprecipitated and the solvent was removed through decantation.

The reprecipitated solid content was dissolved by adding 30 mL of dioxane and a solid content was reprecipitated again by pouring the solution into 300 mL of ultrapure water. The solid content acquired by the reprecipitation was collected and dried under vacuum condition of 0.1 Pa at 25 degrees C. for three hours to acquire the core-shell hyperbranched polymer of the first example. The amount of the core-shell hyperbranched polymer of the first example was 0.4 g and the yield was 66%. A rate of the acid-degradable group and the acid group was 78/22 (molar ratio).

### Second Example

### Synthesis of Core Portion of Core-Shell Hyperbranched Polymer

The synthesis of the core portion of the hyperbranched polymer (hereinafter, “hyperbranched core polymer”) of a second example will be described. For the hyperbranched core polymer of the second example, first, 54.6 g of tributylamine and 18.7 g of iron(II) chloride were measured and placed into a 1-L four-neck reactor with an agitator and a cooling tube attached and the whole reaction system including the reactor was vacuumed and sufficiently degassed. Under an argon gas atmosphere, 430 mL of chlorobenzene was added as a reaction solvent; 90.0 g of chloromethylstyrene was dropped for five minutes; and the mixture was heated and agitated while maintaining a constant internal temperature of 125 degrees C. The reaction time was set to 27 minutes including the dropping time.

After the completion of the above reaction through the heating and agitation, 500 mL of 3-mass % oxalic acid aqueous solution prepared with ultrapure water was added to the reaction system after the completion of the reaction and agitated for 20 minutes. After the agitation, a water layer was removed from the agitated solution. Iron, i.e., the reaction catalyst was removed by repeating, four times, the operations of adding 3-mass % oxalic acid aqueous solution prepared with ultrapure water, agitating the solution, and removing a water layer from the agitated solution.

To the solution after the removal of iron, 700 mL of methanol was added to reprecipitate a solid content; 1200 mL of a mixed solvent of THF:methanol=2:8 was added to the solid content acquired by reprecipitation to wash the polymer; and the solvent was removed through decantation from the solution after the washing.

Subsequently, 500 mL of a mixed solvent of THF:methanol=2:8 was added to the solid content acquired after the removal of the solvent to wash the polymer. After the washing, the solvent was removed through decantation from the solution after the washing. The solution after the removal of the solvent was dried under vacuum condition of 0.1 Pa at 25 degrees C. for three hours.

As a result, 72 g of the hyperbranched core polymer of the second example was acquired as a refined product. The yield of the acquired hyperbranched core polymer was 80%. The weight-average molecular weight (Mw) of the acquired hyperbranched core polymer was 2000, and the branching degree (Br) was 0.50.

### (Synthesis of Shell Portion of Hyperbranched Polymer)

The synthesis of the shell portion of the core-shell hyperbranched polymer of the second example will be described. In the synthesis of the shell portion of the core-shell hyperbranched polymer of the second example, first, 10 g of the hyperbranched core polymer of the second example, 6.1 g of tributylamine, and 2.1 g of iron(II) chloride were measured and placed into a 1-L four-neck reactor with an agitator and a cooling tube attached and the whole reaction system including the reactor was vacuumed and sufficiently degassed. Under an argon gas atmosphere, after 260 mL of chlorobenzene was added as a reaction solvent, 48 mL of acrylic acid tert-butyl ester was injected by syringe and the mixture was heated and agitated at 120 degrees C. for five hours.

After the completion of the above polymerization reaction through the heating and agitation, 3-mass % oxalic acid aqueous solution was added to the reaction system after the completion of the polymerization reaction and agitated for 20 minutes. After the agitation, a water layer was removed from the agitated solution. Iron, i.e., the reaction catalyst was removed by repeating four times the operations of adding 3-mass % oxalic acid aqueous solution prepared with ultrapure water to the solution after the water layer was removed, agitating the solution, and removing a water layer from the agitated solution.

To the solution after the removal of iron, 700 mL of methanol was added to reprecipitate a solid content. After the operation of adding 500 mL of methanol to the solid content acquired by the reprecipitation to reprecipitate the solid content was repeated twice, the solid content was dried under vacuum condition of 0.1 Pa at 25 degrees C. for three hours.

As a result, 22 g of a light yellow solid substance, i.e., the core-shell hyperbranched polymer was acquired as a refined product. The yield of the acquired light yellow solid substance was 74%. A molar rate of the acquired core-shell hyperbranched polymer was calculated with ¹H-NMR. As a result, the core/shell ratio of the core-shell hyperbranched polymer was 30/70 (molar ratio).

The removal of the trace metal of the second example will be described. In the removal of the trace metal of the second example, a solution acquired by dissolving 6 g of the above core-shell hyperbranched polymer with the shell portion formed into chloroform was mixed with 50 g of 3-mass % oxalic acid aqueous solution and 50 g of 1-mass % hydrochloric acid aqueous solution prepared with ultrapure water and was agitated vigorously for 30 minutes. After the agitation, an organic layer was extracted from the agitated solution and the extracted organic layer was mixed again with 50 g of 3-mass % oxalic acid aqueous solution and 50 g of 1-mass % hydrochloric acid aqueous solution prepared with ultrapure water and was agitated vigorously for 30 minutes. After the agitation, an organic layer was extracted from the agitated solution.

The operations of mixing the extracted organic layer with 3-mass % oxalic acid aqueous solution prepared with ultrapure water again and intensely agitating the mixture was repeated five times in total. The agitated solution was mixed with 100 g of 3-mass % hydrochloric acid aqueous solution and agitated vigorously for 30 minutes and an organic layer was extracted from the agitated solution.

Subsequently, the operations of mixing the solution after extracting the organic later with 100 g of the ultrapure water, intensely agitating the mixture for 30 minutes, and extracting an organic later from the agitated solution were repeated three times. The finally acquired organic layer was distilled to remove the solvent and dried under vacuum condition of 0.1 Pa at 25 degrees C. for three hours, and the metal contents in the solid content after the removal of the solvent were measured. As a result, amounts of copper, sodium, iron, and aluminum contained in the solid content after the removal of the solvent were not greater than 10 ppb.

### (Deprotection)

The deprotection of the second example will be described. In the deprotection of the second example, 0.6 g of the solid content after the removal of the solvent above was collected in a reactor with a reflux tube, and 30 mL of dioxane and 0.6 mL of hydrochloric acid (30%) were added thereto and heated and agitated at 90 degrees C. for 60 minutes. The reaction crude product acquired by the heating and agitation was poured into 300 mL of ultrapure water and reprecipitated and the solvent was removed through decantation.

The reprecipitated solid content was dissolved by adding 30 mL of dioxane and a solid content was reprecipitated again by pouring the solution into 300 mL of ultrapure water. The solid content acquired by the reprecipitation was collected and dried under vacuum condition of 0.1 Pa at 25 degrees C. for three hours to acquire the core-shell hyperbranched polymer of the second example. The amount of the core-shell hyperbranched polymer of the second example was 0.4 g and the yield was 66%. A rate of the acid-degradable group and the acid group was 80/20 (molar ratio).

### Third Example

### Synthesis of Core Portion of Core-Shell Hyperbranched Polymer

The core portion of the core-shell hyperbranched polymer (hereinafter, “hyperbranched core polymer”) of a third example will be described. The hyperbranched polymer of the third example was synthesized in the following method. First, 11.8 g of 2,2′-bipyridyl, 3.5 g of copper(I) chloride, and 345 mL of benzonitrile were charged into a 1-L four-neck reactor; a reaction apparatus was assembled by attaching a dropping funnel with 54.2 g of chloromethylstyrene measured, a cooling tube, and an agitator; the inside of the reaction apparatus was entirely degassed; and the inside of the reaction apparatus was entirely replaced with argon after the degassing. After the replacement with argon, the above mixture was heated to 125 degrees C. and chloromethylstyrene was dropped for 30 minutes. After the dropping was completed, the mixture was heated and agitated for 3.5 hours. The reaction time was set to four hours including the time for dropping chloromethylstyrene into the reactor.

After the reaction was completed, the reaction solution was filtrated with the use of filter paper having a retention particle size of 1 μm, and the filtrate was added to a mixed solution acquired by preliminarily mixing 844 g of methanol and 211 g of the ultrapure water to reprecipitate poly(chloromethylstyrene).

After dissolving 29 g of the polymer acquired by the reprecipitation into 100 g of benzonitrile, a mixed solution of 200 g of methanol and 50 g of ultrapure water was added and the solvent was removed through decantation after centrifugal separation to collect the polymer. This collecting operation was repeated three times to acquire a polymer precipitate.

After the decantation, the precipitate was dried under reduced pressure at 25 degrees C. acquiring 14.0 g of poly(chloromethylstyrene). The yield was 26%. The weight-average molecular weight (Mw) of the polymer obtained by the GPC measurement (in terms of polystyrene) was 1140, and the branching degree (Br) obtained by the ¹H-NMR measurement was 0.51.

### (Synthesis of Shell Portion of Core-Shell Hyperbranched Polymer)

The synthesis of the shell portion of the core-shell hyperbranched polymer of the third example will be described. The shell portion of the core-shell hyperbranched polymer of the third example was synthesized in the following method. By syringe, 248 mL of monochlorobenzene and 48 mL of acrylic acid tert-butyl ester were injected respectively into a 500-mL four-neck reactor under an argon gas atmosphere and containing 1.6 g of copper(I) chloride, 5.1 g of 2,2′-bipyridyl, and 10.0 g of the hyperbranched core polymer. After the substances were injected into the reactor, the mixture in the reactor was heated and agitated at 125 degrees C. for five hours.

After the completion of the above polymerization reaction through the heating and agitation, insoluble substances were removed by filtering the reaction system after the completion of the polymerization reaction. Subsequently, 615 g of mixed acid aqueous solution containing 3 mass % of oxalic acid and 1 mass % of hydrochloric acid prepared with ultrapure water was added to 308 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 62.5 g of condensed liquid. By sequentially adding 219 g of methanol and 31 g of ultrapure water to the acquired condensed liquid, a solid content was precipitated. The solid content acquired by the precipitation was dissolved into 20 g of THF to acquire a solution, and 200 g of methanol and 29 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 23.8 g. The molar rate of the copolymer (the core-shell hyperbranched polymer with the shell portion formed) was calculated with ¹H-NMR. The core/shell rate of the core-shell hyperbranched polymer with the shell portion formed was 30/70.

### Fourth Example

The core-shell hyperbranched polymer of a fourth example will be described. For the core-shell hyperbranched polymer of the third example, the deprotection was performed with the use of the core-shell hyperbranched polymer of the third example before the filtration.

### (Deprotection)

The deprotection of the fourth example will be described. In the deprotection of the fourth example, first, 2.0 g of the copolymer (the core-shell hyperbranched polymer of the third example) was collected in a reactor with a reflux tube and 18.0 g of 1,4-dioxane and 0.2 g of 50-mass % sulfuric acid were added thereto. Subsequently, reflux agitation was performed for 60 minutes while the whole reaction system including the reactor with the reflux tube was heated at a temperature for reflux. After the reflux agitation, the reaction crude product after the reflux agitation was poured into 180 mL of ultrapure water to precipitate a solid content.

After the solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.6 g of polymer. A rate of the acid-degradable group and the acid group was 78/22 (molar ratio).

### Fifth Example

The core-shell hyperbranched polymer of a fifth example will be described. In the core-shell hyperbranched polymer of the fifth example, the shell portion was synthesized with the use of the core portion of the core-shell hyperbranched polymer of the third example (hereinafter, “hyperbranched core polymer”).

### (Synthesis of Shell Portion of Core-Shell Hyperbranched Polymer)

The synthesis of the shell portion of the core-shell hyperbranched polymer of the fifth example will be described. The shell portion of the core-shell hyperbranched polymer of the fifth example was synthesized in the following method. By syringe, 248 mL of monochlorobenzene and 81 mL of acrylic acid tert-butyl ester were injected respectively into a 500-mL four-neck reactor under an argon gas atmosphere and containing 1.6 g of copper(I) chloride, 5.1 g of 2,2′-bipyridyl, and 10.0 g of the hyperbranched core polymer of the third example above. After the substances were injected into the reactor, the mixture in the reactor was heated and agitated at 125 degrees C. for five hours.

After the completion of the above polymerization reaction through the heating and agitation, insoluble substances were removed by filtering the reaction system after the completion of the polymerization reaction. Subsequently, 680 g of mixed acid aqueous solution containing 3 mass % of oxalic acid and 1 mass % of hydrochloric acid prepared with ultrapure water was added to 340 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 88.0 g of condensed liquid. By sequentially adding 308 g of methanol and 44 g of ultrapure water to the acquired condensed liquid, a solid content was precipitated. The solid content acquired by the precipitation was dissolved into 44 g of THF to acquire a solution, and 440 g of methanol and 63 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 33.6 g. The molar rate of the copolymer (the core-shell hyperbranched polymer with the shell portion formed) was calculated with ¹H-NMR. The core/shell rate of the core-shell hyperbranched polymer with the shell portion formed was 19/81 (molar ratio).

### (Deprotection)

The deprotection of the fifth example will be described. In the deprotection of the fifth example, first, 2.0 g of the copolymer (the core-shell hyperbranched polymer of the fifth example) was collected in a reactor with a reflux tube and 18.0 g of 1,4-dioxane and 0.2 g of 50-mass % sulfuric acid were added thereto. Subsequently, reflux agitation was performed for 60 minutes while the whole reaction system including the reactor with the reflux tube was heated at a temperature for reflux. After the reflux agitation, the reaction crude product after the reflux agitation was poured into 180 mL of ultrapure water to precipitate a solid content.

After the solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.6 g of polymer. A rate of the acid-degradable group and the acid group was 92/8 (molar ratio).

### Sixth Example

The core-shell hyperbranched polymer of a sixth example will be described. In the core-shell hyperbranched polymer of the sixth example, the shell portion was synthesized with the use of the core portion of the core-shell hyperbranched polymer of the third example (hereinafter, “hyperbranched core polymer”).

### (Synthesis of Shell Portion of Core-Shell Hyperbranched Polymer)

The synthesis of the shell portion of the core-shell hyperbranched polymer of the sixth example will be described. The shell portion of the core-shell hyperbranched polymer of the sixth example was synthesized in the following method. By syringe, 248 mL of monochlorobenzene and 187 mL of acrylic acid tert-butyl ester were injected respectively into a 1000-mL four-neck reactor under an argon gas atmosphere and containing 1.6 g of copper(I) chloride, 5.1 g of 2,2′-bipyridyl, and 10.0 g of the hyperbranched core polymer of the third example above. After the substances were injected into the reactor, the mixture in the reactor was heated and agitated at 125 degrees C. for five hours.

After the completion of the above polymerization reaction through the heating and agitation, insoluble substances were removed by filtering the reaction system after the completion of the polymerization reaction. Subsequently, 880 g of mixed acid aqueous solution containing 3 mass % of oxalic acid and 1 mass % of hydrochloric acid prepared with ultrapure water was added to 440 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 175 g of condensed liquid. By sequentially adding 613 g of methanol and 88 g of ultrapure water to the acquired condensed liquid, a solid content was precipitated. The solid content acquired by the precipitation was dissolved into 85 g of THF to acquire a solution, and 850 g of methanol and 121 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 65.9 g. The molar rate of the copolymer (the core-shell hyperbranched polymer with the shell portion formed) was calculated with ¹H-NMR. The core/shell rate of the core-shell hyperbranched polymer with the shell portion formed was 10/90 (molar ratio).

### (Deprotection)

The deprotection of the sixth example will be described. In the deprotection of the sixth example, first, 2.0 g of the copolymer (the core-shell hyperbranched polymer of the sixth example) was collected in a reactor with a reflux tube and 18.0 g of 1,4-dioxane and 0.2 g of 50-mass % sulfuric acid were added thereto. Subsequently, reflux agitation was performed for 15 minutes while the entire reaction system including the reactor with the reflux tube was heated at a temperature for reflux. After the reflux agitation, the reaction crude product after the reflux agitation was poured into 180 mL of ultrapure water to precipitate a solid content.

After the solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.7 g of polymer. A rate of the acid-degradable group and the acid group was 95/5 (molar ratio).

### Seventh Example

The core-shell hyperbranched polymer of a seventh example will be described. In the core-shell hyperbranched polymer of the seventh example, the shell portion was synthesized with the use of the core portion of the core-shell hyperbranched polymer of the third example (hereinafter, “hyperbranched core polymer”).

(Synthesis of Shell Portion of Core-Shell Hyperbranched polymer)

The synthesis of the shell portion of the core-shell hyperbranched polymer of the seventh example will be described. The shell portion of the core-shell hyperbranched polymer of the seventh example was synthesized in the following method. By syringe, 248 mL of monochlorobenzene and 14 mL of acrylic acid tert-butyl ester were injected respectively into a 500-mL four-neck reactor under an argon gas atmosphere and containing 1.6 g of copper(I) chloride, 5.1 g of 2,2′-bipyridyl, and 10.0 g of the hyperbranched core polymer of the third example above. After the substances were injected into the reactor, the mixture in the reactor was heated and agitated at 125 degrees C. for five hours.

After the completion of the above polymerization reaction through the heating and agitation, insoluble substances were removed by filtering the reaction system after the completion of the polymerization reaction. Subsequently, 570 g of mixed acid aqueous solution containing 3 mass % of oxalic acid and 1 mass % of hydrochloric acid prepared with ultrapure water was added to 285 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 32 g of condensed liquid. By sequentially adding 112 g of methanol and 16 g of ultrapure water to the acquired condensed liquid, a solid content was precipitated. The solid content acquired by the precipitation was dissolved into 16 g of THF to acquire a solution, and 160 g of methanol and 23 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 12.1 g. The molar rate of the copolymer (the core-shell hyperbranched polymer with the shell portion formed) was calculated with ¹H-NMR. The core/shell rate of the core-shell hyperbranched polymer with the shell portion formed was 61/39 (molar ratio).

### (Deprotection)

The deprotection of the seventh example will be described. In the deprotection of the seventh example, first, 2.0 g of the copolymer (the core-shell hyperbranched polymer of the seventh example) was collected in a reactor with a reflux tube and 18.0 g of 1,4-dioxane and 0.2 g of 50-mass % sulfuric acid were added thereto. Subsequently, reflux agitation was performed for 150 minutes while the entire reaction system including the reactor with the reflux tube was heated at a temperature for reflux. After the reflux agitation, the reaction crude product after the reflux agitation was poured into 180 mL of ultrapure water to precipitate a solid content.

After the solid content acquired by reprecipitation was dissolved into 50 g of methyl isobutyl ketone, 50 g of ultrapure water was added and intense agitation was performed for 30 minutes at room temperature. After a water layer was separated, 50 g of ultrapure water was added again and agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.4 g of polymer. A rate of the acid-degradable group and the acid group was 49/51 (molar ratio).

### First Reference Example

### Synthesis of 4-Vinylbenzoic Acid Tert-Butyl Ester

The synthesis of 4-vinylbenzoic acid tert-butyl ester will be described. In a first reference example, 4-vinylbenzoic acid tert-butyl ester was synthesized according to the following synthesizing method with reference to Synthesis, 833-834 (1982).

In the synthesis of 4-vinylbenzoic acid tert-butyl ester of the first reference example, first, into a 1-L reactor with a dropping funnel attached, 91 g of 4-vinylbenzoic acid, 99.5 g of 1,1′-carbodiimidazole, 2.4 g of 4-tert-butylpyrocatechol, and 500 g of dehydrated dimethylformamide were added under an argon gas atmosphere and agitated for one hour while maintaining the while reaction system including the reactor at 30 degrees C. After the agitation, 93 g of 1,8-diazabicyclo[5.4.0]-7-undecene and 91 g of dehydrated 2-methyl-2-propanol were added thereto and agitated for four hours.

After the above reaction through the agitation was completed, 300 mL of diethyl ether and 10% potassium carbonate aqueous solution were added to the reaction system to extract the objective substance, i.e., 4-vinylbenzoic acid tert-butyl ester into the ether layer.

After the extraction, the diethyl ether layer acquired by the extraction was dried under reduced pressure acquiring a light yellow liquid. The acquisition of the objective substance, i.e., 4-vinylbenzoic acid tert-butyl ester was confirmed by ¹H-NMR. The yield of 4-vinylbenzoic acid tert-butyl ester of the first reference example was 88%.

### Eighth Example

### Synthesis of Core Portion of Core-Shell Hyperbranched Polymer

The synthesis of the core portion of the core-shell hyperbranched polymer (hereinafter, “hyperbranched core polymer”) of an eighth example will be described. In the synthesis of the hyperbranched core polymer of the eighth example, 25.5 g of pentamethyldiethylenetriamine and 14.6 g of copper(I) chloride were measured and placed into a 1-L four-neck reactor with an agitator and a cooling tube attached and the whole reaction system including the reactor was vacuumed and sufficiently degassed. Under an argon gas atmosphere, 460 mL of chlorobenzene was added as a reaction solvent; 90.0 g of chloromethylstyrene was dropped for five minutes; and the mixture was heated and agitated while maintaining a constant temperature of the whole reaction system including the reactor at 125 degrees C. The reaction time was set to 27 minutes including the dropping time.

After the completion of the reaction through the heating and agitation, insoluble substances were removed by filtering the reaction system after the completion of the reaction. After the filtration, 500 mL of 3-mass % oxalic acid aqueous solution prepared with ultrapure water was added to the filtrate after the filtration and agitated for 20 minutes. After the agitation, a water layer was removed from the agitated solution. Copper, i.e., the reaction catalyst was removed by repeating, four times, the operations of adding the 3-mass % oxalic acid aqueous solution prepared with ultrapure water to the solution after the water layer was removed, agitating the solution, and removing a water layer from the agitated solution.

To the solution after the removal of copper, 700 mL of methanol was added to reprecipitate a solid content and 1200 mL of a mixed solvent of THF:methanol=2:8 was added to the solid content acquired by reprecipitation to wash the solid content. After the washing, the solvent was removed through decantation from the solution after the washing. The operation of adding 500 mL of a mixed solvent of THF:methanol=2:8 to the solid content acquired by reprecipitation to wash the solid content was further repeated twice.

The solid content was then dried under vacuum condition of 0.1 Pa at 25 degrees C. for two hours. As a result, the hyperbranched core polymer of the eighth example was acquired as a refined product. The yield of the acquired hyperbranched core polymer was 72%. The weight-average molecular weight (Mw) of the acquired hyperbranched core polymer was 2000, and the branching degree (Br) was 0.50.

### (Synthesis of Shell Portion of Core-Shell Hyperbranched Polymer)

The synthesis of the shell portion of the core-shell hyperbranched polymer of the eighth example will be described. In the synthesis of the shell portion of the core-shell hyperbranched polymer of the eighth example, first, 10 g of the hyperbranched core polymer of the eighth example, 2.8 g of pentamethyldiethylenetriamine, and 1.6 g of copper(I) chloride were measured and placed into a 1-L four-neck reactor with an agitator and a cooling tube attached and the whole reaction system including the reactor was vacuumed and sufficiently degassed. Under an argon gas atmosphere, after 400 mL of chlorobenzene was added as a reaction solvent, 40 g of 4-vinylbenzoic acid tert-butyl ester synthesized in the first reference example above was injected by syringe and the mixture was heated and agitated at 120 degrees C. for three hours.

After the completion of the above polymerization reaction through the heating and agitation, insoluble substances were removed by filtering the reaction system after the completion of the polymerization reaction. After the filtration, 3-mass % oxalic acid aqueous solution was added to the filtrate after the filtration and agitated for 20 minutes. After the agitation, a water layer was removed from the agitated solution. Copper, i.e., the reaction catalyst was removed by repeating, four times, the operations of adding the 3-mass % oxalic acid aqueous solution prepared with ultrapure water to the solution after the water layer was removed, agitating the solution, and removing a water layer from the agitated solution.

Subsequently, 700 mL of methanol was added to the solution acquired after the removal of copper to reprecipitate a solid content. After the operations of dissolving the solid content acquired by the reprecipitation into 50 mL of THF and adding 500 mL of methanol to reprecipitate a solid content were further repeated twice, the solid content was dried under vacuum condition of 0.1 Pa at 25 degrees C. for three hours.

As a result, 20 g of a light yellow solid substance, i.e., the core-shell hyperbranched polymer was acquired as a refined product. The yield of the acquired light yellow solid substance was 48%. A molar rate of the acquired core-shell hyperbranched polymer was calculated with ¹H-NMR. As a result, the core/shell ratio of the core-shell hyperbranched polymer was 30/70 (molar ratio).

### (Removal of Trace Metal)

The removal of the trace metal of the eighth example will be described. In the removal of the trace metal of the eighth example, a solution acquired by dissolving 6 g of the above core-shell hyperbranched polymer with the shell portion formed into chloroform was mixed with 50 g of 3-mass % oxalic acid aqueous solution and 50 g of 1-mass % hydrochloric acid aqueous solution prepared with ultrapure water and was agitated vigorously for 30 minutes. After the agitation, an organic layer was extracted from the agitated solution and the extracted organic layer was mixed again with 50 g of 3-mass % oxalic acid aqueous solution and 50 g of 1-mass % hydrochloric acid aqueous solution prepared with ultrapure water and was agitated vigorously for 30 minutes. After the agitation, an organic layer was extracted from the agitated solution.

The operations of mixing the extracted organic layer with 50 g of 3-mass % oxalic acid aqueous solution and 50 g of 1-mass % hydrochloric acid aqueous solution prepared with ultrapure water again and intensely agitating the mixture was repeated five times in total. The agitated solution was mixed with 100 g of 3-mass % hydrochloric acid aqueous solution and agitated vigorously for 30 minutes and an organic layer was extracted from the agitated solution.

Subsequently, the operations of mixing the solution after extracting the organic later with 100 g of the ultrapure water, intensely agitating the mixture for 30 minutes, and extracting an organic later from the agitated solution were repeated three times. The finally acquired organic layer was distilled to remove the solvent and dried under vacuum condition of 0.1 Pa at 25 degrees C. for three hours, and the metal contents in the solid content after the removal of the solvent were measured as described above. As a result, amounts of copper, sodium, iron, and aluminum contained in the solid content after the removal of the solvent were not greater than 10 ppb.

### (Deprotection)

The deprotection of the eighth example will be described. In a reactor with a reflux tube, 2.0 g of the copolymer was collected; 98.0 g of dioxane and 3.5 g of 30-mass % sulfuric acid were added thereto; and reflux agitation was performed at 95 degrees C. for 60 minutes. The reaction crude product was poured into 980 mL of ultrapure water and reprecipitated acquiring a solid substance. The solid content was dissolved into 80 mL of dioxane and reprecipitated again by adding 800 mL of ultrapure water to remove the acid catalyst. The solid content was collected and dried under vacuum condition of 0.1 Pa at 25 degrees C. for three hours acquiring a polymer. The amount of the acquired polymer was 1.6 g and the yield was 82%. A rate of the acid-degradable group and the acid group was 75/25 (molar ratio).

### Ninth Example

The core-shell hyperbranched polymer of a ninth example will be described. In the core-shell hyperbranched polymer of the ninth example, the shell portion was synthesized with the use of the core portion of the core-shell hyperbranched polymer of the third example (hereinafter, “hyperbranched core polymer”).

### (Synthesis of Shell Portion of Core-Shell Hyperbranched Polymer)

The synthesis of the shell portion of the core-shell hyperbranched polymer of the ninth example will be described. The shell portion of the core-shell hyperbranched polymer of the ninth example was synthesized by the following method. By syringe, 421 mL of monochlorobenzene and 46.8 g of tert-butyl 4-vinylbenzoate were injected respectively into a 1000-mL four-neck reactor under an argon gas atmosphere and containing 0.8 g of copper(I) chloride, 2.6 g of 2,2′-bipyridyl, and 5.0 g of the hyperbranched core polymer of the third example above. After the substances were injected into the reactor, the mixture in the reactor was heated and agitated at 125 degrees C. for 3.5 hours.

After the completion of the above polymerization reaction through the heating and agitation, insoluble substances were removed by filtering the reaction system. Subsequently, 980 g of mixed acid aqueous solution containing 3 mass % of oxalic acid and 1 mass % of hydrochloric acid prepared with ultrapure water was added to 490 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 41 g of condensed liquid. By sequentially adding 144 g of methanol and 21 g of ultrapure water to the acquired condensed liquid, a solid content was precipitated. The solid content acquired by the precipitation was dissolved into 21 g of THF to acquire a solution, and 210 g of methanol and 30 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 15.9 g. The molar rate of the copolymer (the core-shell hyperbranched polymer with the shell portion formed) was calculated with ¹H-NMR. The core/shell rate of the core-shell hyperbranched polymer with the shell portion formed was 29/71 (molar ratio).

### (Deprotection)

The protection of the ninth example will be described. In the protection of the acid-degradable group of the ninth example, 2.0 g of the copolymer (the above core-shell hyperbranched polymer of the ninth example) was collected in a reactor with a reflux tube and 18.0 g of 1,4-dioxane and 0.2 g of 50-mass % sulfuric acid were added thereto. Subsequently, reflux agitation was performed for 180 minutes while the whole reaction system including the reactor with the reflux tube was heated to a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and the solution was agitated vigorously for 30 minutes at room temperature. After a water layer was separated, 50 g of ultrapure water was added again and the solution was agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.7 g of polymer. A rate of the acid-degradable group and the acid group was 38/62.

### Tenth Example

The core-shell hyperbranched polymer of a tenth example will be described. In the core-shell hyperbranched polymer of the tenth example, the shell portion was synthesized with the use of the core portion of the core-shell hyperbranched polymer of the third example (hereinafter, “hyperbranched core polymer”).

### (Synthesis of Shell Portion of Core-Shell Hyperbranched Polymer)

The synthesis of the shell portion of the core-shell hyperbranched polymer of the tenth example will be described. The shell portion of the core-shell hyperbranched polymer of the tenth example was synthesized by the following method. By syringe, 421 mL of monochlorobenzene and 46.8 g of tert-butyl 4-vinylbenzoate were injected respectively into a 1000-mL four-neck reactor under an argon gas atmosphere and containing 1.6 g of copper(I) chloride, 5.1 g of 2,2′-bipyridyl, and 5.0 g of the hyperbranched core polymer of the third example above. After the substances were injected into the reactor, the mixture in the reactor was heated and agitated at 125 degrees C. for 3 hours.

After the completion of the above polymerization reaction through the heating and agitation, insoluble substances were removed by filtering the reaction system. Subsequently, 980 g of mixed acid aqueous solution containing 3 mass % of oxalic acid and 1 mass % of hydrochloric acid prepared with ultrapure water was added to 490 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 64 g of condensed liquid. By sequentially adding 224 g of methanol and 32 g of ultrapure water to the acquired condensed liquid, a solid content was precipitated. The solid content acquired by the precipitation was dissolved into 32 g of THF to acquire a solution, and 320 g of methanol and 46 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 24.5 g. The molar rate of the copolymer (the core-shell hyperbranched polymer with the shell portion formed) was calculated with ¹H-NMR. The core/shell rate of the core-shell hyperbranched polymer with the shell portion formed was 20/80 (molar ratio).

### (Deprotection)

The protection of the tenth example will be described. In the protection of the acid-degradable group of the tenth example, 2.0 g of the copolymer (the above core-shell hyperbranched polymer of the tenth example) was collected in a reactor with a reflux tube and 18.0 g of 1,4-dioxane and 0.2 g of 50-mass % sulfuric acid were added thereto. Subsequently, reflux agitation was performed for 90 minutes while the whole reaction system including the reactor with the reflux tube was heated to a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and the solution was agitated vigorously for 30 minutes at room temperature. After a water layer was separated, 50 g of ultrapure water was added again and the solution was agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.7 g of polymer. A rate of the acid-degradable group and the acid group was 71/29.

### Eleventh Example

The core-shell hyperbranched polymer of an eleventh example will be described. The core-shell hyperbranched polymer of the eleventh example was synthesized with the use of the core portion of the core-shell hyperbranched polymer (hereinafter, “hyperbranched core polymer”) of the third example.

### (Synthesis of Shell Portion of Core-Shell Hyperbranched Polymer)

The synthesis of the shell portion of the core-shell hyperbranched polymer of the eleventh example will be described. The shell portion of the core-shell hyperbranched polymer of the eleventh example was synthesized by the following method. By syringe, 530 mL of monochlorobenzene and 60.2 g of tert-butyl 4-vinylbenzoate were injected respectively into a 1000-mL four-neck reactor under an argon gas atmosphere and containing 1.6 g of copper(I) chloride, 5.1 g of 2,2′-bipyridyl, and 5.0 g of the hyperbranched core polymer of the third example above. After the substances were injected into the reactor, the mixture in the reactor was heated and agitated at 125 degrees C. for 4 hours.

After the completion of the above polymerization reaction through the heating and agitation, insoluble substances were removed by filtering the reaction system. Subsequently, 1240 g of mixed acid aqueous solution containing 3 mass % of oxalic acid and 1 mass % of hydrochloric acid prepared with ultrapure water was added to 620 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 130 g of condensed liquid. By sequentially adding 455 g of methanol and 65 g of ultrapure water to the acquired condensed liquid, a solid content was precipitated. The solid content acquired by the precipitation was dissolved into 32 g of THF to acquire a solution, and 650 g of methanol and 93 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 50.2 g. The molar rate of the copolymer (the core-shell hyperbranched polymer with the shell portion formed) was calculated with ¹H-NMR. The core/shell rate of the core-shell hyperbranched polymer with the shell portion formed was 9/91 (molar ratio).

### (Deprotection)

The protection of the eleventh example will be described. In the protection of the acid-degradable group of the eleventh example, 2.0 g of the copolymer (the above core-shell hyperbranched polymer of the eleventh example) was collected in a reactor with a reflux tube and 18.0 g of 1,4-dioxane and 0.2 g of 50-mass % sulfuric acid were added thereto. Subsequently, reflux agitation was performed for 30 minutes while the whole reaction system including the reactor with the reflux tube was heated to a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and the solution was agitated vigorously for 30 minutes at room temperature. After a water layer was separated, 50 g of ultrapure water was added again and the solution was agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.7 g of polymer. A rate of the acid-degradable group and the acid group was 92/8.

### Twelfth Example

The core-shell hyperbranched polymer of a twelfth example will be described. The core-shell hyperbranched polymer of the twelfth example was synthesized with the use of the core portion of the core-shell hyperbranched polymer (hereinafter, “hyperbranched core polymer”) of the third example.

### (Synthesis of Shell Portion of Core-Shell Hyperbranched Polymer)

The synthesis of the shell portion of the core-shell hyperbranched polymer of the twelfth example will be described. The shell portion of the core-shell hyperbranched polymer of the twelfth example was synthesized by the following method. By syringe, 106 mL of monochlorobenzene and 8.0 g of tert-butyl 4-vinylbenzoate were injected respectively into a 300-mL four-neck reactor under an argon gas atmosphere and containing 0.8 g of copper(I) chloride, 2.6 g of 2,2′-bipyridyl, and 5.0 g of the hyperbranched core polymer of the third example above. After the substances were injected into the reactor, the mixture in the reactor was heated and agitated at 125 degrees C. for 1 hour.

After the completion of the above polymerization reaction through the heating and agitation, insoluble substances were removed by filtering the reaction system. Subsequently, 254 g of mixed acid aqueous solution containing 3 mass % of oxalic acid and 1 mass % of hydrochloric acid prepared with ultrapure water was added to 127 g of the filtrate acquired through the filtration and agitated for 20 minutes. After the agitation, a water layer was removed from the agitated reaction system. Copper, i.e., the reaction catalyst was removed by repeating, four times, the operations of adding the above mixed acid aqueous solution containing oxalic acid and hydrochloric acid to the polymer solution after the water layer was removed, agitating the solution, and removing a water layer from the agitated solution.

The light yellow solution after the removal of copper was condensed under reduced pressure of 15 mmHg at 40 degrees C. acquiring 19 g of condensed liquid. By sequentially adding 67 g of methanol and 10 g of ultrapure water to the acquired condensed liquid, a solid content was precipitated. The solid content acquired by the precipitation was dissolved into 10 g of THF to acquire a solution, and 100 g of methanol and 14 g of ultrapure water were sequentially added to this solution to reprecipitate a solid content.

After the above reprecipitation operation, the solid content was collected through centrifugal separation and dried under the condition of 0.1 mmHg at 40 degrees C. for two hours acquiring a light yellow solid substance as a refined product. The yield of the core-shell hyperbranched polymer with the shell portion formed was 7.3 g. The molar rate of the copolymer (the core-shell hyperbranched polymer with the shell portion formed) was calculated with ¹H-NMR. The core/shell rate of the core-shell hyperbranched polymer with the shell portion formed was 60/40 (molar ratio).

### (Deprotection)

The protection of the twelfth example will be described. In the protection of the acid-degradable group of the twelfth example, 2.0 g of the copolymer (the above core-shell hyperbranched polymer of the twelfth example) was collected in a reactor with a reflux tube and 18.0 g of 1,4-dioxane and 0.2 g of 50-mass % sulfuric acid were added thereto. Subsequently, reflux agitation was performed for 240 minutes while the whole reaction system including the reactor with the reflux tube was heated to a temperature for reflux. After the reflux agitation, the reaction crude product after the reflux agitation was poured into 180 mL of ultrapure water to precipitate a solid content.

After a solid content acquired by reprecipitation was dissolved into 50 g of methyl isobutyl ketone, 50 g of ultrapure water was added and the solution was agitated vigorously for 30 minutes at room temperature. After a water layer was separated, 50 g of ultrapure water was added again and the solution was agitated vigorously for 30 minutes at room temperature, and a water layer was separated. The operations of adding 50 g of ultrapure water and separating the water layer after 30 minutes of intense agitation at room temperature were further repeated twice. The methyl isobutyl ketone solution was distilled under reduced pressure to remove the solvent and was dried under reduced pressure at 40 degrees C. acquiring 1.4 g of polymer. A rate of the acid-degradable group and the acid group was 22/78.

### First Comparative Example

### Synthesis of Core Portion of Core-Shell Hyperbranched Polymer

The synthesis of the core portion of the hyperbranched polymer (hereinafter, “hyperbranched core polymer”) of a first comparative example will be described. The hyperbranched core polymer was synthesized by the following method. First, 18.3 g of 2,2′-bipyridyl, 5.8 g of copper(I) chloride, 441 mL of chlorobenzene, and 49 mL of acetonitrile were charged into a 1-L four-neck reactor; a reaction apparatus was assembled by attaching a dropping funnel with 90.0 g of chloromethylstyrene measured, a cooling tube, and an agitator; the inside of the reaction apparatus was entirely degassed; and the inside of the reaction apparatus was entirely replaced with argon after the degassing. After the replacement with argon, the above mixture was heated to 115 degrees C. and chloromethylstyrene was dropped into the reactor for one hour. After the dropping was completed, the mixture was heated and agitated for three hours. The reaction time was set to four hours including the time for dropping chloromethylstyrene into the reactor.

After the completion of the reaction through the heating and agitation, insoluble substances were removed by filtering the reaction system after the completion of the reaction. After the filtration, 500 mL of 3-mass % oxalic acid aqueous solution prepared with ultrapure water was added to the filtrate after the filtration and agitated for 20 minutes. After the agitation, a water layer was removed from the agitated solution. Copper, i.e., the reaction catalyst was removed by repeating, four times, the operations of adding the 3-mass % oxalic acid aqueous solution prepared with ultrapure water to the solution after the water layer was removed, agitating the solution, and removing a water layer from the agitated solution.

To the solution after the removal of copper, 700 mL of methanol was added to reprecipitate a solid content. Subsequently, after repeating twice the operations of adding 500 mL of a mixed solvent of THF:methanol=2:8 to the solid content acquired by reprecipitation to wash the solid content and removing the solvent through decantation from the solution after the washing, the solid content was dried under vacuum condition of 0.1 Pa at 100 degrees C. for two hours. As a result, the reaction system was gelatinized and the washed solid substance could not be refined.

### Second Comparative Example

### Synthesis of Core Portion of Core-Shell Hyperbranched Polymer

The synthesis of the core portion of the core-shell hyperbranched polymer of a second comparative example will be described. The core portion of the core-shell hyperbranched polymer of the second comparative example was synthesized as follows. First, 11.8 g of 2,2′-bipyridyl, 3.5 g of copper(I) chloride, and 345 mL of benzonitrile were charged into a 1-L four-neck reactor; a reaction apparatus was assembled by attaching a dropping funnel with 54.2 g of chloromethylstyrene measured, a cooling tube, and an agitator; the inside of the reaction apparatus was entirely degassed; and the inside of the reaction apparatus was entirely replaced with argon after the degassing. After the replacement with argon, the above mixture was heated to 125 degrees C. and chloromethylstyrene was dropped for 30 minutes. After the dropping was completed, the mixture was heated and agitated for 3.5 hours. The reaction time was set to four hours including the time for dropping chloromethylstyrene into the reactor.

After the reaction was completed, the reaction solution was filtrated with the use of filter paper having a retention particle size of 1 μm, and the filtrate was added to a mixed solution acquired by preliminarily mixing 844 g of methanol and 211 g of the ultrapure water to reprecipitate poly(chloromethylstyrene).

After dissolving 29 g of the polymer acquired by the reprecipitation into 100 g of benzonitrile, a mixed solution of 200 g of methanol and 50 g of ultrapure water was added and the solvent was removed through decantation after centrifugal separation to collect the polymer. This collecting operation was repeated three times to acquire a polymer precipitate.

After the decantation, the precipitate was dried under vacuum condition of 0.1 Pa at 100 degrees C. for two hours. As a result, the reaction system was gelatinized and the washed solid substance could not to be refined.

### (Preparation of Resist Composition)

The preparation of the resist compositions of the examples will be described. In the examples, the resist compositions of the examples were prepared by creating a propylene glycol monomethyl acetate (PEGMEA) solution containing 4.0 mass % of the respective core-shell hyperbranched polymers of the above first to twelfth examples and 0.16 mass % of triphenylsulfonium trifluoromethanesulfonate as a photoacid generator and by filtrating the solution with a filter having a fine pore size of 0.45 μm.

Silicon wafers were spin-coated with the resist compositions prepared as above and the solvent was evaporated by performing one-minute heat treatments at 90 degrees C. for the silicon wafers spin-coated with the resist compositions. As a result, thin films with a thickness of 100 nm were created on the silicon wafers.

### (Measurement of Sensitivity to Ultraviolet Radiation)

The sensitivity to ultraviolet radiation of the resist compositions of the examples will be described. The sensitivity to ultraviolet radiation of the resist compositions of the examples was measured by the following method. In the measurement of sensitivity to ultraviolet radiation of the resist compositions of the examples, a discharge tube type ultraviolet light irradiation apparatus (DF-245 Donafix manufactured by ATTO Corporation) was used as a light source.

The thin films were exposed by applying ultraviolet light having a wavelength of 245 nm to a rectangular portion having a length of 10 mm and width of 3 mm of the thin films formed on the silicon wafers with the use of the above light source. At the time of the exposure, an energy amount was changed from 0 mJ/cm² to 50 mJ/cm². After the exposure, the silicon wafer was treated with heat at 110 degrees C. for four minutes and developed by immersing the heat-treated silicon wafers in 2.4-mass % tetramethylammonium hydroxide (TMAH) aqueous solution at 25 degrees C. for 2 minutes. After the development, the silicon wafers were washed with water and dried and the film thickness after the drying was measured to measure applied energy values (sensitivity) when the film thickness after the development was zero. The measurement was performed with the use of a thin film measurement apparatus (film measurement apparatus F20 manufactured by Filmetrics, Inc.). The result of the measurement is depicted in Table 8.

TABLE 8

| | sensitivity (mJ/cm²) |
|---|---|
| first example | 1 |
| second example | 1 |
| third example | 3 |
| fourth example | 1 |
| fifth example | 1 |
| sixth example | 1 |
| seventh example | 1 |
| eighth example | 1 |
| ninth example | 3 |
| tenth example | 1 |
| eleventh example | 1 |
| twelfth example | 1 |

1. A hyperbranched polymer synthesizing method of synthesizing a hyperbranched polymer by causing living radical polymerization of a monomer in the presence of a metal catalyst, wherein the hyperbranched polymer synthesizing method includes at least adding a compound or setting an amount of the monomer in the living radical polymerization,
the adding of a compound includes adding at least a compound represented by R₁-A or a compound represented by R₂—B—R₃, where R₁ of the compound denotes hydrogen, an alkyl group having 1 to 10 carbon atoms, an aryl group having 1 to 10 carbon atoms, or an aralkyl group having 7 to 10 carbon atoms, A of the compound denotes a cyano group, a hydroxyl group, or a nitro group, R₂ and R₃ of the compound denote hydrogen, alkyl groups having 1 to 10 carbon atoms, aryl groups having 6 to 10 carbon atoms, aralkyl groups having 7 to 10 carbon atoms, or dialkylamino groups having 2 to 10 carbon atoms, and B of the compound denotes a carbonyl group or a sulfonyl group, and
the setting of an amount of the monomer includes setting the amount of the monomer to be mixed into a reaction system at one mixing to be less than a total amount of the monomer to be mixed with the reaction system.

2. The hyperbranched polymer synthesizing method according to claim 1, wherein the setting of an amount of the monomer includes dividing the monomer among a plurality of mixings.

3. The hyperbranched polymer synthesizing method according to claim 1, wherein the setting of an amount of the monomer includes mixing the monomer by dropping the monomer for a predetermined time period.

4. The hyperbranched polymer synthesizing method of synthesizing a hyperbranched polymer by polymerizing a monomer capable of living radical polymerization in the presence of a metal catalyst according to claim 1, further comprising:
generating a precipitate by mixing a mixed solvent consisting of two or more solvents and having a solubility parameter of 10.5 or more with a reaction solution containing a hyperbranched polymer synthesized by living radical polymerization.

5. The hyperbranched polymer synthesizing method according to claim 4, wherein at the generating of a precipitate, the precipitate is generated by mixing 0.2 to 10 parts by volume of the solvent relative to the reaction solution.

6. The hyperbranched polymer synthesizing method according to claim 4, further comprising:
generating a core-shell hyperbranched polymer having a shell portion formed by introducing an acid-degradable group into a core portion that is the precipitate generated at the generating of a precipitate; and
forming an acid group by an acid catalyst to degrade a portion of the acid-degradable group constituting the shell portion of the core-shell hyperbranched polymer generated at the generating of a core-shell hyperbranched polymer.

7. The hyperbranched polymer synthesizing method of synthesizing a core-shell hyperbranched polymer having an acid group and an acid-degradable group in a shell portion according to claim 1, further comprising:
obtaining the core-shell hyperbranched polymer by synthesizing a core portion by polymerizing a monomer capable of living radical polymerization in the presence of a metal catalyst and to the core portion, introducing an acid-degradable group to form the shell portion;
obtaining a hyperbranched polymer having a metal content 100 ppb or less by washing the hyperbranched polymer having the acid-degradable group in the shell portion with pure water; and
forming the acid group by subsequently degrading, by an acid catalyst, a portion of the acid-degradable group constituting the shell portion.

8. The hyperbranched polymer synthesizing method according to claim 7, wherein a total content of the pure water is 10 ppb or less at 25 degrees C.

9. The hyperbranched polymer synthesizing method according to claim 7, wherein at the obtaining of a hyperbranched polymer, filtration with a microfilter is performed in addition to the washing with the pure water.

10. The hyperbranched polymer synthesizing method of synthesizing a core-shell hyperbranched polymer having an acid group and an acid-degradable group in a shell portion according to claim 1, further comprising:
obtaining the core-shell hyperbranched polymer by synthesizing a core portion by polymerizing a monomer capable of living radical polymerization in the presence of a metal catalyst and to the core portion, introducing an acid-degradable group to form the shell portion;
obtaining a hyperbranched polymer having a metal content 100 ppb or less by washing the hyperbranched polymer having the acid-degradable group in the shell portion with pure water and an aqueous solution of an organic compound having chelating ability and/or an aqueous solution of an inorganic acid; and
forming the acid group by subsequently degrading, by an acid catalyst, a portion of the acid-degradable group constituting the shell portion.

11. The hyperbranched polymer synthesizing method according to claim 10, wherein a total metal content of the pure water is 10 ppb or less at 25 degrees C.

12. The hyperbranched polymer synthesizing method according to claim 10, wherein at the obtaining of a hyperbranched polymer, filtration with a microfilter is performed in addition to the washing with the pure water.

13. The hyperbranched polymer synthesizing method according to claim 10, wherein
the organic compound having chelating ability used at the obtaining of a hyperbranched polymer is an organic carboxylic acid selected from among formic acid, oxalic acid, acetic acid, citric acid, gluconic acid, tartaric acid, and malonic acid, and
the inorganic acid is hydrochloric acid or sulfuric acid.

14. The hyperbranched polymer synthesizing method according to claim 1, further comprising:
polymerizing by causing living radical polymerization of a monomer in the presence of a metal catalyst;
refining by using a reprecipitating method to collect a polymer polymerized at the polymerizing, from a reaction solution containing the polymer; and
filtering, through a filter having a pore diameter of 0.1 μm or less, the polymer refined at the refining.

15. The hyperbranched polymer synthesizing method according to claim 14, wherein
the polymer polymerized at the polymerizing is a core-shell hyperbranched polymer containing an acid-degradable group in a shell portion.

16. The hyperbranched polymer synthesizing method of synthesizing a hyperbranched polymer through living radical polymerization of a monomer in the presence of a metal catalyst according to claim 1, further comprising:
removing the metal catalyst in a reaction system where the hyperbranched polymer has been synthesized by the living radical polymerization; and
drying, at 10 to 70 degrees C., a solvent in the reaction system to remove the solvent after the removing of the metal catalyst.

17. The hyperbranched polymer synthesizing method according to claim 16, wherein
at the drying, pressure of the reaction system is reduced to a pressure lower than atmospheric pressure to achieve a vacuum state.

18. A hyperbranched polymer synthesized according to the hyperbranched polymer synthesizing method according to claim 1.

19. A resist composition containing the hyperbranched polymer according to claim 18.

20. A semiconductor integrated circuit having a pattern formed with the resist composition according to claim 19.

21. A semiconductor integrated circuit fabrication method comprising forming a pattern using the resist composition according to claim 19.

22. (canceled)
